(19) United States
(12) Patent Application Publication
(10) Pub. No.: US 2026/0060001 A1
(43) Pub. Date: Feb. 26, 2026

(54) ORGANIC COMPOUND, MIXTURE, COMPOSITION, ORGANIC LIGHT-EMITTING DEVICE AND DISPLAY PANEL

(71) Applicant: GUANGZHOU CHINARAY OPTOELECTRONIC MATERIALS LTD., Guangzhou (CN)

(72) Inventors: Xinlong SONG, Guangzhou (CN); Wenhong DENG, Guangzhou (CN); Jinlong LEI, Guangzhou (CN); Huaqiang FAN, Guangzhou (CN); Fangyi LIU, Guangzhou (CN); Ruifeng HE, Guangzhou (CN); Jingyao SONG, Guangzhou (CN)

(73) Assignee: GUANGZHOU CHINARAY OPTOELECTRONIC MATERIALS LTD., Guangzhou (CN)

(21) Appl. No.: 19/021,003

(22) Filed: Jan. 14, 2025

(30) Foreign Application Priority Data
Aug. 22, 2024 (CN) 202411163442.8

(51) Int. Cl. H10K 85/60; C07F 5/02; C07F 7/08; C09K 11/06; H10K 50/12; H10K 85/40

(52) U.S. Cl. CPC H10K 85/636; C07F 5/027; C07F 7/0812; C09K 11/06; H10K 85/40; C09K 2211/1007; C09K 2211/1011; C09K 2211/1018; H10K 50/12; H10K 85/624; H10K 85/6572; H10K 85/6574; H10K 85/6576; H10K 85/658

(57) ABSTRACT

An organic compound, an organic light-emitting device and a display panel are disclosed herein; the organic compound has a structure as represented by general formula (1) or general formula (2):

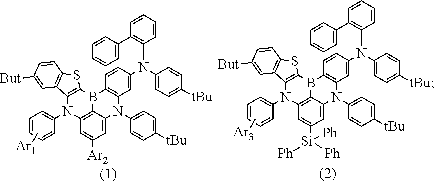

The present application can make the organic compound easily purified, thereby improving the purity of the organic compound, and further improving a luminescence efficiency and service life of the organic light-emitting device made from the organic compound.

### CROSS-REFERENCE TO RELATED APPLICATION

The present application claims a priority of Chinese patent application No. 202411163442.8, filed on Aug. 22, 2024, the entire disclosures of which are hereby incorporated by reference.

### TECHNICAL FIELD

The present application relates to the field of display technology, and in particular to an organic compound, a mixture, a composition, an organic light-emitting device and a display panel.

### BACKGROUND

At present, an organic electroluminescent element such as an organic light-emitting diode (OLED) generally has an anode, a cathode, and an organic layer located between the two, and the organic material of the organic layer is utilized to convert electrical energy into light energy, thereby realizing an organic electroluminescence. In order to improve a luminescence efficiency and a service life of the organic electroluminescent element, the organic layer is often multi-layered, and the organic matter of each layer is different. Specifically, the organic layer mainly includes a hole injection layer, a hole transport layer, a light-emitting layer, an electron transport layer, an electron injection layer and so on. When a voltage is applied between the anode and the cathode of the organic electroluminescent element, the anode injects holes into the organic layer, and the cathode injects electrons into the organic layer. The injected holes meet with the electrons to form excitons, and the excitons emit light when transition back to a ground state, thereby realizing the luminescence of the organic electroluminescent element. The organic electroluminescent element has the characteristics such as self-luminescence, high brightness, high efficiency, low voltage drive, wide viewing angle, high contrast, and high response. Therefore, the organic electroluminescent device has broad application prospects.

### SUMMARY

The embodiments of the present application provide an organic compound, a mixture, a composition, an organic light-emitting device and a display panel, such that the organic compound is easily purified, enhancing the purity of the organic compound, and improving the luminescence efficiency and the service life of the organic light-emitting device prepared from the organic compound.

In order to achieve the above object, an embodiment of the present application provides an organic compound, wherein the organic compound has a structure as represented by general formula (1) or general formula (2):

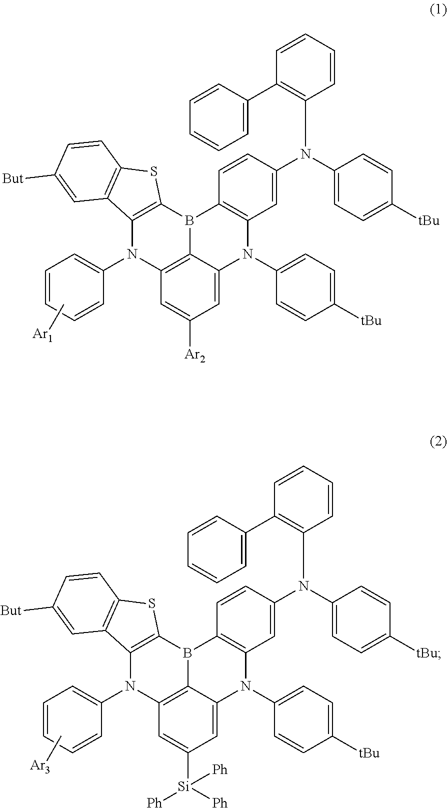

Ar₁ and Ar₃ are selected from a group represented by any one of formula (A-1) to formula (A-8):

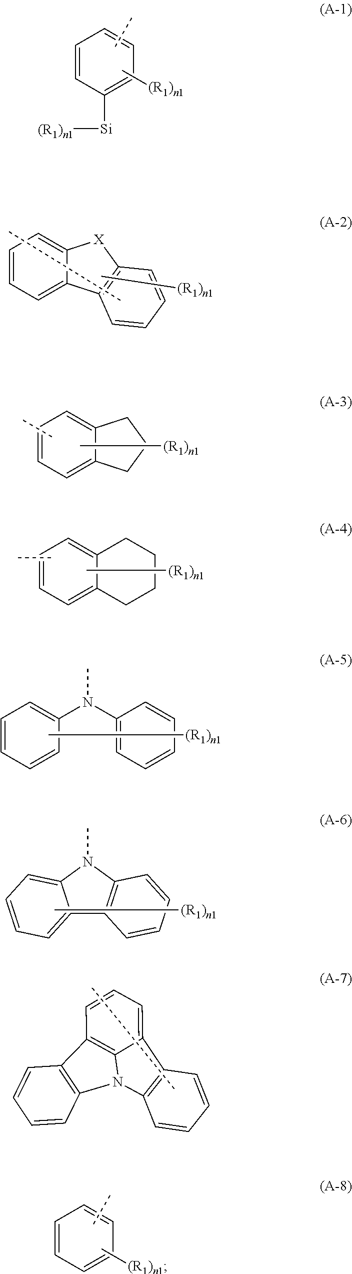

Ar₂ is selected from a group represented by any one of formula (B-1) to formula (B-9):

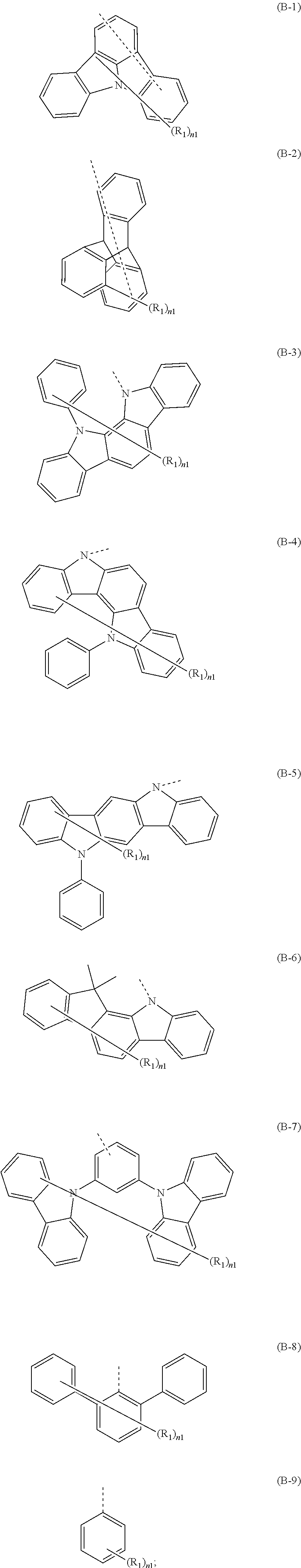

X is selected from O, S, N—CH₃, N-Ph or C(CH₃)₂;
n1 is selected from 0, 1, 2, 3, 4, 5, 6, 7, 8, 9 or 10;
R₁ is selected from H, D, a linear alkyl group having a carbon atom number ranging from 1 to 20, a linear silicon group having a carbon atom number ranging from 1 to 20, a branched silicon group having a carbon atom number ranging from 1 to 20, a linear alkoxy group having a carbon atom number ranging from 1 to 20, a linear thioalkoxy group having a carbon atom number ranging from 1 to 20, a branched alkyl group having a carbon atom number ranging from 3 to 20, a cyclic alkyl group having a carbon atom number ranging from 3 to 20, a branched alkoxy group having a carbon atom number ranging from 3 to 20, a cyclic alkoxy group having a carbon atom number ranging from 3 to 20, a branched thioalkoxy group having a carbon atom number ranging from 3 to 20, a cyclic thioalkoxy group having a carbon atom number ranging from 3 to 20, a silyl group, a trimethylsilyl group, a triphenylsilyl group, a keto group having a carbon atom number ranging from 1 to 20, an alkoxycarbonyl group having a carbon atom number ranging from 2 to 20, an aryloxycarbonyl group having a carbon atom number ranging from 7 to 20, an olefin group having a carbon atom number ranging from 1 to 20, CN, a carbamoyl group, a haloformyl group, a formyl group, isocyano, an isocyanate group, a thiocyanate group, an isothiocyanate group, a hydroxyl group, a nitro group, CF₃, Cl, Br, F, a substituted or unsubstituted aromatic group having a ring atom number ranging from 6 to 30, a substituted or unsubstituted heteroaromatic group having a ring atom number ranging from 5 to 30, a substituted or unsubstituted aryloxy group having a ring atom number ranging from 6 to 30, or a substituted or unsubstituted heteroaryloxy group having a ring atom number ranging from 5 to 30.

In one embodiment of the present application, Ar₂ is selected from the group represented by any one of the formulas (B-1) to (B-8);

Alternatively, when Ar₂ is selected from the group represented by the formula (B-9), Ar₁ is selected from the structure represented by any one of the formulas (A-1) to (A-7).

In one embodiment of the present application, Ar₃ is selected from the group represented by any one of the formulas (A-1) to (A-7).

In one embodiment of the present application, R₁ is selected from H, D, a linear alkyl group having carbon atom number ranging 1 to 10, a branched-chain alkyl group having a carbon atom number ranging 3 to 10, and a cyclic alkyl group having a carbon atom number ranging 3 to 10.

In one embodiment of the present application, R₁ is selected from H, D, a linear alkyl group having a carbon atom number ranging 1 to 4, and a branched-chain alkyl group having a carbon atom number ranging 3 to 5.

In one embodiment of the present application, when Ar₁ is a group represented by the formula (A-2), the group represented by the formula (A-2) is selected from:
at least one of

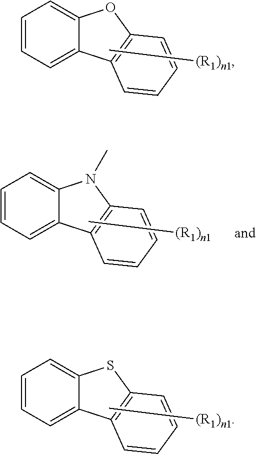

In one embodiment of the present application, the organic compound is a blue light-emitting material.

In one embodiment of the present application, the organic compound is selected from the following compounds:

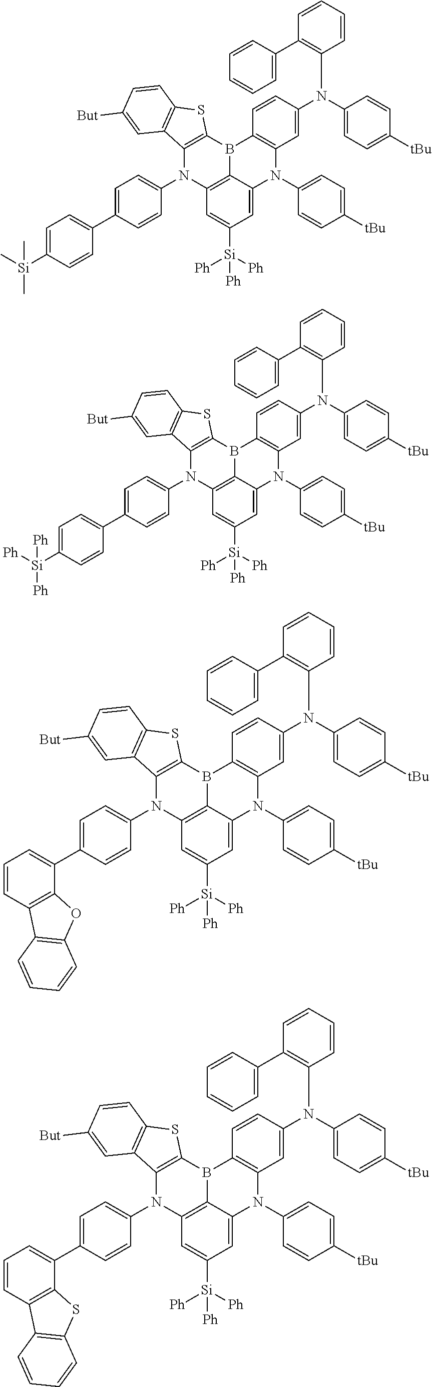

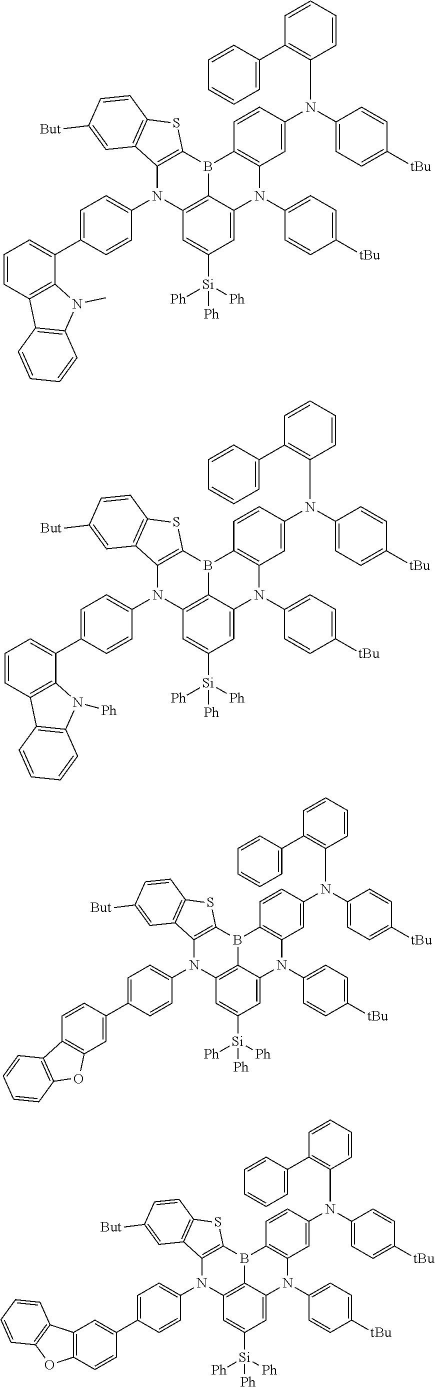

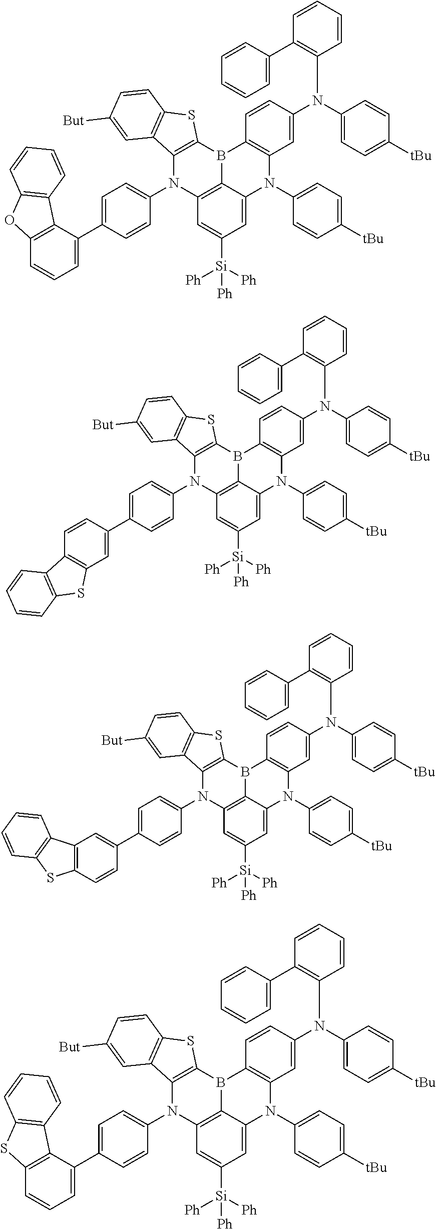

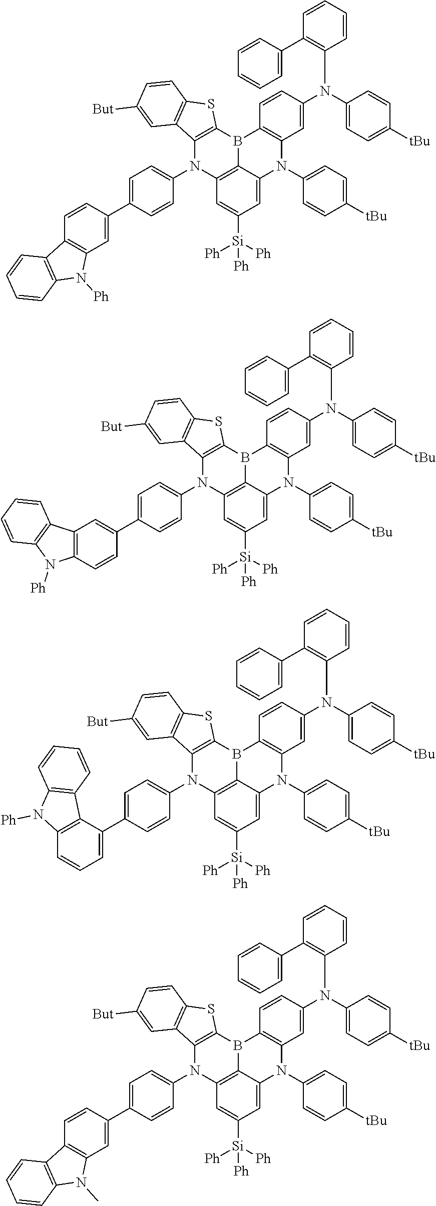

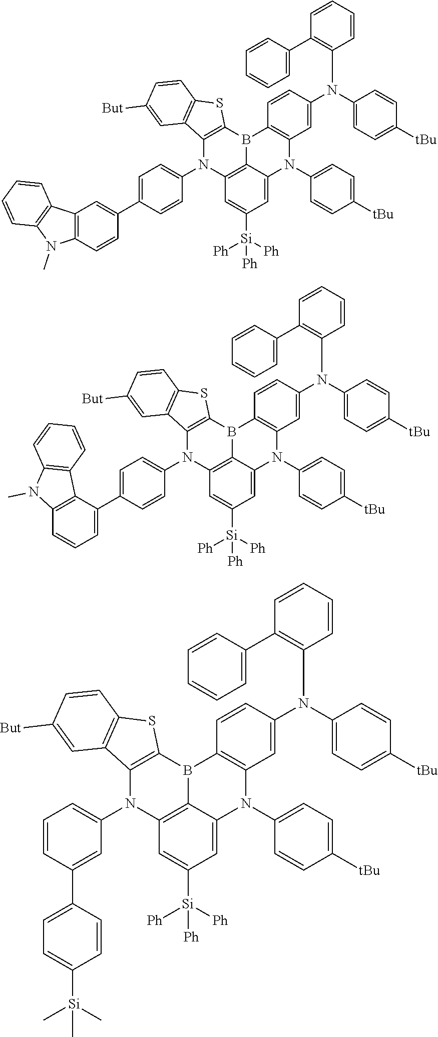

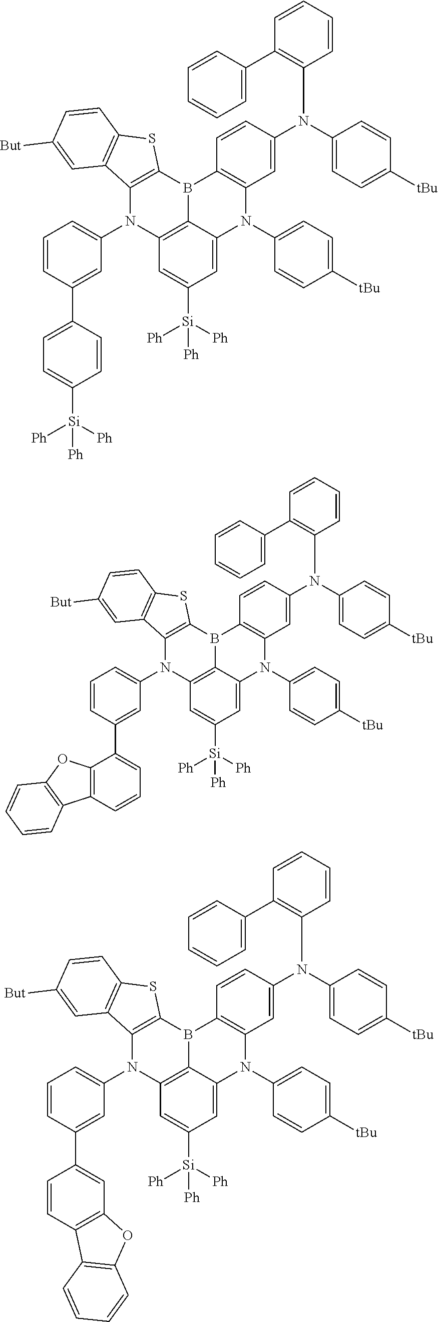

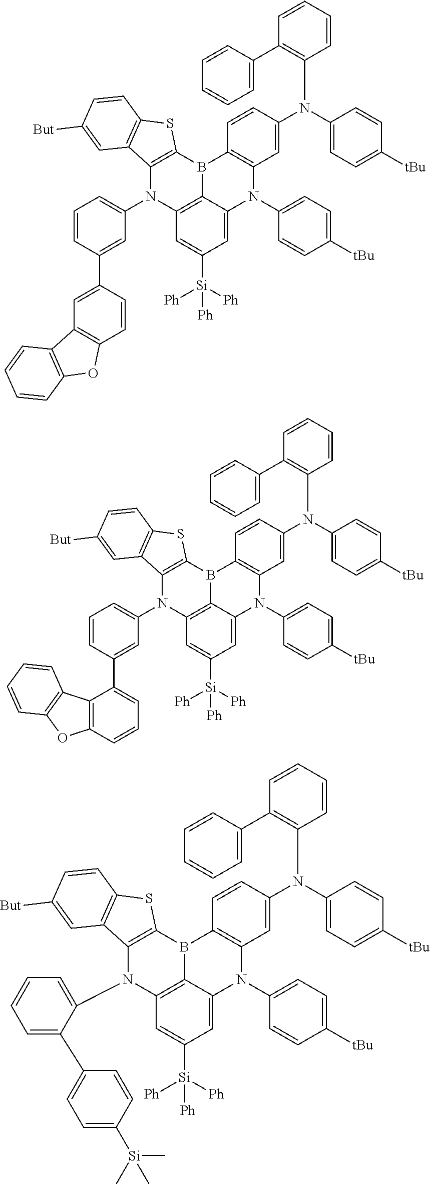

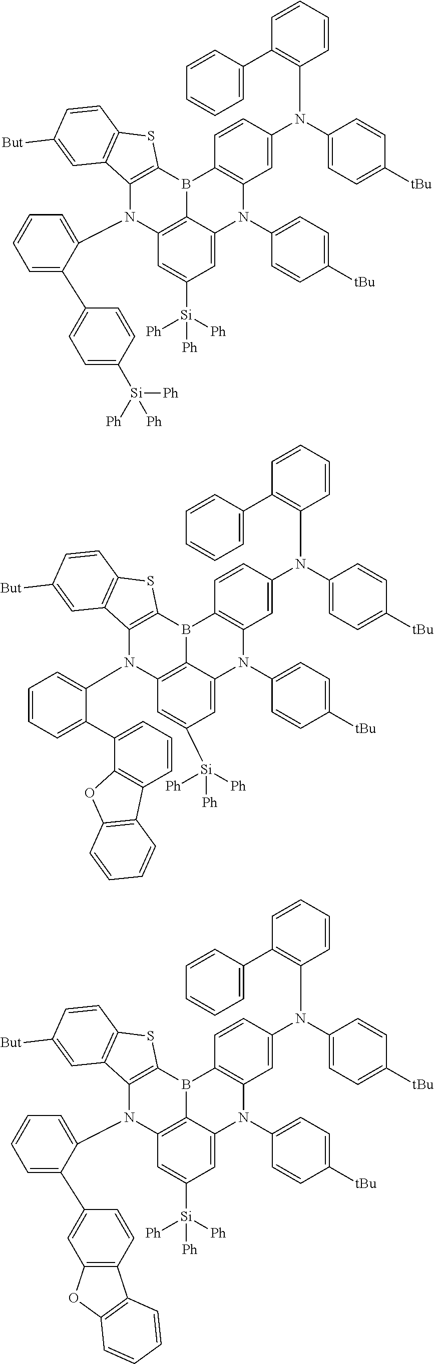

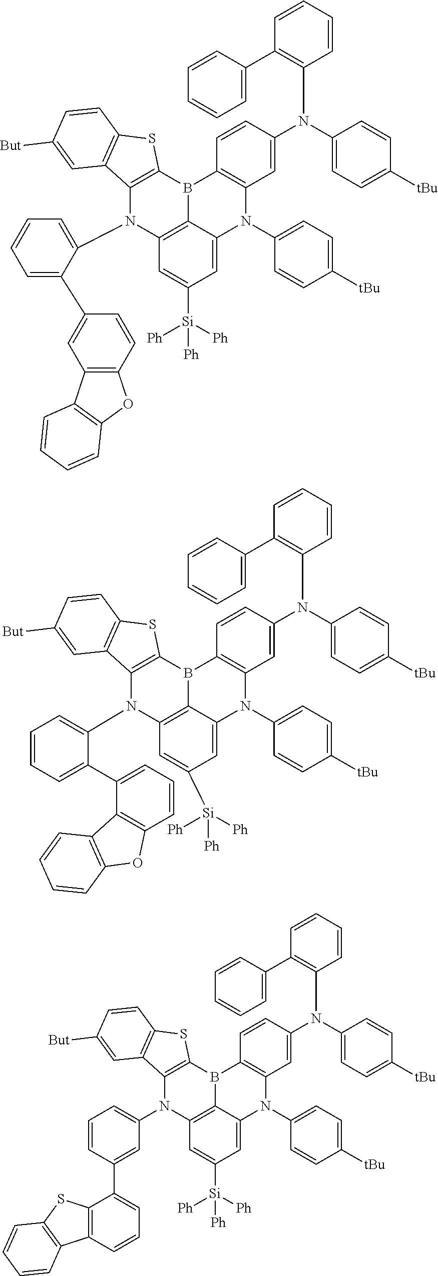

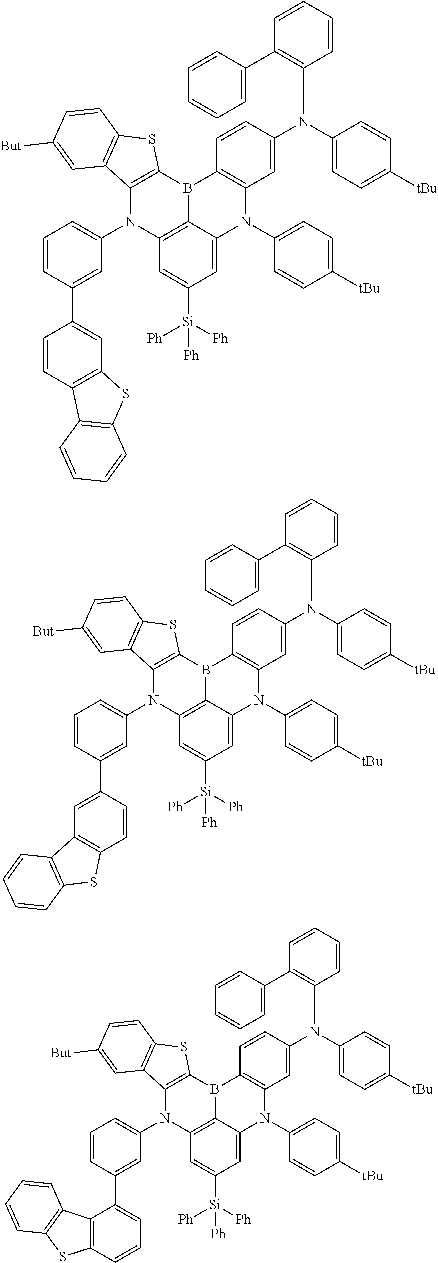

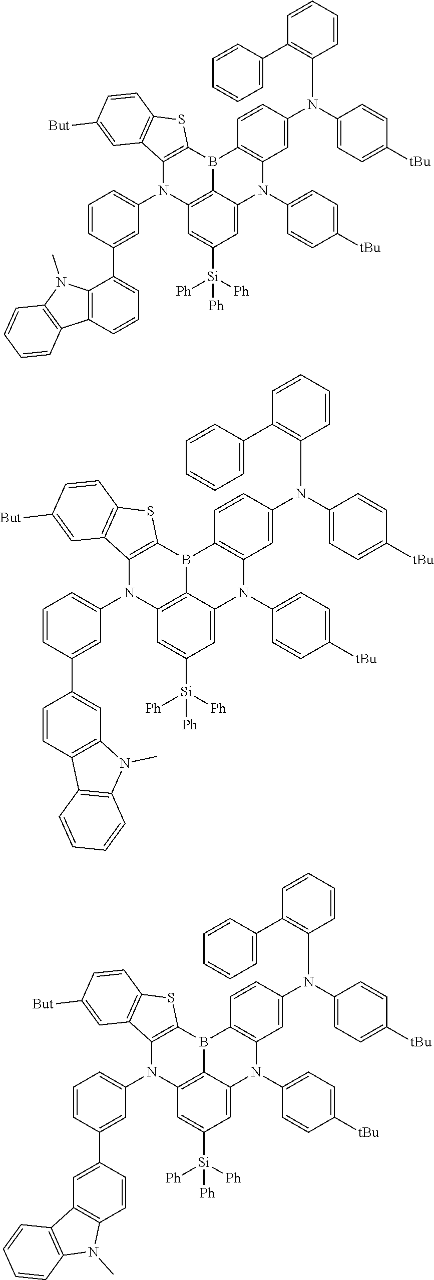

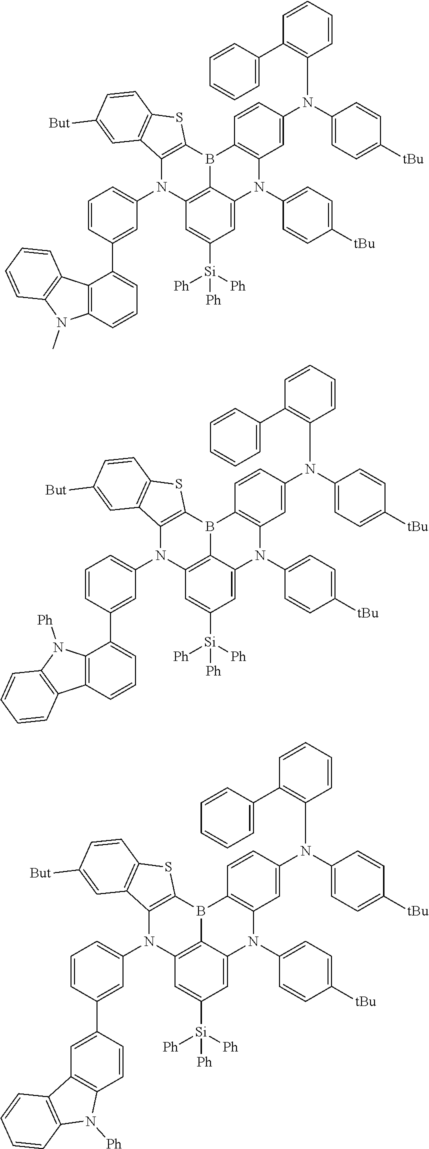

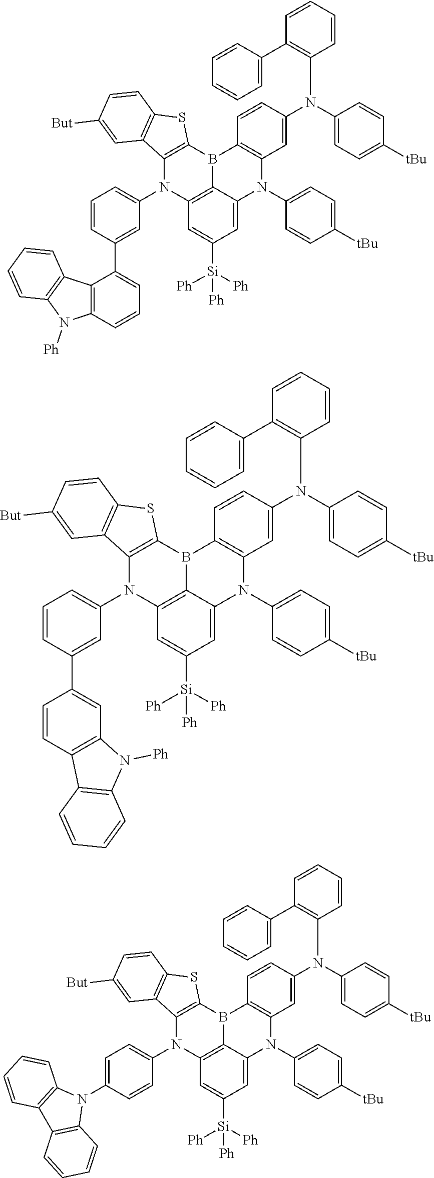

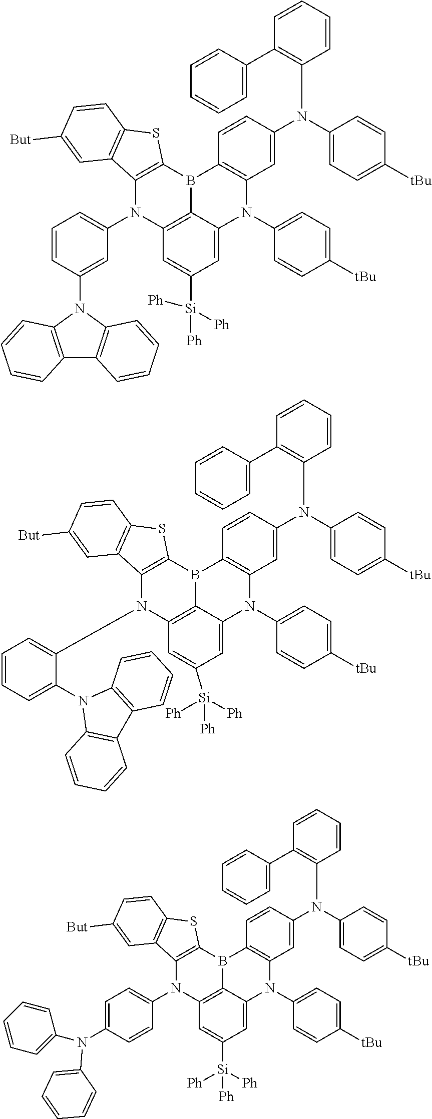

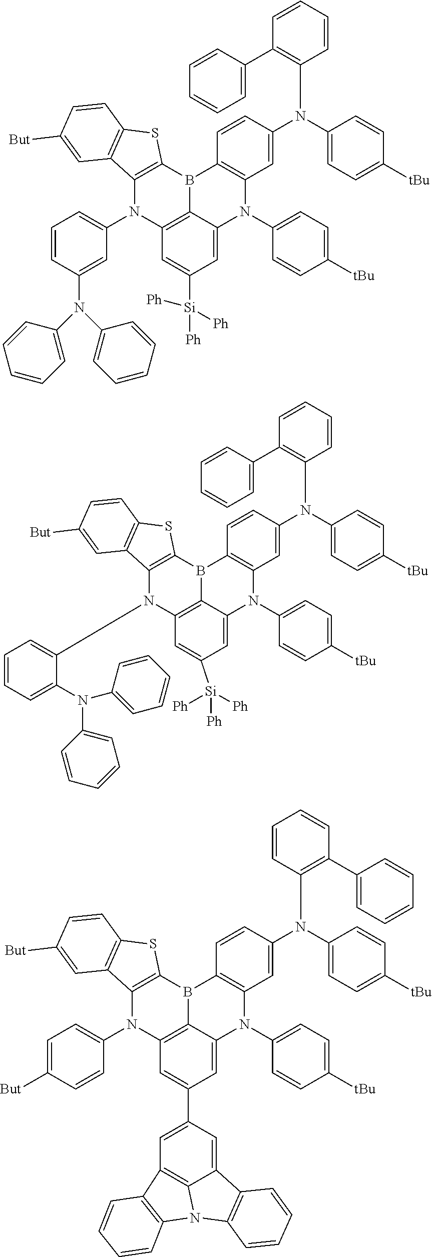

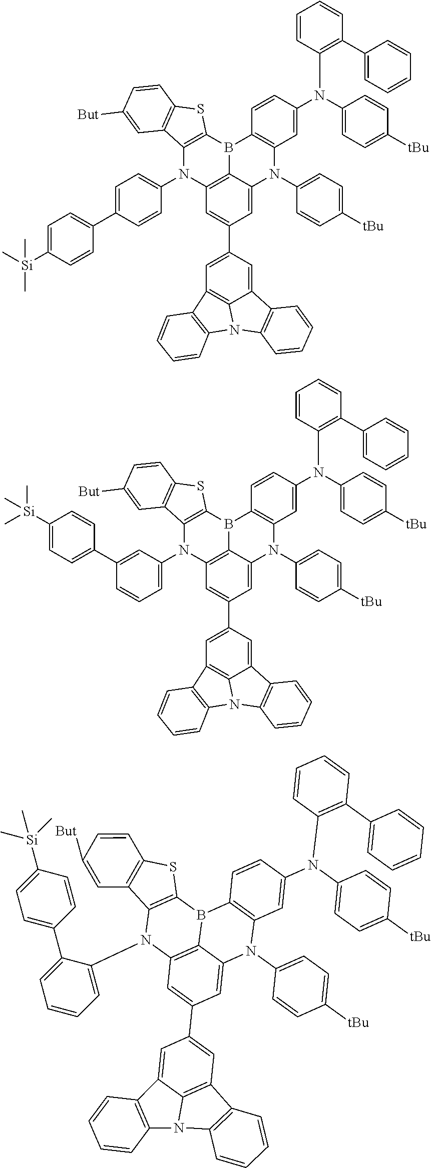

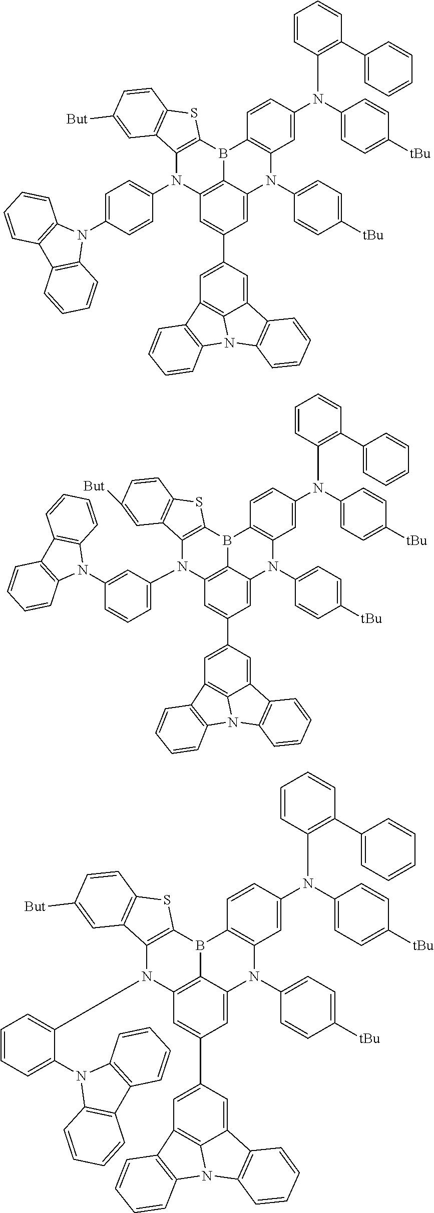

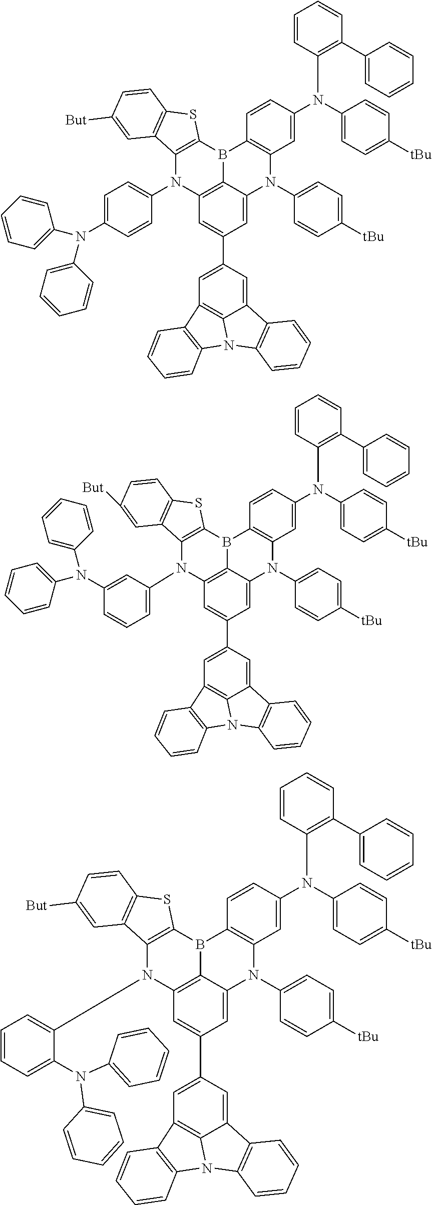

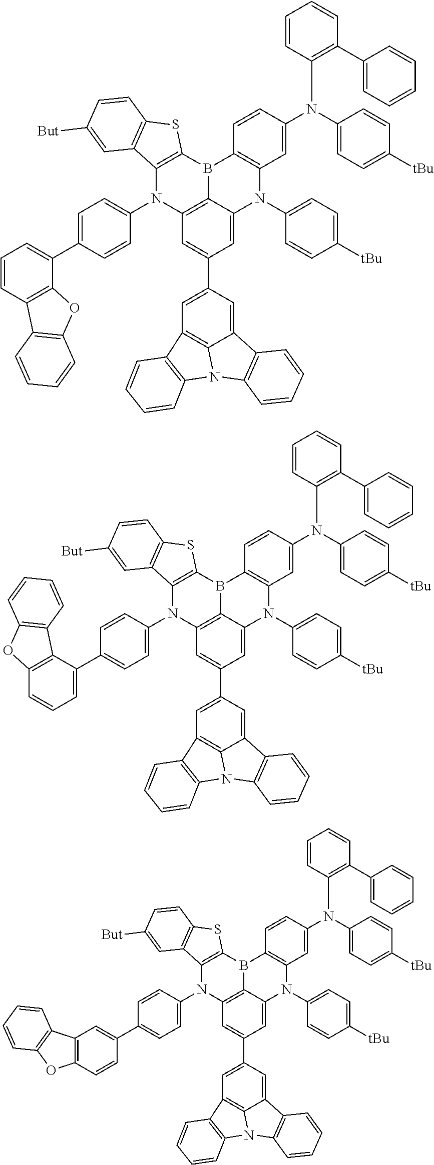

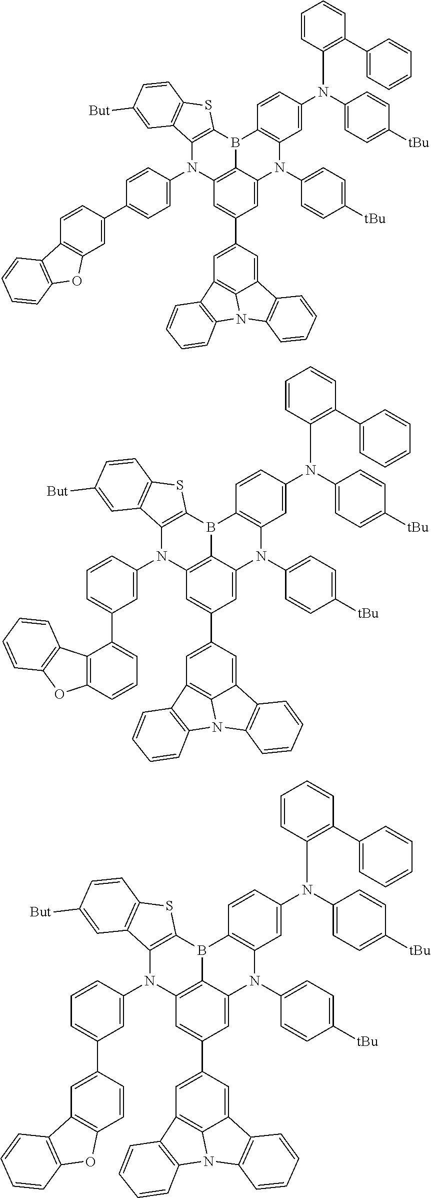

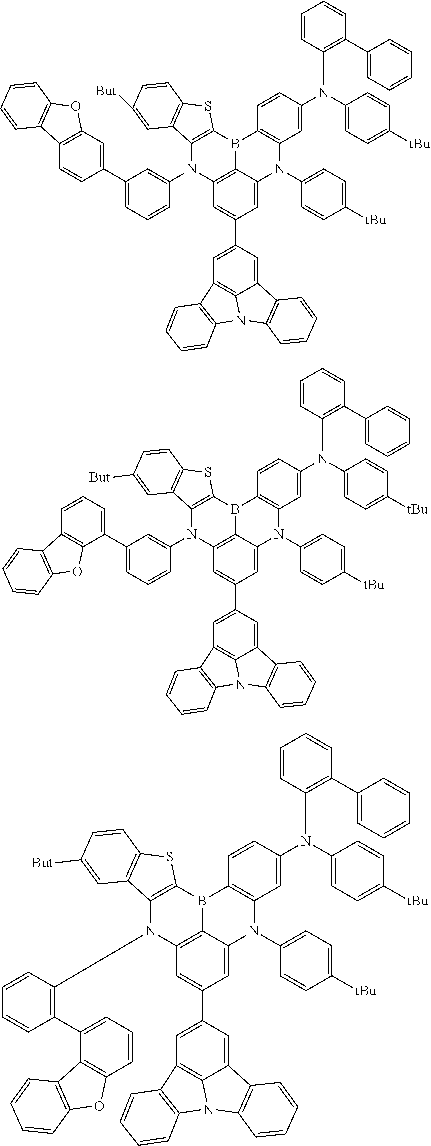

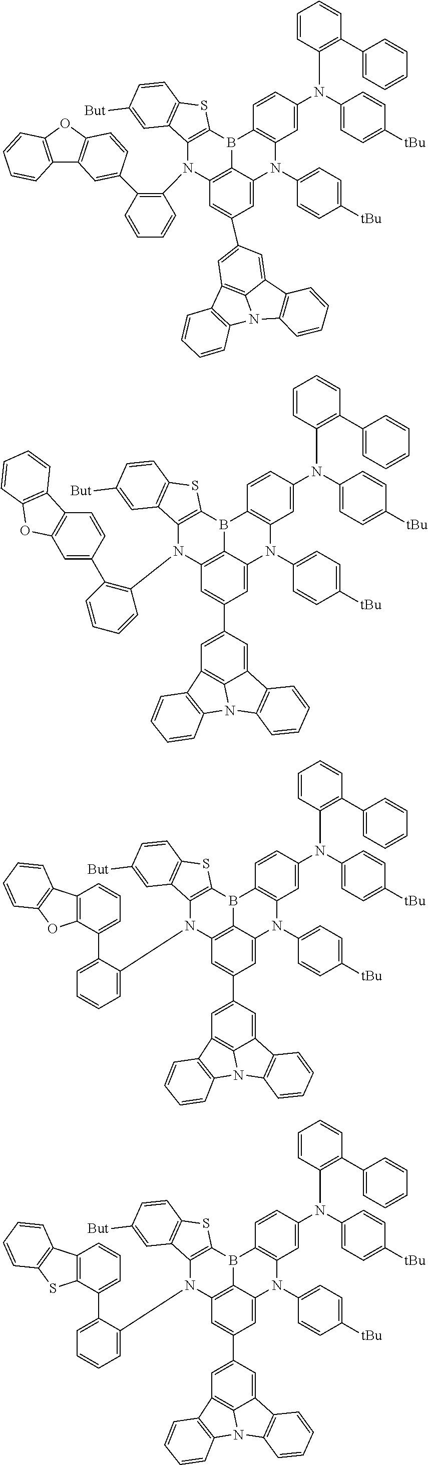

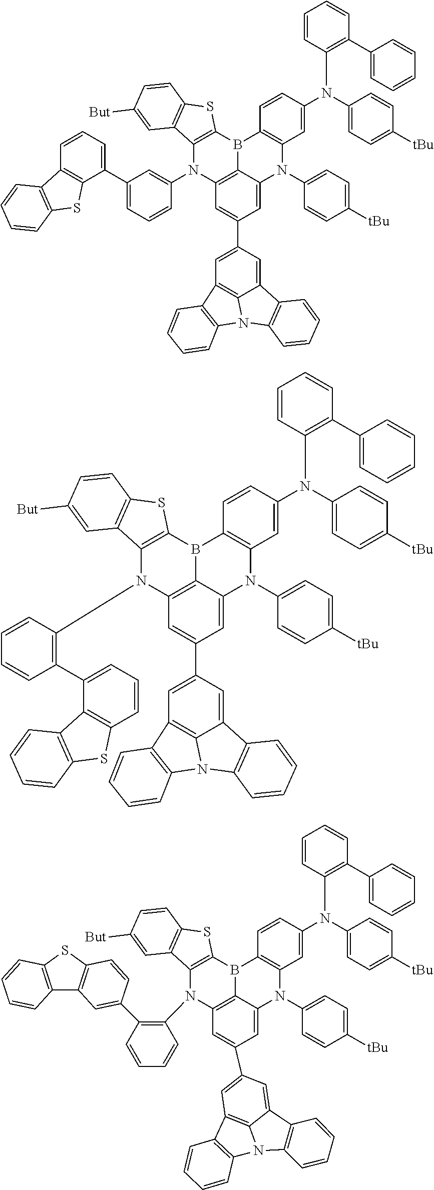

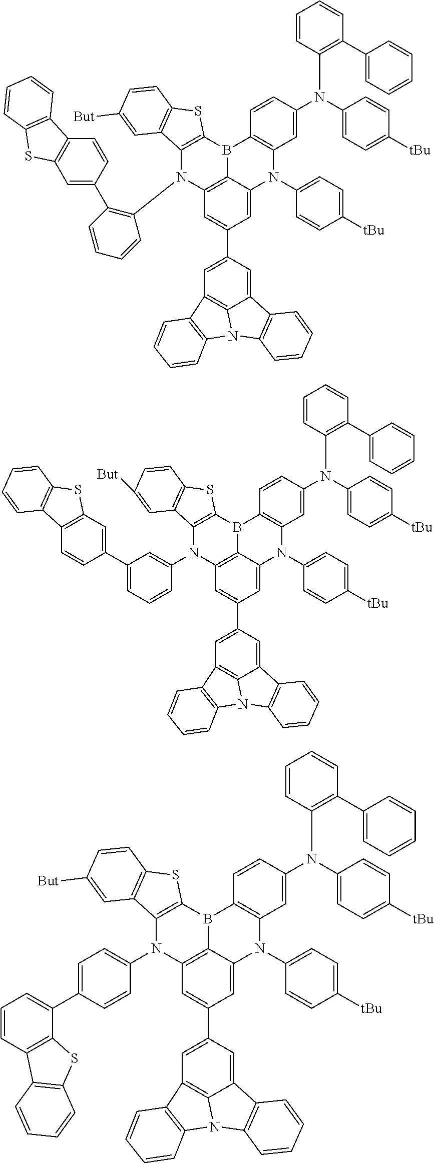

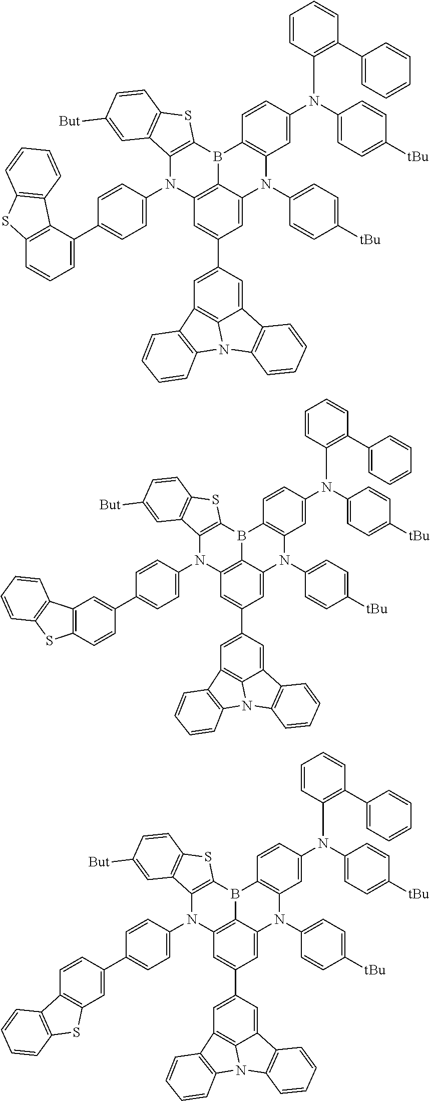

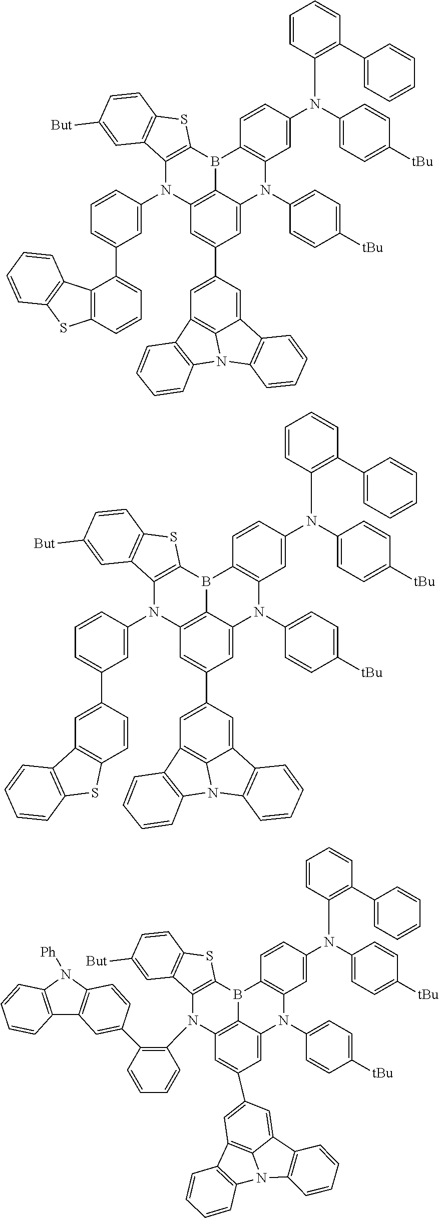

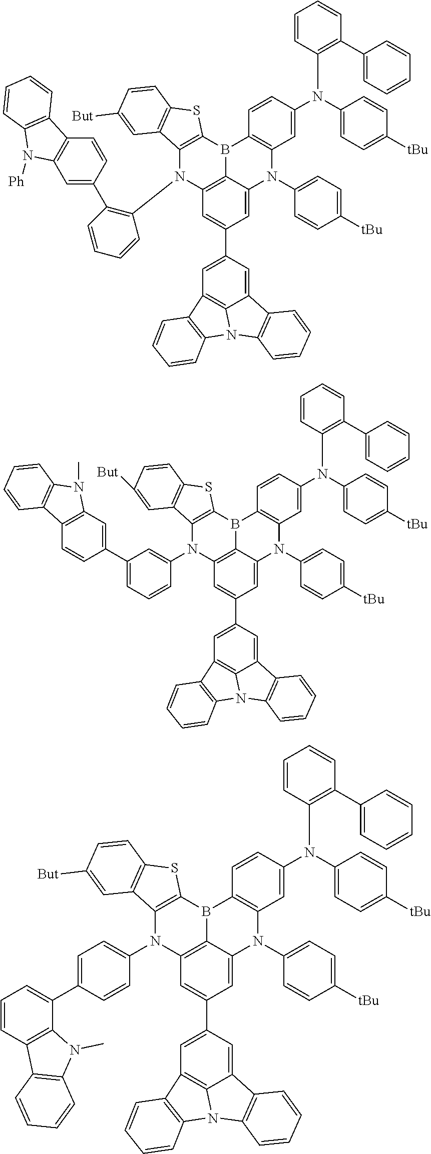

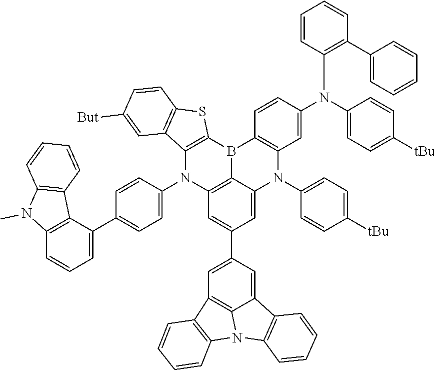

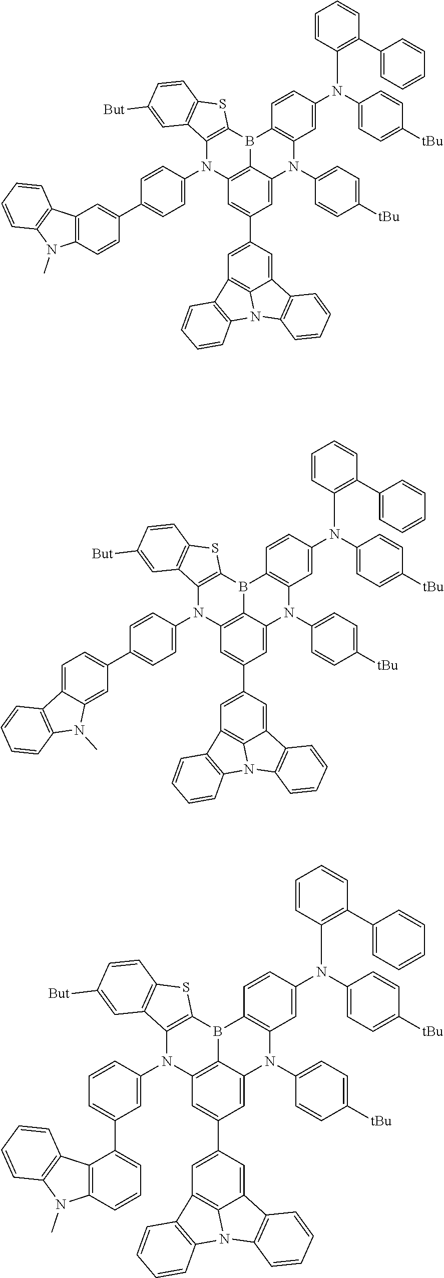

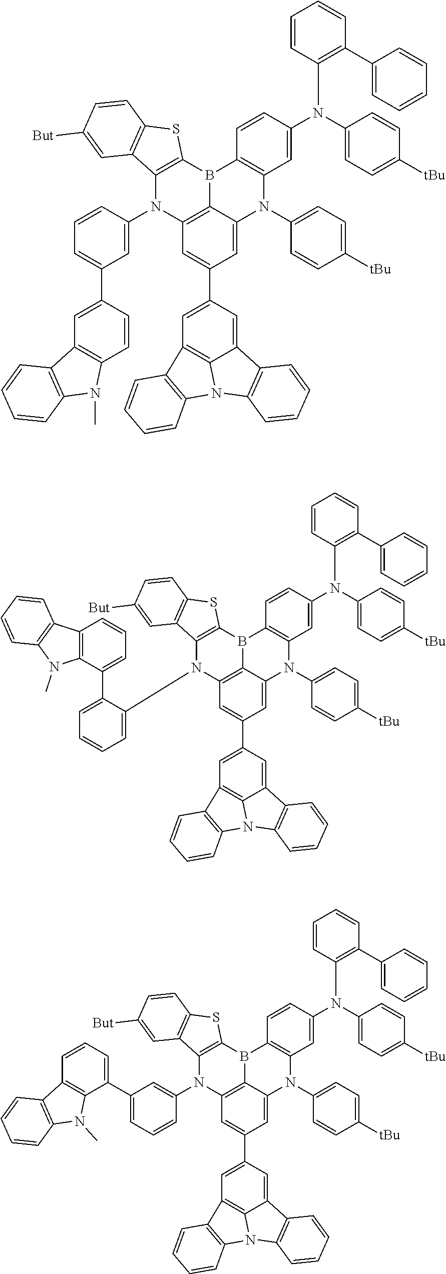

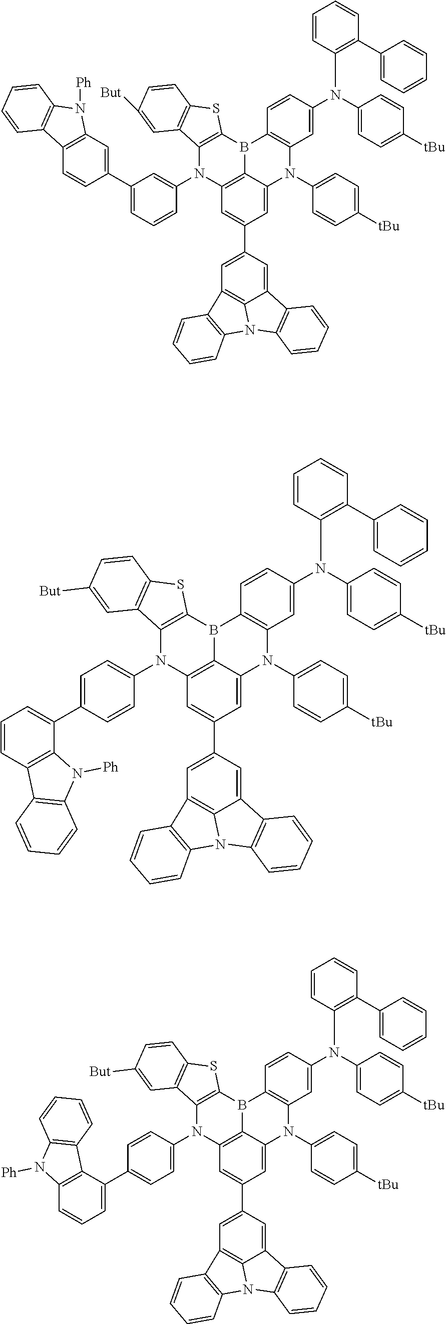

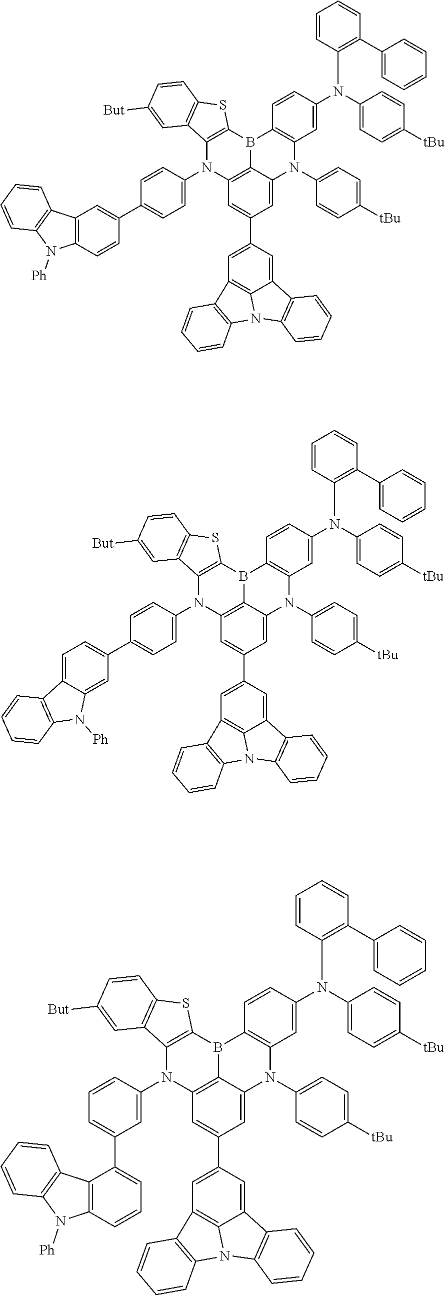

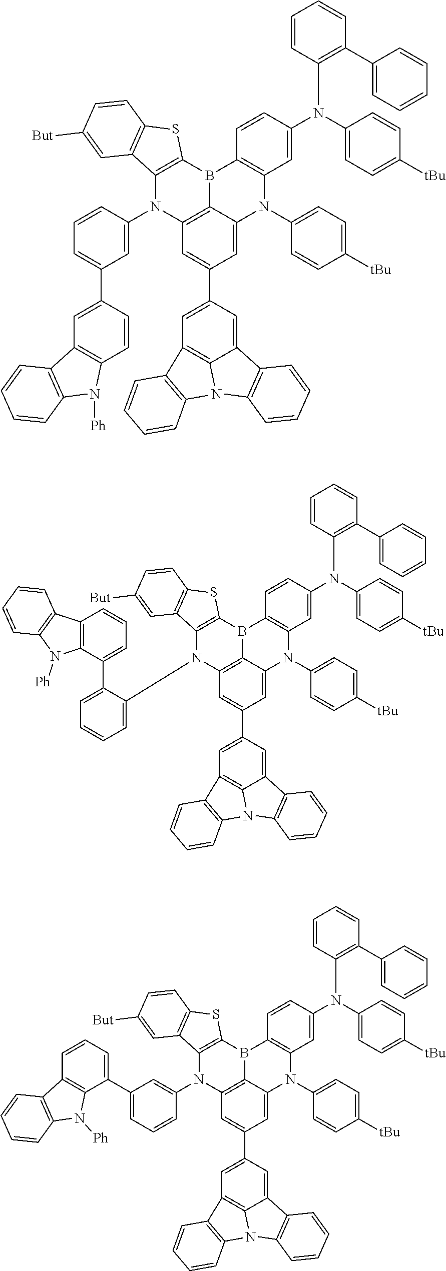

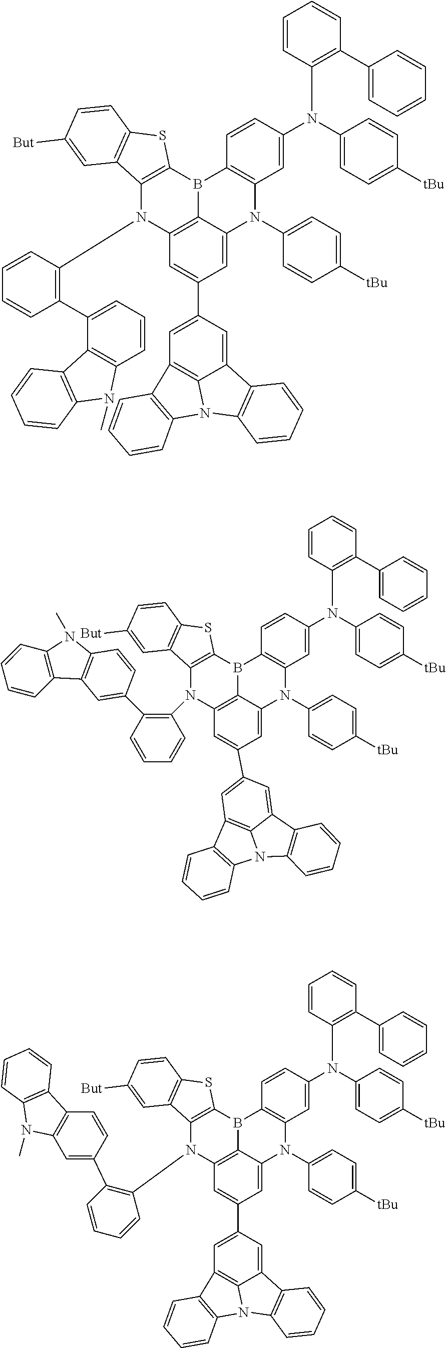

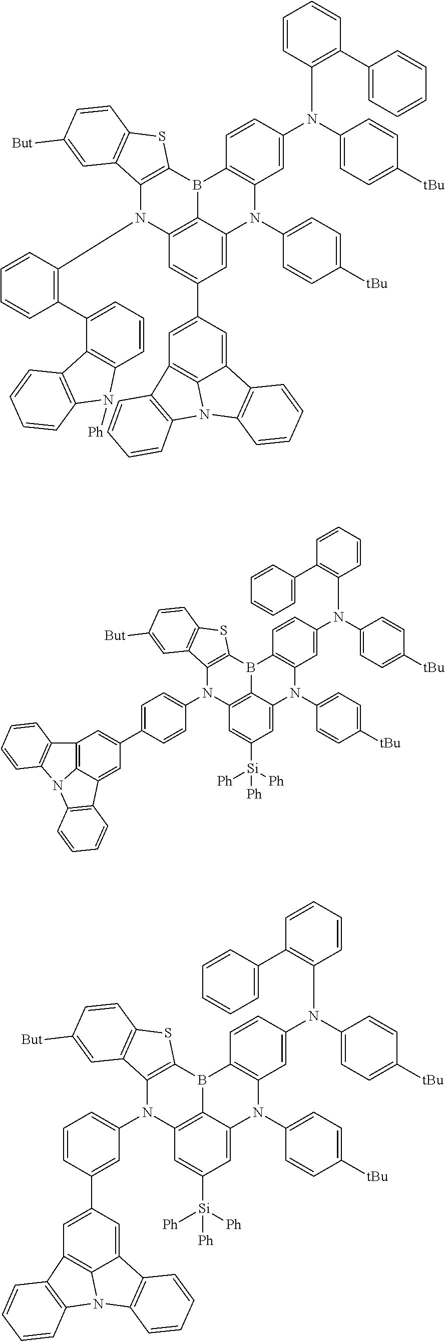

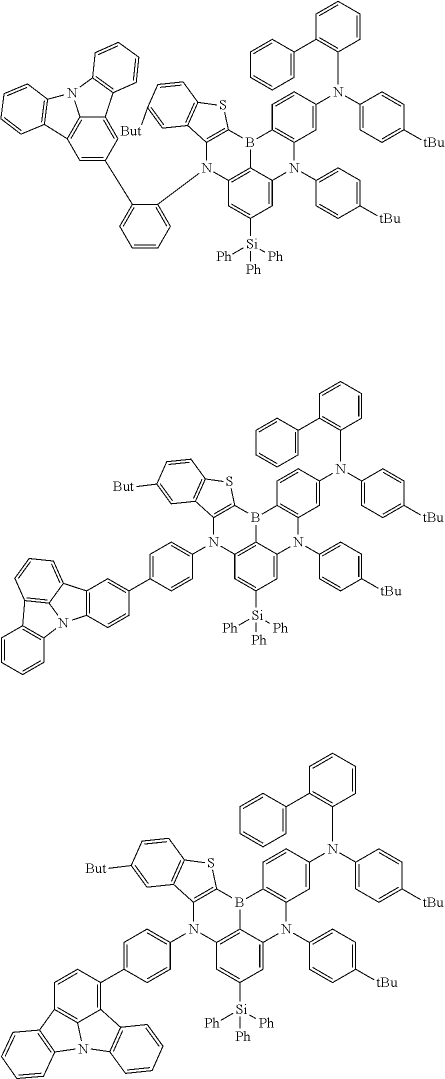

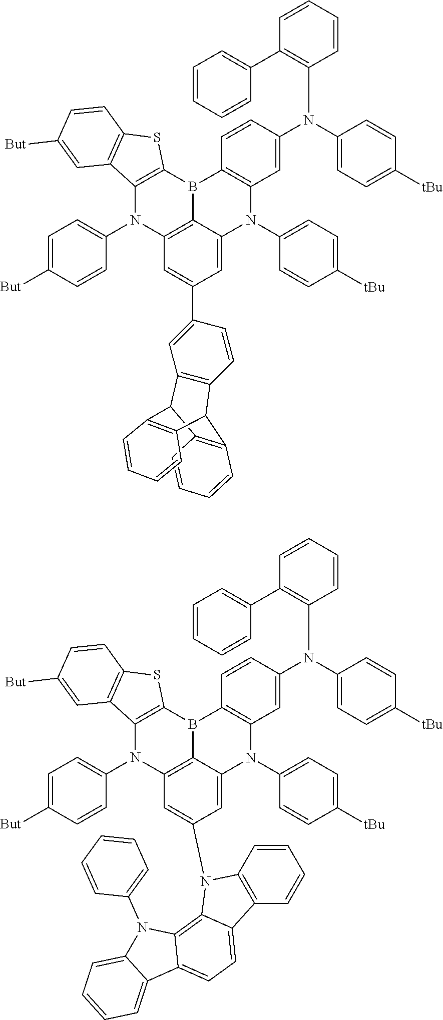

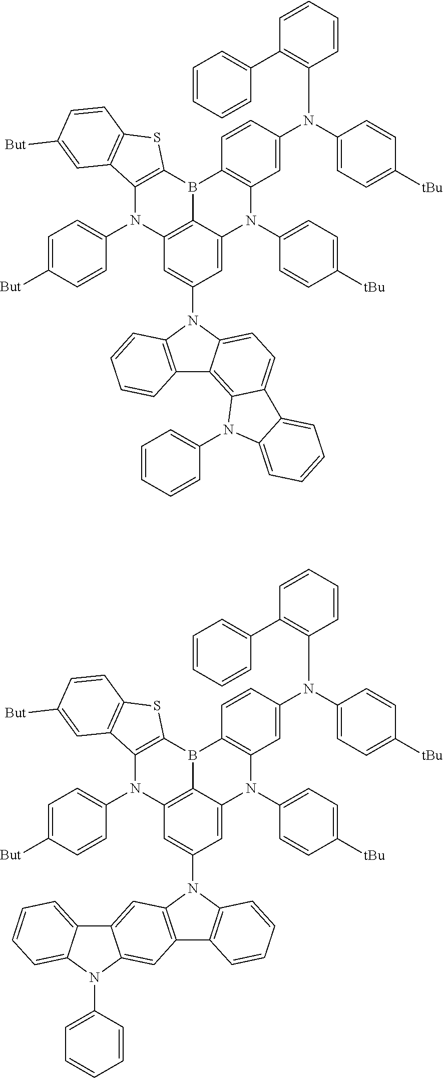

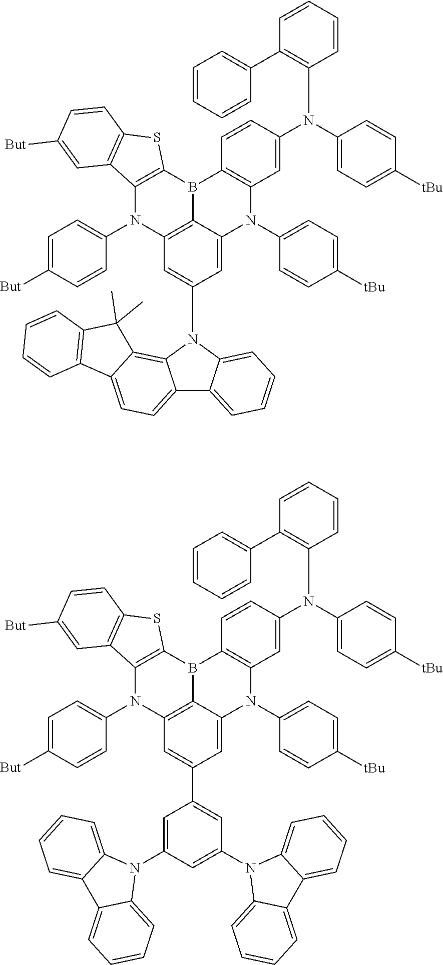

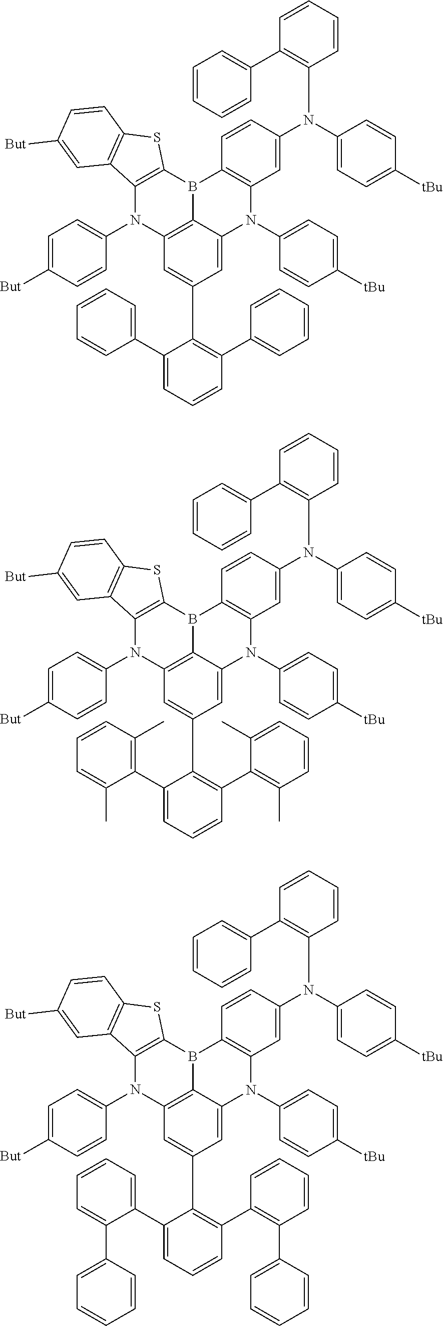

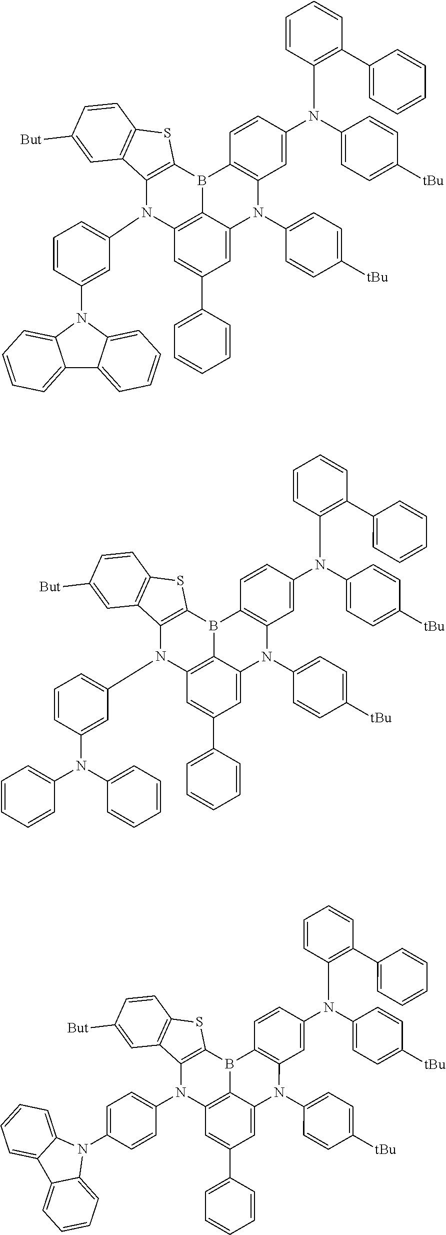

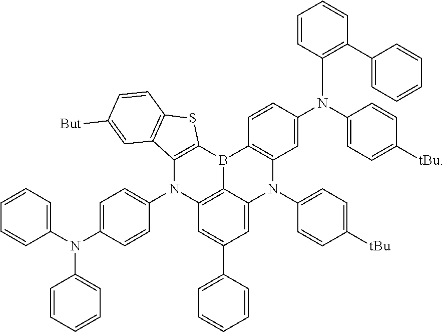

According to the above-mentioned purpose of the present application, an embodiment of the present application also provides a mixture, which includes the organic compound and at least one organic functional material, and the organic functional material is selected from a hole injection material, a hole transport material, an electron transport material, an electron injection material, an electron blocking material, a hole blocking material, a light-emitting material, a host material or an organic dye.

According to the above-mentioned purpose of the present application, an embodiment of the present application further provides a composition, which includes the organic compound and at least one organic solvent, or the composition includes the mixture and at least one organic solvent.

According to the above-mentioned purpose of the present application, the embodiment of the present application further provides an organic light-emitting device, which includes:
a first electrode;
a second electrode, disposed opposite to the first electrode; and
an organic functional layer, located between the first electrode and the second electrode;
the material of the organic functional layer includes one or more of the organic compounds, or the material of the organic functional layer includes the mixture, or the material of the organic functional layer includes the composition.

In one embodiment of the present application, the organic functional layer includes a light-emitting layer, and the material of the light-emitting layer includes a host material and a guest material, and the guest material includes one or more of the organic compounds.

In one embodiment of the present application, a mass ratio of the host material to the guest material ranges from 99:1 to 70:30.

According to the above-mentioned purpose of the present application, an embodiment of the present application further provides a display panel, which includes the organic light-emitting device.

The present application provides an organic compound, a mixture, a composition, an organic light-emitting device and a display panel. By introducing a large group, such as an alkyl silicon based group and a dibenzofuran based group, into the phenyl amino of the boron nitrogen compound benzothiophene, or introducing a silicon-containing group, an indenocarbazol group, an indolecarbazol group, a fluorenecarbazol group, a triazine group, a dicarbazolylphenyl group, a 2,6-diphenylphenyl group and a phenyl group into the para position of the boron, the organic compound is made easily purified, thereby improving the purity of the organic compound, and further improving the luminescence efficiency and the service life of the organic light-emitting device made from the organic compound.

The present application will be described in detail in the subsequent section of description of the embodiments.

### DESCRIPTION OF THE DRAWINGS

In order to more clearly illustrate the technical solutions in the embodiments of the present application, the following briefly introduces the drawings required for use in the description of the embodiments. Obviously, the drawings described below are only some embodiments of the present application, and those skilled in the art can obtain other drawings based on these drawings without creative work.

In order to more completely understand the present application and its beneficial effects, the following description will be given in conjunction with the accompanying drawings, in which the same reference symbols represent the same parts in the following description.

FIG. 1 is a hydrogen nuclear magnetic resonance spectrum of an organic compound M1 provided in an embodiment of the present application;

FIG. 2 is a hydrogen nuclear magnetic resonance spectrum of an organic compound M22 provided in an example of the present application;

FIG. 3 is a schematic diagram of a first structure of an organic light-emitting device provided in an embodiment of the present application;

FIG. 4 is a schematic diagram of a second structure of an organic light-emitting device provided in an embodiment of the present application.

### DESCRIPTION OF REFERENCE SYMBOLS

100, Organic light-emitting device; 110, Substrate; 101, First electrode; 102, Second electrode; 103, Organic functional layer; 104, Hole injection layer; 105, Hole transport layer; 106, Electron blocking layer; 107, Light-emitting layer; 108, Electron transport layer; 109, Electron injection layer.

### DESCRIPTION OF THE EMBODIMENTS

The present application provides an organic compound, a mixture, a composition, an organic light-emitting device and a display panel. In order to make the purpose, technical solution and the effect of the present application clearer and more specific, the present application is further described in detail with reference to the accompanying drawings and embodiments. It should be understood that the specific embodiments described herein are only used to explain the present application and are not used to limit the present application.

It should be noted that the description order of the following embodiments is not intended to limit the preferred order of the embodiments.

Unless otherwise defined, all terms (including a technical and scientific term) used herein have the same meaning as commonly understood by one of ordinary skill in the art to which the present general inventive concept belongs. It will be further understood that the terms, such as those defined in commonly used dictionaries, should be interpreted as having a meaning consistent with their meaning in the context of the relevant art and the present disclosure, and will not be interpreted in an idealized or overly formal sense unless clearly so defined herein.

In the present application, an aromatic group, an aromatic family and an aromatic ring system have the same meaning and may be interchanged.

In the present application, a heteroaromatic group, a heteroaromatic family and a heteroaromatic ring system have the same meaning and may be interchanged.

In the present application, “substituted” means that a hydrogen atom in a substituted group is substituted by a substituent.

In the present application, when the same substituent appears multiple times, it may be independently selected from the same or different groups. If the general formula contains multiple Rs, then Rs may be independently selected from different or the same groups.

In the present application, “substituted or unsubstituted” means that the defined group may either be substituted or unsubstituted. When the defined group is substituted, it is understood that the defined group may be substituted by one or more substituents R, in which R is selected from, but not limited to, a deuterium atom, a cyano group, an isocyano group, a nitro group or a halogen (e.g., F, Cl, Br or I), an alkyl group having a carbon atom number ranging from 1 to 20, a heterocyclic group having 3 to 20 ring atoms, an aromatic group having 6 to 20 ring atoms, a heteroaromatic group having 5 to 20 ring atoms, —NR′R″, a silane group, a carbonyl group, an alkoxycarbonyl group, an aryloxycarbonyl group, a carbamoyl group, a haloformyl group, a formyl group, an isocyanate group, a thiocyanate group, an isothiocyanate group, a hydroxyl group, a trifluoromethyl group, and the above groups may also be further substituted by the substituents acceptable in the art; it is understood that R′ and R″ in —NR′R″ are each independently selected from, but not limited to, H, a deuterium atom, a cyano group, an isocyano group, a nitro group or a halogen (e.g., F, Cl, Br or I), an alkyl group having carbon atom number ranging 1 to 10, a heterocyclic group having 3 to 20 ring atoms, an aromatic group having 6 to 20 ring atoms, and a heteroaromatic group having 5 to 20 ring atoms. Preferably, R is selected from, but not limited to, a deuterium atom, a cyano group, an isocyano group, a nitro group or a halogen (such as F, Cl, Br or I), an alkyl group having carbon atom number ranging 1 to 10, a heterocyclic group having 3 to 10 ring atoms, an aromatic group containing 6 to 20 ring atoms, and a heteroaromatic group containing 5 to 20 ring atoms, a silane group, a carbonyl group, an alkoxycarbonyl group, an aryloxycarbonyl group, a carbamoyl group, a haloformyl group, a formyl group, an isocyanate group, a thiocyanate group, an isothiocyanate group, a hydroxyl group, and a trifluoromethyl group, and the above groups may also be further substituted by the substituents acceptable in the art.

In the present application, the “ring atom number” refers to the number of atoms constituting the ring itself of a structural compound (e.g., a monocyclic compound, a condensed ring compound, a cross-linked compound, a carbocyclic compound, a heterocyclic compound) obtained by bonding the atoms to form a ring. When the ring is substituted by a substituent, the atoms contained in the substituent are not included in the ring atoms. The same is true for the “ring atom number” described below unless otherwise specified. For example, the ring atom number of a benzene ring is 6, the ring atom number of a naphthalene ring is 10, and the ring atom number of a thienyl group is 5.

In the present application, “aryl” or “aromatic group” refers to an aromatic hydrocarbon group whose ring atoms derived by removing a hydrogen atom from an aromatic ring compound are all carbon atoms, which may be a monocyclic aromatic group, a condensed aromatic group, or a polycyclic aromatic group. As for the ring of the polycyclic rings, at least one is an aromatic ring system. For example, “substituted or unsubstituted aryl having 6 to 40 ring atoms” refers to an aryl group containing 6 to 40 ring atoms, preferably a substituted or unsubstituted aryl group having 6 to 30 ring atoms, more preferably a substituted or unsubstituted aryl group having 6 to 18 ring atoms, and particularly preferably a substituted or unsubstituted aryl group having 6 to 14 ring atoms, and the aryl group is optionally further substituted; suitable examples include, but are not limited to: phenyl, biphenyl, terphenyl, naphthyl, anthracenyl, phenanthrenyl, fluoranthenyl, triphenylene, pyrenyl, perylenyl, tetracenyl, fluorenyl, acenaphthenyl and derivatives thereof. It is understood that the multiple aromatic groups may also be interrupted by short non-aromatic units (for example, based on the total number of total atoms in the system, the non-aromatic units preferably contain <10% non-H atoms, such as C, N or O atom), such as acenaphthene, fluorene, or 9,9-diarylfluorene, triarylamine, diaryl ether system should also be included in the definition of the aromatic group.

In the present application, “heteroaryl” or “heteroaromatic group” means that at least one carbon atom on the ring skeleton is replaced by a non-carbon atom on the basis of the aryl, and the non-carbon atom may be an N atom, an O atom, an S atom, etc. That is, the ring atoms of the heteroaryl include one or more non-carbon atoms selected from an N atom, an O atom, an S atom. For example, “substituted or unsubstituted heteroaryl having 5 to 40 ring atoms” refers to a heteroaryl with 5 to 40 ring atoms, preferably a substituted or unsubstituted heteroaryl with a ring atom number ranging from 6 to 30, more preferably a substituted or unsubstituted heteroaryl with 6 to 18 ring atoms, and particularly preferably a substituted or unsubstituted heteroaryl with 6 to 14 ring atoms, and the heteroaryl is optionally further substituted, and the suitable examples include, but are not limited to: thienyl, furanyl, pyrrolyl, imidazolyl, diazolyl, triazolyl, pyridyl, bipyridyl, pyrimidyl, triazine, acridinyl, pyridazinyl, pyrazinyl, quinolyl, isoquinolyl, quinazolinyl, quinoxalinyl, phthalazinyl, pyridopyrimidinyl, pyridopyrazinyl, benzothiophenyl, benzofuranyl, indolyl, pyrroloimidazolyl, pyrrolopyrrolyl, thienopyrrolyl, thienothiphenyl, furopyrrolyl, furofuranyl, thienofuranyl, benzisoxazolyl, benzisothiazolyl, benzimidazolyl, o-diazanaphthyl, phenanthridinyl, perimidinyl, quinazolinonyl, dibenzothiophenyl, dibenzofuranyl, carbazolyl and derivatives thereof.

In the present application, “alkyl” may refer to a fully saturated straight chain, branched and/or cyclic aliphatic hydrocarbon group. The carbon number of the alkyl group may be 1 to 50, 1 to 30, 1 to 20, 1 to 10 or 1 to 6. A phrase containing this term, for example, “C₁₋₉ alkyl” refers to an alkyl group containing 1 to 9 carbon atoms, and for each occurrence, it may be each independently C₁ alkyl, C₂ alkyl, C₃ alkyl, C₄ alkyl, C₅ alkyl, C₆ alkyl, C₇ alkyl, C₈ alkyl or C₉ alkyl. Non-limiting examples of the alkyl group include methyl, ethyl, n-propyl, isopropyl, n-butyl, sec-butyl, tert-butyl, isobutyl, 2-ethylbutyl, 3,3-dimethylbutyl, n-pentyl, isopentyl, neopentyl, tert-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-methylcyclohexyl, 4-tert-butylcyclohexyl, n-heptyl, 1-methylheptyl, 2,2-dimethylheptyl, 2-ethylheptyl, 2-butylheptyl, n-octyl, tert-octyl, 2-ethyloctyl, 2-butyloctyl, 2-hexyloctyl, 3,3-dimethyloctyl, cyclooctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldodecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-heneicosyl, n-docosyl, n-tricosyl, n-tetracosyl, n-pentacosyl, n-hexacosyl, n-heptacosyl, n-octacosyl, n-nonacosyl, n-triacontyl, and the like.

In the present application, the abbreviations of the substituent correspond to: n-normal, sec-secondary, i-iso, t-tertiary, o-ortho, m-meta, p-para, Me-methyl, Et-ethyl, Pr-propyl, Bu-butyl, Am-n-pentyl, Hx-hexyl, Cy-cyclohexyl.

In the present application, “amino” refers to an amine derivative having the structural characteristics of the formula —N(X)₂, in which each “X” is independently H, substituted or unsubstituted alkyl, substituted or unsubstituted cycloalkyl, substituted or unsubstituted heterocyclyl, etc. Non-limiting types of amino include —NH₂, —N(alkyl)₂, —NH(alkyl), —N (cycloalkyl)₂, —NH(cycloalkyl), —N(heterocyclyl), —NH (heterocyclyl), —N(aryl), —NH (aryl), —N (alkyl) (aryl), —N (alkyl) (heterocyclyl), —N (cycloalkyl) (heterocyclyl), —N(aryl) (heteroaryl), —N(alkyl)(heteroaryl), etc.

Herein, the term “cycloalkyl” or “cyclic alkyl group” refers to a monovalent group having one or more saturated rings in which all ring members are carbon, in which the term “alkyl” has the same meaning as described above.

In the present application, the term “heterocyclyl”, “heterocyclic” or “heterocycle” refers to a fully saturated or partially unsaturated, but non-aromatic cyclic group having one or more oxygen, sulfur, silicon or nitrogen heteroatoms in the ring, the nitrogen and sulfur heteroatoms may be optionally oxidized and the nitrogen heteroatom may be optionally quaternized. The heterocyclic group may be attached at any atom or carbon atom of the ring or ring system and may be unsubstituted or substituted with one or more moieties as described above for the aryl group.

In the present application, unless otherwise defined, hydroxyl refers to —OH, carboxyl refers to —COOH, carbonyl refers to —C(═O)—, amino refers to —NH₂, formyl refers to —C(═O)H, haloformyl refers to —C(═O)Z (wherein Z represents halogen (e.g., F, Cl, Br or I)), carbamoyl refers to —C(═O)NH₂, isocyanate refers to —NCO, and isothiocyanate refers to —NCS.

In the present application, the term “alkoxy” refers to a group with the structure “—O-alkyl”, i.e., an alkyl group as defined above is connected to other groups via an oxygen atom. As for the hhrases containing this term, the suitable examples include, but are not limited to, methoxy (—O—CH₃ or —OMe), ethoxy (—O—CH₂CH₃ or —OEt) and tert-butoxy (—OC(CH₃)₃ or -OtBu).

In the present application, “*” connected to a single bond indicates a connection or fusion site.

In the present application, when the connection site is not specified in a group, it means that an optional connection site in the group can be used as a connection site.

In the present application, when the fusion site is not specified in the group, it means that any fusion site in the group may be used as the fusion site, and preferably two or more sites in the ortho position in the group are the fusion sites.

In the present application, when a group contains multiple substituents with the same symbol, the substituents may be the same as or different from each other. For example

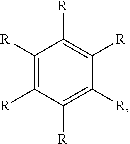

the six Rs on the benzene ring may be the same as or different from each other.

In the present application, the single bond connecting the substituent penetrates through the corresponding ring, indicating that the substituent may be connected to any position of the ring, for example

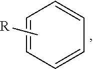

R is connected to any substitutable site of the benzene ring; such as

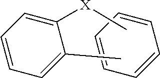

means that

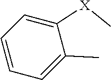

may form a fused ring with any position on the benzene ring in

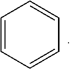

The cyclic alkyl or cycloalkyl described in the present application have the same meaning and are interchangeable.

In the present application, “adjacent groups” means that there is no substitutable site between two substituents.

In the present application, “two adjacent R₁ or two adjacent R₃ or two adjacent R₅ form a ring with each other” means a ring system formed by two adjacent R₁ or two adjacent R₃ or two adjacent R₅ connected to each other, and the ring system may be selected from an aliphatic hydrocarbon ring, an aliphatic heterocycle, an aromatic hydrocarbon ring or an aromatic heterocycle. Preferably, they may form

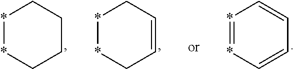

In order to improve the luminescence efficiency of the organic electroluminescent element, various luminescent material systems based on fluorescence and phosphorescence have been developed. Among them, the organic electroluminescent element using the fluorescent materials have the characteristics of high reliability, but under electro-excitation, due to the branching ratio of the singlet excited state and the triplet excited state of the excitons is 1:3, the internal electroluminescent quantum efficiency will be limited to less than 25%, while the organic electroluminescent element using the phosphorescent materials can achieve almost 100% internal electroluminescent quantum efficiency. However, the phosphorescent materials usually use metal complexes containing iridium and platinum, have the expensive raw materials are and have the complicated synthesis, and the phosphorescent organic electroluminescent element will also produce efficiency roll-off (Roll-off) effect, that is, the luminescence efficiency decreases rapidly with the increase of current or brightness, limiting its application under high brightness.

In order to overcome the above problems, the existing technology is usually based on various material combinations of the organic compounds, such as composite excited state materials, thermally activated delayed fluorescence (TADF) materials, etc., trying to use reverse internal conversion to achieve high efficiency comparable to the phosphorescent organic electroluminescent element. However, the performance improvement of the traditional organic compounds with TADF is limited in terms of both efficiency and lifetime, resulting in difficulty in improving the luminescence efficiency and service life of the organic electroluminescent element using the organic compounds with TADF.

Therefore, an embodiment of the present application provides an organic compound having a structure as represented by general formula (1) or general formula (2):

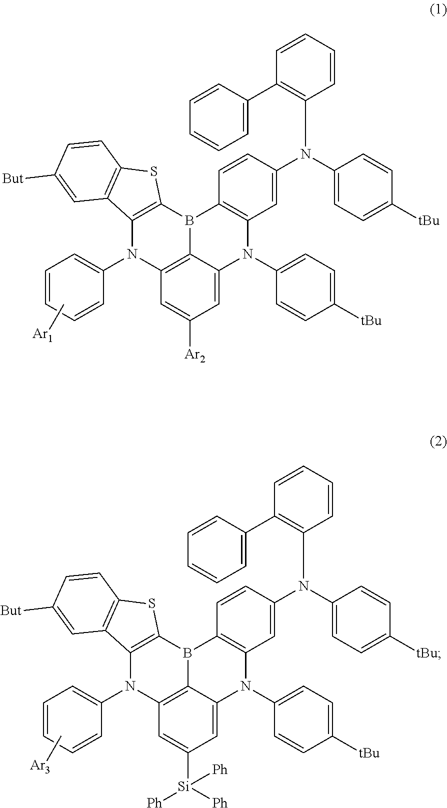

In which, Ar₁ and Ar₃ are selected from the group represented by any one of formula (A-1) to formula (A-8):

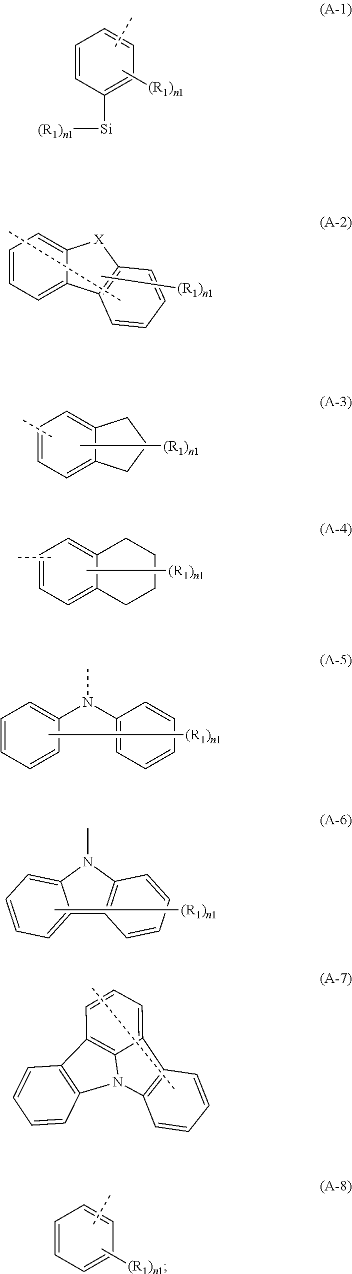

Ar₂ is selected from a group represented by any one of formula (B-1) to formula (B-9):

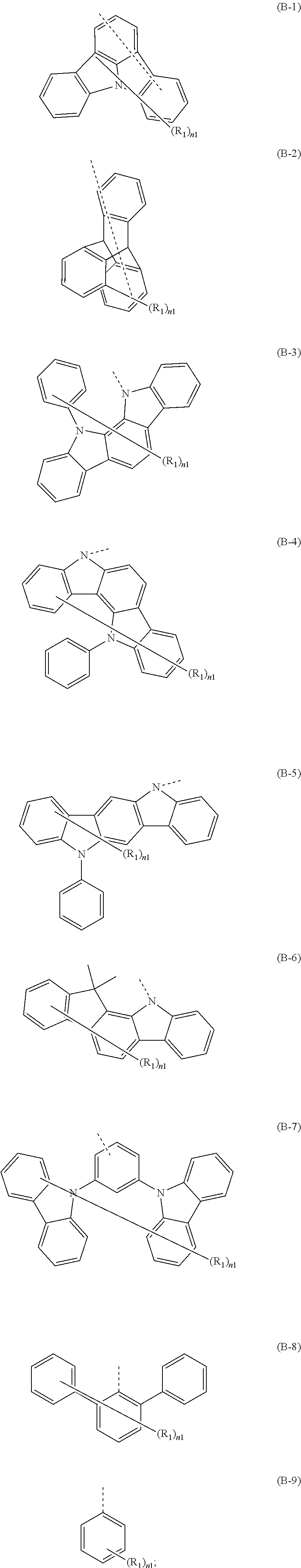

X is selected from O, S, N—CH₃, N-Ph or C(CH₃)₂;
n1 is selected from 0, 1, 2, 3, 4, 5, 6, 7, 8, 9 or 10;
R1 is selected from H, D, a linear alkyl group having a carbon atom number ranging from 1 to 20, a linear silicon group having a carbon atom number ranging from 1 to 20, a 0, a branched silicon group having a carbon atom number ranging from 1 to 20, a linear alkoxy group having a carbon atom number ranging from 1 to 20, a linear thioalkoxy group having a carbon atom number ranging from 1 to 20, a branched alkyl group having a carbon atom number ranging from 3 to 20, a cyclic alkyl group having a carbon atom number ranging from 3 to 20, a branched alkoxy group having a carbon atom number ranging from 3 to 20, a cyclic alkoxy group having a carbon atom number ranging from 3 to 20, a branched thioalkoxy group having a carbon atom number ranging from 3 to 20, a cyclic thioalkoxy group having a carbon atom number ranging from 3 to 20, a silyl group, a trimethylsilyl group, a triphenylsilyl group, a keto group having a carbon atom number ranging from 1 to 20, an alkoxycarbonyl group having a carbon atom number ranging from 2 to 20, an aryloxycarbonyl group having a carbon atom number ranging from 7 to 20, an olefin group having a carbon atom number ranging from 1 to 20, CN, a carbamoyl group, a haloformyl group, a formyl group, isocyano, an isocyanate group, a thiocyanate group, an isothiocyanate group, a hydroxyl group, a nitro group, CF₃, Cl, Br, F, a substituted or unsubstituted aromatic group having a ring atom number ranging from 6 to 30, a substituted or unsubstituted heteroaromatic group having a ring atom number ranging from 5 to 30, a substituted or unsubstituted aryloxy group having a ring atom number ranging from 6 to 30, or a substituted or unsubstituted heteroaryloxy group having a ring atom number ranging from 5 to 30.

The embodiments of the present application has introduced a large group, such as an alkyl silicon based group and a dibenzofuran based group, into the phenyl amino of the boron nitrogen compound benzothiophene, or introduced a silicon-containing group, an indenocarbazol group, an indolecarbazol group, a fluorenecarbazol group, a triazine group, a dicarbazolylphenyl group, a 2,6-diphenylphenyl group and a phenyl group into the para position of the boron, such that the organic compound is easily purified, thereby improving the purity of the organic compound, and further improving the luminescence efficiency and the service life of the organic light-emitting device made from the organic compound.

It should be noted that the large group at the para-boron position in the general formula (1) is an alkyl silicon based group or a dibenzofuran based group, or a silicon-containing group, an indenocarbazol group, an indolecarbazol group, a fluorenecarbazol group, a triazine group, a dicarbazolylphenyl group, a 2,6-diphenylphenyl group or a phenyl group is introduced at the para-boron position, which is beneficial to the purification of the organic compound, thereby improving the purity of the organic compound, and thus improving the efficiency and lifetime of the organic light-emitting device made from the organic compound. The large group at the para-boron position in the general formula (2) is triphenylsilicon, which can effectively narrow the half-peak width of the luminescence spectrum of the organic light-emitting device made from the organic compound.

In some embodiments, two adjacent R₁s form a ring mutually; further, two adjacent R₁s form a ring mutually to form a 6-membered aromatic ring or aliphatic ring; further, two adjacent R₁s form a ring mutually to form

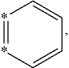 [SMILES: *1:*cccc1]

in which * represents a connection site.

In some embodiments, Ar₂ is selected from the group represented by any one of Formula (B-1) to Formula (B-8).

In some embodiments, when Ar₂ is selected from the group represented by formula (B-9), Ar₁ is selected from the structure represented by any one of formula (A-1) to formula (A-7).

In some embodiments, Ar₃ is selected from the group represented by any one of Formula (A-1) to Formula (A-7).

In some embodiments, R₁ is selected from H, D, a linear alkyl group having carbon atom number ranging 1 to 10, a branched-chain alkyl group having a carbon atom number ranging 3 to 10, and a cyclic alkyl group having a carbon atom number ranging 3 to 10; by introducing an alkyl group into the organic compound, it is beneficial to improve the solubility of the organic compound in processes such as inkjet printing, and improve the product quality of the organic light-emitting device using the organic compound.

Further, in some embodiments, R₁ is selected from H, D, a linear alkyl group having a carbon atom number ranging 1 to 4, and a branched-chain alkyl group having a carbon atom number ranging 3 to 5.

In some embodiments, when Ar₁ is a group represented by the formula (A-2), the group represented by the formula (A-2) is selected from:
at least one of

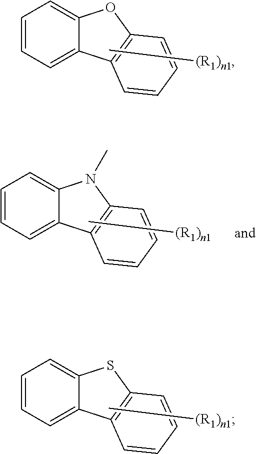

the above groups can increase the overall molecular weight of the organic compound, making the intermolecular gaps of the organic compound larger, which is not conducive to molecular stacking, but is conducive to the transfer of the holes and the electrons, making the molecular hole and electron transfer capabilities of the organic compound stronger, thereby improving the luminescence efficiency and service life of the organic light-emitting device made from the organic compound.

In some embodiments, the organic compound is a blue light-emitting material, and the blue light-emitting material may include one or more of the organic compounds described in the above embodiments.

In some embodiments, the organic compound is selected from the following compounds:

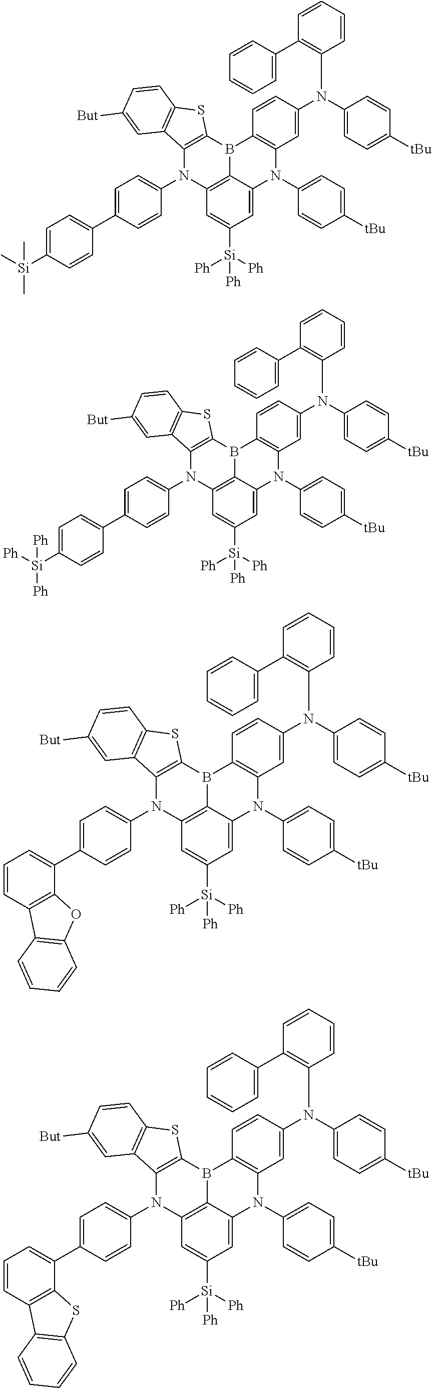

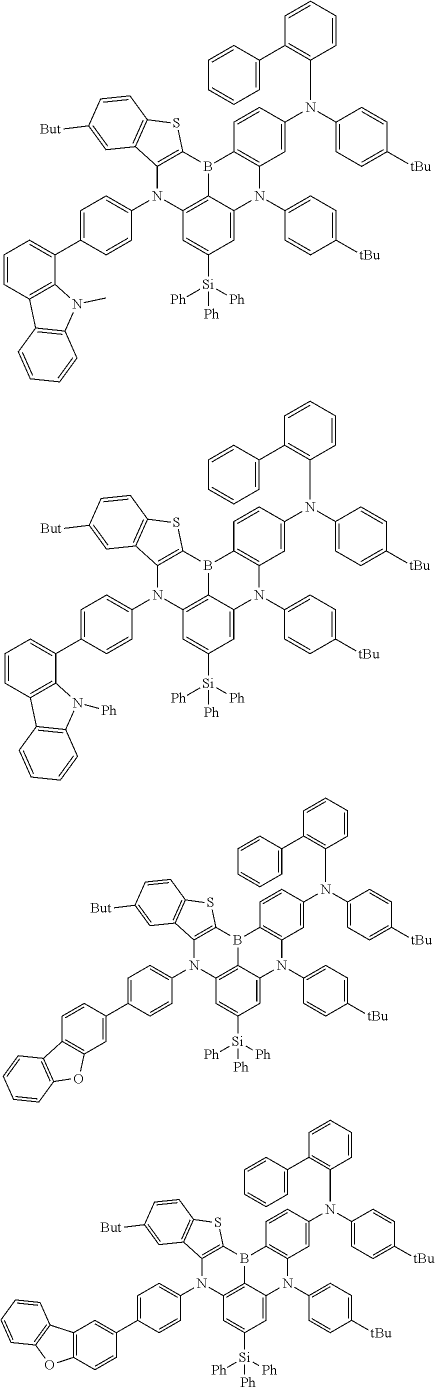

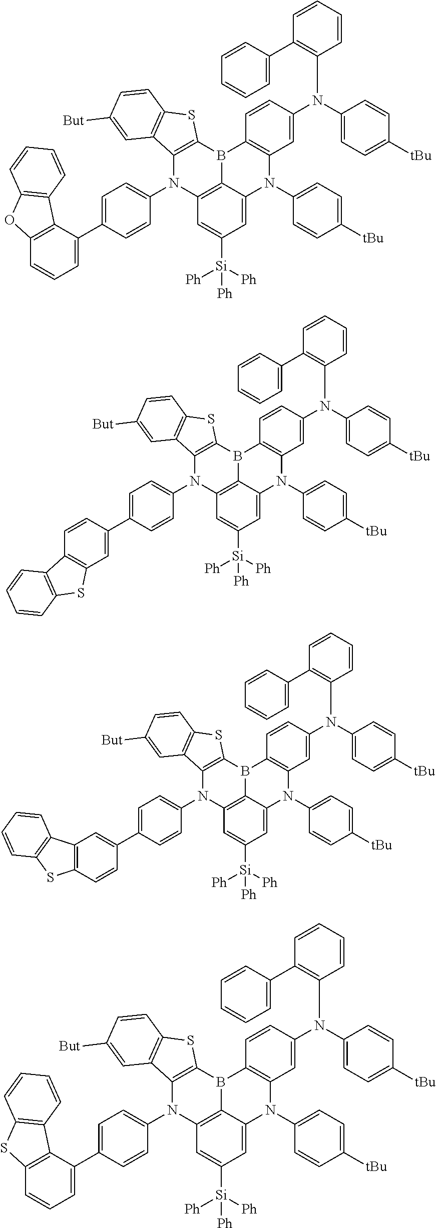

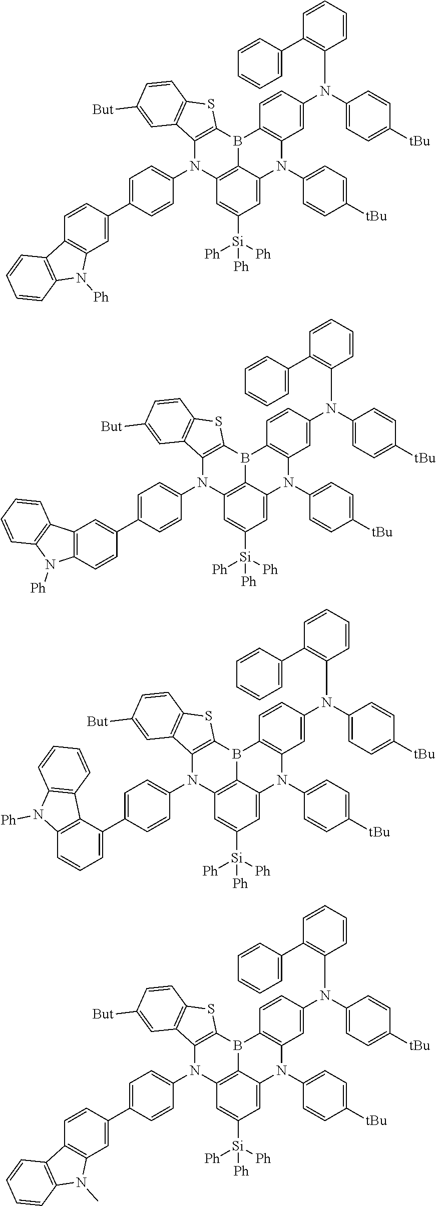

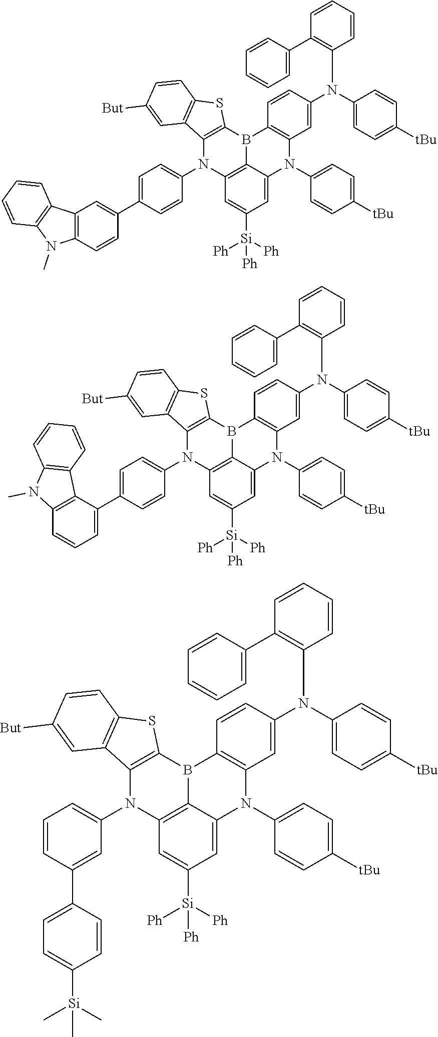

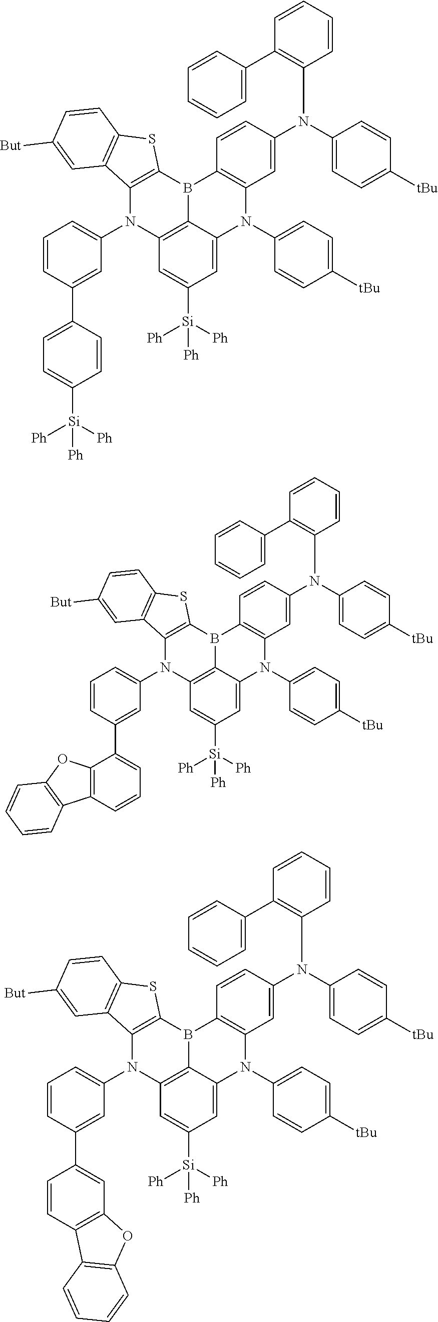

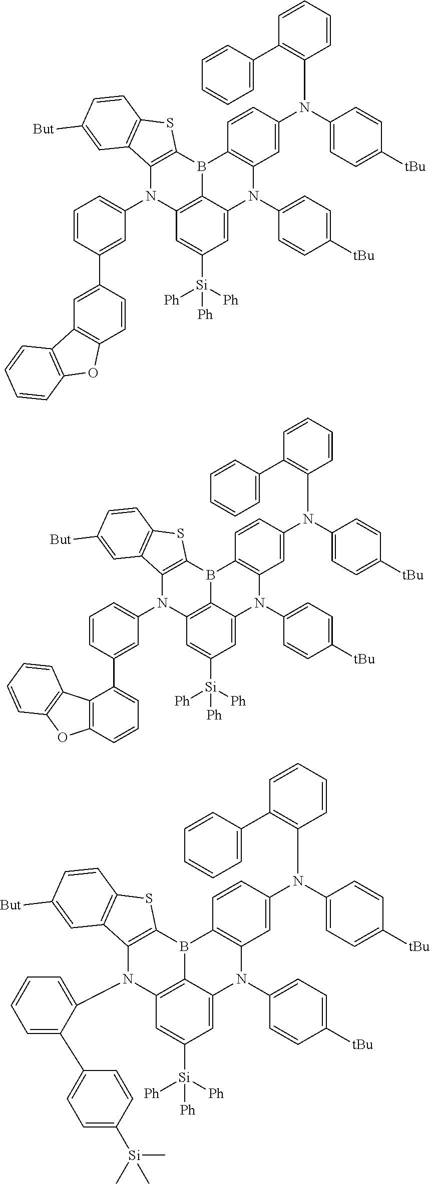

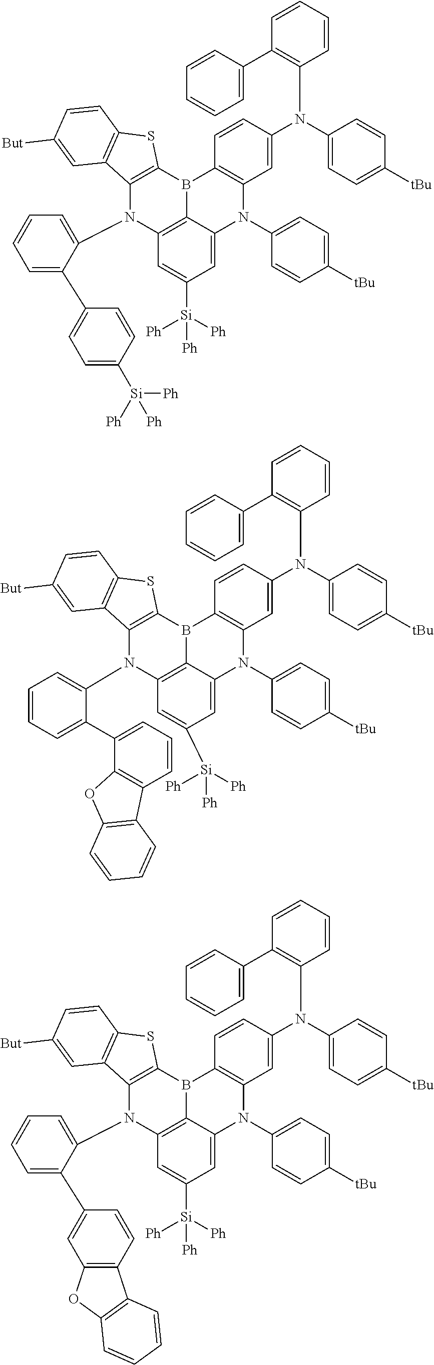

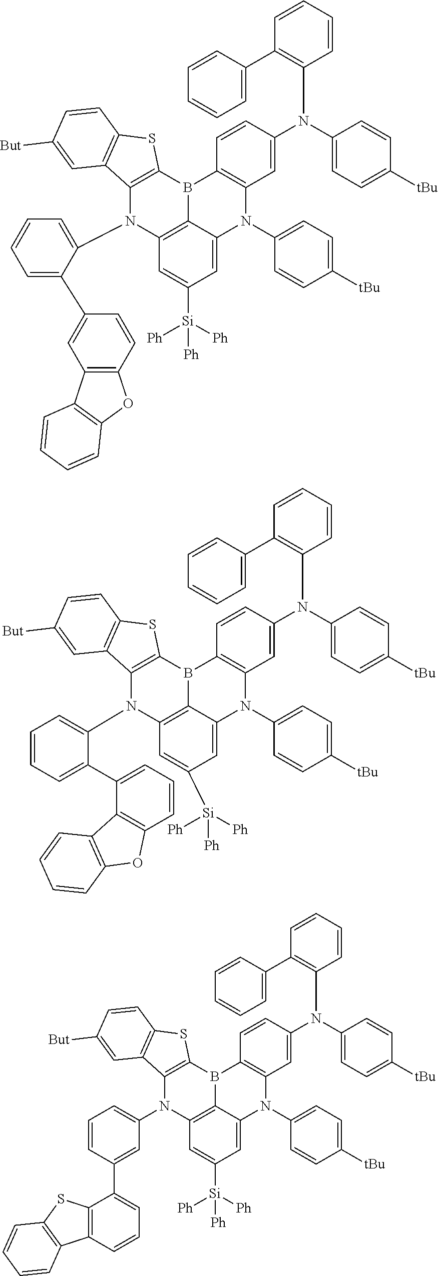

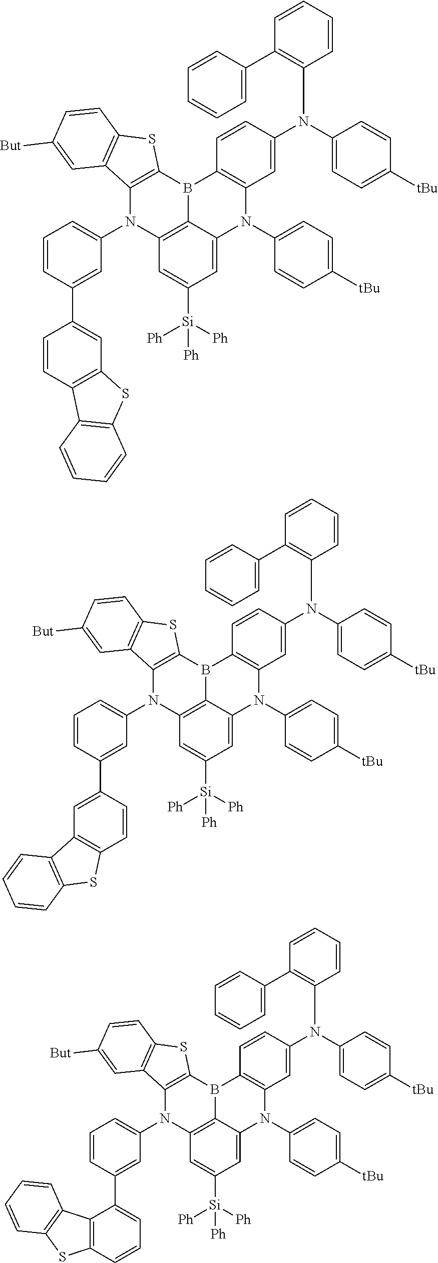

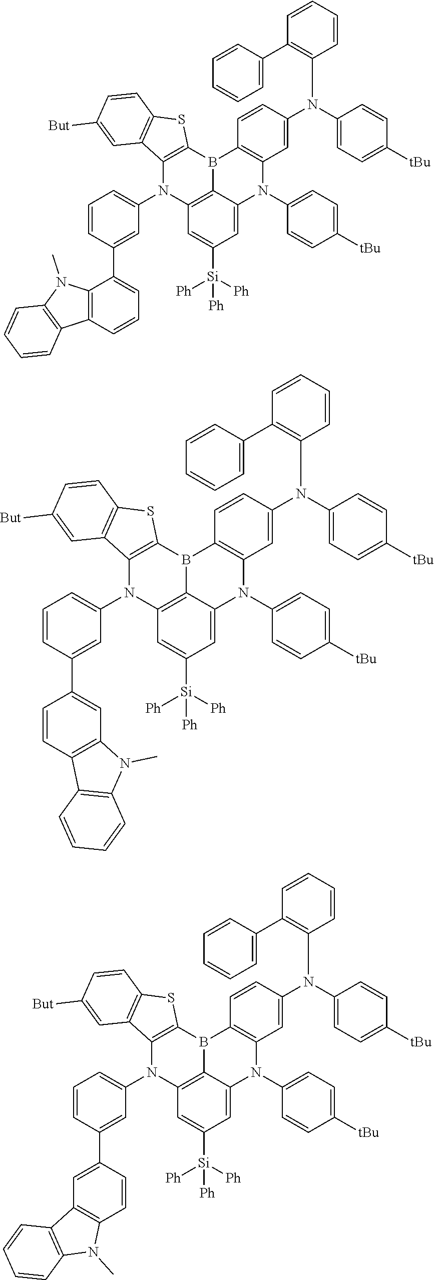

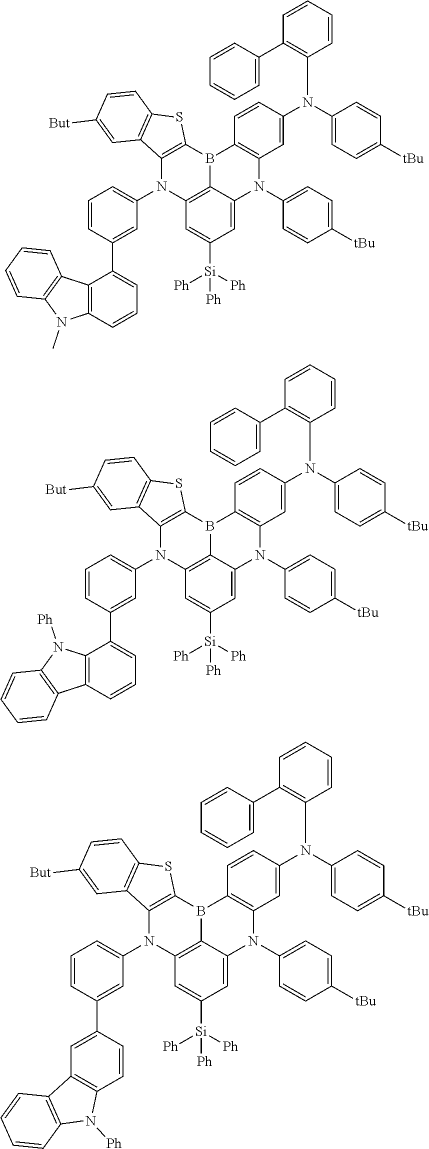

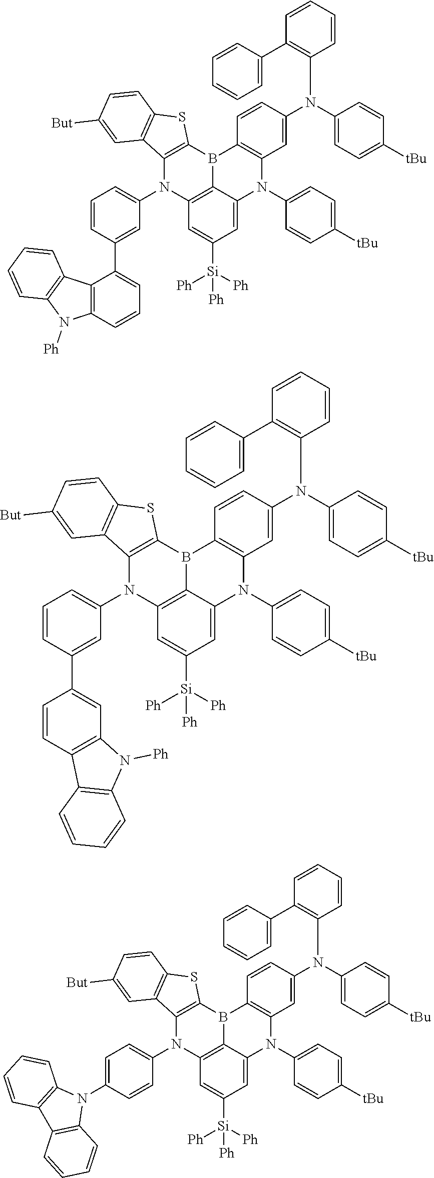

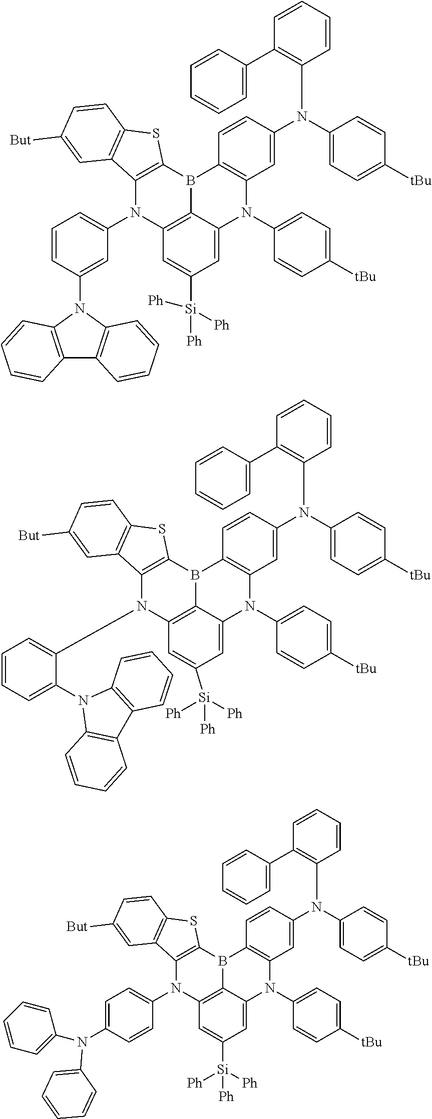

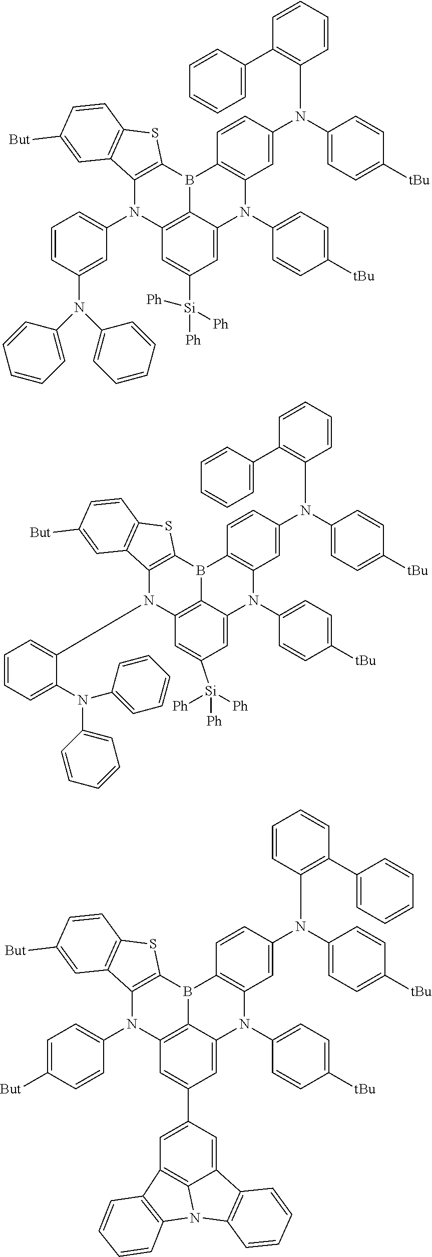

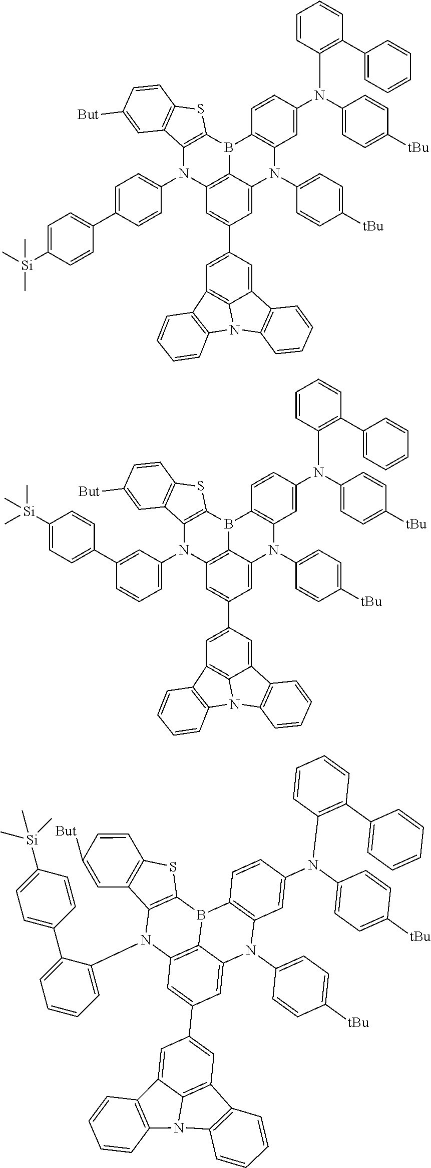

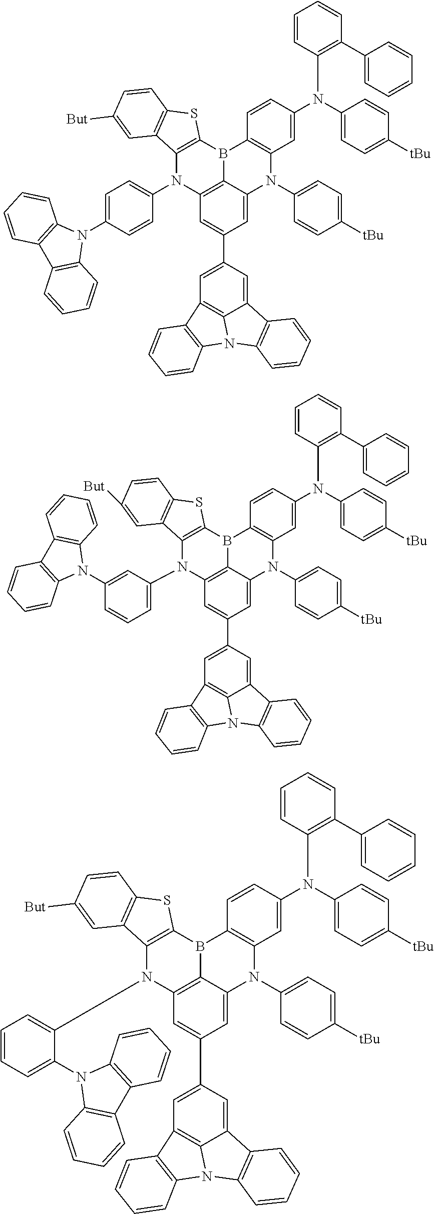

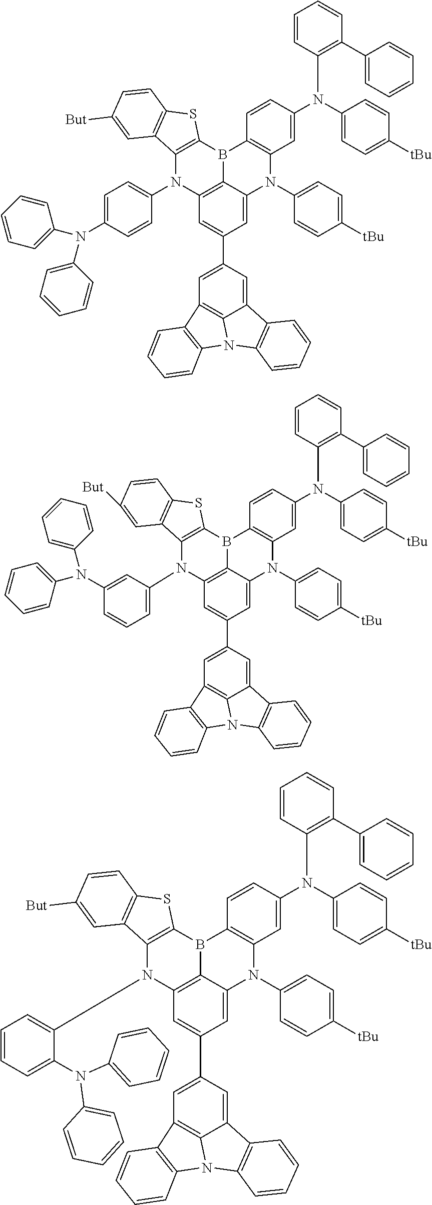

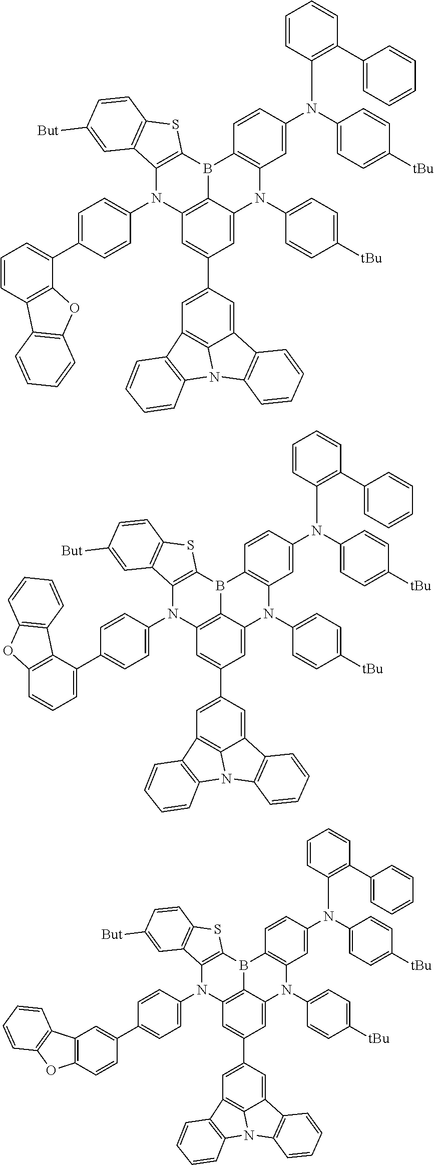

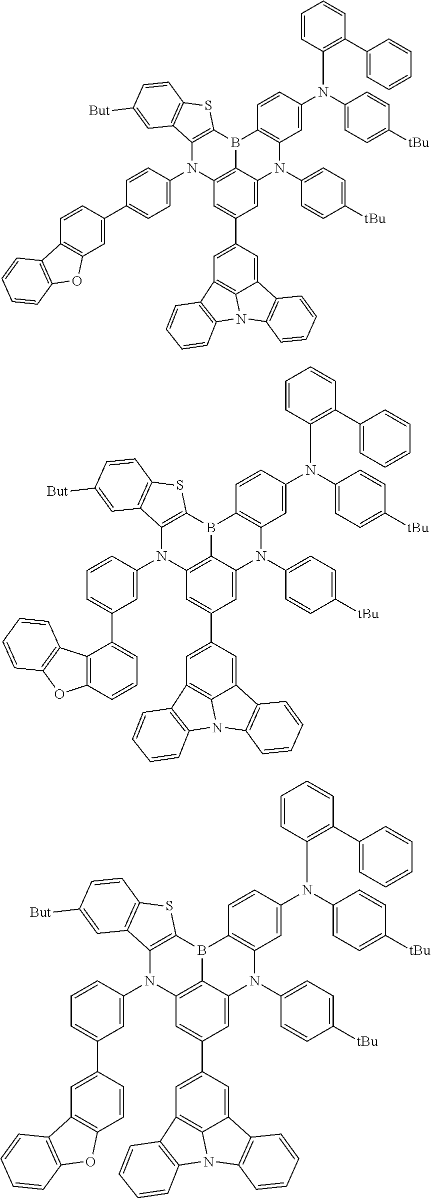

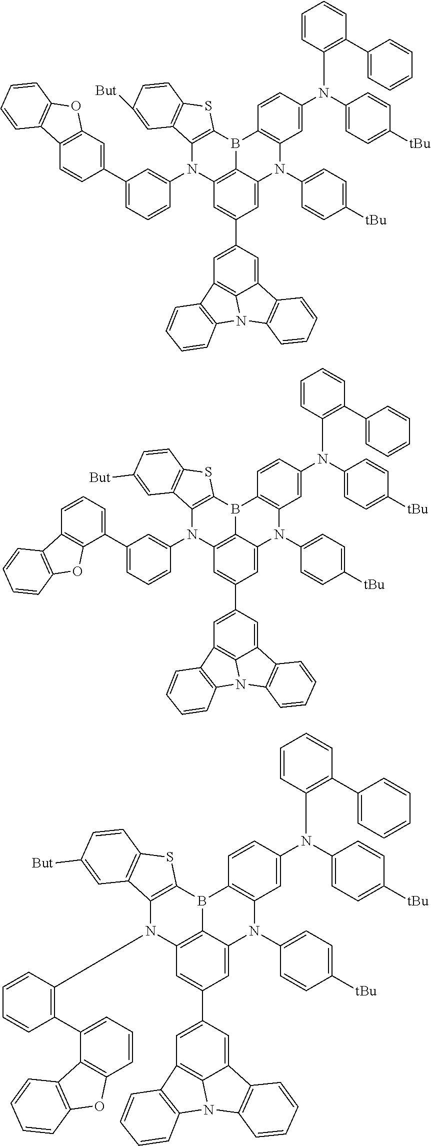

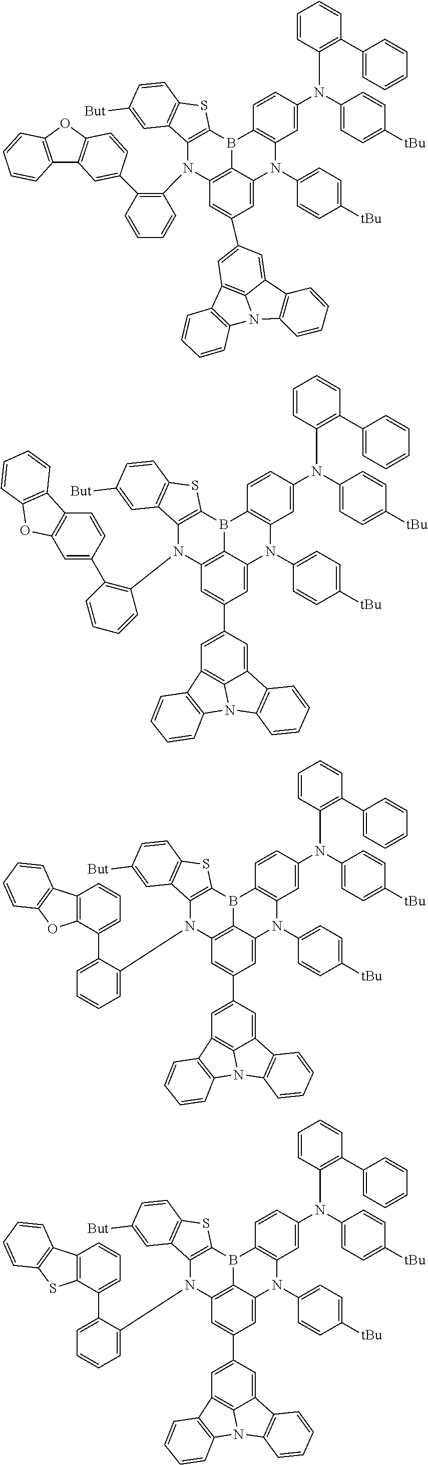

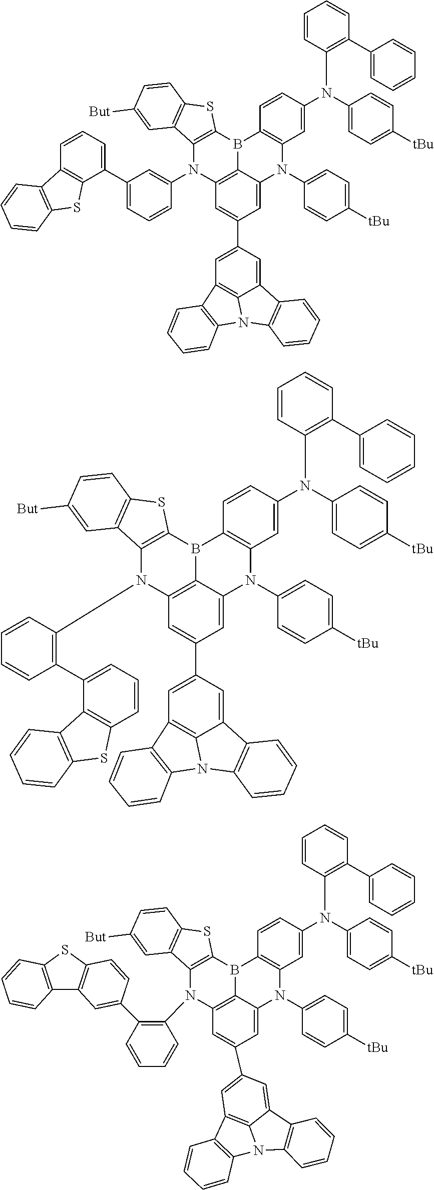

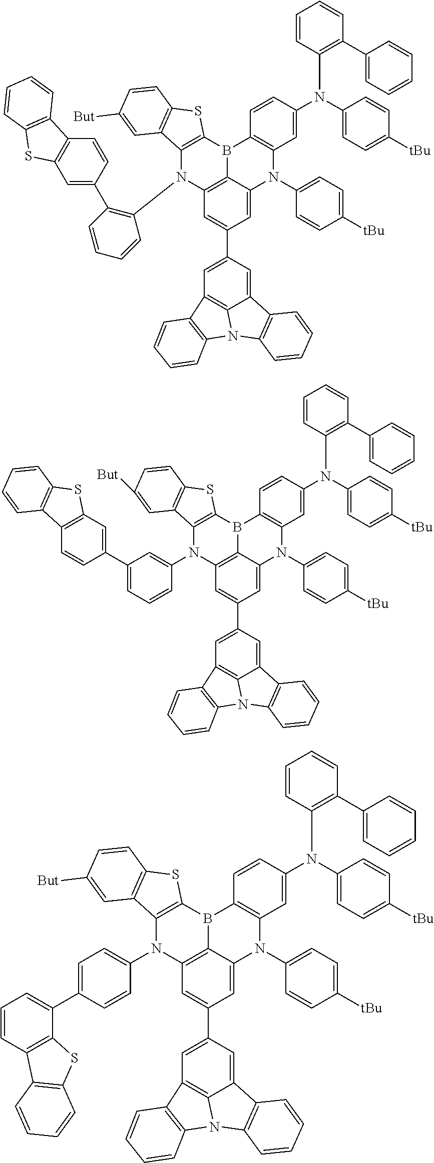

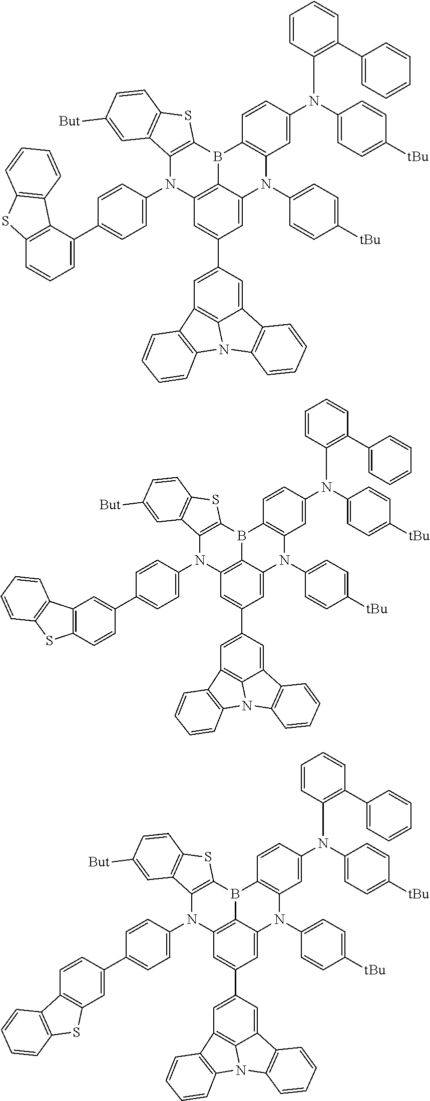

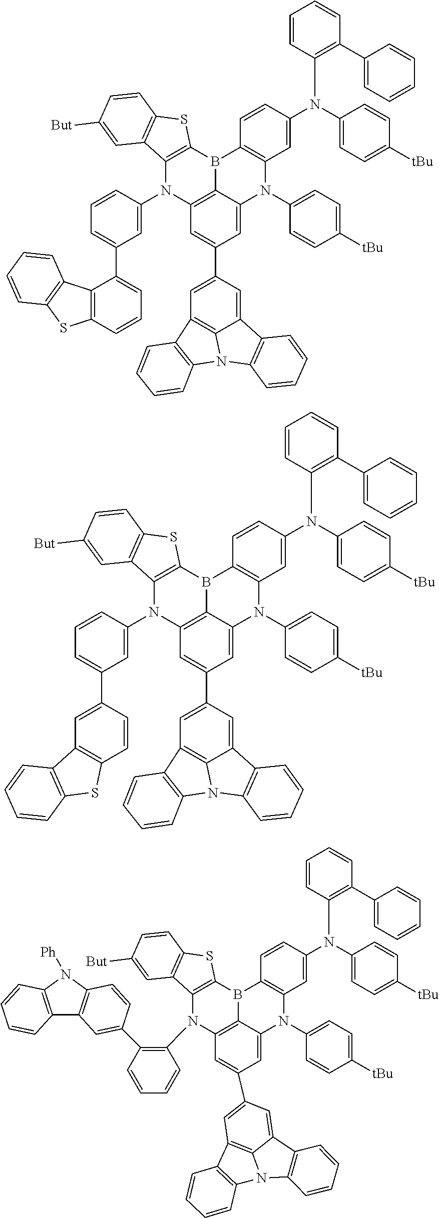

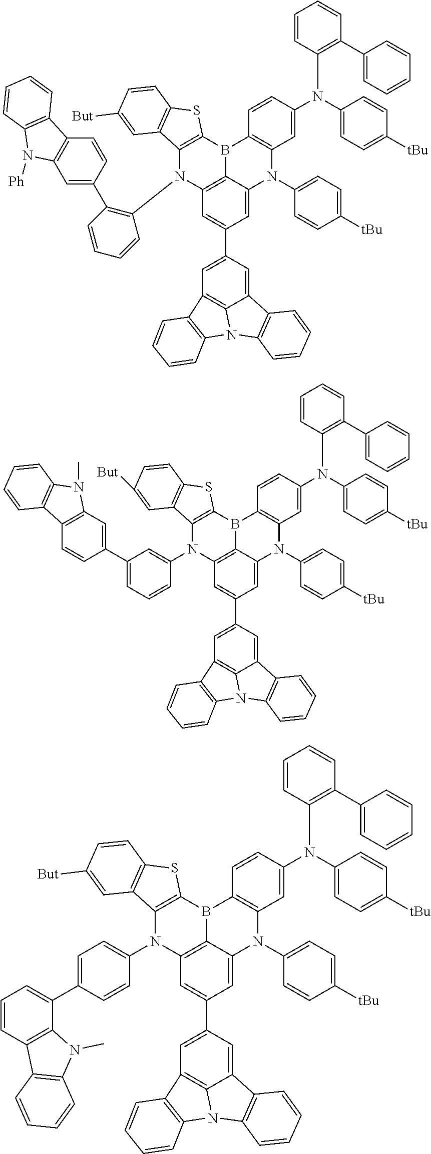

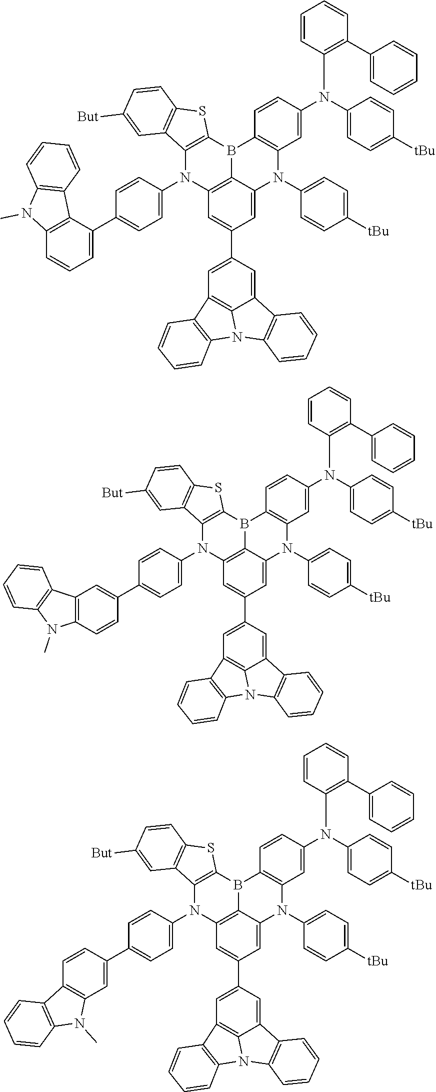

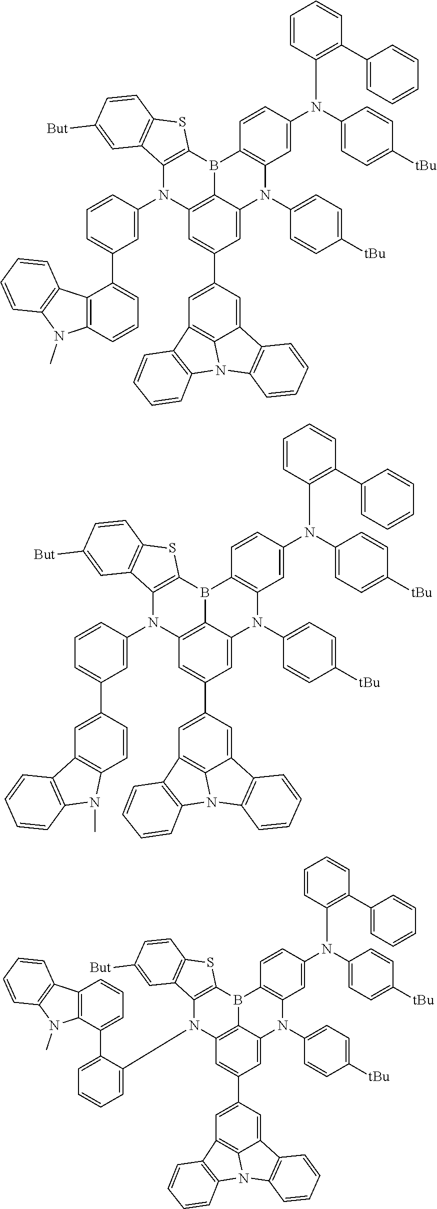

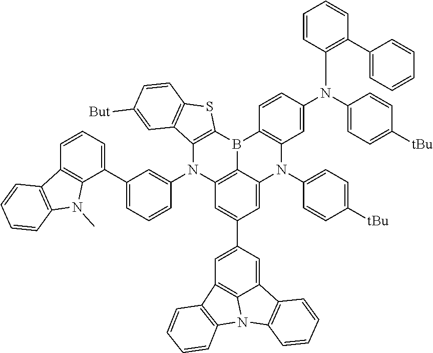

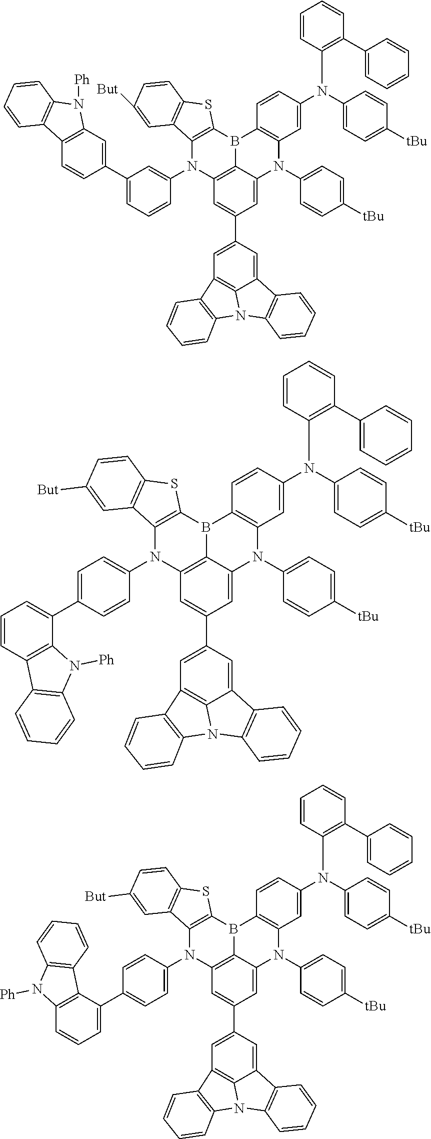

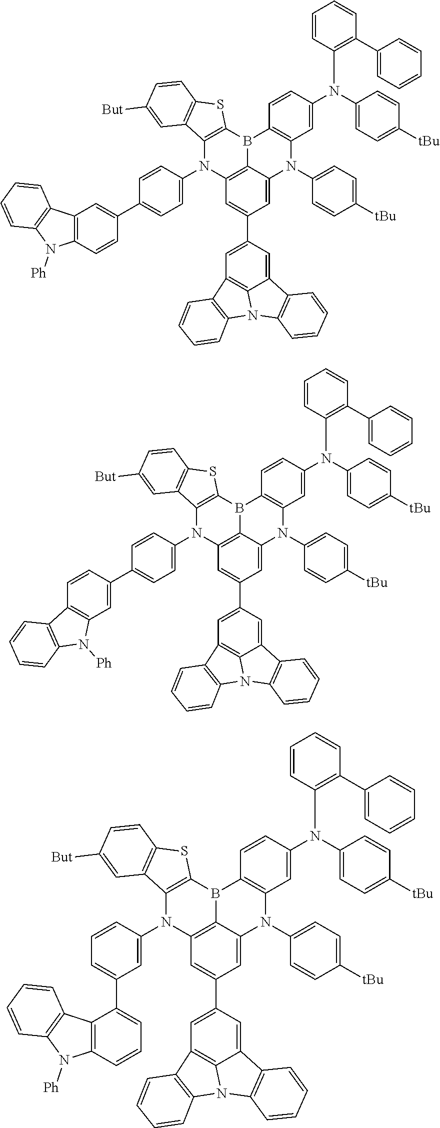

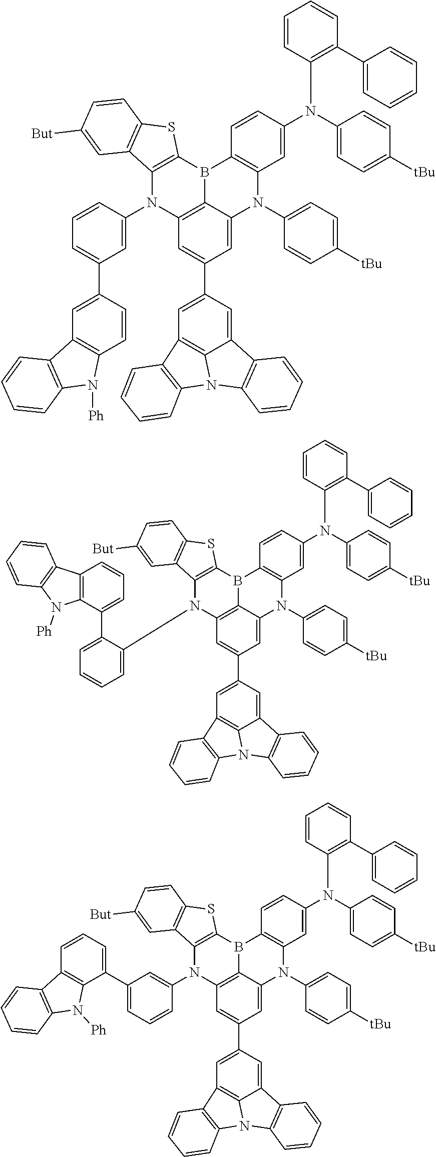

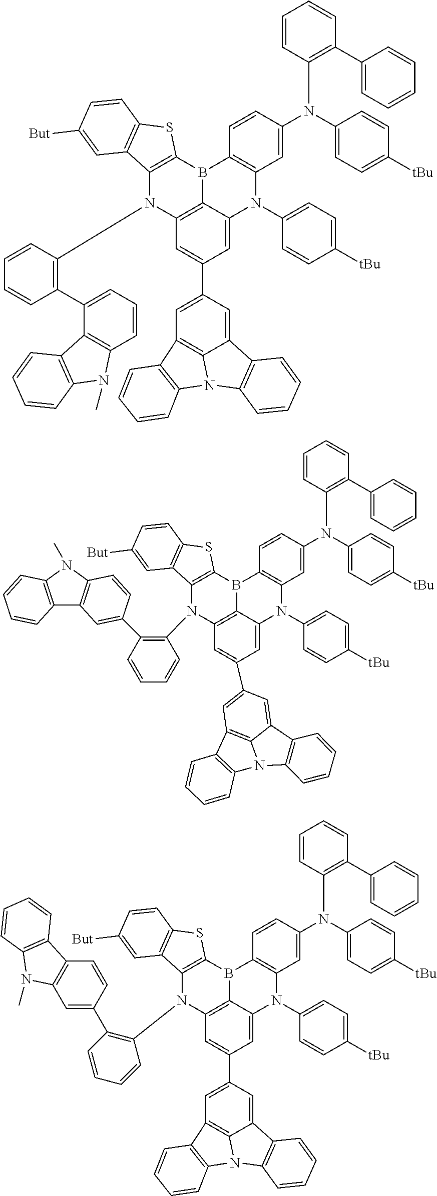

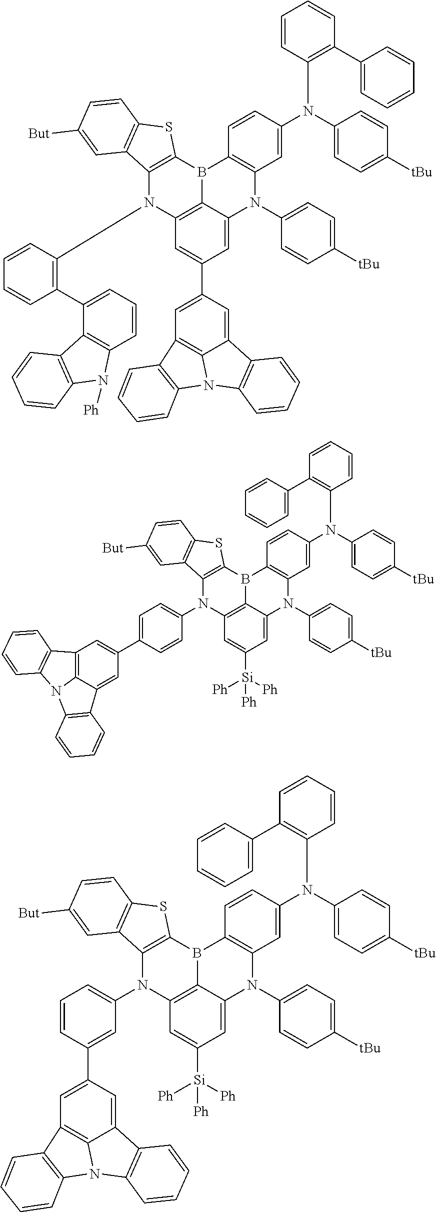

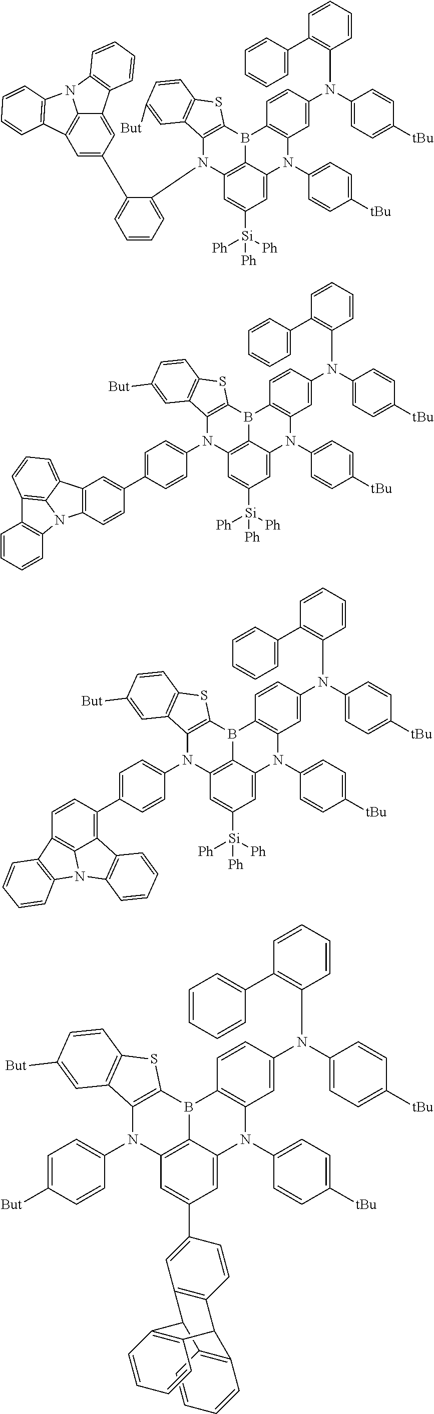

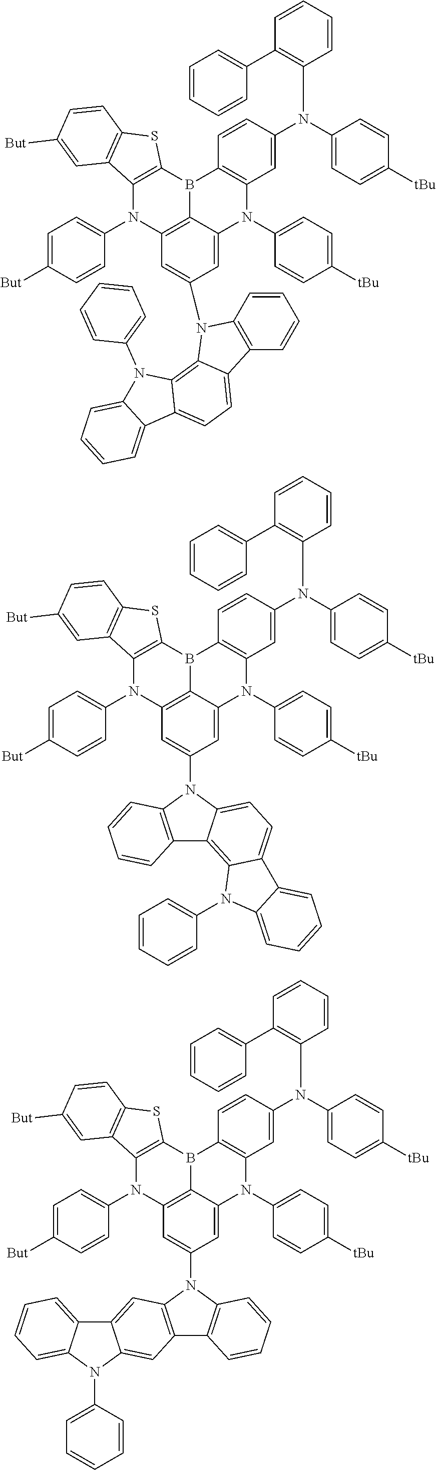

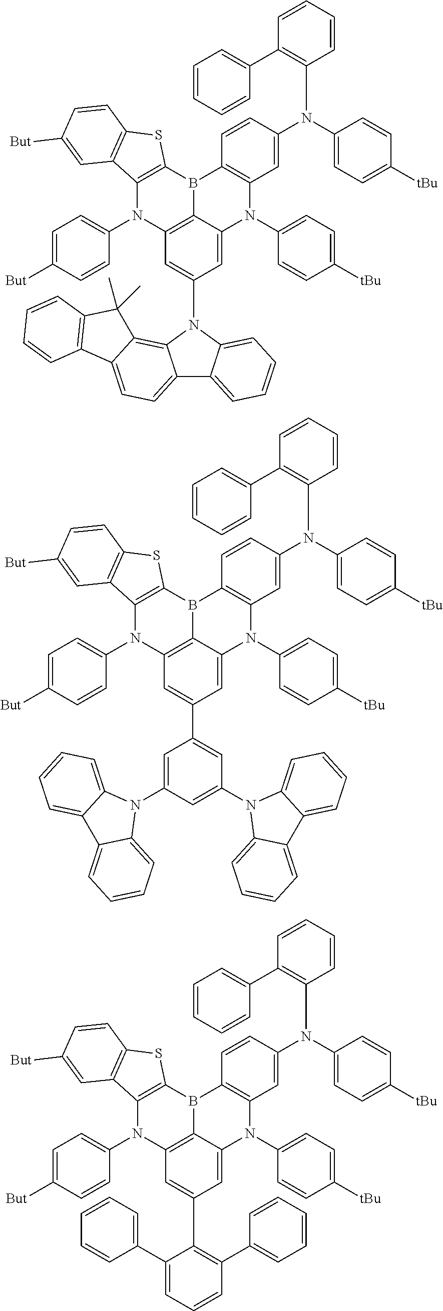

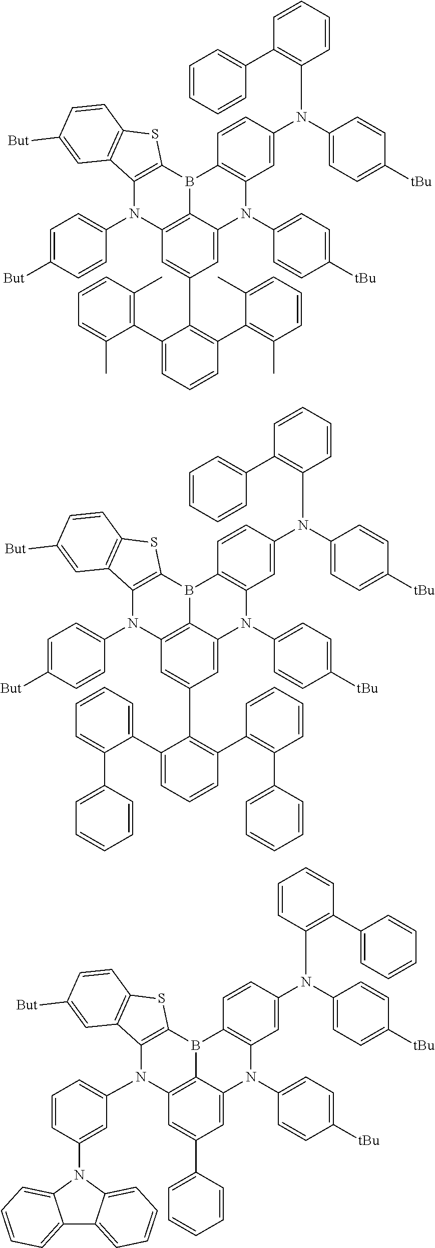

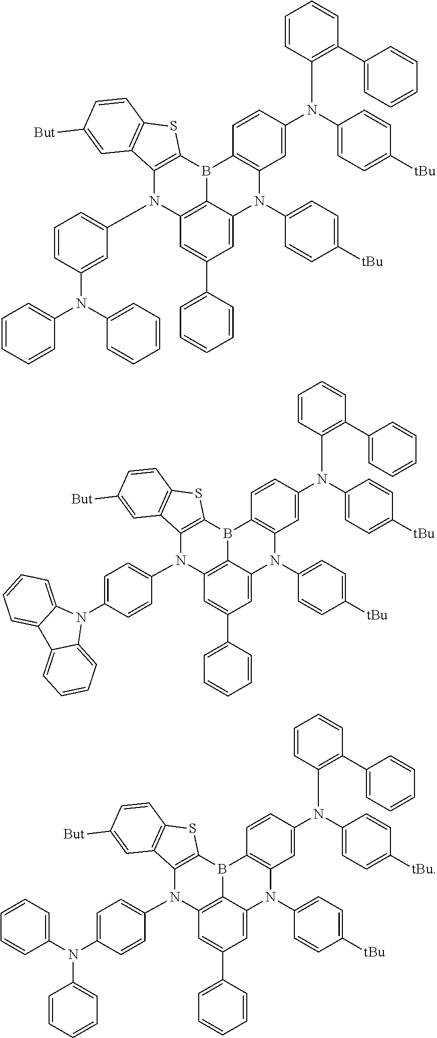

Further, the embodiments of the present application also provide a method for preparing the above-mentioned organic compound, and provide the following Examples 1 to 36 to describe in detail the preparation process of the organic compounds provided in the embodiments of the present application.

### Example 1

The synthetic route of the organic compound M1 is as follows:

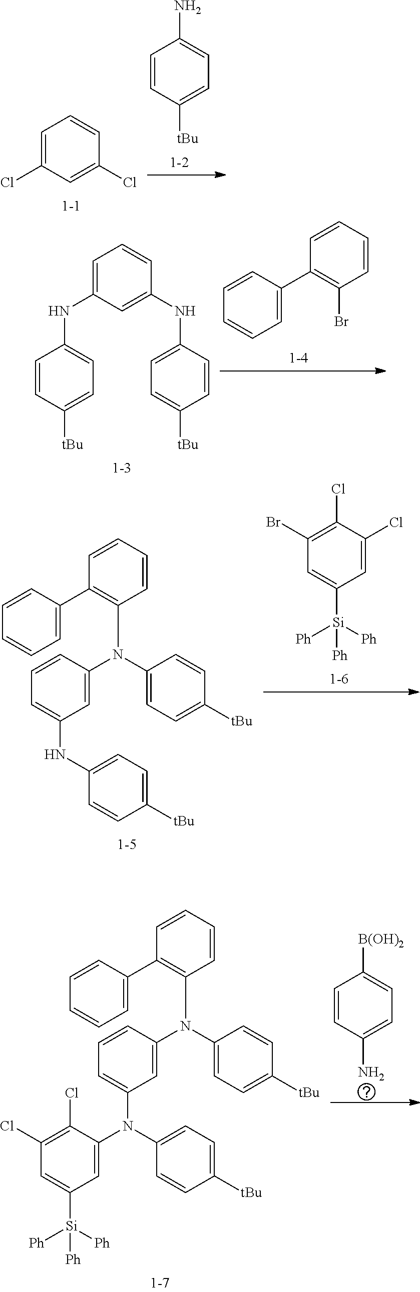

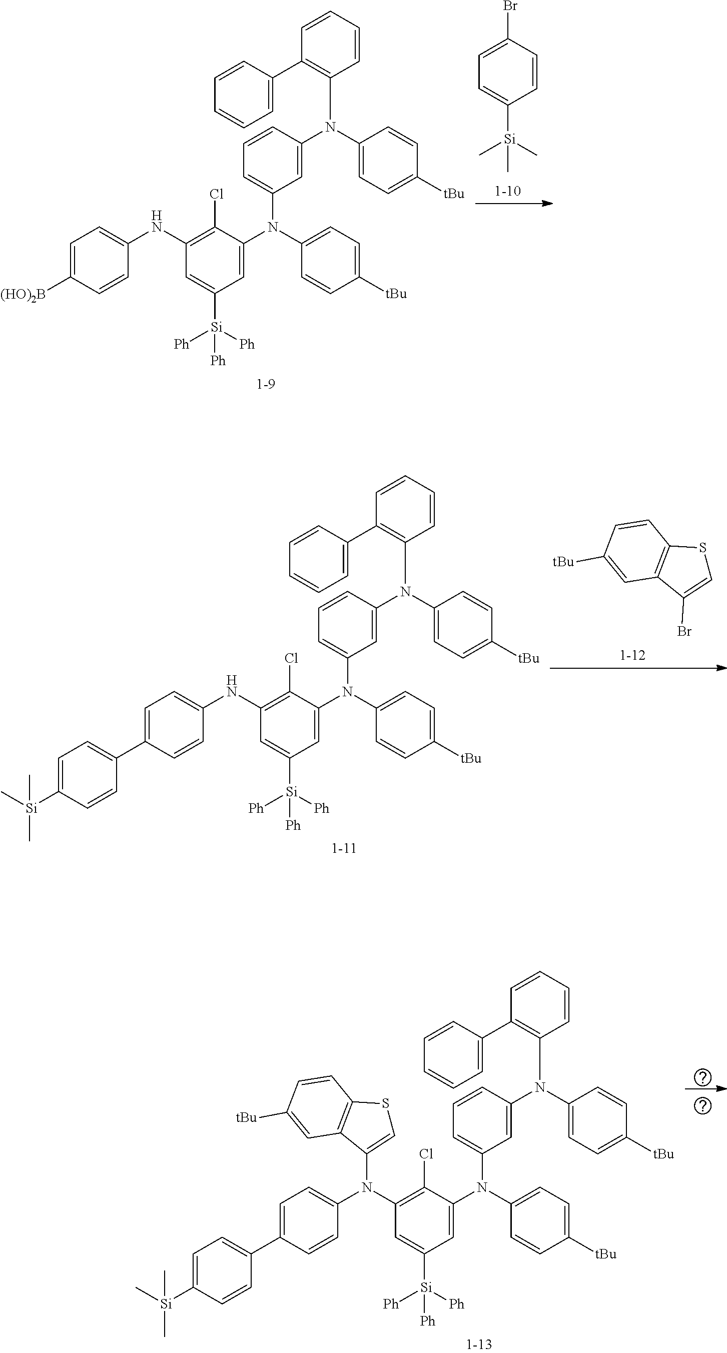

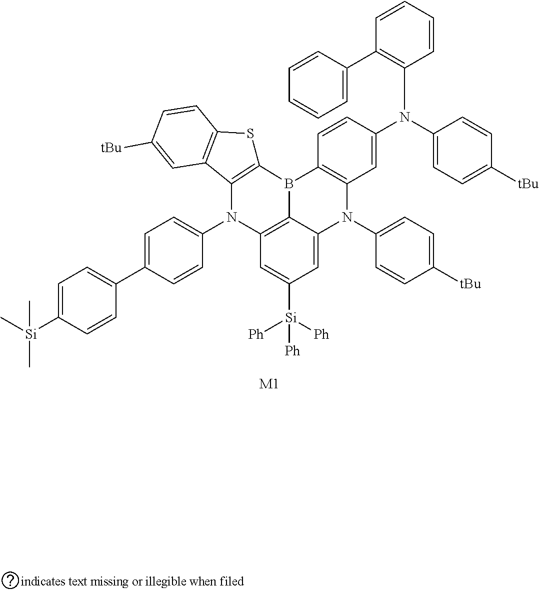

### Synthesis of the Intermediate 1-3

Compound 1-1 (10 mmol), Compound 1-2 (20 mmol), Pd(dba)₂ (bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. and stirred for 6 h under a nitrogen atmosphere; after the reaction solution was cooled, the solvent was removed by rotary evaporation, the reaction solution was extracted and the separated solution was washed with water, and the organic phase was subjected to column chromatography to obtain the intermediate 1-3 with a molar amount of 8.33 mmol and a yield of 83.3%. The atmospheric pressure solid phase analysis probe mass spectrometry (ASAP-MS) result of the intermediate 1-3 was: MS (ASAP)=372.

### Synthesis of the Intermediate 1-5

Compound 1-3 (10 mmol), Compound 1-4 (10 mmol), Pd(dba)₂ (bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. under a nitrogen atmosphere and stirred for 6 h; after the reaction solution was cooled, the solvent was removed by rotary evaporation, the reaction solution was extracted and the separated solution was washed with water, and the organic phase was subjected to column chromatography to obtain the intermediate 1-5 with a molar amount of 7.57 mmol and a yield of 75.7%. The atmospheric pressure solid phase analysis probe mass spectrometry (ASAP-MS) result of the intermediate 1-5 was: MS (ASAP)=524.

### Synthesis of the Intermediate 1-7

The intermediate 1-5 (10 mmol), Compound 1-6 (10 mmol), Pd-132 (bis(di-tert-butyl-4-dimethylaminophenylphosphine)palladium chloride, 0.1 mmol), S-Phos (2-dicyclohexylphosphine-2′,6′-dimethoxy-1,1′-biphenyl, 0.2 mmol) and sodium tert-butoxide (30 mmol) were dissolved in toluene, heated to 100° C. under a nitrogen atmosphere and stirred for 6 h; after the reaction solution was cooled, the solvent was removed by rotary evaporation, the reaction solution was extracted and the separated solution was washed with water, and the organic phase was subjected to column chromatography to obtain the intermediate 1-7 with a molar amount of 6.32 mmol and a yield of 63.2%. The atmospheric pressure solid phase analysis probe mass spectrometry (ASAP-MS) result of the intermediate 1-7 was: MS (ASAP)=926.

### Synthesis of the Intermediate 1-9

The intermediate 1-7 (10 mmol), Compound 1-8 (10 mmol), Pd-132 (bis(di-tert-butyl-4-dimethylaminophenylphosphine)palladium chloride, 0.1 mmol), S-Phos (2-dicyclohexylphosphine-2′,6′-dimethoxy-1,1′-biphenyl, 0.2 mmol) and sodium tert-butoxide (30 mmol) were dissolved in toluene, heated to 100° C. and stirred for 6 h under a nitrogen atmosphere; after the reaction solution was cooled, most of the solvent was removed by rotary evaporation, and then the reaction solution was extracted and the separated solution was washed with water, and the organic phase was subjected to column chromatography and recrystallization to obtain the intermediate 1-9, with a molar amount of 6.37 mmol and a yield of 63.7%. The atmospheric pressure solid phase analysis probe mass spectrometry (ASAP-MS) result of the intermediate 1-9 was: MS (ASAP)=1027.

### Synthesis of the Intermediate 1-11

The intermediate 1-9 (10 mmol) and the intermediate 1-10 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. and stirred for 6 h under a nitrogen atmosphere. After the reaction solution was cooled, most of the solvent was removed by rotary evaporation, and then the reaction solution was extracted and the separated solution was washed with water. The organic phase was subjected to column chromatography and recrystallization to obtain the intermediate 1-11 with a molar amount of 7.28 mmol and a yield of 72.8%. The atmospheric pressure solid phase analysis probe mass spectrometry (ASAP-MS) result of the intermediate 1-11 was: MS (ASAP)=1131.

### Synthesis of the Intermediate 1-13

The intermediate 1-11 (10 mmol), the intermediate 1-12 (10 mmol), Pd(dba)₂ (bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. and stirred for 6 h under nitrogen atmosphere; after the reaction solution was cooled, the solvent was removed by rotary evaporation, the reaction solution was extracted and the separated solution was washed with water, and the organic phase was subjected to column chromatography to obtain the intermediate 1-13 with a molar amount of 5.39 mmol and a yield of 53.9%. The atmospheric pressure solid phase analytical probe mass spectrometry (ASAP-MS) result of the intermediate 1-13 was: MS (ASAP)=1319.

### Synthesis of the Organic Compound M1

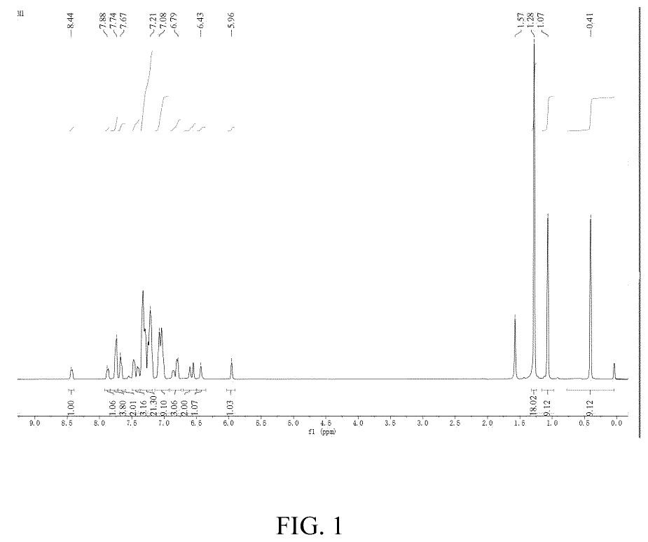

A 250 ml three-necked flask was added with 10 mmol of the intermediate 1-13 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M1, the yield is 47.3%, the atmospheric pressure solid phase analysis probe mass spectrometry (ASAP-MS) result of the organic compound M1 is: MS (ASAP)=1293; and the nuclear magnetic resonance hydrogen spectrum of the organic compound M1 is shown in FIG. 1.

### Example 2

The synthesis route of the organic compound M2 is as follows:

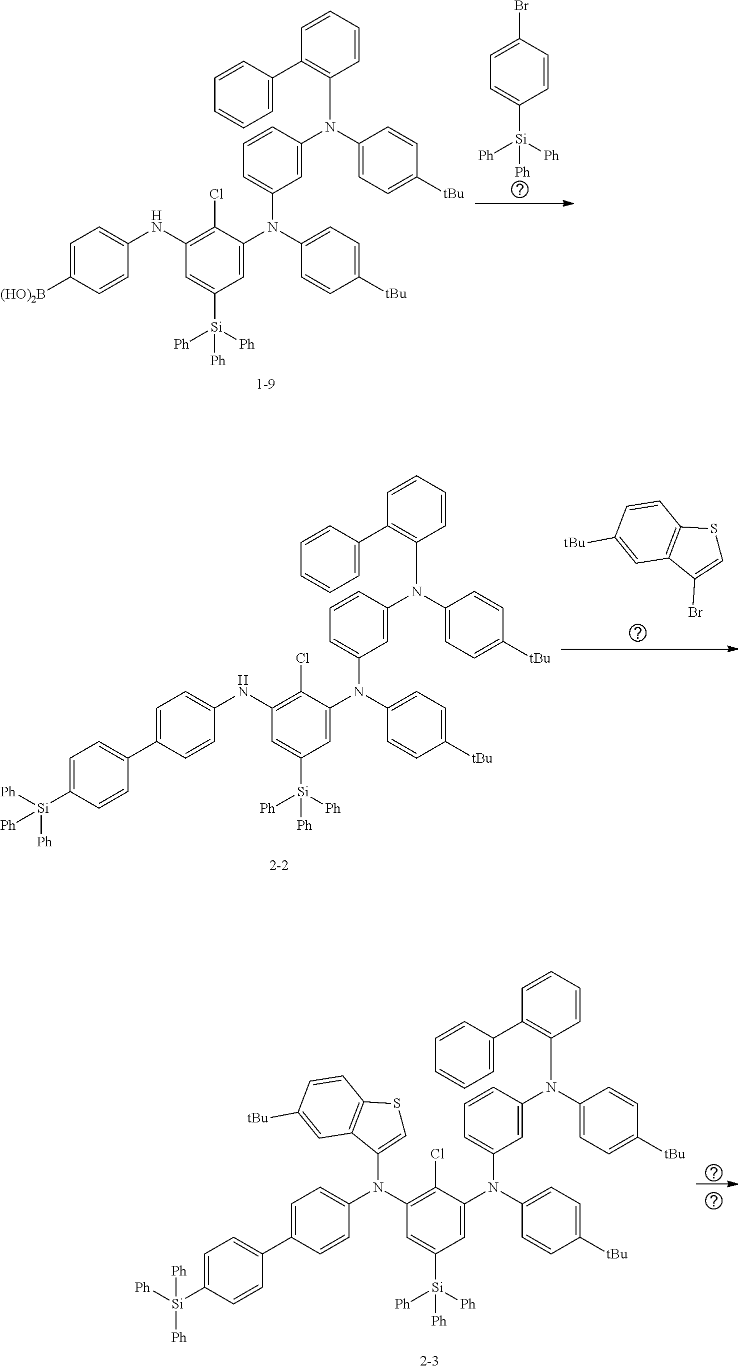

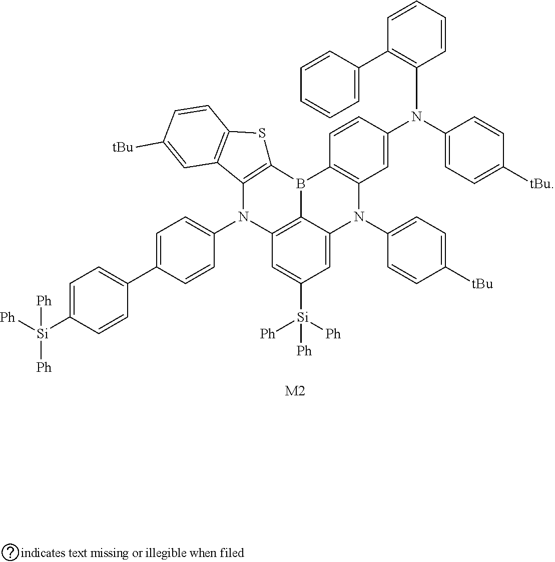

### Synthesis of the Intermediate 2-2

Compound 1-9 (10 mmol) and Compound 2-1 (10 mmol) were dissolved in a mixed solvent of 1,4-dioxane and water (21/2 ml), and Pd(PPh₃)₄ (0.1 mmol) and potassium Carbonate (30 mmol) were added. The temperature was raised to 100° C. under a nitrogen atmosphere and stirred for 6 h. After the reaction solution was cooled, the solvent was removed by rotary evaporation, the reaction solution was extracted and the separated solution was washed with water, and the organic phase was subjected to column chromatography to obtain the intermediate 2-2 with a molar amount of 8.38 mmol and a yield of 83.8%. The atmospheric pressure solid phase analysis probe mass spectrometry (ASAP-MS) result of the intermediate 2-2 was: MS (ASAP)=1317.

### Synthesis of the Intermediate 2-3

The intermediate 2-2 (10 mmol), the intermediate 1-12 (10 mmol), Pd(dba)₂ (bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. under nitrogen atmosphere and stirred for 6 h; after the reaction solution was cooled, the solvent was removed by rotary evaporation, the reaction solution was extracted and the separated solution was washed with water, and the organic phase was subjected to column chromatography to obtain the intermediate 2-3 with a molar amount of 5.81 mmol and a yield of 58.1%. The atmospheric pressure solid phase analytical probe mass spectrometry (ASAP-MS) result of the intermediate 2-3 was: MS (ASAP)=1505.

### Synthesis of the Organic Compound M2

10 mmol of the intermediate 2-3 and 100 ml of dry tert-butylbenzene were added to a 250 ml three-necked flask. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The pure product was obtained by rapid silica gel column purification. The product was recrystallized from toluene and ethyl acetate to obtain a light yellow solid powder product product, i.e., the organic compound M2, with a yield of 39.7%. Atmospheric pressure solid phase analysis probe mass spectrometry (ASAP-MS) results of organic compound M2: MS (ASAP)=1479.

### Example 3

The synthetic route of the organic compound M3 is as follows:

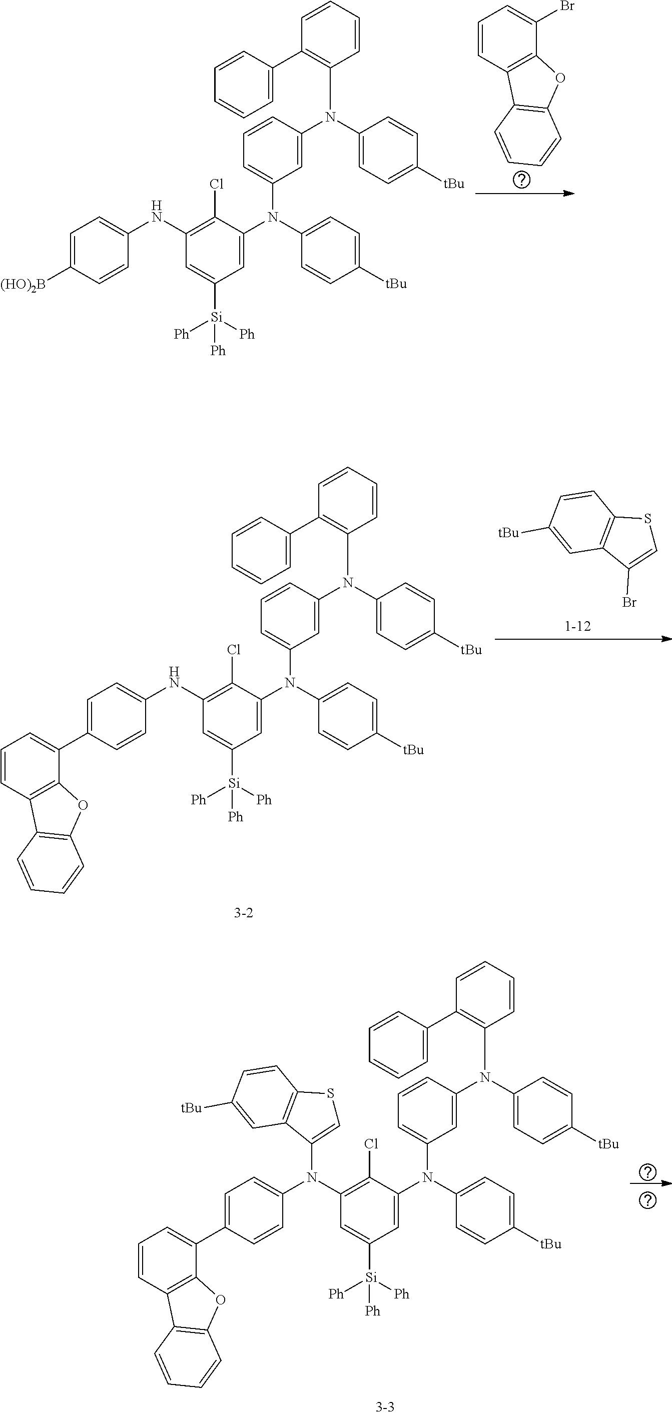

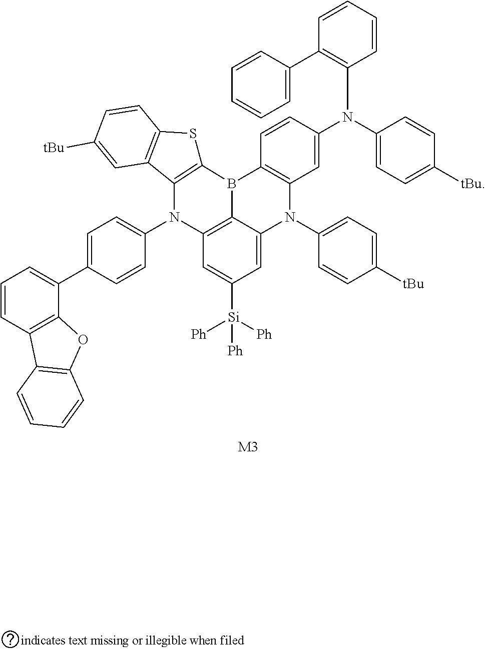 [SMILES: CC(C)(C)c1ccc(N(c2ccc3c(c2)N(c2ccc(C(C)(C)C)cc2)c2cc([Si](c4ccccc4)(c4ccccc4)c4ccccc4)cc4c2B3c2sc3ccc(C(C)(C)C)cc3c2N4c2ccc(-c3cccc4c3oc3ccccc34)cc2)c2ccccc2-c2ccccc2)cc1 ; "M3"]

### Synthesis of the Intermediate 3-2

Compound 1-9 (10 mmol) and Compound 3-1 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. under a nitrogen atmosphere and stirred for 6 h. After the reaction solution was cooled, the solvent was removed by rotary evaporation, the reaction solution was extracted and the separated solution was washed with water, and the organic phase was subjected to column chromatography to obtain the intermediate 3-2 with a molar amount of 8.64 mmol and a yield of 86.4%. The atmospheric pressure solid phase analysis probe mass spectrometry (ASAP-MS) result of the intermediate 3-2 was: MS (ASAP)=1149.

### Synthesis of the Intermediate 3-3

The intermediate 3-2 (10 mmol), the intermediate 1-12 (10 mmol), Pd(dba)₂ (bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. under nitrogen atmosphere and stirred for 6 h; after the reaction solution was cooled, the solvent was removed by rotary evaporation, the reaction solution was extracted and the separated solution was washed with water, and the organic phase was subjected to column chromatography to obtain the intermediate 3-3 with a molar amount of 6.43 mmol and a yield of 64.3%. The atmospheric pressure solid phase analytical probe mass spectrometry (ASAP-MS) result of the intermediate 3-3 was: MS (ASAP)=1337.

### Synthesis of the Organic Compound M3

A 250 ml three-necked flask was added with 10 mmol of the intermediate 3-3 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The pure product was obtained by rapid silica gel column purification. The product was recrystallized from toluene and ethyl acetate to obtain a light yellow solid powder product, i.e., the organic compound M3, with a yield of 34.2%. The atmospheric pressure solid phase analysis probe mass spectrometry (ASAP-MS) results of the organic compound M3: MS (ASAP)=1311.

### Example 4

The synthetic route of the organic compound M4 is as follows:

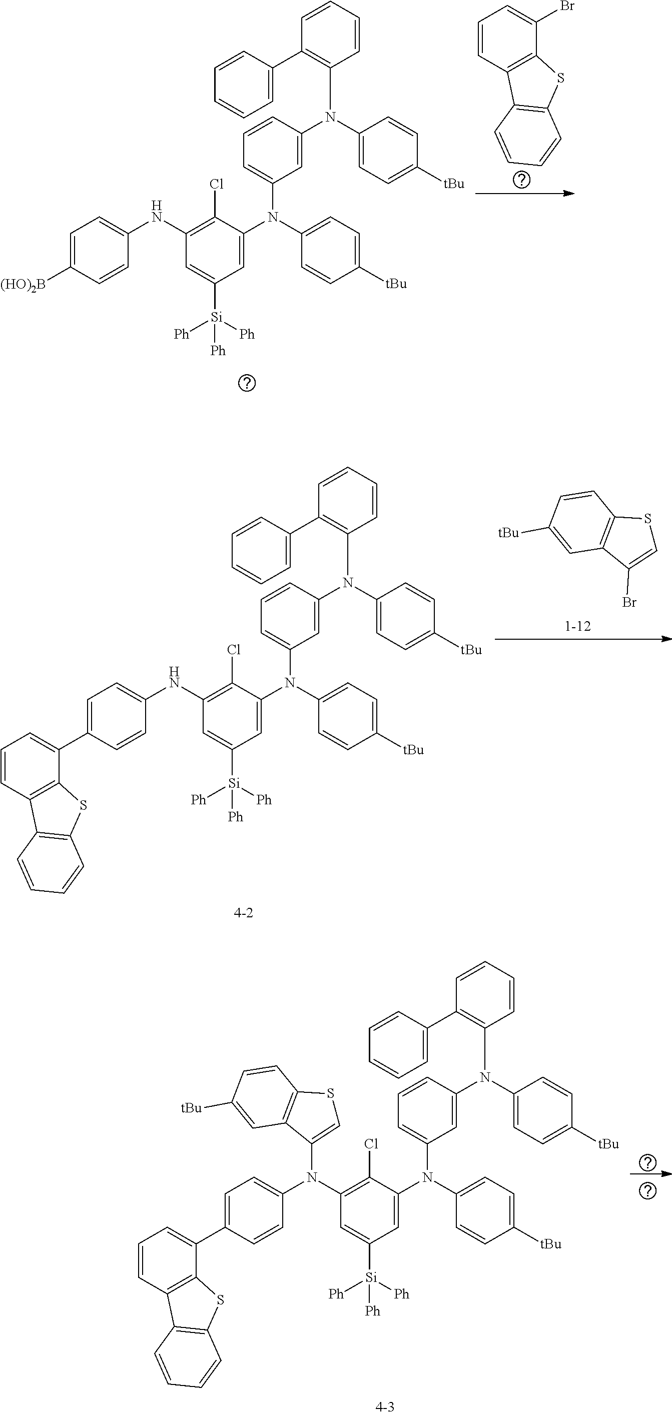

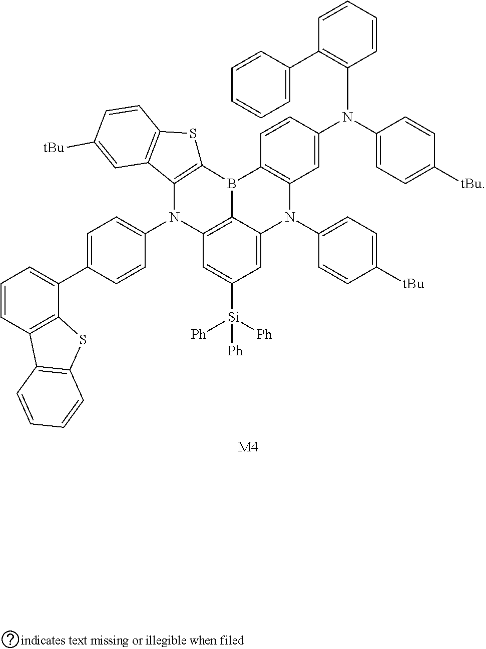 [SMILES: CC(C)(C)c1ccc(N(c2ccc3c(c2)N(c2ccc(C(C)(C)C)cc2)c2cc([Si](c4ccccc4)(c4ccccc4)c4ccccc4)cc4c2B3c2sc3ccc(C(C)(C)C)cc3c2N4c2ccc(-c3cccc4c3sc3ccccc34)cc2)c2ccccc2-c2ccccc2)cc1 ; "M4"]

### Synthesis of the Intermediate 4-2

Compound 1-9 (10 mmol) and Compound 4-1 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. under a nitrogen atmosphere and stirred for 6 h. After the reaction solution was cooled, the solvent was removed by rotary evaporation, the reaction solution was extracted and the separated solution was washed with water, and the organic phase was subjected to column chromatography to obtain the intermediate 4-2 with a molar amount of 8.31 mmol and a yield of 83.1%. The atmospheric pressure solid phase analysis probe mass spectrometry (ASAP-MS) result of the intermediate 4-2 was: MS (ASAP)=1165.

### Synthesis of the Intermediate 4-3

The intermediate 4-2 (10 mmol), the intermediate 1-12 (10 mmol), Pd(dba)-(bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. under nitrogen atmosphere and stirred for 6 h; after the reaction solution was cooled, the solvent was removed by rotary evaporation, the reaction solution was extracted and the separated solution was washed with water, and the organic phase was subjected to column chromatography to obtain the intermediate 4-3, with a molar amount of 6.15 mmol and a yield of 61.5%. The atmospheric pressure solid phase analytical probe mass spectrometry (ASAP-MS) result of the intermediate 4-3 was: MS (ASAP)=1353.

### Synthesis of the Organic Compound M4

A 250 ml three-necked flask was added with 10 mmol of the intermediate 4-3 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M4, the yield was 42.7%, and the atmospheric pressure solid phase analysis probe mass spectrometry (ASAP-MS) result of the organic compound M4 was: MS (ASAP)=1327.

### Example 5

The synthetic route of the organic compound M5 is as follows:

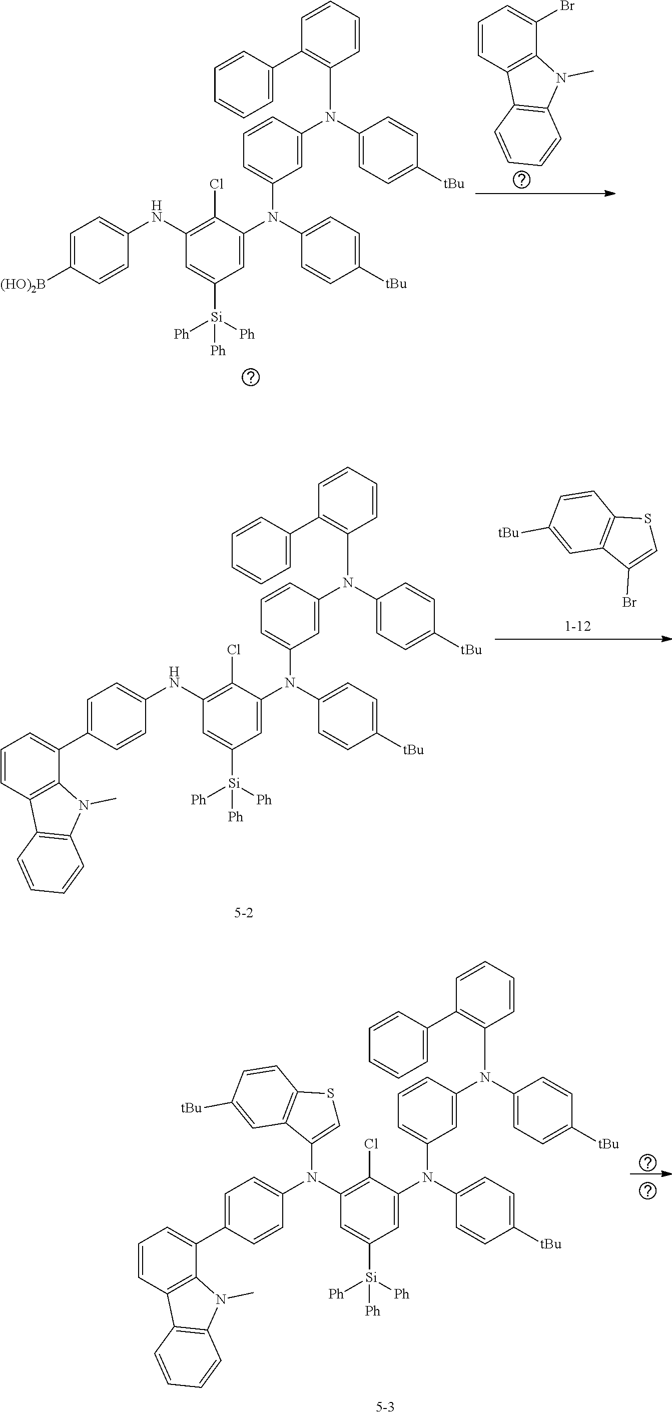

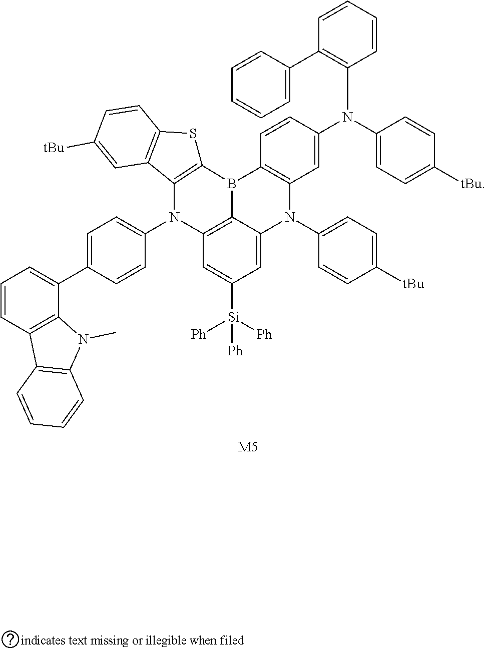 [SMILES: Cn1c2ccccc2c2cccc(-c3ccc(N4c5cc([Si](c6ccccc6)(c6ccccc6)c6ccccc6)cc6c5B(c5ccc(N(c7ccc(C(C)(C)C)cc7)c7ccccc7-c7ccccc7)cc5N6c5ccc(C(C)(C)C)cc5)c5sc6ccc(C(C)(C)C)cc6c54)cc3)c21 ; "M5"]

### Synthesis of the Intermediate 5-2

Compound 1-9 (10 mmol) and compound 5-1 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. under a nitrogen atmosphere and stirred for 6 h. After the reaction solution was cooled, the solvent was removed by rotary evaporation, the reaction solution was extracted and the separated solution was washed with water, and the organic phase was subjected to column chromatography to obtain the intermediate 5-2 with a molar amount of 8.24 mmol and a yield of 82.4%. The atmospheric pressure solid phase analysis probe mass spectrometry (ASAP-MS) result of the intermediate 5-2 was: MS (ASAP)=1162.

### Synthesis of the Intermediate 5-3

The intermediate 5-2 (10 mmol), the intermediate 1-12 (10 mmol), Pd(dba)₂ (bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. under nitrogen atmosphere and stirred for 6 h; after the reaction solution was cooled, the solvent was removed by rotary evaporation, the reaction solution was extracted and the separated solution was washed with water, and the organic phase was subjected to column chromatography to obtain the intermediate 5-3, with a molar amount of 7.13 mmol and a yield of 71.3%. The atmospheric pressure solid phase analytical probe mass spectrometry (ASAP-MS) result of the intermediate 5-3 was: MS (ASAP)=1350.

### Synthesis of the Organic Compound M5

A 250 ml three-necked flask was added with 10 mmol of the intermediate 5-3 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M5, the yield was 38.8%, and the atmospheric pressure solid phase analysis probe mass spectrometry (ASAP-MS) result of the organic compound M5 was: MS (ASAP)=1324.

### Example 6

The synthetic route of the organic compound M6 is as follows:

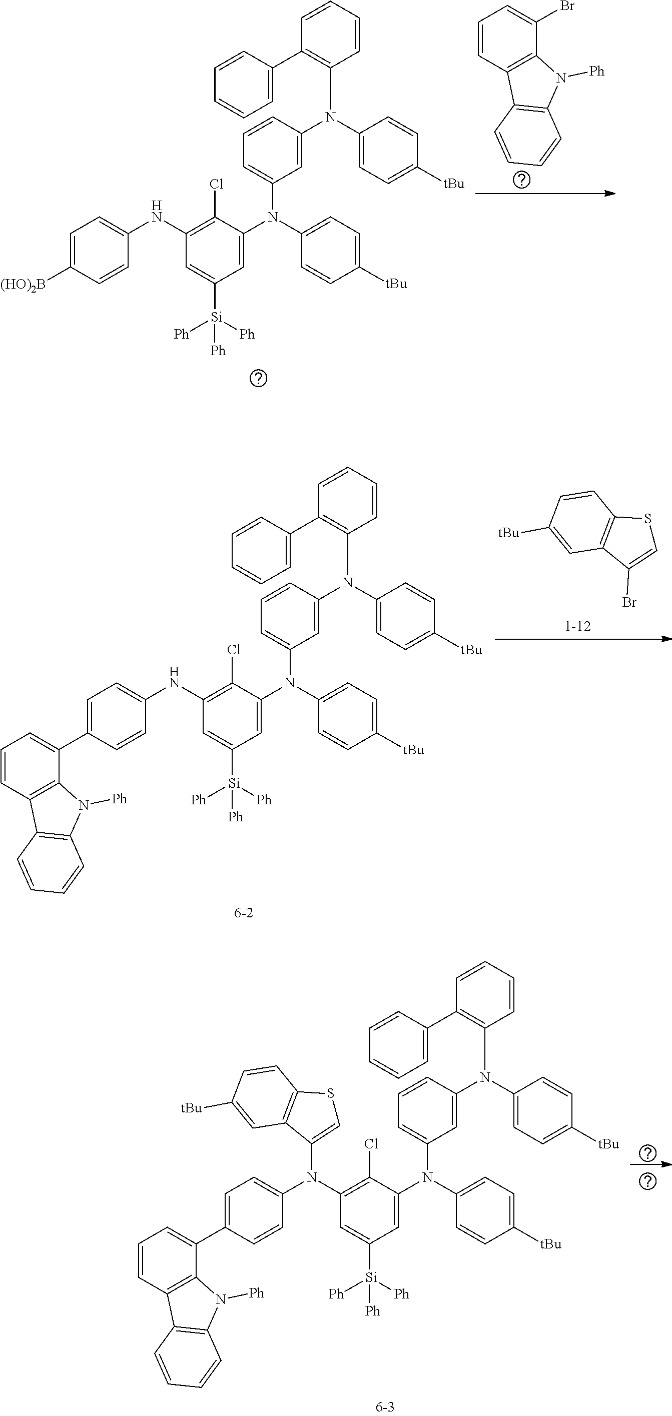

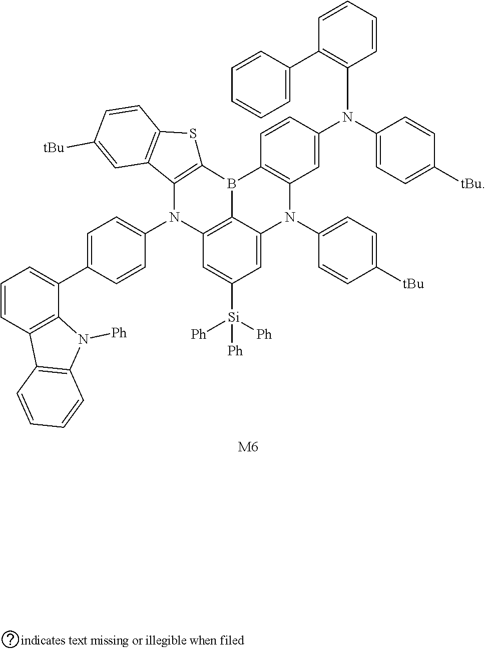 [SMILES: CC(C)(C)c1ccc(N(c2ccc3c(c2)N(c2ccc(C(C)(C)C)cc2)c2cc([Si](c4ccccc4)(c4ccccc4)c4ccccc4)cc4c2B3c2sc3ccc(C(C)(C)C)cc3c2N4c2ccc(-c3cccc4c5ccccc5n(-c5ccccc5)c34)cc2)c2ccccc2-c2ccccc2)cc1 ; "M6"]

### Synthesis of the Intermediate 6-2

Compound 1-9 (10 mmol) and Compound 6-1 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. under a nitrogen atmosphere and stirred for 6 h. After the reaction solution was cooled, the solvent was removed by rotary evaporation, the reaction solution was extracted and the separated solution was washed with water, and the organic phase was subjected to column chromatography to obtain the intermediate 6-2 with a molar amount of 6.52 mmol and a yield of 65.2%. The atmospheric pressure solid phase analysis probe mass spectrometry (ASAP-MS) result of the intermediate 6-2 was: MS (ASAP)=1224.

### Synthesis of the Intermediate 6-3

The intermediate 6-2 (10 mmol), the intermediate 1-12 (10 mmol), Pd(dba)₂ (bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. under nitrogen atmosphere and stirred for 6 h; after the reaction solution was cooled, the solvent was removed by rotary evaporation, the reaction solution was extracted and the separated solution was washed with water, and the organic phase was subjected to column chromatography to obtain the intermediate 6-3, with a molar amount of 8.34 mmol and a yield of 83.4%. The atmospheric pressure solid phase analytical probe mass spectrometry (ASAP-MS) result of the intermediate 6-3 was: MS (ASAP)=1412.

The synthesis of the organic compound M6:

A 250 ml three-necked flask was added with 10 mmol of the intermediate 6-3 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M6, the yield was 45.3%, and the atmospheric pressure solid phase analysis probe mass spectrometry (ASAP-MS) result of the organic compound M6 was: MS (ASAP)=1386.

### Example 7

The synthetic route of the organic compound M7 is as follows:

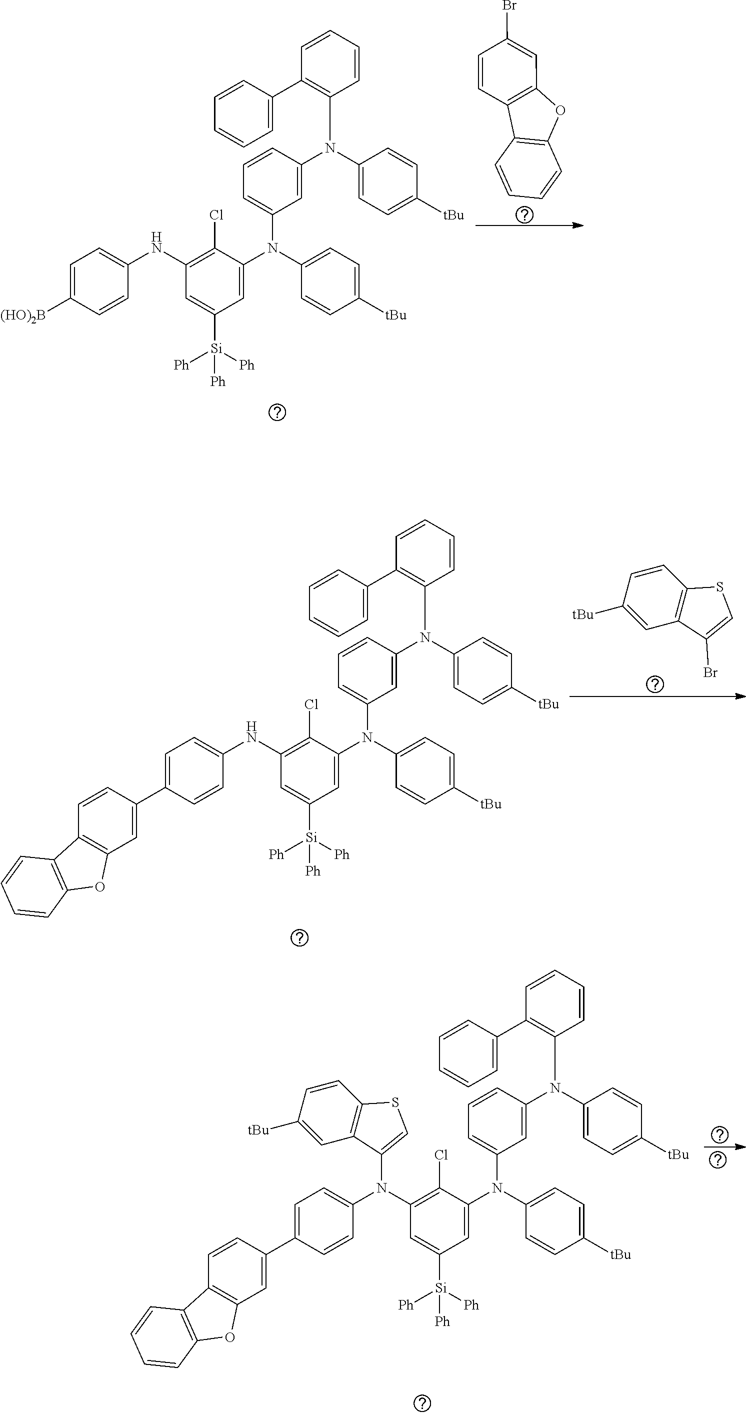

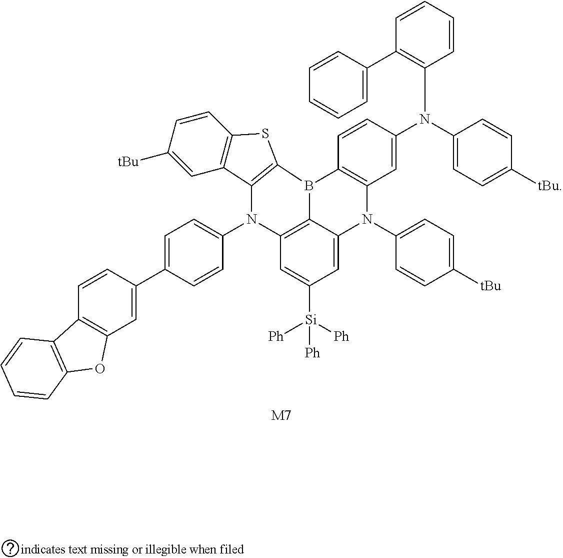 [SMILES: CC(C)(C)c1ccc(N(c2ccc3c(c2)N(c2ccc(C(C)(C)C)cc2)c2cc([Si](c4ccccc4)(c4ccccc4)c4ccccc4)cc4c2B3c2sc3ccc(C(C)(C)C)cc3c2N4c2ccc(-c3ccc4c(c3)oc3ccccc34)cc2)c2ccccc2-c2ccccc2)cc1 ; "M7"]

### Synthesis of the Intermediate 7-2

The Compound 1-9 (10 mmol) and Compound 7-1 (10 mml) were dissolved in a mixed solvent of 1,4-dioxane and water (21/2 ml), and Pd(PPh₃)₄ (0.1 mmol) and potassium Carbonate (30 mmol) were added. The temperature was raised to 100° C. under a nitrogen atmosphere and stirred for 6 h. After the reaction solution was cooled, the solvent was removed by rotary evaporation, the reaction solution was extracted and the separated solution was washed with water, and the organic phase was subjected to column chromatography to obtain the intermediate 7-2 with a molar amount of 7.46 mmol and a yield of 74.6%. The atmospheric pressure solid phase analysis probe mass spectrometry (ASAP-MS) result of the intermediate 7-2 was: MS (ASAP)=1149.

### Synthesis of the Intermediate 7-3

The intermediate 7-2 (10 mmol), the intermediate 1-12 (10 mmol), Pd(dba)₂ (bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. under nitrogen atmosphere and stirred for 6 h; after the reaction solution was cooled, the solvent was removed by rotary evaporation, the reaction solution was extracted and the separated solution was washed with water, and the organic phase was subjected to column chromatography to obtain the intermediate 7-3, with a molar amount of 8.59 mmol and a yield of 85.9%. The atmospheric pressure solid phase analytical probe mass spectrometry (ASAP-MS) result of the intermediate 7-3 was: MS (ASAP)=1337.

The synthesis of the organic compound M7:

A 250 ml three-necked flask was added with 10 mmol of the intermediate 7-3 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the the organic compound M 7, the yield was 41.6%, and the atmospheric pressure solid phase analysis probe mass spectrometry (ASAP-MS) result of the organic compound M 7 was: MS (ASAP)=1311.

### Example 8

The synthetic route of the organic compound M8 is as follows:

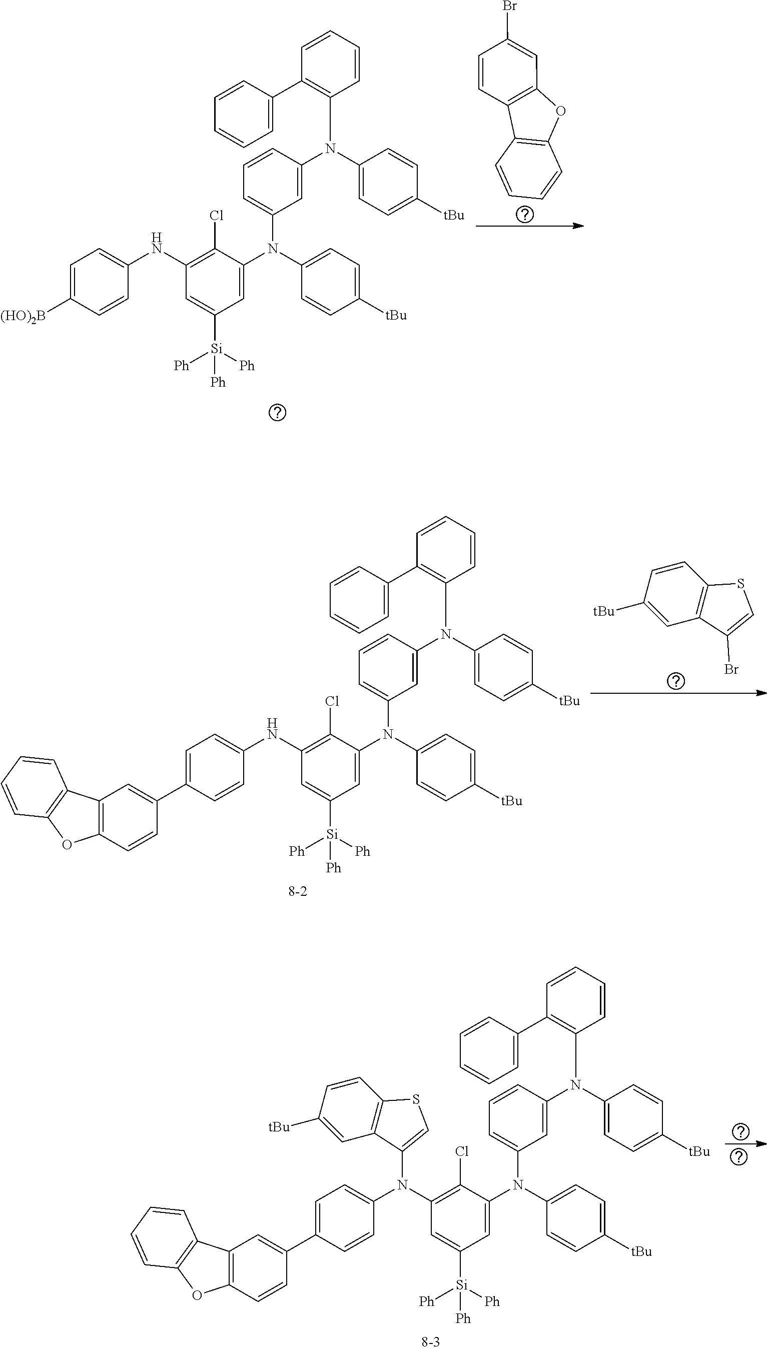

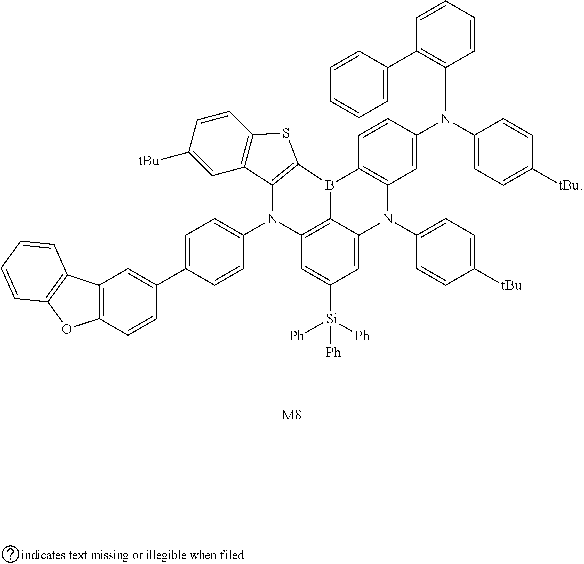 [SMILES: CC(C)(C)c1ccc(N(c2ccc3c(c2)N(c2ccc(C(C)(C)C)cc2)c2cc([Si](c4ccccc4)(c4ccccc4)c4ccccc4)cc4c2B3c2sc3ccc(C(C)(C)C)cc3c2N4c2ccc(-c3ccc4oc5ccccc5c4c3)cc2)c2ccccc2-c2ccccc2)cc1 ; "M8"]

### Synthesis of the Intermediate 8-2

Compound 1-9 (10 mmol) and compound 8-1 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. under a nitrogen atmosphere and stirred for 6 h. After the reaction solution was cooled, the solvent was removed by rotary evaporation, the reaction solution was extracted and the separated solution was washed with water, and the organic phase was subjected to column chromatography to obtain the intermediate 8-2 with a molar amount of 7.58 mmol and a yield of 75.8%. The atmospheric pressure solid phase analysis probe mass spectrometry (ASAP-MS) result of the intermediate 8-2 was: MS (ASAP)=1149.

### Synthesis of the Intermediate 8-3

The intermediate 8-2 (10 mmol), the intermediate 1-12 (10 mmol), Pd(dba)₂ (bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. under nitrogen atmosphere and stirred for 6 h; after the reaction solution was cooled, the solvent was removed by rotary evaporation, the reaction solution was extracted and the separated solution was washed with water, and the organic phase was subjected to column chromatography to obtain the intermediate 8-3, with a molar amount of 8.13 mmol and a yield of 81.3%. The atmospheric pressure solid phase analytical probe mass spectrometry (ASAP-MS) result of the intermediate 8-3 was: MS (ASAP)=1337.

### Synthesis of the Organic Compound M8

A 250 ml three-necked flask was added with 10 mmol of the intermediate 8-3 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M8, the yield was 49.2%, and the atmospheric pressure solid phase analysis probe mass spectrometry (ASAP-MS) result of the organic compound M8 was: MS (ASAP)=1311.

### Example 9

The synthetic route of the organic compound M9 is as follows:

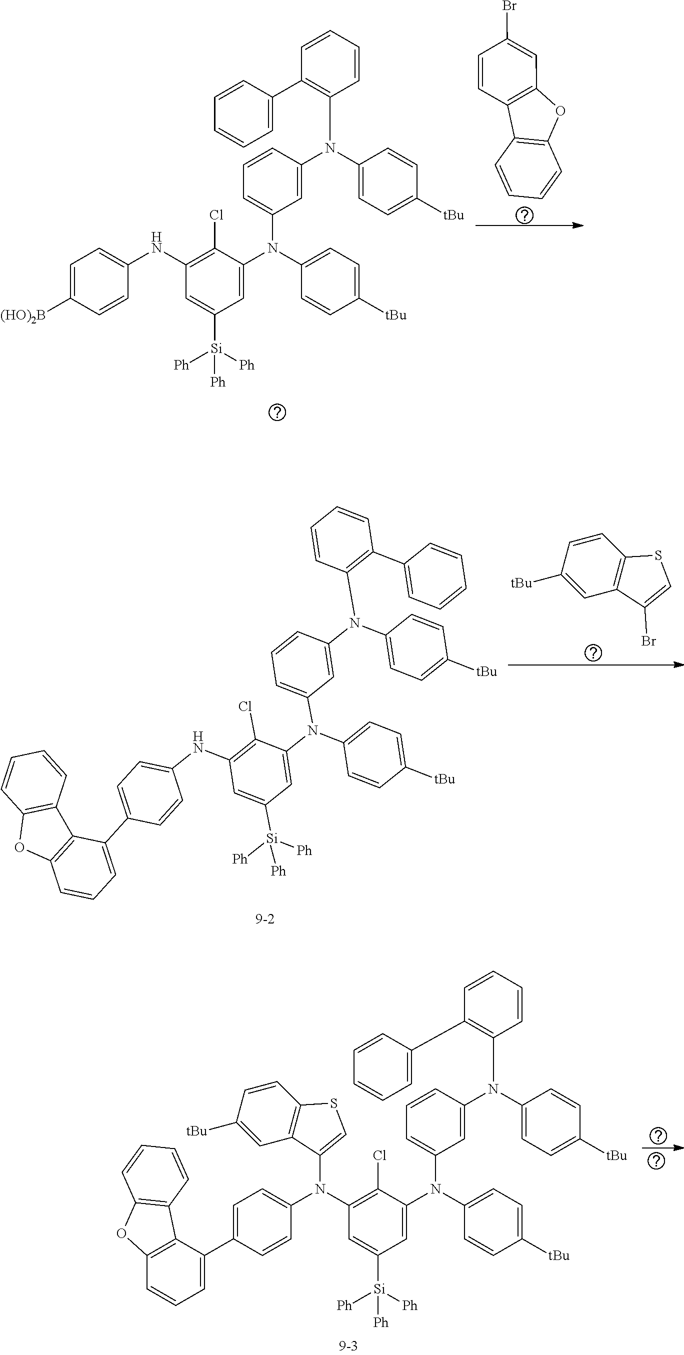

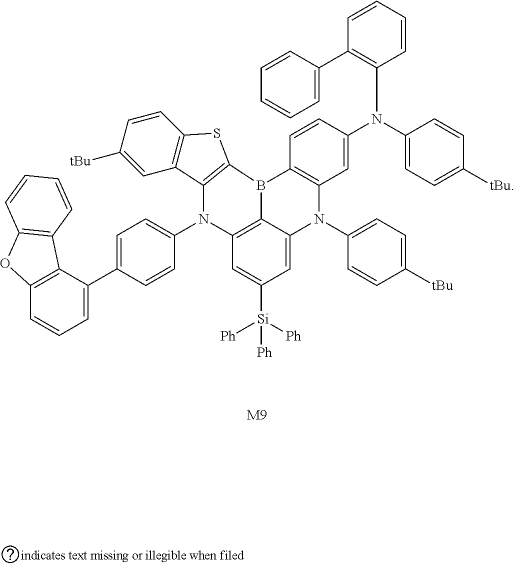 [SMILES: CC(C)(C)c1ccc(N(c2ccc3c(c2)N(c2ccc(C(C)(C)C)cc2)c2cc([Si](c4ccccc4)(c4ccccc4)c4ccccc4)cc4c2B3c2sc3ccc(C(C)(C)C)cc3c2N4c2ccc(-c3cccc4oc5ccccc5c34)cc2)c2ccccc2-c2ccccc2)cc1 ; "M9"]

### Synthesis of the Intermediate 9-2

Compound 1-9 (10 mmol) and compound 9-1 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. under a nitrogen atmosphere and stirred for 6 h. After the reaction solution was cooled, the solvent was removed by rotary evaporation, the reaction solution was extracted and the separated solution was washed with water, and the organic phase was subjected to column chromatography to obtain the intermediate 9-2 with a molar amount of 7.68 mmol and a yield of 76.8%. The atmospheric pressure solid phase analysis probe mass spectrometry (ASAP-MS) result of the intermediate 9-2 was: MS (ASAP)=1149.

### Synthesis of the Intermediate 9-3

The intermediate 9-2 (10 mmol), the intermediate 1-12 (10 mmol), Pd(dba)₂ (bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. under nitrogen atmosphere and stirred for 6 h; after the reaction solution was cooled, the solvent was removed by rotary evaporation, the reaction solution was extracted and the separated solution was washed with water, and the organic phase was subjected to column chromatography to obtain the intermediate 9-3, with a molar amount of 7.59 mmol and a yield of 75.9%. The atmospheric pressure solid phase analytical probe mass spectrometry (ASAP-MS) result of the intermediate 9-3 was: MS (ASAP)=1337.

### Synthesis of the Organic Compound M9

A 250 ml three-necked flask was added with 10 mmol of the intermediate 9-3 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M9, the yield was 44.6%, and the atmospheric pressure solid phase analysis probe mass spectrometry (ASAP-MS) result of the organic compound M9 was: MS (ASAP)=1311.

### Example 10

The synthetic route of the organic compound M10 is as follows:

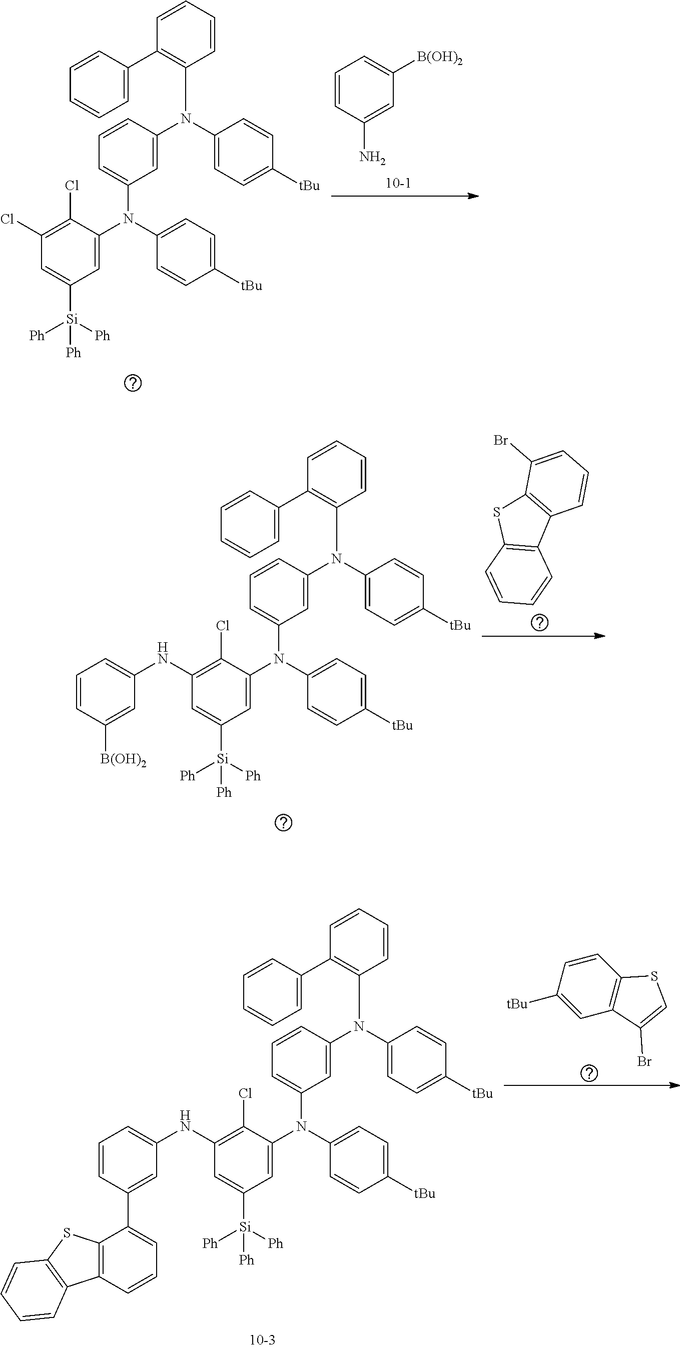 [SMILES: CC(C)(C)c1ccc(N(c2cccc(N(c3ccc(C(C)(C)C)cc3)c3cc([Si](c4ccccc4)(c4ccccc4)c4ccccc4)cc(Cl)c3Cl)c2)c2ccccc2-c2ccccc2)cc1 ; Nc1cccc(B(O)O)c1 ; CC(C)(C)c1ccc(N(c2cccc(N(c3ccc(C(C)(C)C)cc3)c3cc([Si](c4ccccc4)(c4ccccc4)c4ccccc4)cc(Nc4cccc(B(O)O)c4)c3Cl)c2)c2ccccc2-c2ccccc2)cc1 ; Brc1cccc2c1sc1ccccc12 ; CC(C)(C)c1ccc(N(c2cccc(N(c3ccc(C(C)(C)C)cc3)c3cc([Si](c4ccccc4)(c4ccccc4)c4ccccc4)cc(Nc4cccc(-c5cccc6c5sc5ccccc56)c4)c3Cl)c2)c2ccccc2-c2ccccc2)cc1 ; CC(C)(C)c1ccc2scc(Br)c2c1]

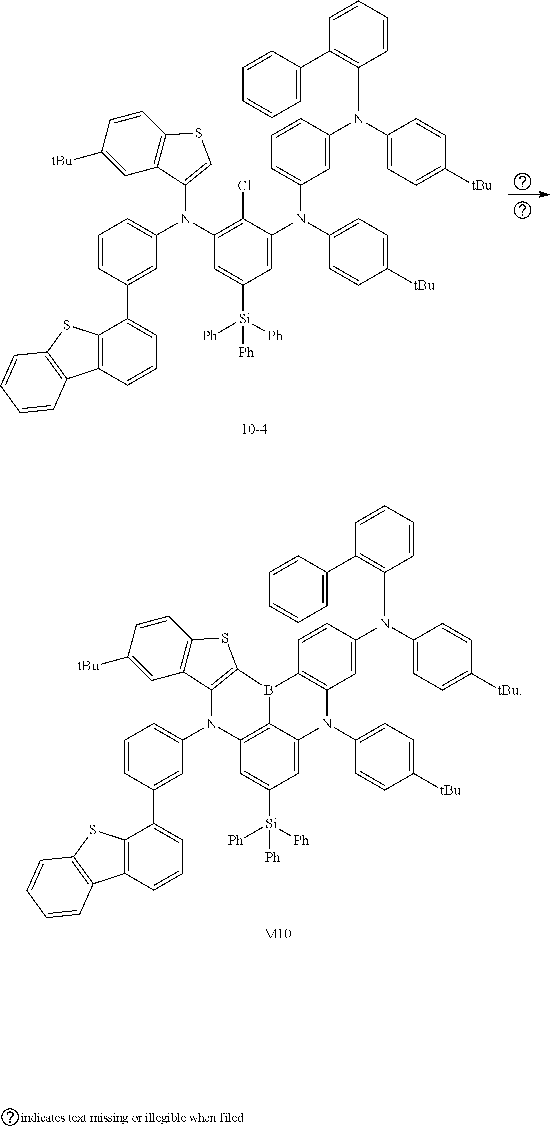 [SMILES: CC(C)(C)c1ccc(N(c2cccc(N(c3ccc(C(C)(C)C)cc3)c3cc([Si](c4ccccc4)(c4ccccc4)c4ccccc4)cc(N(c4cccc(-c5cccc6c5sc5ccccc56)c4)c4csc5ccc(C(C)(C)C)cc45)c3Cl)c2)c2ccccc2-c2ccccc2)cc1 ; "10-4" ; CC(C)(C)c1ccc(N(c2ccc3c(c2)N(c2ccc(C(C)(C)C)cc2)c2cc([Si](c4ccccc4)(c4ccccc4)c4ccccc4)cc4c2B3c2sc3ccc(C(C)(C)C)cc3c2N4c2cccc(-c3cccc4c3sc3ccccc34)c2)c2ccccc2-c2ccccc2)cc1 ; "M10"]

### Synthesis of the Intermediate 10-2

The intermediate 1-7 (10 mmol), Compound 10-1 (10 mmol), Pd-132 (bis(di-tert-butyl-4-dimethylaminophenylphosphine)palladium chloride, 0.1 mmol), S-Phos (2-dicyclohexylphosphine-2′,6′-dimethoxy-1,1′-biphenyl, 0.2 mmol) and sodium tert-butoxide (30 mmol) were dissolved in toluene, heated to 100° C. and stirred for 6 h under a nitrogen atmosphere; after the reaction solution was cooled, most of the solvent was removed by rotary evaporation, and then the reaction solution was extracted and the separated solution was washed with water, and the organic phase was subjected to column chromatography and recrystallization to obtain the intermediate 10-2, with a molar amount of 8.18 mmol and a yield of 81.8%. The atmospheric pressure solid phase analysis probe mass spectrometry (ASAP-MS) result of the intermediate 10-2 was: MS (ASAP)=1027.

### Synthesis of the Intermediate 10-3

The intermediate 10-2 (10 mmol) and the intermediate 4-1 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. and stirred for 6 h under a nitrogen atmosphere. After the reaction solution was cooled, most of the solvent was removed by rotary evaporation, and then the reaction solution was extracted and the separated solution was washed with water. The organic phase was subjected to column chromatography and recrystallization to obtain the intermediate 10-3 with a molar amount of 6.57 mmol and a yield of 65.7%. The atmospheric pressure solid phase analysis probe mass spectrometry (ASAP-MS) result of the intermediate 10-3 was: MS (ASAP)=1165.

### Synthesis of the Intermediate 10-4

The intermediate 10-3 (10 mmol), the intermediate 1-12 (10 mmol), Pd(dba)₂ (bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. under nitrogen atmosphere and stirred for 6 h; after the reaction solution was cooled, the solvent was removed by rotary evaporation, the reaction solution was extracted and the separated solution was washed with water, and the organic phase was subjected to column chromatography to obtain the intermediate 10-4 with a molar amount of 7.43 mmol and a yield of 74.3%. The atmospheric pressure solid phase analytical probe mass spectrometry (ASAP-MS) result of the intermediate 10-4 was: MS (ASAP)=1353.

### Synthesis of the Organic Compound M10

250 ml three-necked flask was added with 10 mmol of the intermediate 10-4 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N, N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M10, the yield was 32.8%, and the atmospheric pressure solid phase analysis probe mass spectrometry (ASAP-MS) result of the organic compound M10 was: MS (ASAP)=1327.

### Example 11

The synthetic route of the organic compound M11 is as follows:

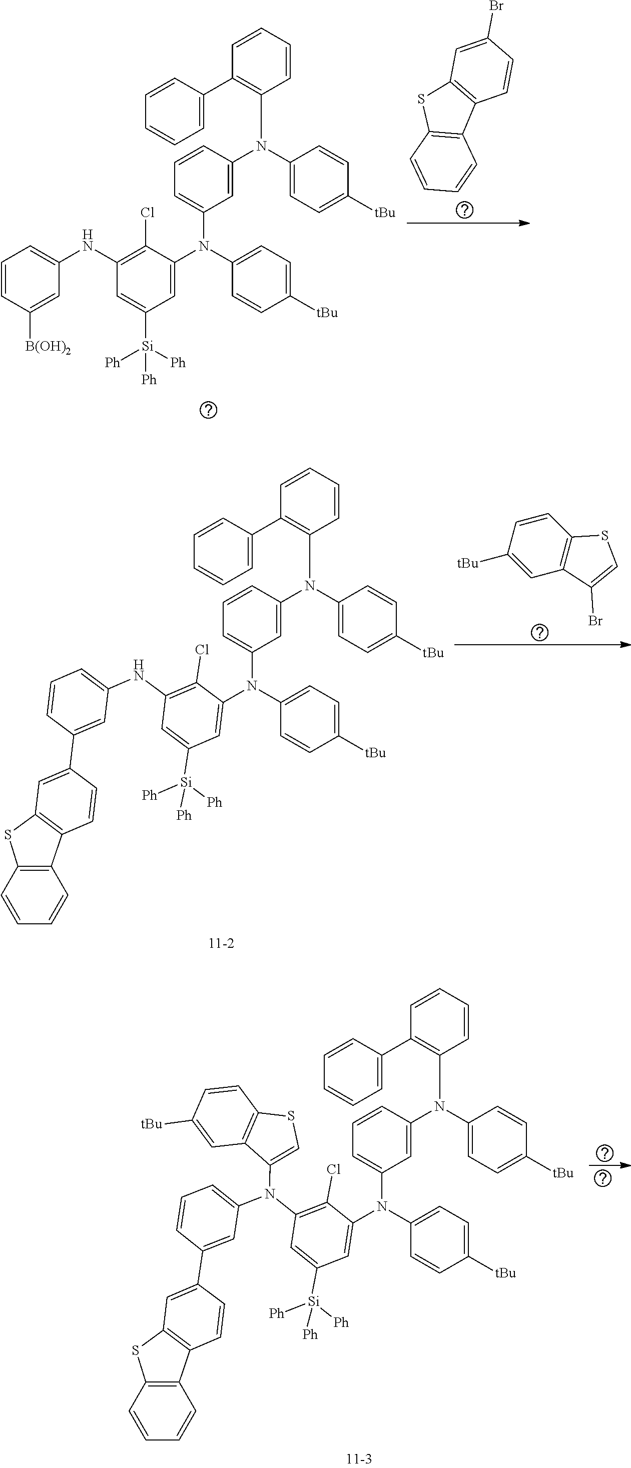

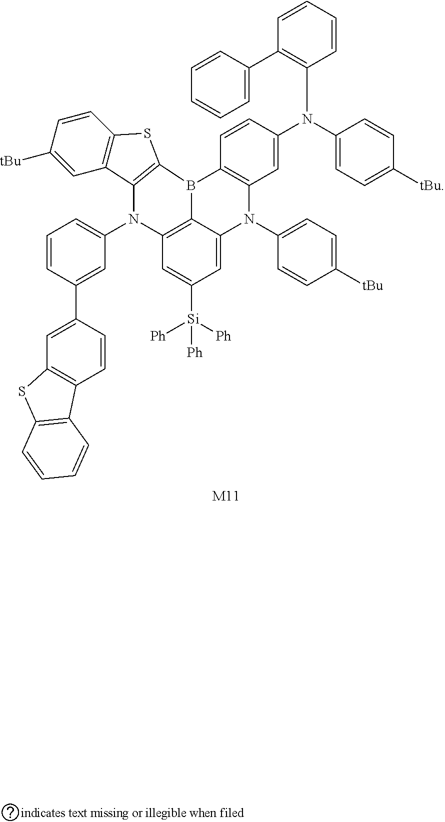 [SMILES: CC(C)(C)c1ccc(N(c2ccc3c(c2)N(c2ccc(C(C)(C)C)cc2)c2cc([Si](c4ccccc4)(c4ccccc4)c4ccccc4)cc4c2B3c2sc3ccc(C(C)(C)C)cc3c2N4c2cccc(-c3ccc4c(c3)sc3ccccc34)c2)c2ccccc2-c2ccccc2)cc1 ; "M11"]

### Synthesis of the Intermediate 11-2

The intermediate 10-2 (10 mmol) and the intermediate 11-1 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. and stirred for 6 h under a nitrogen atmosphere. After the reaction solution was cooled, most of the solvent was removed by rotary evaporation, and then the reaction solution was extracted and the separated solution was washed with water. The organic phase was subjected to column chromatography and recrystallization to obtain the intermediate 11-2 with a molar amount of 6.36 mmol and a yield of 63.6%. The atmospheric pressure solid phase analysis probe mass spectrometry (ASAP-MS) result of the intermediate 11-2 was: MS (ASAP)=1165.

### Synthesis of the Intermediate 11-3

The intermediate 11-2 (10 mmol), the intermediate 1-12 (10 mmol), Pd(dba)₂ (bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. and stirred for 6 h under nitrogen atmosphere; after the reaction solution was cooled, the solvent was removed by rotary evaporation, the reaction solution was extracted and the separated solution was washed with water, and the organic phase was subjected to column chromatography to obtain the intermediate 11-3, with a molar amount of 7.22 mmol and a yield of 72.2%. The atmospheric pressure solid phase analytical probe mass spectrometry (ASAP-MS) result of the intermediate 11-3 was: MS (ASAP)=1353.

### Synthesis of the Organic Compound M11

A 250 ml three-necked flask was added with 10 mmol of the intermediate 11-3 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M11, the yield was 35.8%, and the atmospheric pressure solid phase analysis probe mass spectrometry (ASAP-MS) result of organic compound M11 was: MS (ASAP)=1327.

### Example 12

The synthetic route of the organic compound M12 is as follows:

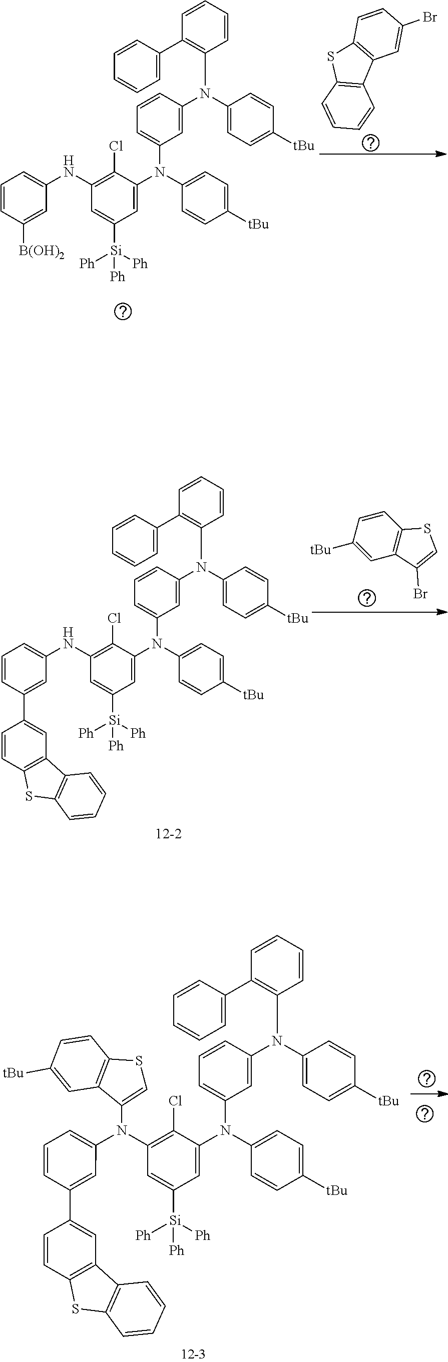

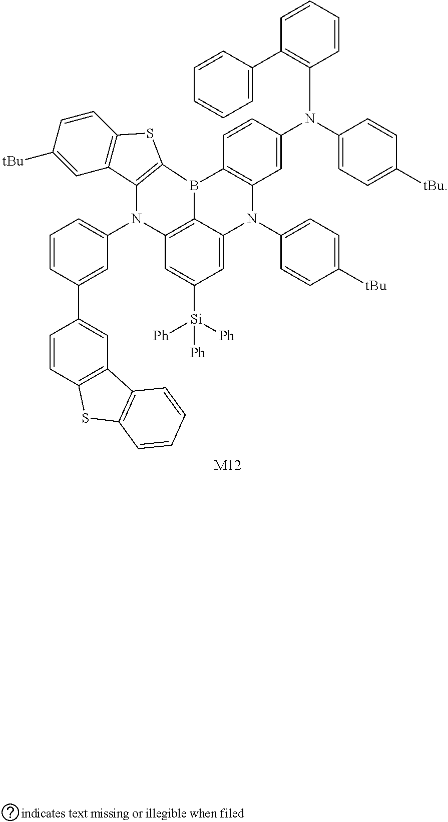 [SMILES: CC(C)(C)c1ccc(N(c2ccc3c(c2)N(c2ccc(C(C)(C)C)cc2)c2cc([Si](c4ccccc4)(c4ccccc4)c4ccccc4)cc4c2B3c2sc3ccc(C(C)(C)C)cc3c2N4c2cccc(-c3ccc4sc5ccccc5c4c3)c2)c2ccccc2-c2ccccc2)cc1 ; "M12"]

### Synthesis of the Intermediate 12-2

The intermediate 10-2 (10 mmol) and the intermediate 12-1 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. and stirred for 6 h under a nitrogen atmosphere. After the reaction solution was cooled, most of the solvent was removed by rotary evaporation, and then the reaction solution was extracted and the separated solution was washed with water. The organic phase was subjected to column chromatography and recrystallization to obtain the intermediate 12-2 with a molar amount of 8.59 mmol and a yield of 85.9%. The atmospheric pressure solid phase analysis probe mass spectrometry (ASAP-MS) result of the intermediate 12-2 was: MS (ASAP)=1165.

### Synthesis of the Intermediate 12-3

The intermediate 12-2 (10 mmol), the intermediate 1-12 (10 mmol), Pd(dba)₂ (bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. under nitrogen atmosphere and stirred for 6 h; after the reaction solution was cooled, the solvent was removed by rotary evaporation, the reaction solution was extracted and the separated solution was washed with water, and the organic phase was subjected to column chromatography to obtain the intermediate 12-3, with a molar amount of 6.89 mmol and a yield of 68.9%. The atmospheric pressure solid phase analytical probe mass spectrometry (ASAP-MS) result of the intermediate 12-3 was: MS (ASAP)=1353.

### Synthesis of the Organic Compound M12

A 250 ml three-necked flask was added with 10 mmol of the intermediate 12-3 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N, N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M12, the yield was 37.4%, and the atmospheric pressure solid phase analysis probe mass spectrometry (ASAP-MS) result of the organic compound M12 was: MS (ASAP)=1327.

### Example 13

The synthetic route of the organic compound M13 is as follows:

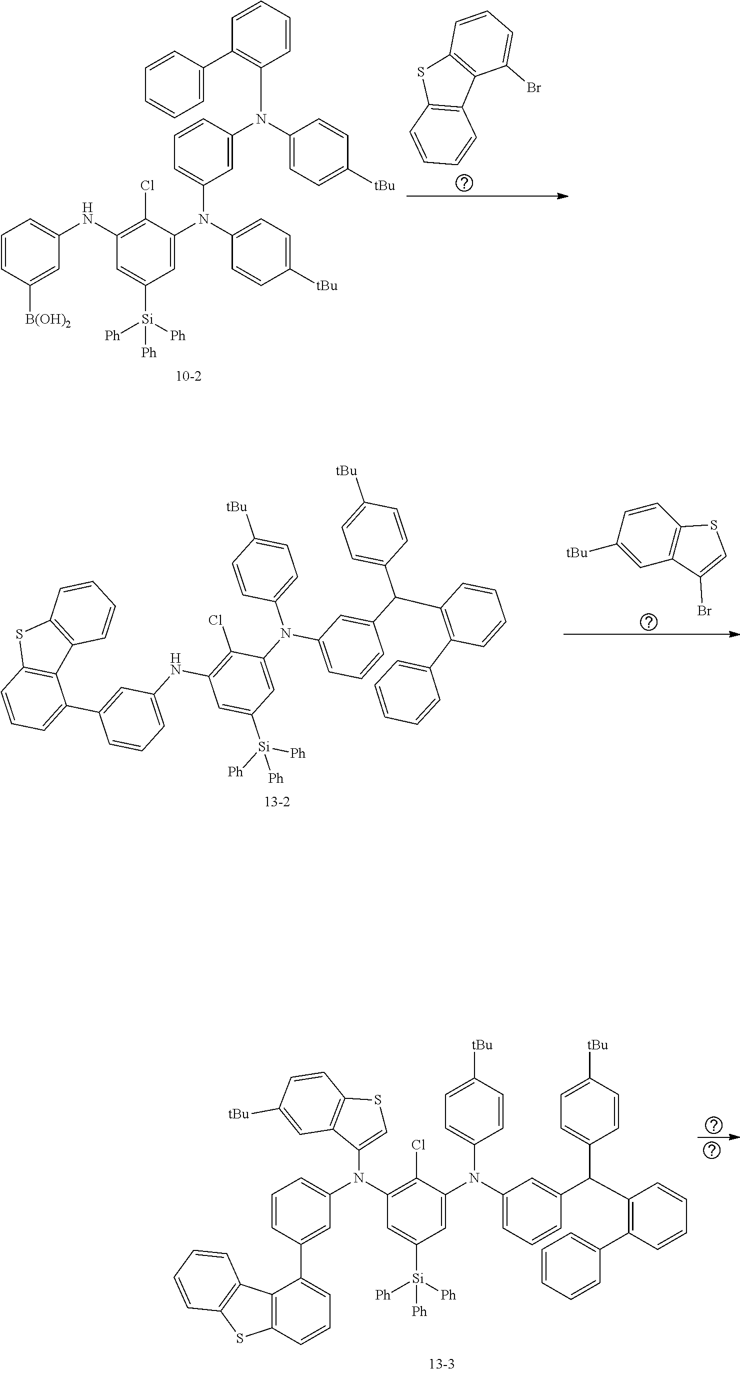

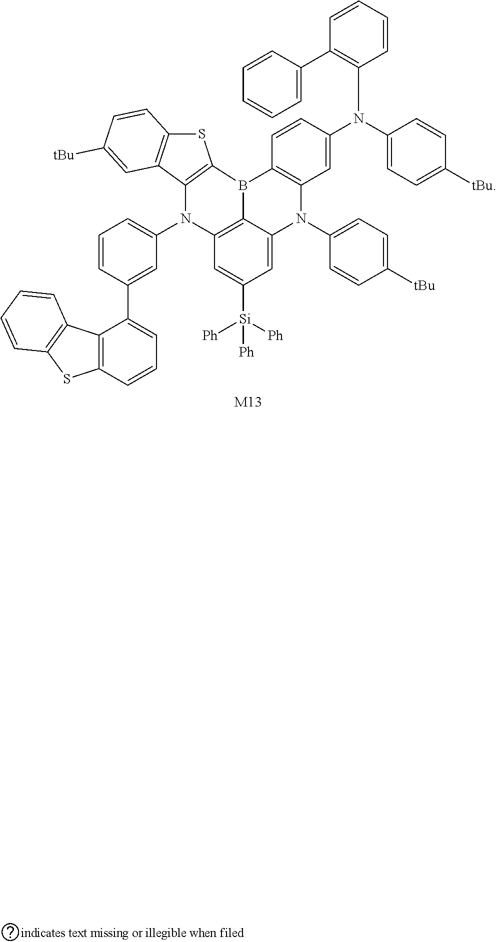 [SMILES: CC(C)(C)c1ccc(N(c2ccc3c(c2)N(c2ccc(C(C)(C)C)cc2)c2cc([Si](c4ccccc4)(c4ccccc4)c4ccccc4)cc4c2B3c2sc3ccc(C(C)(C)C)cc3c2N4c2cccc(-c3cccc4sc5ccccc5c34)c2)c2ccccc2-c2ccccc2)cc1 ; "M13"]

### Synthesis of the Intermediate 13-2

The intermediate 10-2 (10 mmol) and the intermediate 13-1 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. and stirred for 6 h under a nitrogen atmosphere. After the reaction solution was cooled, most of the solvent was removed by rotary evaporation, and then the reaction solution was extracted and the separated solution was washed with water. The organic phase was subjected to column chromatography and recrystallization to obtain the intermediate 13-2 with a molar amount of 8.33 mmol and a yield of 83.3%. The atmospheric pressure solid phase analysis probe mass spectrometry (ASAP-MS) result of the intermediate 13-2 was: MS (ASAP)=1165.

### Synthesis of the Intermediate 13-3

The intermediate 13-2 (10 mmol), the intermediate 1-12 (10 mmol), Pd(dba)₂ (bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. and stirred for 6 h under nitrogen atmosphere; after the reaction solution was cooled, the solvent was removed by rotary evaporation, the reaction solution was extracted and the separated solution was washed with water, and the organic phase was subjected to column chromatography to obtain the intermediate 13-3, with a molar amount of 6.16 mmol and a yield of 61.6%. The atmospheric pressure solid phase analytical probe mass spectrometry (ASAP-MS) result of the intermediate 13-3 was: MS (ASAP)=1353.

### Synthesis of the Organic Compound M13

10 mmol of the intermediate 13-3 and 100 ml of dry tert-butylbenzene were added to a 250 ml three-necked flask. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M13, the yield was 32.9%, and the atmospheric pressure solid phase analysis probe mass spectrometry (ASAP-MS) result of organic compound M13 was: MS (ASAP)=1327.

### Example 14

The synthesis route of the organic compound M14 is as follows:

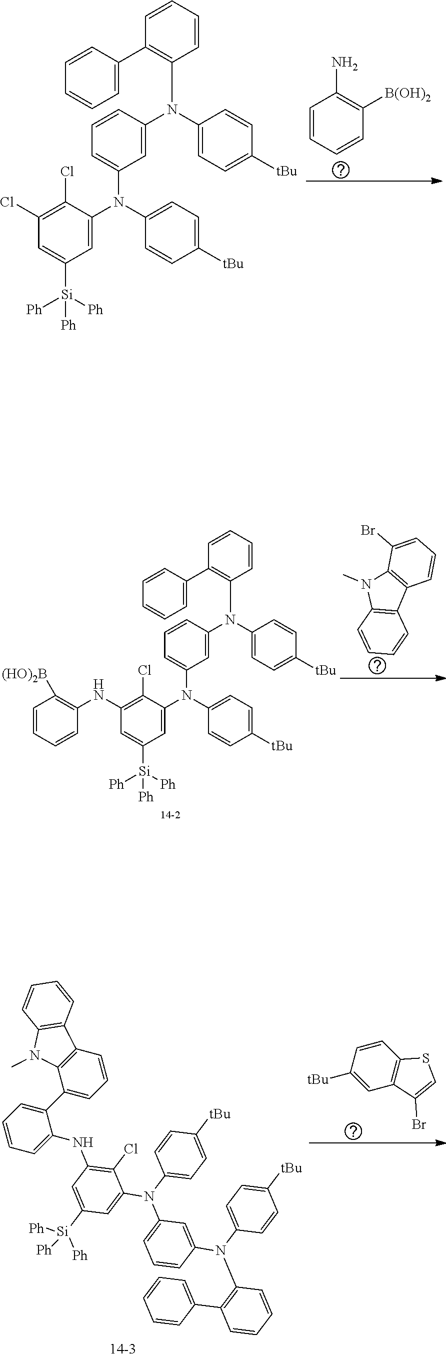 [SMILES: CC(C)(C)c1ccc(N(c2cccc(N(c3ccc(C(C)(C)C)cc3)c3cc([Si](c4ccccc4)(c4ccccc4)c4ccccc4)cc(Cl)c3Cl)c2)c2ccccc2-c2ccccc2)cc1 ; Nc1ccccc1B(O)O ; CC(C)(C)c1ccc(N(c2cccc(N(c3ccc(C(C)(C)C)cc3)c3cc([Si](c4ccccc4)(c4ccccc4)c4ccccc4)cc(Nc4ccccc4B(O)O)c3Cl)c2)c2ccccc2-c2ccccc2)cc1 ; Cn1c2ccccc2c2cccc(Br)c21 ; Cn1c2ccccc2c2cccc(-c3ccccc3Nc3cc([Si](c4ccccc4)(c4ccccc4)c4ccccc4)cc(N(c4ccc(C(C)(C)C)cc4)c4cccc(N(c5ccc(C(C)(C)C)cc5)c5ccccc5-c5ccccc5)c4)c3Cl)c21 ; CC(C)(C)c1ccc2scc(Br)c2c1]

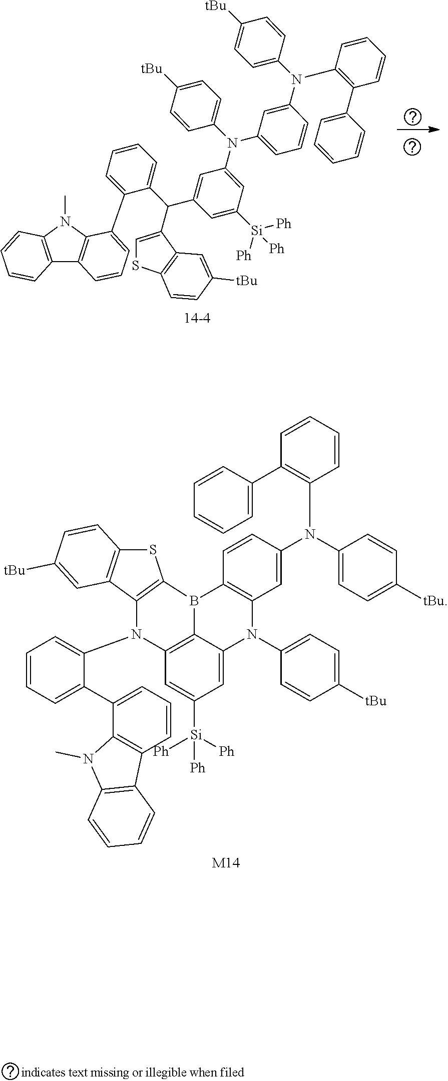 [SMILES: Cn1c2ccccc2c2cccc(-c3ccccc3C(c3cc(N(c4ccc(C(C)(C)C)cc4)c4cccc(N(c5ccc(C(C)(C)C)cc5)c5ccccc5-c5ccccc5)c4)cc([Si](c4ccccc4)(c4ccccc4)c4ccccc4)c3)c3csc4ccc(C(C)(C)C)cc34)c21 ; Cn1c2ccccc2c2cccc(-c3ccccc3N3c4cc([Si](c5ccccc5)(c5ccccc5)c5ccccc5)cc5c4B(c4ccc(N(c6ccc(C(C)(C)C)cc6)c6ccccc6-c6ccccc6)cc4N5c4ccc(C(C)(C)C)cc4)c4sc5ccc(C(C)(C)C)cc5c43)c21 ; "M14"]

### Synthesis of the Intermediate 14-2

The intermediate 1-7 (10 mmol), Compound 14-1 (10 mmol), Pd-132 (bis(di-tert-butyl-4-dimethylaminophenylphosphine)palladium chloride, 0.1 mmol), S-Phos (2-dicyclohexylphosphine-2′,6′-dimethoxy-1,1′-biphenyl, 0.2 mmol) and sodium tert-butoxide (30 mmol) were dissolved in toluene, heated to 100° C. and stirred for 6 h under a nitrogen atmosphere; after the reaction solution was cooled, most of the solvent was removed by rotary evaporation, and then the reaction solution was extracted and the separated solution was washed with water, and the organic phase was subjected to column chromatography and recrystallization to obtain the intermediate 14-2, with a molar amount of 8.36 mmol and a yield of 83.6%. The atmospheric pressure solid phase analysis probe mass spectrometry (ASAP-MS) result of the intermediate 14-2 was: MS (ASAP)=1027.

### Synthesis of the Intermediate 14-3

The intermediate 14-2 (10 mmol) and the intermediate 5-1 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. and stirred for 6 h under a nitrogen atmosphere. After the reaction solution was cooled, most of the solvent was removed by rotary evaporation, and then the reaction solution was extracted and the separated solution was washed with water. The organic phase was subjected to column chromatography and recrystallization to obtain the intermediate 14-3 with a molar amount of 6.09 mmol and a yield of 60.9%. The atmospheric pressure solid phase analysis probe mass spectrometry (ASAP-MS) result of the intermediate 14-3 was: MS (ASAP)=1162.

### Synthesis of the Intermediate 14-4

The intermediate 14-3 (10 mmol), the intermediate 1-12 (10 mmol), Pd(dba)₂ (bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. and stirred for 6 h under nitrogen atmosphere; after the reaction solution was cooled, the solvent was removed by rotary evaporation, the reaction solution was extracted and the separated solution was washed with water, and the organic phase was subjected to column chromatography to obtain the intermediate 14-4, with a molar amount of 8.93 mmol and a yield of 89.3%. The atmospheric pressure solid phase analytical probe mass spectrometry (ASAP-MS) result of the intermediate 14-4 was: MS (ASAP)=1350.

### Synthesis of Organic Compound M14

A 250 ml three-necked flask was added with 10 mmol of the intermediate 14-4 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M14, the yield was 44.1%, and the atmospheric pressure solid phase analysis probe mass spectrometry (ASAP-MS) result of organic compound M14 was: MS (ASAP)=1324.

### Example 15

The synthetic route of the organic compound M15 is as follows:

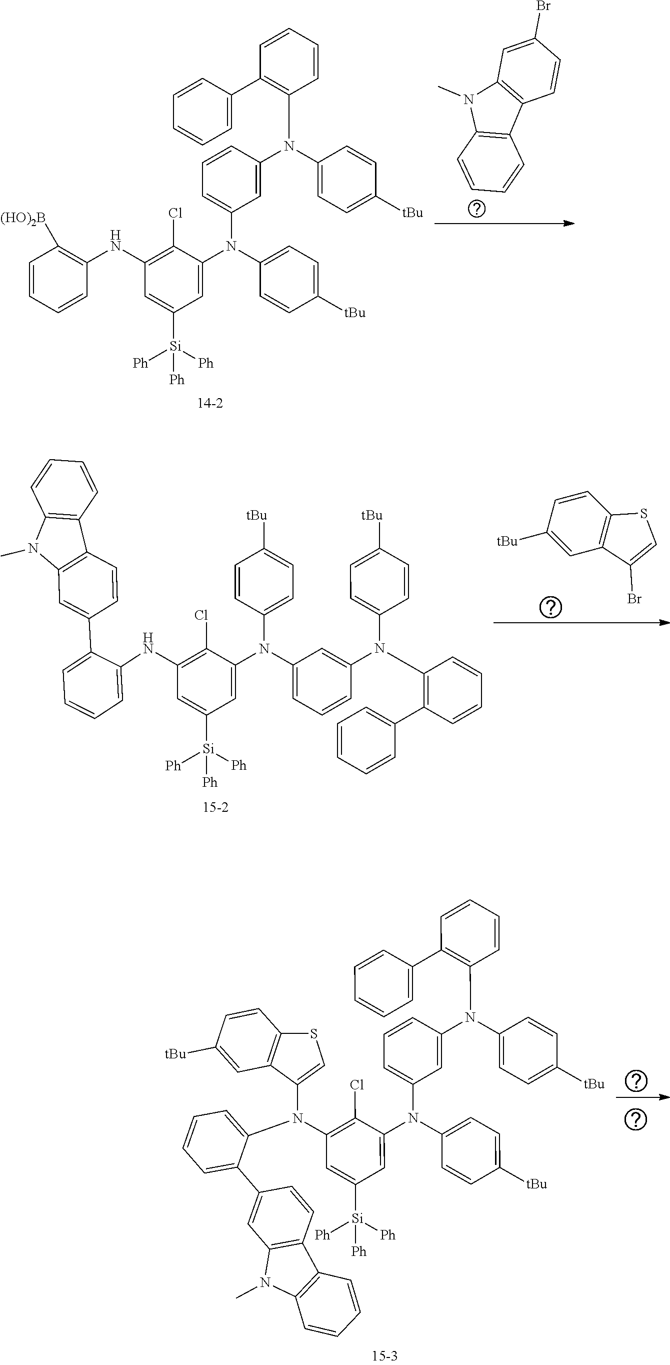

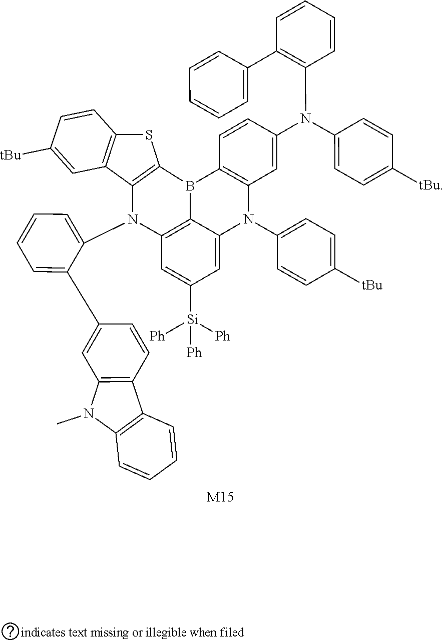 [SMILES: Cn1c2ccccc2c2ccc(-c3ccccc3N3c4cc([Si](c5ccccc5)(c5ccccc5)c5ccccc5)cc5c4B(c4ccc(N(c6ccc(C(C)(C)C)cc6)c6ccccc6-c6ccccc6)cc4N5c4ccc(C(C)(C)C)cc4)c4sc5ccc(C(C)(C)C)cc5c43)cc21 ; "M15"]

### Synthesis of the Intermediate 15-2

The intermediate 14-2 (10 mmol) and the intermediate 15-1 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. and stirred for 6 h under a nitrogen atmosphere. After the reaction solution was cooled, most of the solvent was removed by rotary evaporation, and then the reaction solution was extracted and the separated solution was washed with water. The organic phase was subjected to column chromatography and recrystallization to obtain the intermediate 15-2 with a molar amount of 7.68 mmol and a yield of 76.8%. The atmospheric pressure solid phase analysis probe mass spectrometry (ASAP-MS) result of the intermediate 15-2 was: MS (ASAP)=1162.

### Synthesis of the Intermediate 15-3

The intermediate 15-2 (10 mmol), the intermediate 1-12 (10 mmol), Pd(dba)₂ (bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. and stirred for 6 h under nitrogen atmosphere; after the reaction solution was cooled, the solvent was removed by rotary evaporation, the reaction solution was extracted and the separated solution was washed with water, and the organic phase was subjected to column chromatography to obtain the intermediate 15-3, with a molar amount of 8.37 mmol and a yield of 83.7%. The atmospheric pressure solid phase analytical probe mass spectrometry (ASAP-MS) result of the intermediate 15-3 was: MS (ASAP)=1350.

### Synthesis of the Organic Compound M15

A 250 ml three-necked flask was added with 10 mmol of the intermediate 15-3 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M15, the yield was 50.2%, and the atmospheric pressure solid phase analysis probe mass spectrometry (ASAP-MS) result of organic compound M15 was: MS (ASAP)=1324.

### Example 16

The synthetic route of the organic compound M16 is as follows:

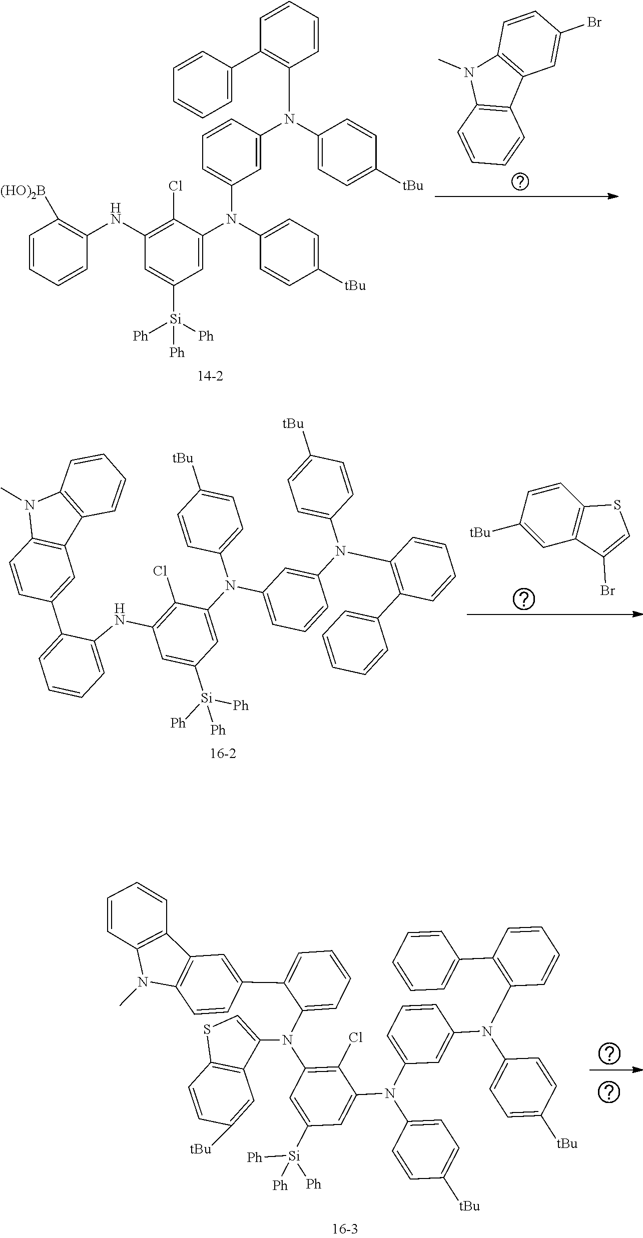

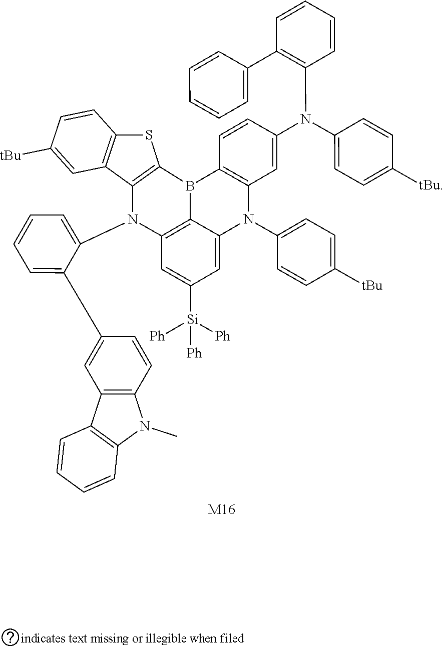 [SMILES: Cn1c2ccccc2c2cc(-c3ccccc3N3c4cc([Si](c5ccccc5)(c5ccccc5)c5ccccc5)cc5c4B(c4ccc(N(c6ccc(C(C)(C)C)cc6)c6ccccc6-c6ccccc6)cc4N5c4ccc(C(C)(C)C)cc4)c4sc5ccc(C(C)(C)C)cc5c43)ccc21 ; "M16"]

### Synthesis of the Intermediate 16-2

The intermediate 14-2 (10 mmol) and the intermediate 16-1 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. and stirred for 6 h under a nitrogen atmosphere. After the reaction solution was cooled, most of the solvent was removed by rotary evaporation, and then the reaction solution was extracted and the separated solution was washed with water. The organic phase was subjected to column chromatography and recrystallization to obtain the intermediate 16-2 with a molar amount of 7.21 mmol and a yield of 72.1%. The atmospheric pressure solid phase analysis probe mass spectrometry (ASAP-MS) result of the intermediate 16-2 was: MS (ASAP)=1162.

### Synthesis of the Intermediate 16-3

The intermediate 16-2 (10 mmol), the intermediate 1-12 (10 mmol), Pd(dba)₂ (bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. and stirred for 6 h under nitrogen atmosphere; after the reaction solution was cooled, the solvent was removed by rotary evaporation, the reaction solution was extracted and the separated solution was washed with water, and the organic phase was subjected to column chromatography to obtain the intermediate 16-3, with a molar amount of 8.15 mmol and a yield of 81.5%. The atmospheric pressure solid phase analytical probe mass spectrometry (ASAP-MS) result of the intermediate 16-3 was: MS (ASAP)=1350.

### Synthesis of the Organic Compound M16

A 250 ml three-necked flask was added with 10 mmol of the intermediate 16-3 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M16, the yield was 34.9%, and the atmospheric pressure solid phase analysis probe mass spectrometry (ASAP-MS) result of organic compound M16 was: MS (ASAP)=1324.

### Embodiment 17

The synthetic route of the organic compound M17 is as follows:

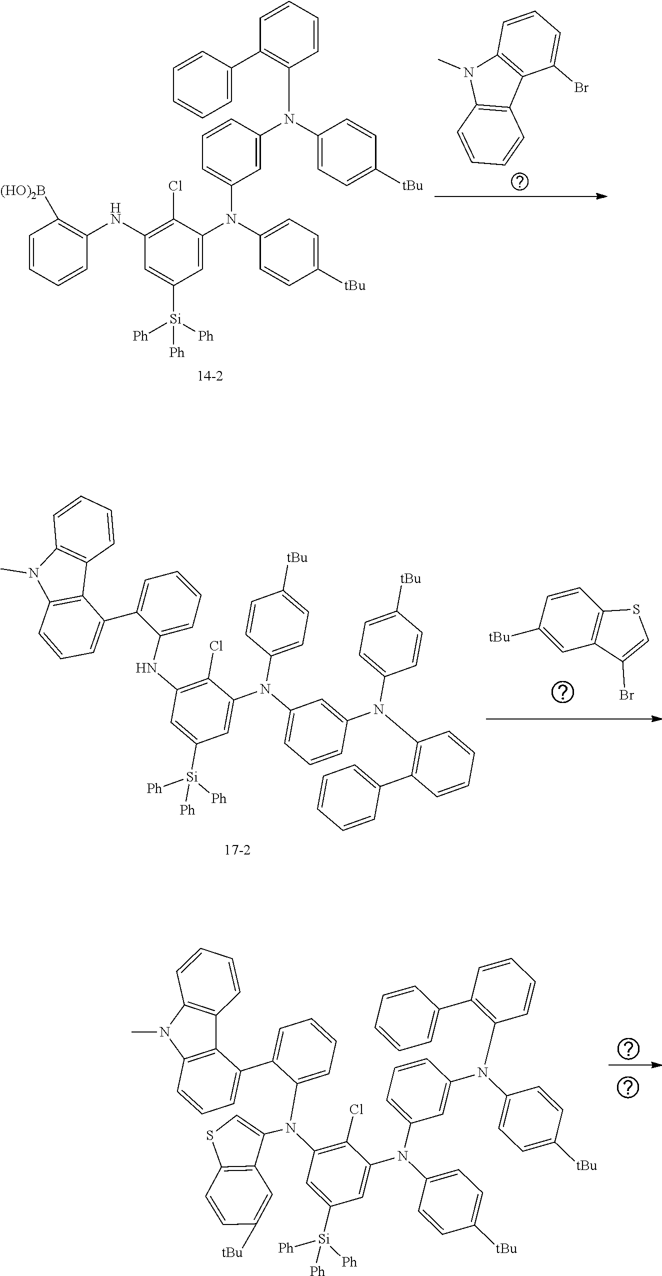

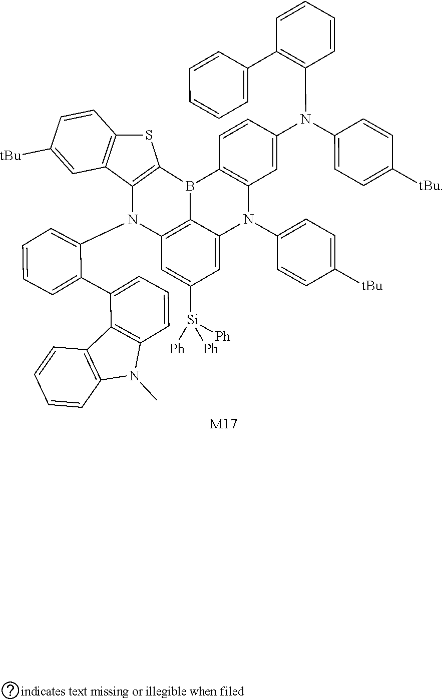 [SMILES: Cn1c2ccccc2c2c(-c3ccccc3N3c4cc([Si](c5ccccc5)(c5ccccc5)c5ccccc5)cc5c4B(c4ccc(N(c6ccc(C(C)(C)C)cc6)c6ccccc6-c6ccccc6)cc4N5c4ccc(C(C)(C)C)cc4)c4sc5ccc(C(C)(C)C)cc5c43)cccc21 ; "M17"]

### Synthesis of the Intermediate 17-2

The intermediate 14-2 (10 mmol) and the intermediate 17-1 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. and stirred for 6 h under a nitrogen atmosphere. After the reaction solution was cooled, most of the solvent was removed by rotary evaporation, and then the reaction solution was extracted and the separated solution was washed with water. The organic phase was subjected to column chromatography and recrystallization to obtain the intermediate 17-2 with a molar amount of 6.87 mmol and a yield of 68.7%. The atmospheric pressure solid phase analysis probe mass spectrometry (ASAP-MS) result of the intermediate 17-2 was: MS (ASAP)=1162.

### Synthesis of the Intermediate 17-2

The intermediate 17-2 (10 mmol), the intermediate 1-12 (10 mmol), Pd(dba)-(bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. and stirred for 6 h under nitrogen atmosphere; after the reaction solution was cooled, the solvent was removed by rotary evaporation, the reaction solution was extracted and the separated solution was washed with water, and the organic phase was subjected to column chromatography to obtain the intermediate 17-3, with a molar amount of 8.49 mmol and a yield of 84.9%. The atmospheric pressure solid phase analytical probe mass spectrometry (ASAP-MS) result of the intermediate 17-3 was: MS (ASAP)=1350.

### Synthesis of the Organic Compound M17

250 ml three-necked flask was added with 10 mmol of the intermediate 17-3 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M17, the yield was 32.7%, and the atmospheric pressure solid phase analysis probe mass spectrometry (ASAP-MS) result of organic compound M17 was: MS (ASAP)=1324.

### Example 18

Synthesis route of the organic compound M18 is as follows:

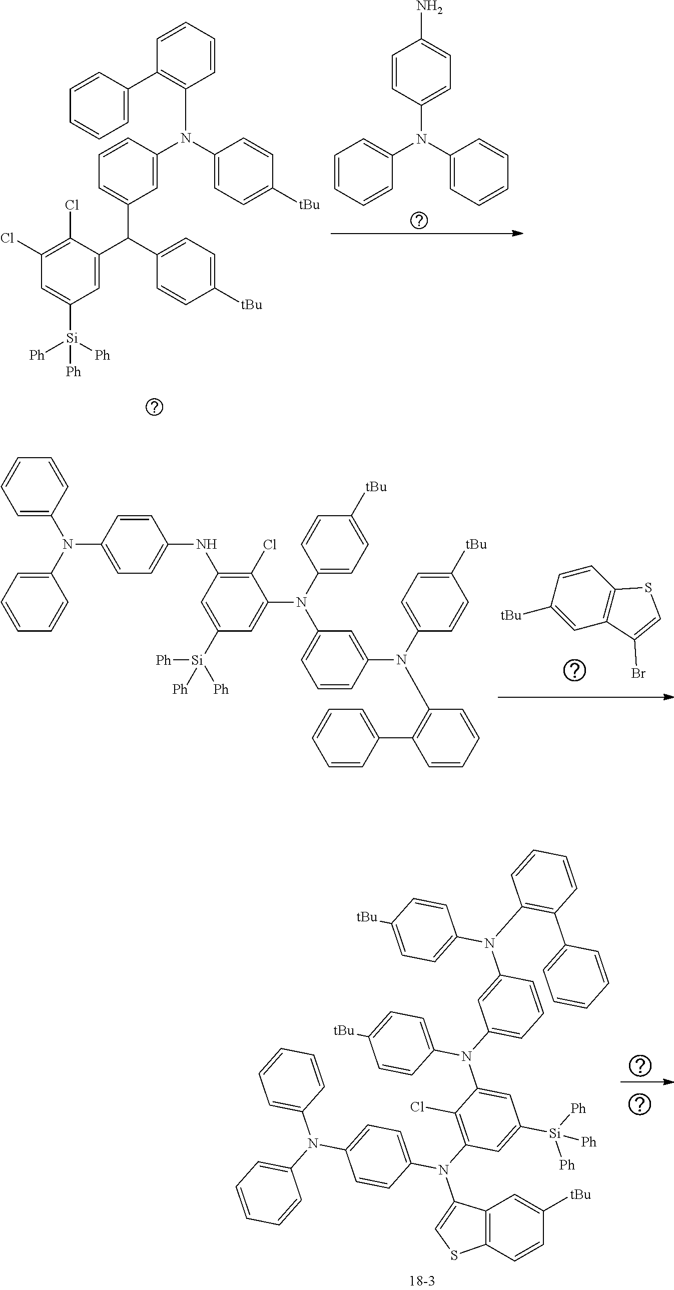

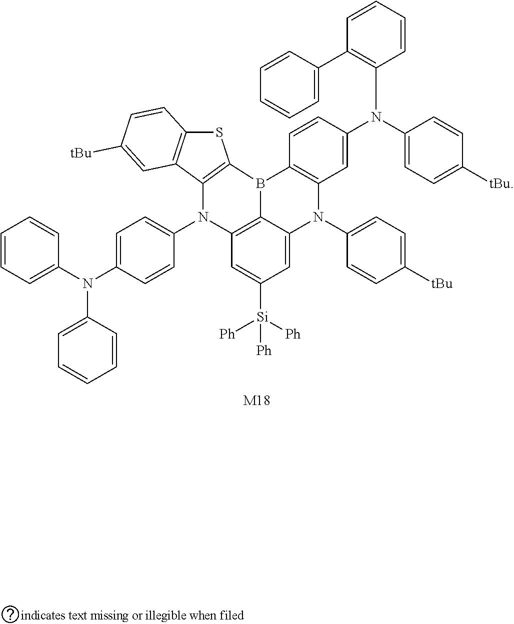 [SMILES: CC(C)(C)c1ccc(N(c2ccc3c(c2)N(c2ccc(C(C)(C)C)cc2)c2cc([Si](c4ccccc4)(c4ccccc4)c4ccccc4)cc4c2B3c2sc3ccc(C(C)(C)C)cc3c2N4c2ccc(N(c3ccccc3)c3ccccc3)cc2)c2ccccc2-c2ccccc2)cc1 ; "M18"]

### Synthesis of the Intermediate 18-2

The intermediate 1-7 (10 mmol), Compound 18-1 (10 mmol), Pd-132 (bis(di-tert-butyl-4-dimethylaminophenylphosphine)palladium chloride, 0.1 mmol), S-Phos (2-dicyclohexylphosphine-2′,6′-dimethoxy-1,1′-biphenyl, 0.2 mmol) and sodium tert-butoxide (30 mmol) were dissolved in toluene, heated to 100° C. and stirred for 6 h under a nitrogen atmosphere; after the reaction solution was cooled, most of the solvent was removed by rotary evaporation, and then the reaction solution was extracted and the separated solution was washed with water, and the organic phase was subjected to column chromatography and recrystallization to obtain the intermediate 18-2 with a molar amount of 7.52 mmol and a yield of 75.2%. The atmospheric pressure solid phase analysis probe mass spectrometry (ASAP-MS) result of the intermediate 18-2 was: MS (ASAP)=1150.

### Synthesis of the Intermediate 18-3

The intermediate 18-2 (10 mmol), the intermediate 1-12 (10 mmol), Pd(dba)-(bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. and stirred for 6 h under nitrogen atmosphere; after the reaction solution was cooled, the solvent was removed by rotary evaporation, the reaction solution was extracted and the separated solution was washed with water, and the organic phase was subjected to column chromatography to obtain the intermediate 18-3 with a molar amount of 8.18 mmol and a yield of 81.8%. The atmospheric pressure solid phase analytical probe mass spectrometry (ASAP-MS) result of the intermediate 18-3 was: MS (ASAP)=1338.

### Synthesis of the Organic Compound M18

A 250 ml three-necked flask was added with 10 mmol of the intermediate 18-3 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M18, the yield was 42.6%, and the atmospheric pressure solid phase analysis probe mass spectrometry (ASAP-MS) result of the organic compound M18 was: MS (ASAP)=1312.

### Example 19

Synthesis route of the organic compound M19 is as follows:

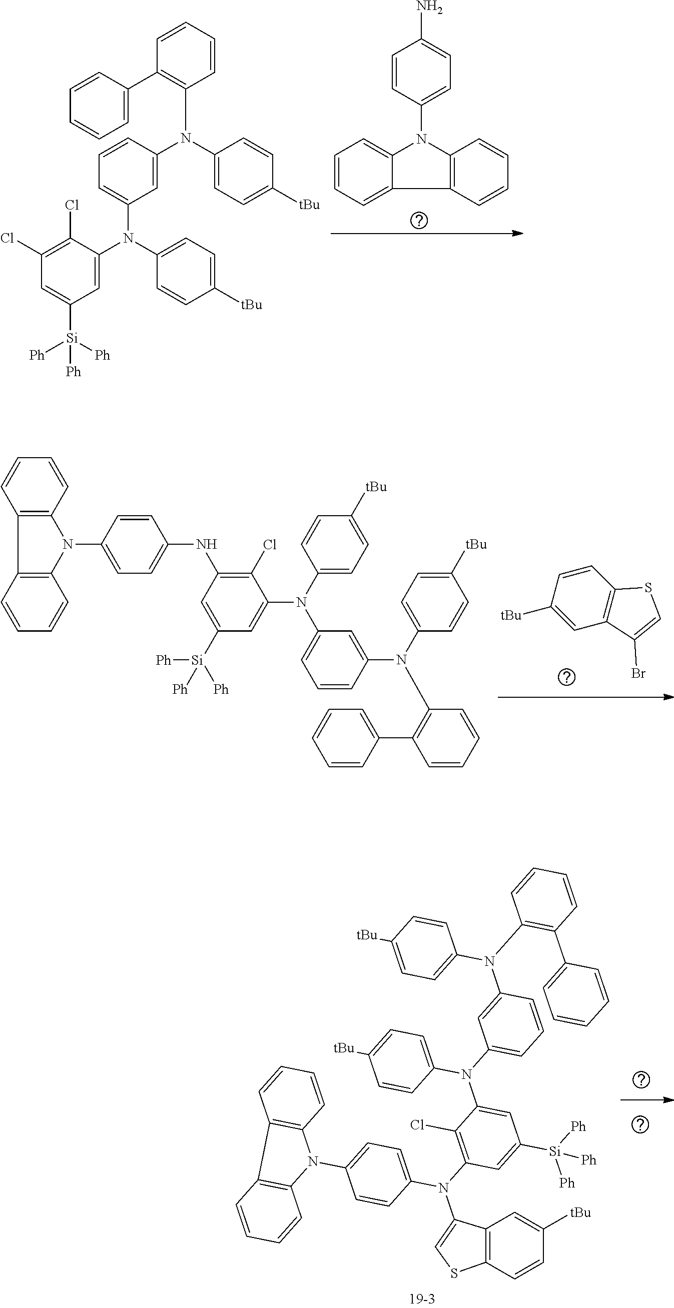

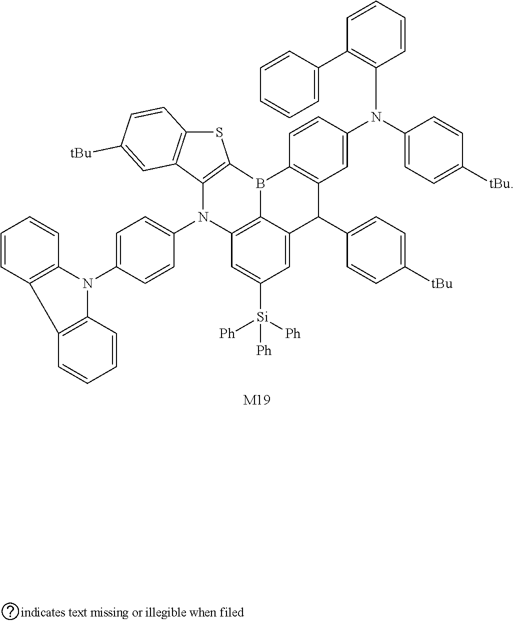 [SMILES: CC(C)(C)c1ccc(C2c3cc(N(c4ccc(C(C)(C)C)cc4)c4ccccc4-c4ccccc4)ccc3B3c4sc5ccc(C(C)(C)C)cc5c4N(c4ccc(-n5c6ccccc6c6ccccc65)cc4)c4cc([Si](c5ccccc5)(c5ccccc5)c5ccccc5)cc2c43)cc1 ; "M19"]

### Synthesis of the Intermediate 19-2

The intermediate 1-7 (10 mmol), Compound 19-1 (10 mmol), Pd-132 (bis(di-tert-butyl-4-dimethylaminophenylphosphine)palladium chloride, 0.1 mmol), S-Phos (2-dicyclohexylphosphine-2′,6′-dimethoxy-1,1′-biphenyl, 0.2 mmol) and sodium tert-butoxide (30 mmol) were dissolved in toluene, heated to 100° C. and stirred for 6 h under a nitrogen atmosphere; after the reaction solution was cooled, most of the solvent was removed by rotary evaporation, and then the reaction solution was extracted and the separated solution was washed with water, and the organic phase was subjected to column chromatography and recrystallization to obtain the intermediate 19-2, with a molar amount of 7.86 mmol and a yield of 78.6%. The atmospheric pressure solid phase analysis probe mass spectrometry (ASAP-MS) result of the intermediate 19-2 was: MS (ASAP)=1150.

### Synthesis of the Intermediate 19-3

The intermediate 19-2 (10 mmol), the intermediate 1-12 (10 mmol), Pd(dba)-(bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. and stirred for 6 h under nitrogen atmosphere; after the reaction solution was cooled, the solvent was removed by rotary evaporation, the reaction solution was extracted and the separated solution was washed with water, and the organic phase was subjected to column chromatography to obtain the intermediate 19-3 with a molar amount of 8.67 mmol and a yield of 86.7%. The atmospheric pressure solid phase analytical probe mass spectrometry (ASAP-MS) result of the intermediate 19-3 was: MS (ASAP)=1338.

### Synthesis of the Organic Compound M19

A 250 ml three-necked flask was added with 10 mmol of the intermediate 19-3 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M19, the yield was 45.7%, and the atmospheric pressure solid phase analysis probe mass spectrometry (ASAP-MS) result of the organic compound M19 was: MS (ASAP)=1312.

### Example 20

Synthesis route of the organic compound M20 is as follows:

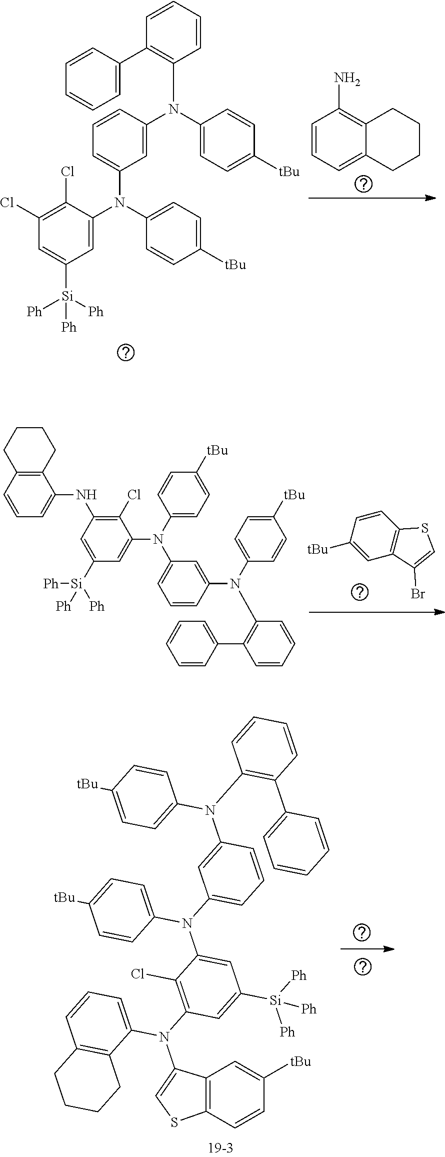

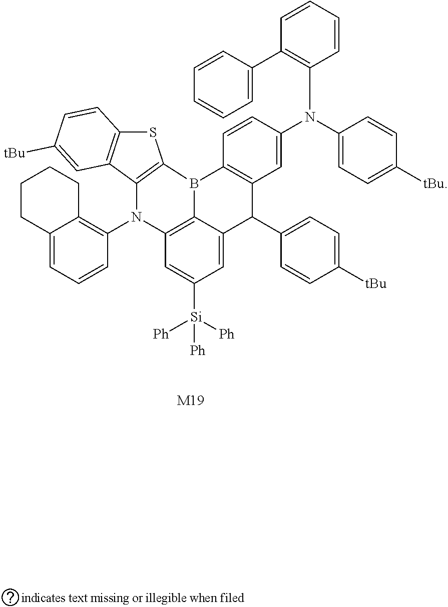 [SMILES: CC(C)(C)c1ccc(C2c3cc(N(c4ccc(C(C)(C)C)cc4)c4ccccc4-c4ccccc4)ccc3B3c4sc5ccc(C(C)(C)C)cc5c4N(c4cccc5c4CCCC5)c4cc([Si](c5ccccc5)(c5ccccc5)c5ccccc5)cc2c43)cc1 ; "M19"]

### Synthesis of the Intermediate 20-2

The intermediate 1-7 (10 mmol), Compound 20-1 (10 mmol), Pd-132 (bis(di-tert-butyl-4-dimethylaminophenylphosphine)palladium chloride, 0.1 mmol), S-Phos (2-dicyclohexylphosphine-2′,6′-dimethoxy-1,1-biphenyl, 0.2 mmol) and sodium tert-butoxide (30 mmol) were dissolved in toluene, heated to 100° C. and stirred for 6 h under a nitrogen atmosphere; after the reaction solution was cooled, most of the solvent was removed by rotary evaporation, and then the reaction solution was extracted and the separated solution was washed with water, and the organic phase was subjected to column chromatography and recrystallization to obtain the intermediate 20-2, with a molar amount of 7.20 mmol and a yield of 72.0%. The atmospheric pressure solid phase analysis probe mass spectrometry (ASAP-MS) result of the intermediate 20-2 was: MS (ASAP)=1037.

### Synthesis of the Intermediate 20-3

The intermediate 20-2 (10 mmol), the intermediate 1-12 (10 mmol), Pd(dba)₂ (bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. and stirred for 6 h under nitrogen atmosphere; after the reaction solution was cooled, the solvent was removed by rotary evaporation, the reaction solution was extracted and the separated solution was washed with water, and the organic phase was subjected to column chromatography to obtain the intermediate 20-3 with a molar amount of 8.18 mmol and a yield of 81.8%. The atmospheric pressure solid phase analytical probe mass spectrometry (ASAP-MS) result of the intermediate 20-3 was: MS (ASAP)=1225.

### Synthesis of the Organic Compound M20

A 250 ml three-necked flask was added with 10 mmol of the intermediate 20-3 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M20, the yield was 48.5%, and the atmospheric pressure solid phase analysis probe mass spectrometry (ASAP-MS) result of the organic compound M20 was: MS (ASAP)=1199.

### Example 21

Synthesis route of the organic compound M21 is as follows:

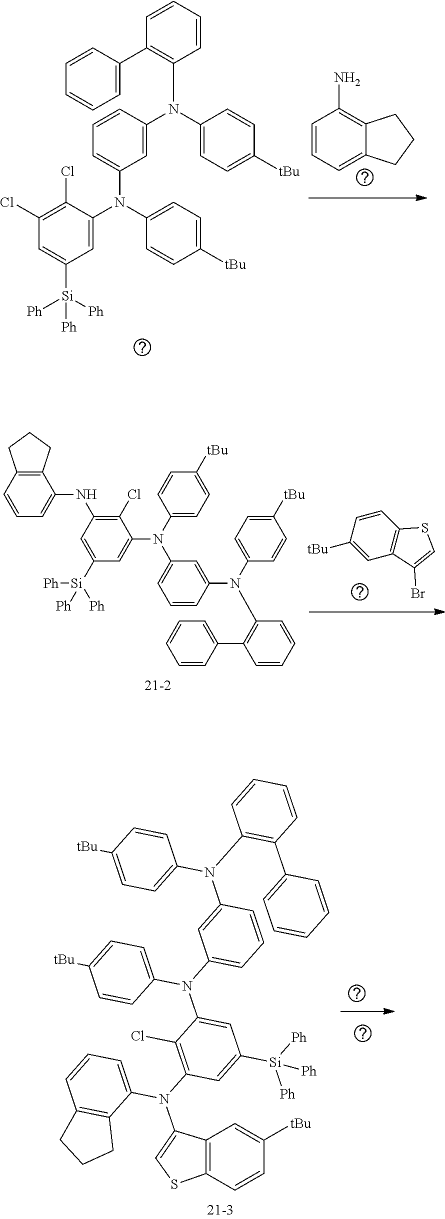

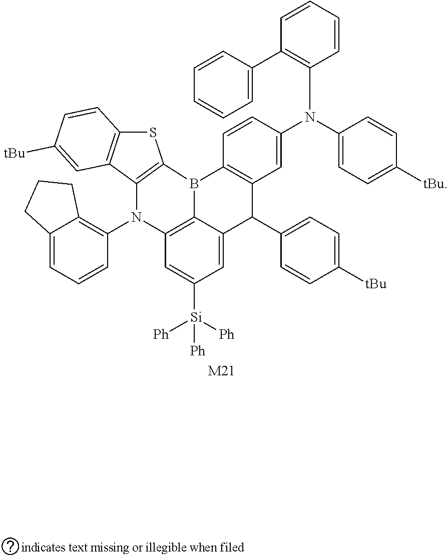

### Synthesis of the Intermediate 21-2

The intermediate 1-7 (10 mmol), Compound 21-1 (10 mmol), Pd-132 (bis(di-tert-butyl-4-dimethylaminophenylphosphine)palladium chloride, 0.1 mmol), S-Phos (2-dicyclohexylphosphine-2′,6′-dimethoxy-1,1′-biphenyl, 0.2 mmol) and sodium tert-butoxide (30 mmol) were dissolved in toluene, heated to 100° C. and stirred for 6 h under a nitrogen atmosphere; after the reaction solution was cooled, most of the solvent was removed by rotary evaporation, and then the reaction solution was extracted and the separated solution was washed with water, and the organic phase was subjected to column chromatography and recrystallization to obtain the intermediate 21-2 with a molar amount of 7.48 mmol and a yield of 74.8%. The atmospheric pressure solid phase analysis probe mass spectrometry (ASAP-MS) result of the intermediate 21-2 was: MS (ASAP)=1023.

### Synthesis of the Intermediate 21-3

The intermediate 21-2 (10 mmol), the intermediate 1-12 (10 mmol), Pd(dba)₂ (bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. and stirred for 6 h under nitrogen atmosphere; after the reaction solution was cooled, the solvent was removed by rotary evaporation, the reaction solution was extracted and the separated solution was washed with water, and the organic phase was subjected to column chromatography to obtain the intermediate 21-3 with a molar amount of 8.55 mmol and a yield of 85.5%. The atmospheric pressure solid phase analytical probe mass spectrometry (ASAP-MS) result of the intermediate 21-3 was: MS (ASAP)=1211.

### Synthesis of the Organic Compound M21

A 250 ml three-necked flask was added with 10 mmol of the intermediate 21-3 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M21, the yield was 40.2%, and the atmospheric pressure solid phase analysis probe mass spectrometry (ASAP-MS) result of organic compound M21 was: MS (ASAP)=1185.

### Example 22

The synthetic route of the organic compound M22 is as follows:

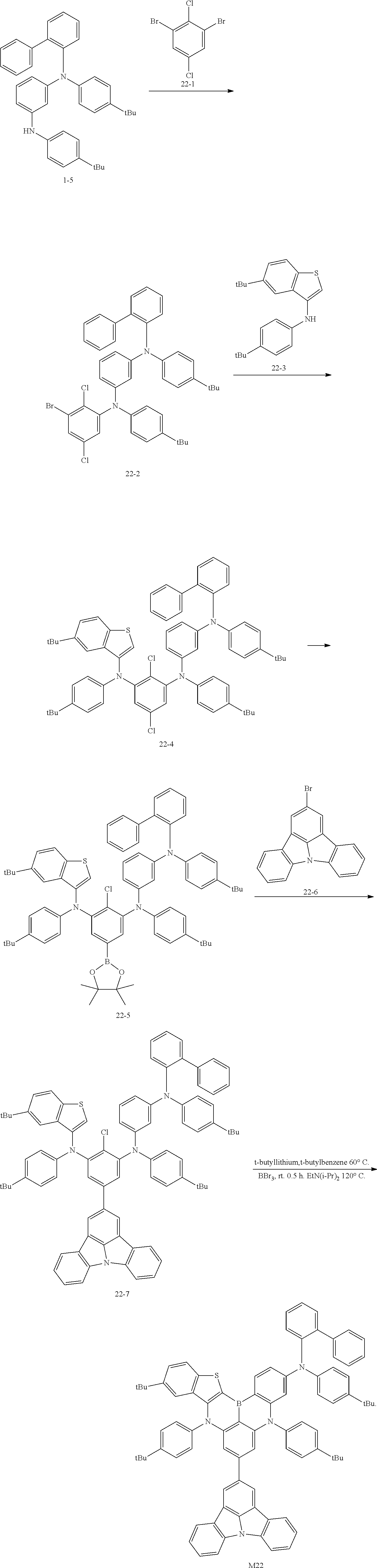

### Synthesis of the Intermediate 22-2

The intermediate 1-5 (10 mmol), Compound 22-1 (10 mmol), Pd-132 (bis(di-tert-butyl-4-dimethylaminophenylphosphine)palladium chloride, 0.1 mmol), S-Phos (2-dicyclohexylphosphine-2′,6′-dimethoxy-1,1′-biphenyl, 0.2 mmol) and sodium tert-butoxide (30 mmol) were dissolved in toluene, heated to 100° C. and stirred for 6 h under a nitrogen atmosphere; after the reaction solution was cooled, the solvent was removed by rotary evaporation, the reaction solution was extracted and the separated solution was washed with water, and the organic phase was subjected to column chromatography to obtain the intermediate 22-2 with a molar amount of 6.29 mmol and a yield of 62.9%. The atmospheric pressure solid phase analysis probe mass spectrometry (ASAP-MS) result of the intermediate 22-2 was: MS (ASAP)=746.

### Synthesis of the Intermediate 22-4

The intermediate 22-2 (10 mmol), Compound 22-3 (10 mmol), Pd-132 (bis(di-tert-butyl-4-dimethylaminophenylphosphine)palladium chloride, 0.1 mmol), S-Phos (2-dicyclohexylphosphine-2′,6′-dimethoxy-1,1′-biphenyl, 0.2 mmol) and sodium tert-butoxide (30 mmol) were dissolved in toluene, heated to 100° C. and stirred for 6 h under a nitrogen atmosphere; after the reaction solution was cooled, most of the solvent was removed by rotary evaporation, and then the reaction solution was extracted and the separated solution was washed with water, and the organic phase was subjected to column chromatography and recrystallization to obtain the intermediate 22-4, with a molar amount of 7.59 mmol and a yield of 75.9%. The atmospheric pressure solid phase analysis probe mass spectrometry (ASAP-MS) result of the intermediate 22-4 was: MS (ASAP)=1003.

### Synthesis of the Intermediate 22-5

The the intermediate 22-4 (10 mmol), pinacol borate (20 mmol), palladium acetate (0.1 mmol) and potassium acetate (30 mmol) were dissolved in 1,4-dioxane, heated to 100° C. and stirred for 6 h under a nitrogen atmosphere; after the reaction solution was cooled, most of the solvent was removed by rotary evaporation, and then the reaction solution was extracted and the separated solution was washed with water, and The organic phase was subjected to column chromatography and recrystallization to obtain the the intermediate 22-5 with a molar amount of 7.34 mmol and a yield of 73.4%. The atmospheric pressure solid phase analysis probe mass spectrometry (ASAP-MS) result of the the intermediate 22-5 was: MS (ASAP)=1095.

### Synthesis of the Intermediate 22-7

The intermediate 22-5 (10 mmol) and the intermediate 22-6 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. and stirred for 6 h under a nitrogen atmosphere. After the reaction solution was cooled, most of the solvent was removed by rotary evaporation, and then the reaction solution was extracted and the separated solution was washed with water. The organic phase was subjected to column chromatography and recrystallization to obtain the intermediate 22-7 with a molar amount of 7.36 mmol and a yield of 73.6%. The atmospheric pressure solid phase analysis probe mass spectrometry (ASAP-MS) result of the intermediate 22-7 was: MS (ASAP)=1208.

### Synthesis of the Organic Compound M22

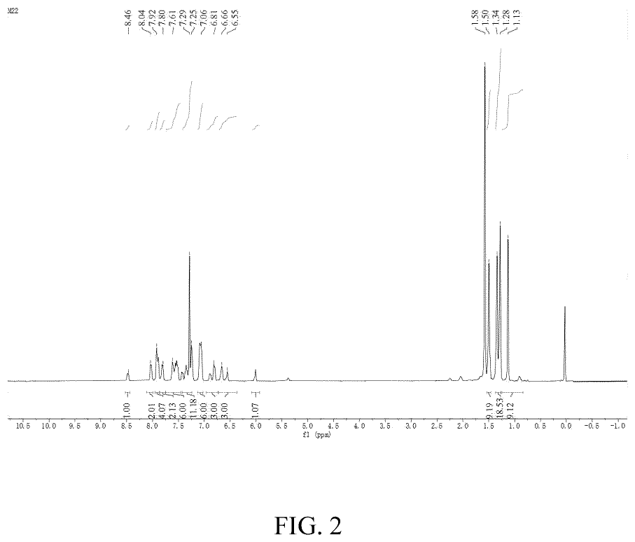

10 mmol of the intermediate 22-7 and 100 ml of dry tert-butylbenzene were added to a 250 ml three-necked flask, cooled to −30° C. in a N₂ atmosphere, and a n-hexane solution of t-BuLi (tert-butyl lithium) (21 mmol) was added dropwise, the temperature was raised to 60° C. for reaction for 2 hours, and the n-hexane solvent was evaporated under reduced pressure; the reaction solution was cooled to −30° C. again, boron tribromide (21 mmol) was added, and the mixture was heated to a room temperature and stirred for 0.5 hours, then the reaction solution was cooled to 0° C., 42 mmol of N,N-diisopropylethylamine was added, and after the dropwise addition was completed, the mixture was heated to a room temperature and stirred, and then the temperature was further raised to 120° C. and stirred for 3 hours, and the reaction solution was cooled to a room temperature; sodium carbonate aqueous solution and ethyl acetate were added to quench the reaction; the aqueous phase was extracted with ethyl acetate and the organic phases were combined, and The solvent was rotary-evaporated off to obtain a crude product, which was purified by a rapid silica gel column to obtain a pure product; and the product was recrystallized from toluene and ethyl acetate to obtain a light yellow solid powder product, i.e., the organic compound M22, the yield is 43.9%, the atmospheric pressure solid phase analysis probe mass spectrometry (ASAP-MS) result of the organic compound M22 is: MS (ASAP)=1182; the nuclear magnetic resonance hydrogen spectrum of the organic compound M22 is shown in FIG. 2.

### Example 23

Synthesis route of the organic compound M23 is as follows:

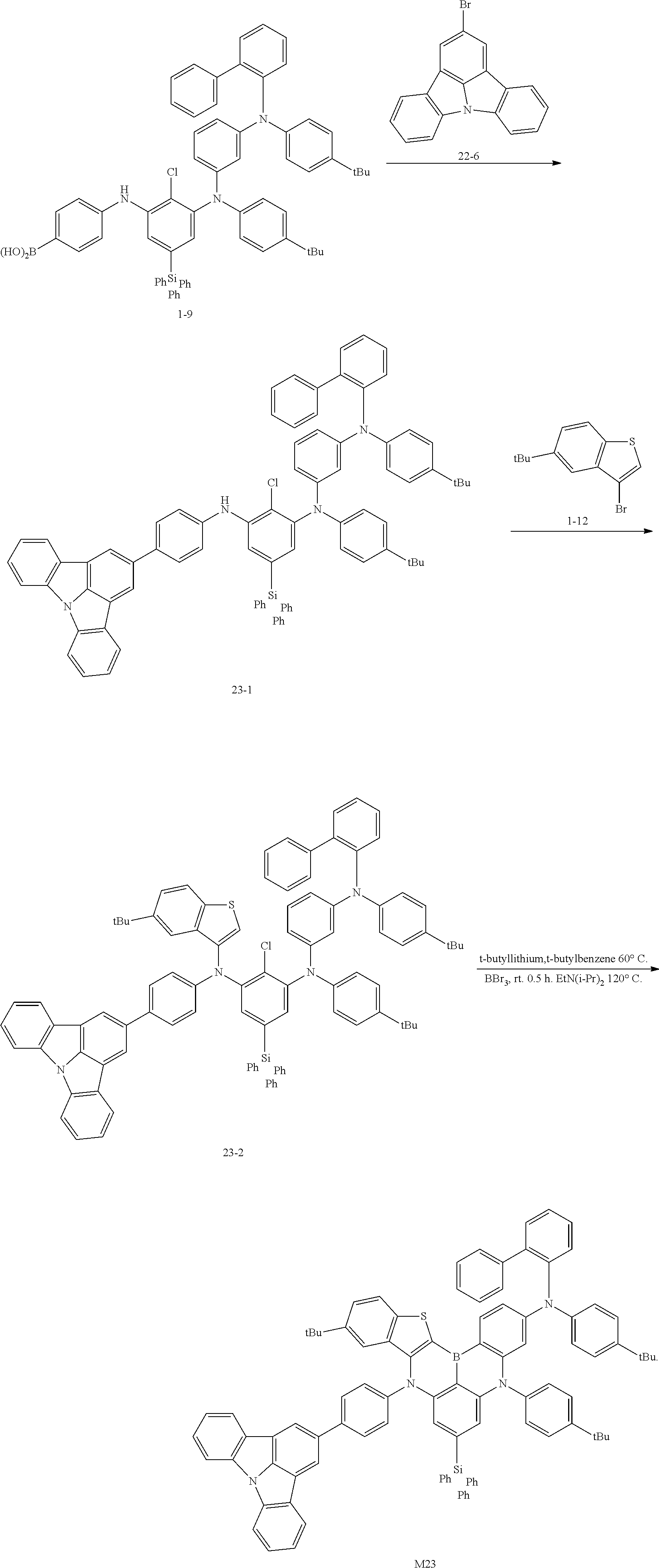

### Synthesis of the Intermediate 23-1

Compound 1-9 (10 mmol) and Compound 22-6 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. under a nitrogen atmosphere and stirred for 6 h. After the reaction solution was cooled, the solvent was removed by rotary evaporation, the reaction solution was extracted and the separated solution was washed with water, and the organic phase was subjected to column chromatography to obtain the intermediate 23-1 with a molar amount of 7.87 mmol and a yield of 78.7%. The atmospheric pressure solid phase analysis probe mass spectrometry (ASAP-MS) result of the intermediate 23-1 was: MS (ASAP)=1222.

### Synthesis of the Intermediate 23-2

The intermediate 23-1 (10 mmol), the intermediate 1-12 (10 mmol), Pd(dba)₂ (bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. under nitrogen atmosphere and stirred for 6 h; after the reaction solution was cooled, the solvent was removed by rotary evaporation, the reaction solution was extracted and the separated solution was washed with water, and the organic phase was subjected to column chromatography to obtain the intermediate 23-2, with a molar amount of 8.29 mmol and a yield of 82.9%. The atmospheric pressure solid phase analytical probe mass spectrometry (ASAP-MS) result of the intermediate 23-2 was: MS (ASAP)=1410.

### Synthesis of the Organic Compound M23

A 250 ml three-necked flask was added with 10 mmol of the intermediate 23-2 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M23, the yield was 35.9%, and the atmospheric pressure solid phase analysis probe mass spectrometry (ASAP-MS) result of Synthesis route of the organic compound M23 was: MS (ASAP)=1384.

### Example 24

Synthesis route of the organic compound M24 is as follows:

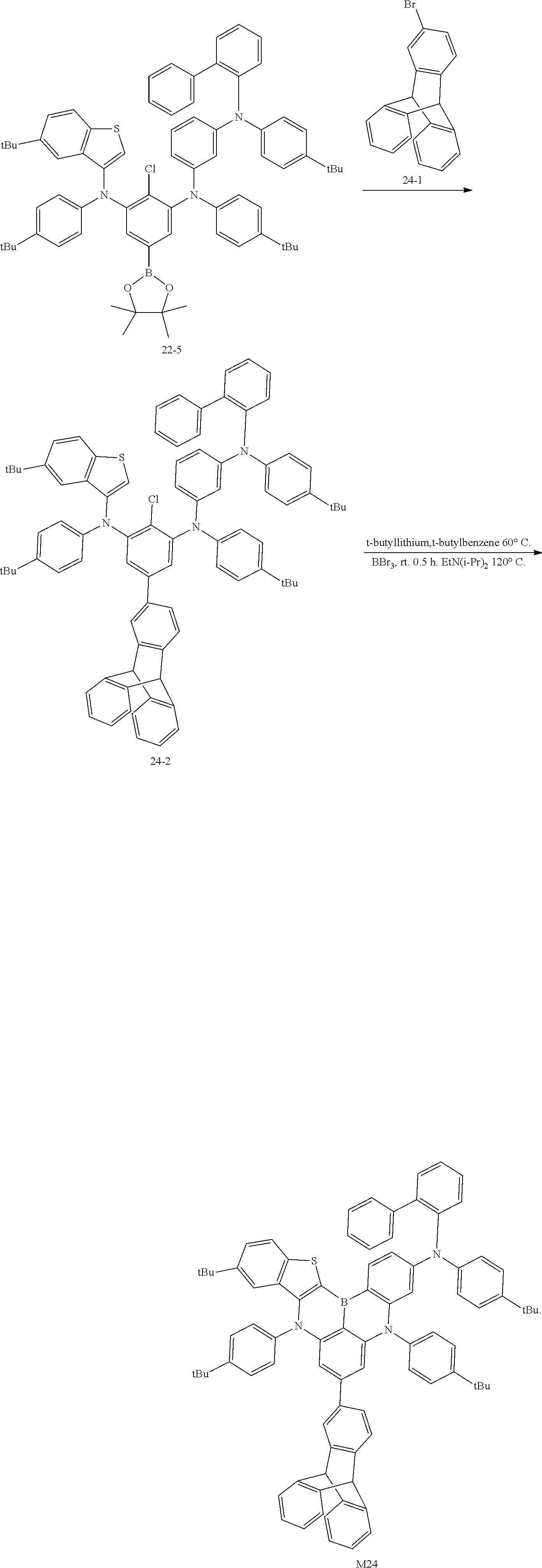

### Synthesis of the Intermediate 24-2

The intermediate 22-5 (10 mmol) and the intermediate 24-1 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. and stirred for 6 h under a nitrogen atmosphere. After the reaction solution was cooled, most of the solvent was removed by rotary evaporation, and then the reaction solution was extracted and the separated solution was washed with water. The organic phase was subjected to column chromatography and recrystallization to obtain the intermediate 24-2 with a molar amount of 8.24 mmol and a yield of 82.4%. The atmospheric pressure solid phase analysis probe mass spectrometry (ASAP-MS) result of the intermediate 24-2 was: MS (ASAP)=1221.

### Synthesis Route of the Organic Compound M24

10 mmol of the intermediate 24-2 and 100 ml of dry tert-butylbenzene were added to a 250 ml three-necked flask. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N, N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M24, the yield was 41.6%, and the atmospheric pressure solid phase analysis probe mass spectrometry (ASAP-MS) result of Synthesis route of the organic compound M24 was: MS (ASAP)=1195.

### Example 25

Synthesis route of the organic compound M25 is as follows:

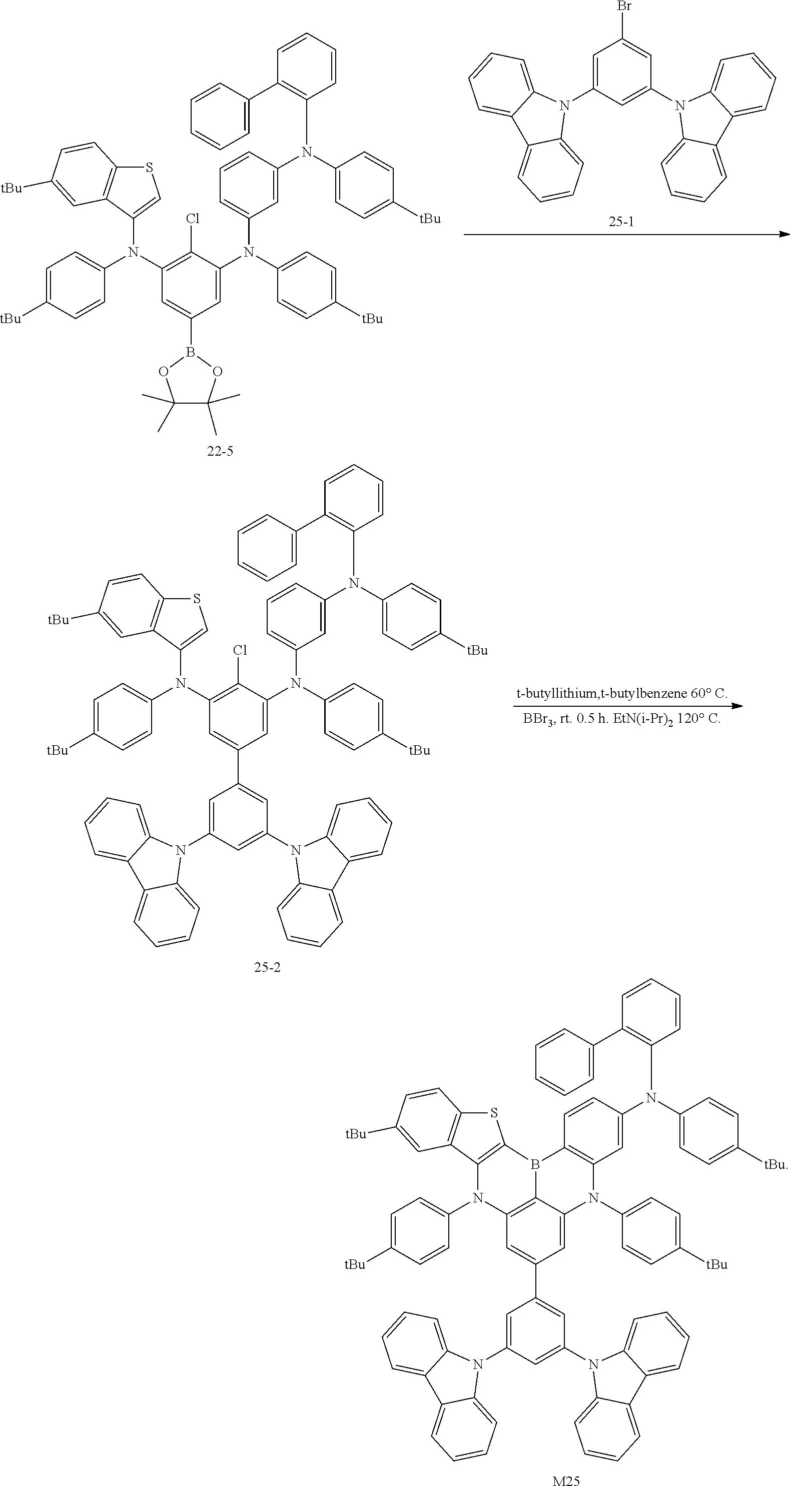

### Synthesis of the Intermediate 25-2

The intermediate 22-5 (10 mmol) and the intermediate 25-1 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. and stirred for 6 h under a nitrogen atmosphere. After the reaction solution was cooled, most of the solvent was removed by rotary evaporation, and then the reaction solution was extracted and the separated solution was washed with water. The organic phase was subjected to column chromatography and recrystallization to obtain the intermediate 25-2 with a molar amount of 8.86 mmol and a yield of 88.6%. The atmospheric pressure solid phase analysis probe mass spectrometry (ASAP-MS) result of the intermediate 25-2 was: MS (ASAP)=1375.

### Synthesis of the Organic Compound M25

10 mmol of the intermediate 25-2 and 100 ml of dry tert-butylbenzene were added to a 250 ml three-necked flask. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M25, the yield was 44.8%, and the atmospheric pressure solid phase analysis probe mass spectrometry (ASAP-MS) result of Synthesis route of the organic compound M25 was: MS (ASAP)=1349.

### Example 26

Synthesis route of the organic compound M26 is as follows:

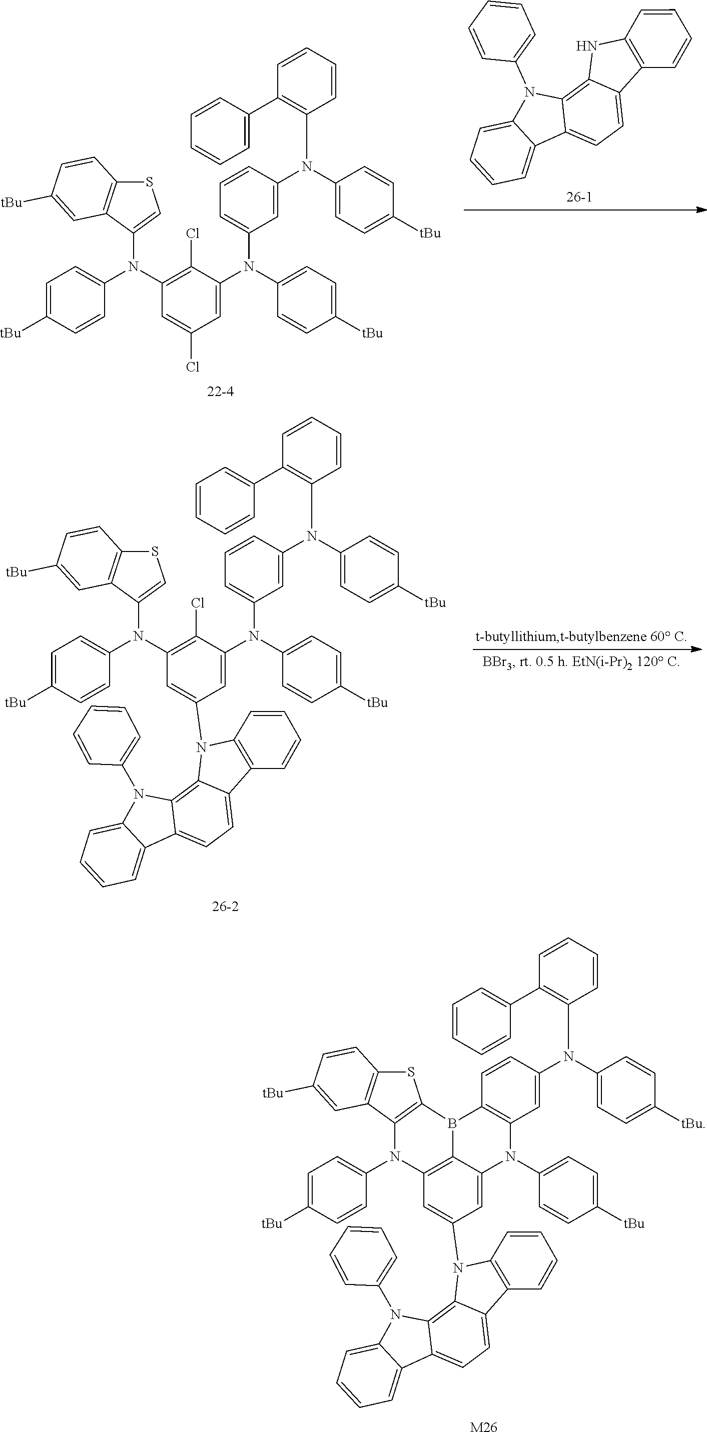

### Synthesis of the Intermediate 26-2

The intermediate 22-4 (10 mmol) and the intermediate 26-1 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. and stirred for 6 h under a nitrogen atmosphere. After the reaction solution was cooled, most of the solvent was removed by rotary evaporation, and then the reaction solution was extracted and the separated solution was washed with water. The organic phase was subjected to column chromatography and recrystallization to obtain the intermediate 26-2 with a molar amount of 8.17 mmol and a yield of 81.7%. The atmospheric pressure solid phase analysis probe mass spectrometry (ASAP-MS) result of the intermediate 26-2 was: MS (ASAP)=1299.

### Synthesis of the Organic Compound M26

10 mmol of the intermediate 26-2 and 100 ml of dry tert-butylbenzene were added to a 250 ml three-necked flask. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M26, the yield was 34.8%, and the atmospheric pressure solid phase analysis probe mass spectrometry (ASAP-MS) result of Synthesis route of the organic compound M26 was: MS (ASAP)=1273.

### Example 27

Synthesis route of the organic compound M27 is as follows:

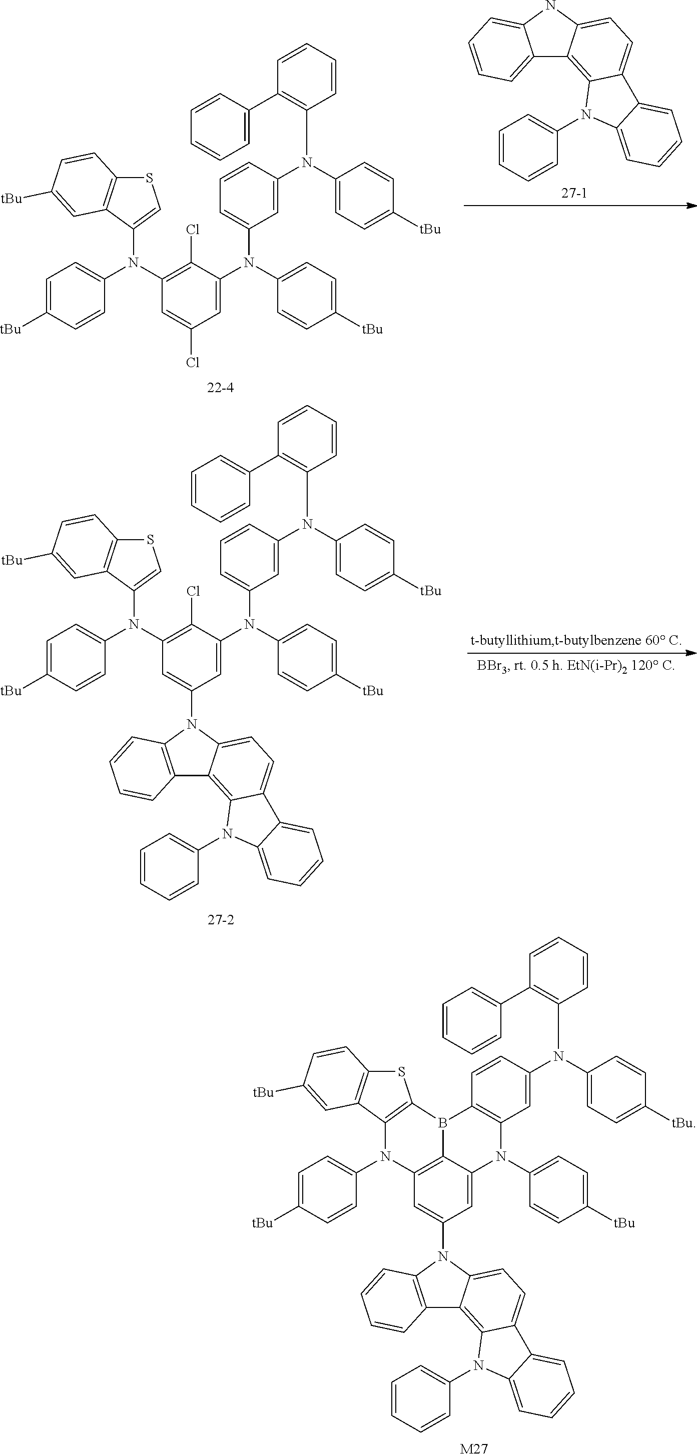

### Synthesis of the Intermediate 27-2

The intermediate 22-4 (10 mmol) and the intermediate 27-1 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. and stirred for 6 h under a nitrogen atmosphere. After the reaction solution was cooled, most of the solvent was removed by rotary evaporation, and then the reaction solution was extracted and the separated solution was washed with water. The organic phase was subjected to column chromatography and recrystallization to obtain the intermediate 27-2 with a molar amount of 8.35 mmol and a yield of 83.5%. The atmospheric pressure solid phase analysis probe mass spectrometry (ASAP-MS) result of the intermediate 27-2 was: MS (ASAP)=1299.

### Synthesis of the Organic Compound M27

10 mmol of the intermediate 27-2 and 100 ml of dry tert-butylbenzene were added to a 250 ml three-necked flask. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M27, the yield was 39.2%, and the atmospheric pressure solid phase analysis probe mass spectrometry (ASAP-MS) result of the organic compound M27 was: MS (ASAP)=1273.

### Example 28

Synthesis route of the organic compound M28 is as follows:

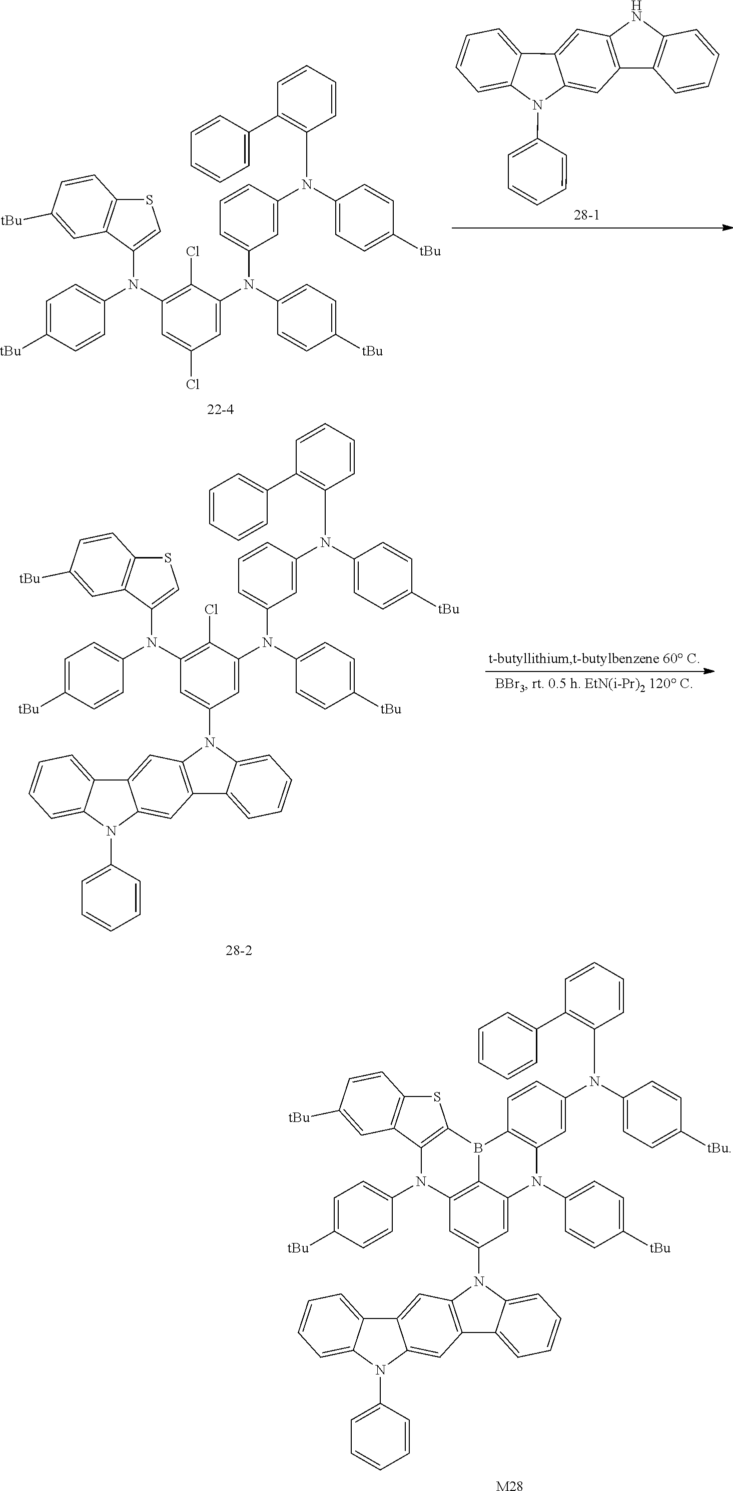

### Synthesis of the Intermediate 28-2

The intermediate 22-4 (10 mmol) and the intermediate 28-1 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. and stirred for 6 h under a nitrogen atmosphere. After the reaction solution was cooled, most of the solvent was removed by rotary evaporation, and then the reaction solution was extracted and the separated solution was washed with water. The organic phase was subjected to column chromatography and recrystallization to obtain the intermediate 28-2 with a molar amount of 8.54 mmol and a yield of 85.4%. The atmospheric pressure solid phase analysis probe mass spectrometry (ASAP-MS) result of the intermediate 28-2 was: MS (ASAP)=1299.

### Synthesis of the Organic Compound M28

A 250 ml three-necked flask was added with 10 mmol of the intermediate 28-2 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M28, the yield was 38.4%, and the atmospheric pressure solid phase analysis probe mass spectrometry (ASAP-MS) result of the Synthesis route of the organic compound M28 was: MS (ASAP)=1273.

### Example 29

Synthesis route of the organic compound M29 is as follows:

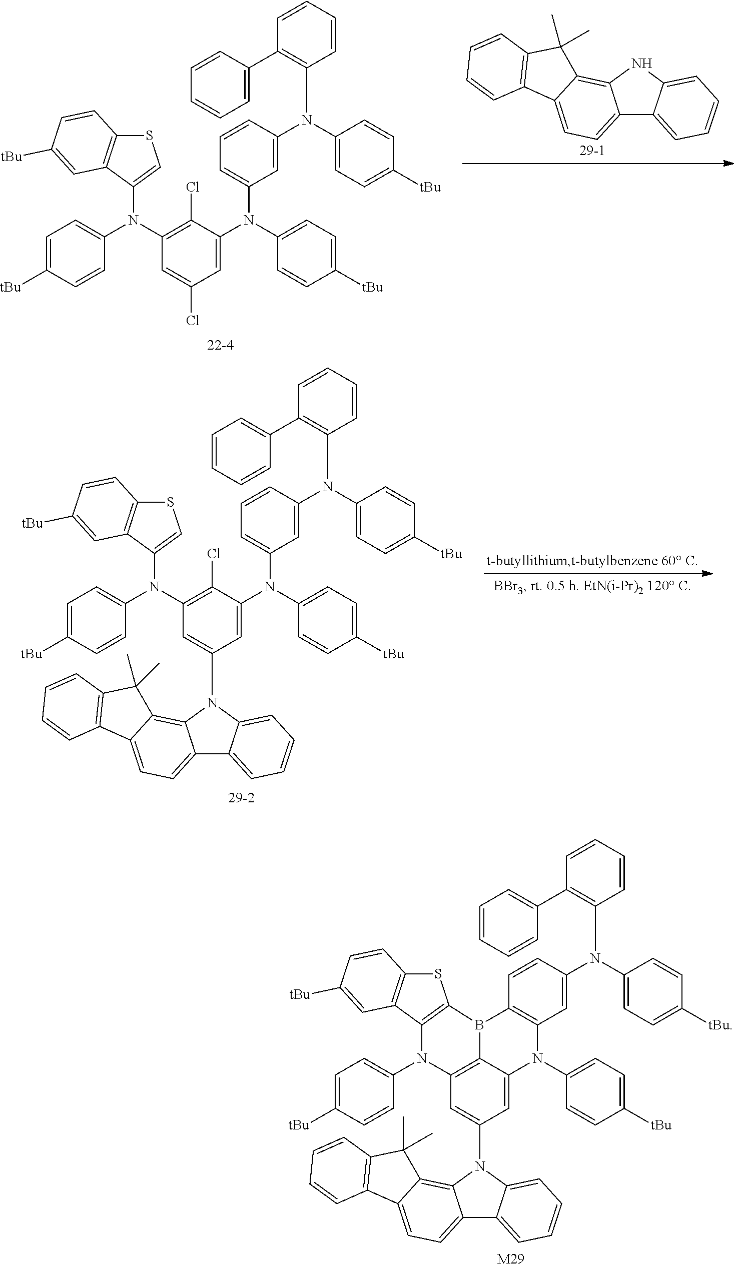

### Synthesis of the Intermediate 29-2

The intermediate 22-4 (10 mmol) and the intermediate 29-1 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. and stirred for 6 h under a nitrogen atmosphere. After the reaction solution was cooled, most of the solvent was removed by rotary evaporation, and then the reaction solution was extracted and the separated solution was washed with water. The organic phase was subjected to column chromatography and recrystallization to obtain the intermediate 29-2 with a molar amount of 7.45 mmol and a yield of 74.5%. The atmospheric pressure solid phase analysis probe mass spectrometry (ASAP-MS) result of the intermediate 29-2 was: MS (ASAP)=1250.

### Synthesis of the Organic Compound M29

A 250 ml three-necked flask was added with 10 mmol of the intermediate 29-2 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M29, the yield was 31.3%, and the atmospheric pressure solid phase analysis probe mass spectrometry (ASAP-MS) result of organic compound M29 was: MS (ASAP)=1224.

### Example 30

Synthesis route of the organic compound M30 is as follows:

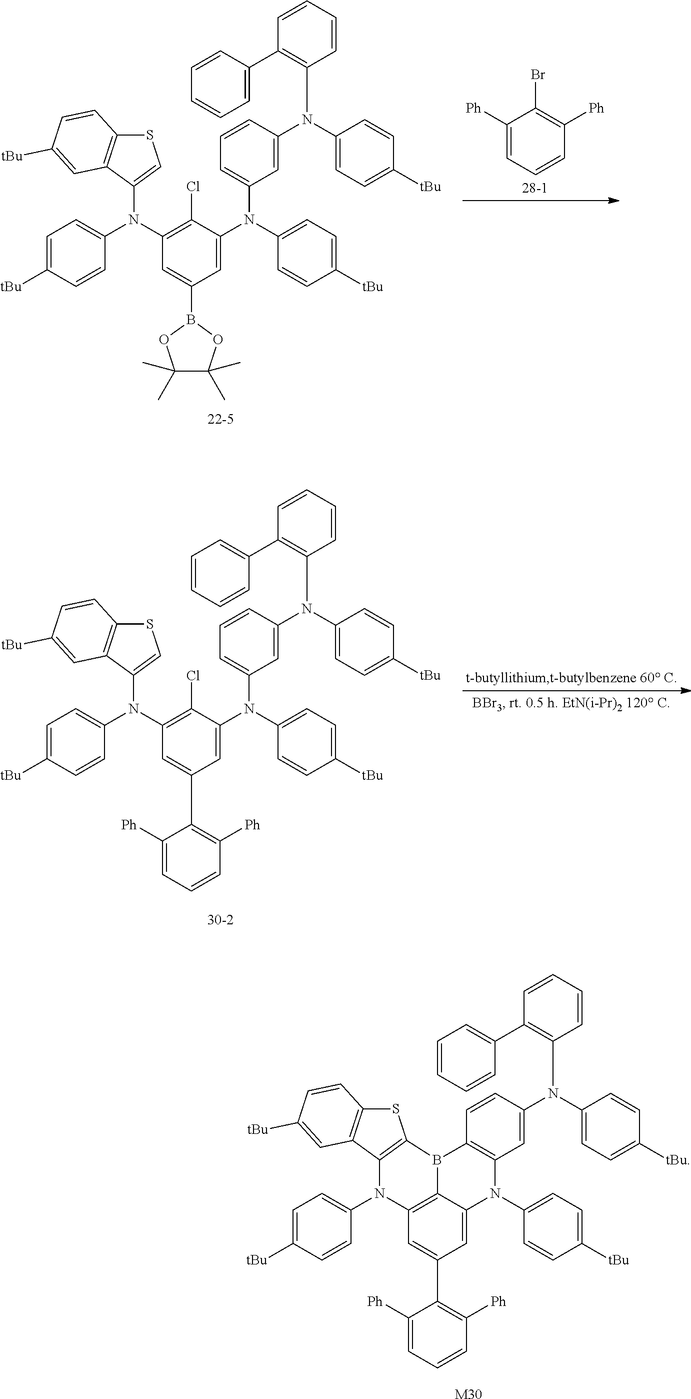

### Synthesis of the Intermediate 30-2

The intermediate 22-5 (10 mmol) and the intermediate 30-1 (10 mmol) were dissolved in a mixed solvent of 1,4-dioxane and water (21/2 ml), and Pd(PPh₃)₄ (0.1 mmol) and potassium carbonate (30 mmol) were added. The temperature was raised to 100° C. and stirred for 6 h under a nitrogen atmosphere. After the reaction solution was cooled, most of the solvent was removed by rotary evaporation, and then the reaction solution was extracted and the separated solution was washed with water. The organic phase was subjected to column chromatography and recrystallization to obtain the intermediate 30-2 with a molar amount of 8.14 mmol and a yield of 81.4%. The atmospheric pressure solid phase analysis probe mass spectrometry (ASAP-MS) result of the intermediate 30-2 was: MS (ASAP)=1197.

### Synthesis of Organic Compound M30

A 250 ml three-necked flask was added with 10 mmol of the intermediate 30-2 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M30, the yield was 42.7%, and the atmospheric pressure solid phase analysis probe mass spectrometry (ASAP-MS) result of organic compound M30 was: MS (ASAP)=1171.

### Example 31

Synthesis route of the organic compound M31 is as follows:

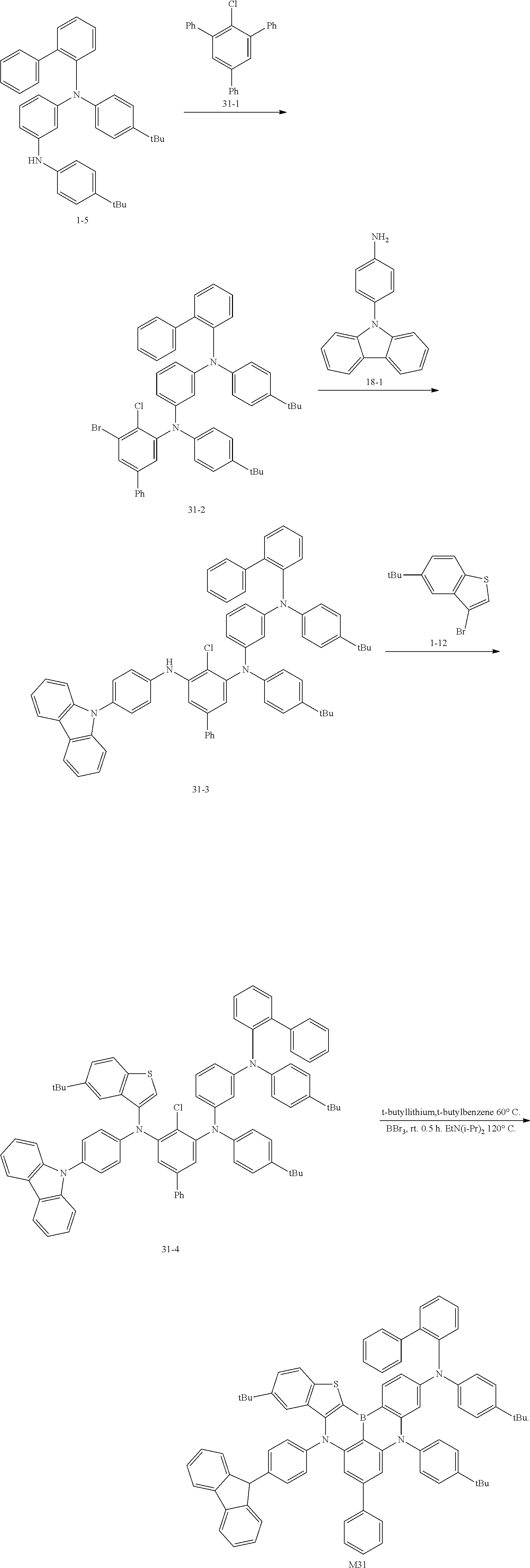

### Synthesis of the Intermediate 31-2

The intermediate 1-5 (10 mmol), Compound 31-1 (10 mmol), Pd-132 (bis(di-tert-butyl-4-dimethylaminophenylphosphine)palladium chloride, 0.1 mmol), S-Phos (2-dicyclohexylphosphine-2′,6′-dimethoxy-1,1′-biphenyl, 0.2 mmol) and sodium tert-butoxide (30 mmol) were dissolved in toluene, heated to 100° C. and stirred for 6 h under a nitrogen atmosphere; after the reaction solution was cooled, the solvent was removed by rotary evaporation, the reaction solution was extracted and the separated solution was washed with water, and the organic phase was subjected to column chromatography to obtain the intermediate 31-2 with a molar amount of 8.33 mmol and a yield of 83.3%. The atmospheric pressure solid phase analysis probe mass spectrometry (ASAP-MS) result of the intermediate 31-2 was: MS (ASAP)=788.

### Synthesis of the Intermediate 31-3

The intermediate 31-2 (10 mmol), Compound 18-1 (10 mmol), Pd-132 (bis(di-tert-butyl-4-dimethylaminophenylphosphine)palladium chloride, 0.1 mmol), S-Phos (2-dicyclohexylphosphine-2′,6′-dimethoxy-1,1′-biphenyl, 0.2 mmol) and sodium tert-butoxide (30 mmol) were dissolved in toluene, heated to 100° C. and stirred for 6 h under a nitrogen atmosphere; after the reaction solution was cooled, most of the solvent was removed by rotary evaporation, and then the reaction solution was extracted and the separated solution was washed with water, and the organic phase was subjected to column chromatography and recrystallization to obtain the intermediate 31-3, with a molar amount of 7.28 mmol and a yield of 72.8%. The atmospheric pressure solid phase analysis probe mass spectrometry (ASAP-MS) result of the intermediate 31-3 was: MS (ASAP)=966.

### Synthesis of the Intermediate 31-4

The intermediate 31-3 (10 mmol), Compound 1-12 (10 mmol), Pd-132 (bis(di-tert-butyl-4-dimethylaminophenylphosphine)palladium chloride, 0.1 mmol), S-Phos (2-dicyclohexylphosphine-2′,6′-dimethoxy-1,1′-biphenyl, 0.2 mmol) and sodium tert-butoxide (30 mmol) were dissolved in toluene, heated to 100′C and stirred for 6 h under a nitrogen atmosphere; after the reaction solution was cooled, most of the solvent was removed by rotary evaporation, and then the reaction solution was extracted and the separated solution was washed with water, and the organic phase was subjected to column chromatography and recrystallization to obtain the intermediate 31-4, with a molar amount of 7.86 mmol and a yield of 78.6%. The atmospheric pressure solid phase analysis probe mass spectrometry (ASAP-MS) result of the intermediate 31-4 was: MS (ASAP)=1154.

### Synthesis of the Organic Compound M31

A 250 ml three-necked flask was added with 10 mmol of the intermediate 31-4 and 100 ml of dry tert-butylbenzene. The mixture was cooled to −30′C in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M31, the yield was 42.7%, and the atmospheric pressure solid phase analysis probe mass spectrometry (ASAP-MS) result of organic compound M31 was: MS (ASAP)=1128.

### Example 32

Synthesis route of the organic compound M32 is as follows:

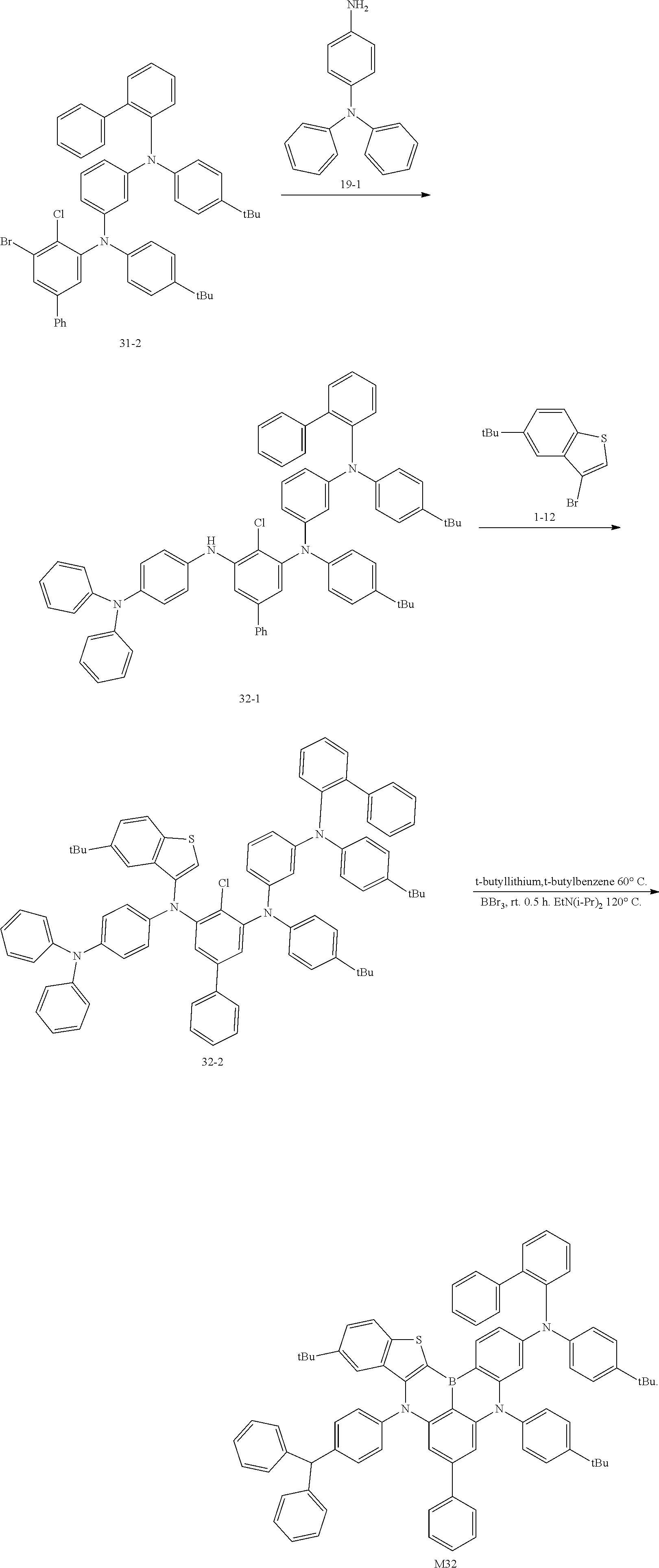

### Synthesis of the Intermediate 32-1

The intermediate 31-2 (10 mmol), Compound 19-1 (10 mmol), Pd-132 (bis(di-tert-butyl-4-dimethylaminophenylphosphine)palladium chloride, 0.1 mmol), S-Phos (2-dicyclohexylphosphine-2′,6′-dimethoxy-1,1′-biphenyl, 0.2 mmol) and sodium tert-butoxide (30 mmol) were dissolved in toluene, heated to 100° C. and stirred for 6 h under a nitrogen atmosphere; after the reaction solution was cooled, most of the solvent was removed by rotary evaporation, and then the reaction solution was extracted and the separated solution was washed with water, and the organic phase was subjected to column chromatography and recrystallization to obtain the intermediate 32-1, with a molar amount of 7.55 mmol and a yield of 75.5%. The atmospheric pressure solid phase analysis probe mass spectrometry (ASAP-MS) result of the intermediate 32-1 was: MS (ASAP)=968.

### Synthesis of the Intermediate 32-2

The intermediate 32-1 (10 mmol), Compound 1-12 (10 mmol), Pd-132 (bis(di-tert-butyl-4-dimethylaminophenylphosphine)palladium chloride, 0.1 mmol), S-Phos (2-dicyclohexylphosphine-2′,6′-dimethoxy-1,1′-biphenyl, 0.2 mmol) and sodium tert-butoxide (30 mmol) were dissolved in toluene, heated to 100° C. and stirred for 6 h under a nitrogen atmosphere; after the reaction solution was cooled, most of the solvent was removed by rotary evaporation, and then the reaction solution was extracted and the separated solution was washed with water, and the organic phase was subjected to column chromatography and recrystallization to obtain the intermediate 32-2, with a molar amount of 7.13 mmol and a yield of 71.3%. The atmospheric pressure solid phase analysis probe mass spectrometry (ASAP-MS) result of the intermediate 32-2 was: MS (ASAP)=1156.

### Synthesis of the Organic Compound M32

A 250 ml three-necked flask was added with 10 mmol of the intermediate 32-2 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M32, the yield was 45.9%, the atmospheric pressure solid phase analysis probe mass spectrometry (ASAP-MS) result of organic compound M32 was: MS (ASAP)=1130.

### Example 33

Synthesis route of the organic compound M33 is as follows:

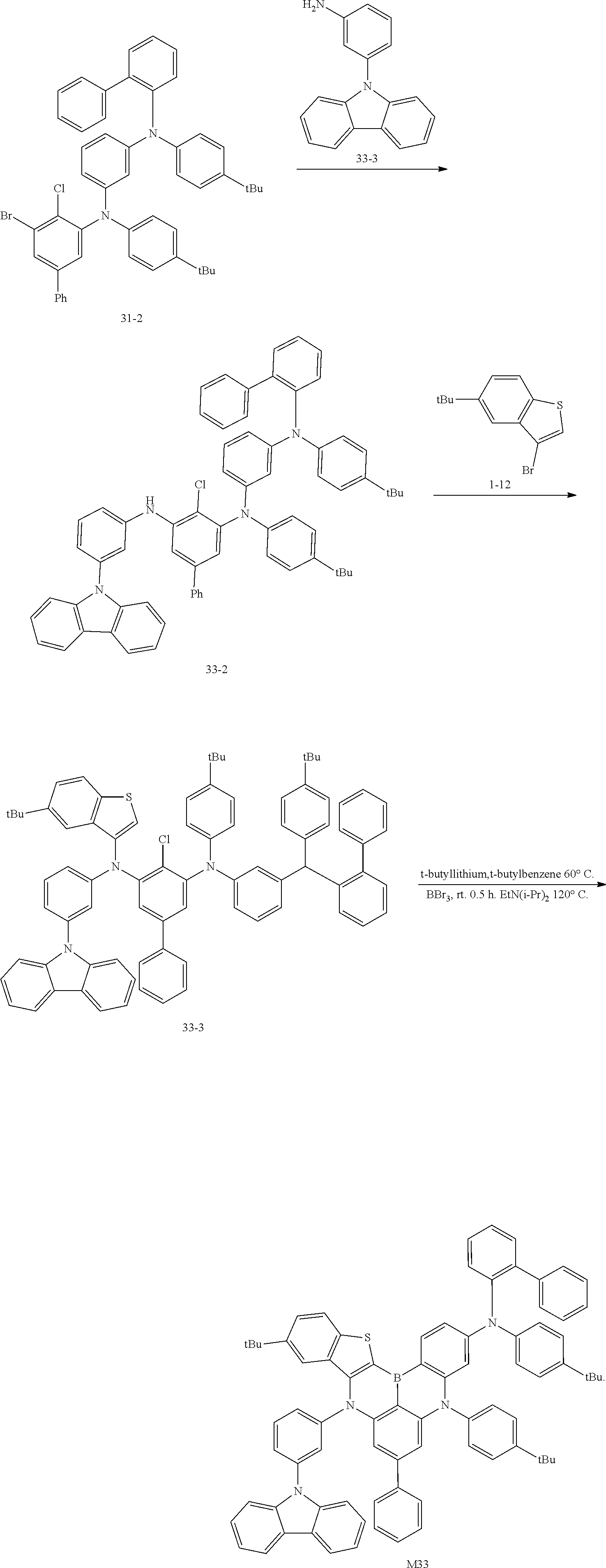

### Synthesis of the Intermediate 33-2

The intermediate 31-2 (10 mmol), Compound 33-1 (10 mmol), Pd-132 (bis(di-tert-butyl-4-dimethylaminophenylphosphine)palladium chloride, 0.1 mmol), S-Phos (2-dicyclohexylphosphine-2′,6′-dimethoxy-1,1′-biphenyl, 0.2 mmol) and sodium tert-butoxide (30 mmol) were dissolved in toluene, heated to 100° C. and stirred for 6 h under a nitrogen atmosphere; after the reaction solution was cooled, most of the solvent was removed by rotary evaporation, and then the reaction solution was extracted and the separated solution was washed with water, and the organic phase was subjected to column chromatography and recrystallization to obtain the intermediate 33-2, with a molar amount of 7.56 mmol and a yield of 75.6%. The atmospheric pressure solid phase analysis probe mass spectrometry (ASAP-MS) result of the intermediate 33-2 was: MS (ASAP)=966.

### Synthesis of the Intermediate 33-3

The intermediate 33-2 (10 mmol), Compound 1-12 (10 mmol), Pd-132 (bis(di-tert-butyl-4-dimethylaminophenylphosphine)palladium chloride, 0.1 mmol), S-Phos (2-dicyclohexylphosphine-2′,6′-dimethoxy-1,1′-biphenyl, 0.2 mmol) and sodium tert-butoxide (30 mmol) were dissolved in toluene, heated to 100° C. and stirred for 6 h under a nitrogen atmosphere; after the reaction solution was cooled, most of the solvent was removed by rotary evaporation, and then the reaction solution was extracted and the separated solution was washed with water, and The organic phase was subjected to column chromatography and recrystallization to obtain the intermediate 33-3, with a molar amount of 7.12 mmol and a yield of 71.2%. The atmospheric pressure solid phase analysis probe mass spectrometry (ASAP-MS) result of the intermediate 33-3 was: MS (ASAP)=1154.

### Synthesis of the Organic Compound M33

A 250 ml three-necked flask was added with 10 mmol of the intermediate 33-3 and 100 ml of dry tert-butylbenenne. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M33, the yield was 44.6%, and the atmospheric pressure solid phase analysis probe mass spectrometry (ASAP-MS) result of organic compound M33 was: MS (ASAP)=1128.

### Example 34

Synthesis route of the organic compound M34 is as follows:

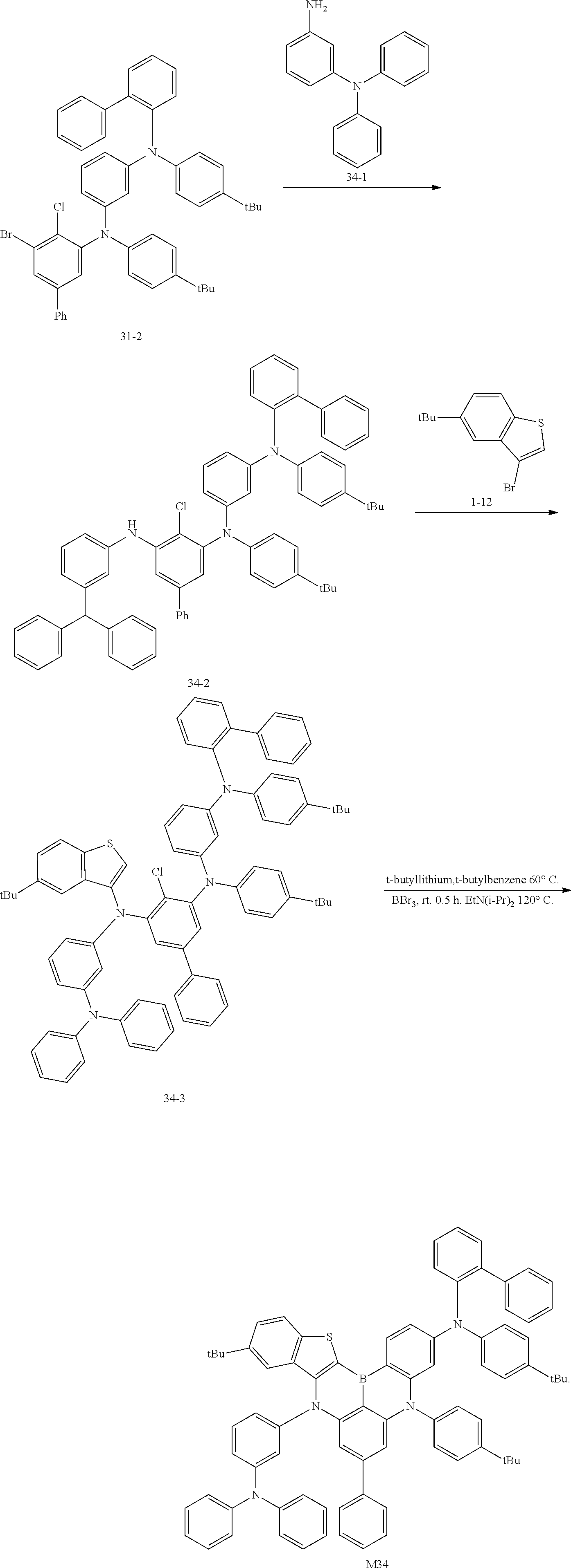

### Synthesis of the Intermediate 34-2

The intermediate 31-2 (10 mmol), Compound 34-1 (10 mmol), Pd-132 (bis(di-tert-butyl-4-dimethylaminophenylphosphine)palladium chloride, 0.1 mmol), S-Phos (2-dicyclohexylphosphine-2′,6′-dimethoxy-1,1′-biphenyl, 0.2 mmol) and sodium tert-butoxide (30 mmol) were dissolved in toluene, heated to 100° C. and stirred for 6 h under a nitrogen atmosphere; after the reaction solution was cooled, most of the solvent was removed by rotary evaporation, and then the reaction solution was extracted and the separated solution was washed with water, and the organic phase was subjected to column chromatography and recrystallization to obtain the intermediate 34-2, with a molar amount of 7.26 mmol and a yield of 72.6%. The atmospheric pressure solid phase analysis probe mass spectrometry (ASAP-MS) result of the intermediate 34-2 was: MS (ASAP)=968.

### Synthesis of the Intermediate 34-3

The intermediate 34-2 (10 mmol), Compound 1-12 (10 mmol), Pd-132 (bis(di-tert-butyl-4-dimethylaminophenylphosphine)palladium chloride, 0.1 mmol), S-Phos (2-dicyclohexylphosphine-2′,6′-dimethoxy-1,1′-biphenyl, 0.2 mmol) and sodium tert-butoxide (30 mmol) were dissolved in toluene, heated to 100° C. and stirred for 6 h under a nitrogen atmosphere; after the reaction solution was cooled, most of the solvent was removed by rotary evaporation, and then the reaction solution was extracted and the separated solution was washed with water, and The organic phase was subjected to column chromatography and recrystallization to obtain the intermediate 34-3, with a molar amount of 7.57 mmol and a yield of 75.7%. The atmospheric pressure solid phase analysis probe mass spectrometry (ASAP-MS) result of the intermediate 34-3 was: MS (ASAP)=1156.

### Synthesis of the Organic Compound M34

A 250 ml three-necked flask was added with 10 mmol of the intermediate 34-3 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M34, the yield was 41.1%, and the atmospheric pressure solid phase analysis probe mass spectrometry (ASAP-MS) result of organic compound M34 was: MS (ASAP)=1130.

### Example 35

Synthesis route of the organic compound M35 is as follows:

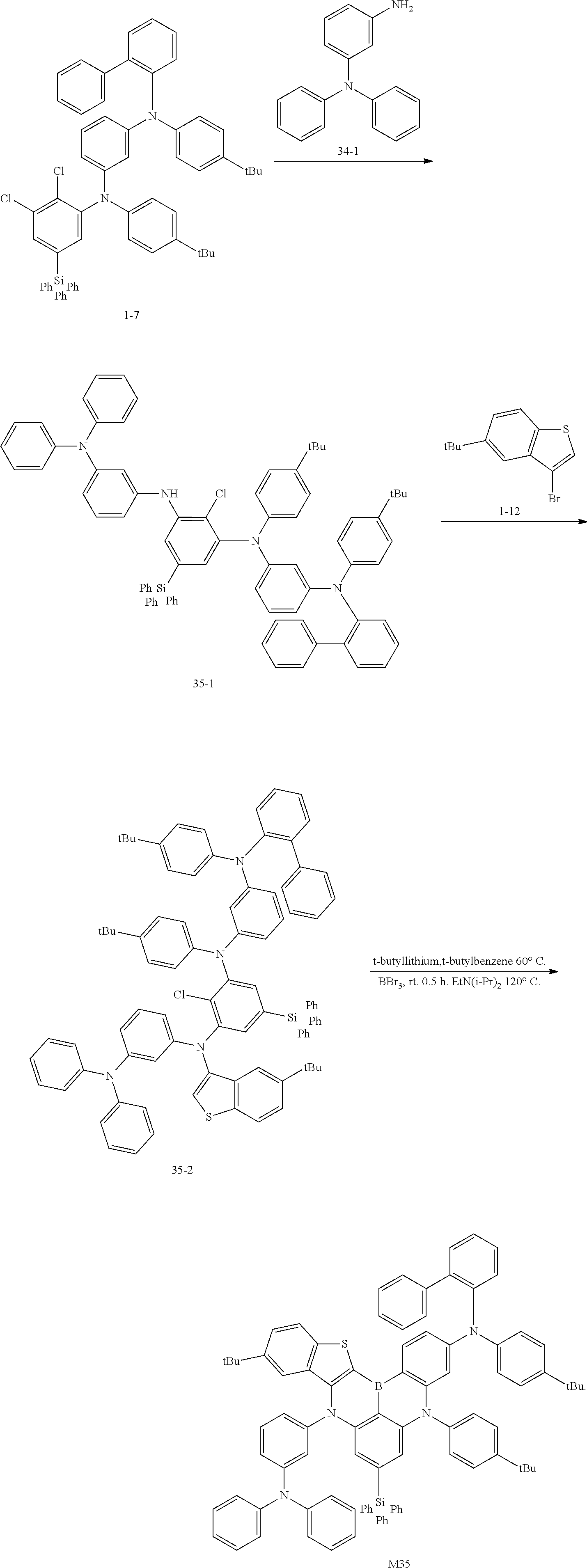

### Synthesis of the Intermediate 35-1

The intermediate 1-7 (10 mmol), Compound 34-1 (10 mmol), Pd-132 (bis(di-tert-butyl-4-dimethylaminophenylphosphine)palladium chloride, 0.1 mmol), S-Phos (2-dicyclohexylphosphine-2′,6′-dimethoxy-1,1′-biphenyl, 0.2 mmol) and sodium tert-butoxide (30 mmol) were dissolved in toluene, heated to 100° C. and stirred for 6 h under a nitrogen atmosphere; after the reaction solution was cooled, most of the solvent was removed by rotary evaporation, and then the reaction solution was extracted and the separated solution was washed with water, and the organic phase was subjected to column chromatography and recrystallization to obtain the intermediate 35-1 with a molar amount of 8.26 mmol and a yield of 82.6%. The atmospheric pressure solid phase analysis probe mass spectrometry (ASAP-MS) result of the intermediate 35-1 was: MS (ASAP)=1150.

### Synthesis of the Intermediate 35-2

The intermediate 35-1 (10 mmol), the intermediate 1-12 (10 mmol), Pd(dba) 2 (bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. and stirred for 6 h under nitrogen atmosphere; after the reaction solution was cooled, the solvent was removed by rotary evaporation, the reaction solution was extracted and the separated solution was washed with water, and the organic phase was subjected to column chromatography to obtain the intermediate 35-2 with a molar amount of 8.39 mmol and a yield of 83.9%. The atmospheric pressure solid phase analytical probe mass spectrometry (ASAP-MS) result of the intermediate 35-2 was: MS (ASAP)=1338.

### Synthesis of the Organic Compound M35

A 250 ml three-necked flask was added with 10 mmol of the intermediate 35-2 and 100 ml of dry tert-butylbenzene. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M35, the yield was 44.9%, and the atmospheric pressure solid phase analysis probe mass spectrometry (ASAP-MS) result of organic compound M35 was: MS (ASAP)=1312.

### Example 36

Synthesis route of the organic compound M36 is as follows:

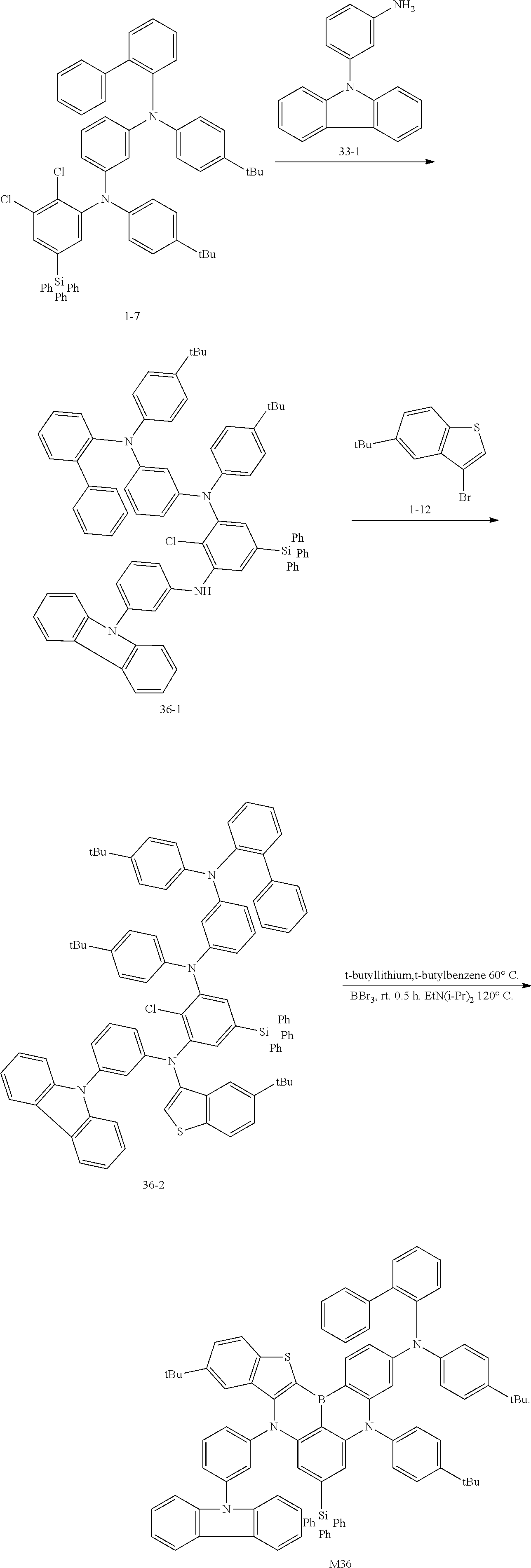

### Synthesis of the Intermediate 36-1

The intermediate 1-7 (10 mmol), Compound 33-1 (10 mmol), Pd-132 (bis(di-tert-butyl-4-dimethylaminophenylphosphine)palladium chloride, 0.1 mmol), S-Phos (2-dicyclohexylphosphine-2′,6′-dimethoxy-1,1′-biphenyl, 0.2 mmol) and sodium tert-butoxide (30 mmol) were dissolved in toluene, heated to 100° C. and stirred for 6 h under a nitrogen atmosphere; after the reaction solution was cooled, most of the solvent was removed by rotary evaporation, and then the reaction solution was extracted and the separated solution was washed with water, and the organic phase was subjected to column chromatography and recrystallization to obtain the intermediate 36-1, with a molar amount of 7.29 mmol and a yield of 72.9%. The atmospheric pressure solid phase analysis probe mass spectrometry (ASAP-MS) result of the intermediate 36-1 was: MS (ASAP)=1150.

### Synthesis of the Intermediate 36-2

The intermediate 36-1 (10 mmol), the intermediate 1-12 (10 mmol), Pd(dba)₂ (bis(dibenzylideneacetonepalladium, 0.1 mmol), TTBP (tri-tert-butylphosphine, 0.2 mmol) and sodium tert-butoxide (30 mmol) were dissolved in toluene, heated to 100° C. under nitrogen atmosphere and stirred for 6 h; after the reaction solution was cooled, the solvent was removed by rotary evaporation, the reaction solution was extracted and the separated solution was washed with water, and the organic phase was subjected to column chromatography to obtain the intermediate 36-2 with a molar amount of 8.25 mmol and a yield of 82.5%. The atmospheric pressure solid phase analytical probe mass spectrometry (ASAP-MS) result of the intermediate 36-2 was: MS (ASAP)=1338.

### Synthesis of the Organic Compound M36

10 mmol of the intermediate 36-2 and 100 ml of dry tert-butylbenzene were added to a 250 ml three-necked flask. The mixture was cooled to −30° C. in a N₂ atmosphere. A n-hexane solution of t-BuLi (tert-butyl lithium) (21 mmol) was added dropwise. The temperature was raised to 60° C. for reaction for 2 hours. The n-hexane solvent was evaporated under reduced pressure. The reaction solution was cooled to −30° C. again. Boron tribromide (21 mmol) was added. The mixture was heated to a room temperature and stirred for 0.5 hours. The reaction solution was then cooled to 0° C. 42 mmol of N,N-diisopropylethylamine was added. After the dropwise addition was completed, the mixture was heated to a room temperature and stirred. The mixture was further heated to 120° C. and stirred for 3 hours. The reaction solution was cooled to a room temperature. A sodium carbonate aqueous solution and ethyl acetate were added to quench the reaction. The aqueous phase was extracted with ethyl acetate and the organic phases were combined. The solvent was rotary-evaporated off to obtain a crude product. The product was purified by rapid silica gel column to obtain a pure product. The product was recrystallized from toluene and ethyl acetate to obtain a light yellow solid powder product, i.e., the organic compound M36, the yield was 45.1%, and the atmospheric pressure solid phase analysis probe mass spectrometry (ASAP-MS) result of the organic compound M36 was: MS (ASAP)=1312.

In view of the above, the embodiments of the present application have introduced a large group, such as an alkyl silicon based group and a dibenzofuran based group, into the phenyl amino of the boron nitrogen compound benzothiophene, or introduced a silicon-containing group, an indenocarbazol group, an indolecarbazol group, a fluorenecarbazol group, a triazine, a dicarbazolylphenyl group, a 2,6-diphenylphenyl group and a phenyl group into the para position of the boron, such that the organic compound is easily purified, thereby improving the purity of the organic compound, and further improving the luminescence efficiency and the service life of the organic light-emitting device made from the organic compound.

An embodiment of the present application further provides a mixture, which includes the organic compound described in the above embodiment and at least one organic functional material; in some embodiments, when the mixture provided by the embodiment of the present application is used in the organic light-emitting device, the organic functional material is selected from a hole injection material, a hole transport material, an electron transport material, an electron injection materials, an electron blocking material, a hole blocking material, a light-emitting material, a host material or an organic dye.

In addition, embodiments of the present application further provide a composition, which includes the organic compound described in the above embodiments and at least one organic solvent, or the composition includes the mixture described in the above embodiments and at least one organic solvent.

In some embodiments, the composition may be a solution or a suspension, and the composition may include a dispersate and a dispersant. The dispersate is one or more of the organic compounds described above and at least one organic solvent, or the dispersate is a mixture described above, and the dispersant is used to disperse the dispersate.

In the composition, a mass fraction of the organic compound as described above may be 0.3% to 30%, preferably 0.5% to 20%, more preferably 0.5% to 15%, further preferably 0.5% to 10%, most preferably 1% to 5%.

When the composition is used in a printing process, the composition may be an ink, and the viscosity and surface tension of the ink are important parameters. The surface tension parameters of the appropriate ink are suitable for a specific substrate and a specific printing method. In some embodiments, the surface tension of the ink at the working temperature or at 25° C. ranges from 19 dyne/cm to 50 dyne/cm; preferably 22 dyne/cm to 35 dyne/cm; more preferably 25 dyne/cm to 33 dyne/cm, which is beneficial to be applied in inkjet printing process. In some embodiments, the viscosity of the ink at the working temperature or at 25° C. ranges from 1 cps to 100 cps; preferably 1 cps to 50 cps; more preferably 1.5 cps to 20 cps; most preferably 4.0 cps to 20 cps, which is beneficial to be applied in inkjet printing process.

In some embodiments, the Hansen solubility parameter of the dispersant is within the following range: the δd (dispersion force) of the dispersant is within the range of 17.0 to 23.2 MPa^{1/2}, preferably within the range of 18.5 to 21.0 MPa^{1/2}; the δp (polar force) is within the range of 0.2 to 12.5 MPa^{1/2}, preferably within the range of 2.0 to 6.0 MPa^{1/2}; the δh (hydrogen bonding force) is within the range of 0.9 to 14.2 MPa^{1/2}, preferably within the range of 2.0 to 6.0 MPa^{1/2}.

In some embodiments, the boiling point of the dispersant is greater than or equal to 150° C., preferably greater than or equal to 180° C., more preferably greater than or equal to 200° C., more preferably greater than or equal to 250° C., further preferably greater than or equal to 275° C., and most preferably greater than or equal to 300° C. The boiling point of the dispersant is at least greater than or equal to 150° C., which is beneficial to preventing the nozzle of the inkjet print head from being blocked during inkjet printing, and the higher the boiling point, the more beneficial it is to preventing blockage.

The dispersant may include at least one organic solvent, which may be evaporated from the solvent system to form a film containing the functional material. The organic solvent may be selected from an aromatic or a heteroaromatic solvent. Specifically, the organic solvent may be selected from p-diisopropylbenzene, pentylbenzene, tetralin, cyclohexylbenzene, chloronaphthalene, 1,4-dimethylnaphthalene, 3-isopropylbiphenyl, p-methylisopropylbenzene, dipentylbenzene, tripentylbenzene, pentyltoluene, o-diethylbenzene, m-diethylbenzene, p-diethylbenzene, 1,2,3,4-tetramethylbenzene, 1,2,3,5-tetramethylbenzene, 1,2,4,5-tetramethylbenzene, butylbenzene, dodecylbenzene, dihexylbenzene, dibutylbenzene, p-diisopropylbenzene, cyclohexylbenzene, benzylbutylbenzene, dimethylnaphthalene, 3-isopropylbiphenyl, p-methylisopropylbenzene, 1-methylnaphthalene, 1,2,4-trichlorobenzene, 4,4-difluorodiphenylmethane, 1,2-dimethoxy-4-(1-propenyl)benzene, diphenylmethane, 2-phenylpyridine, 3-phenylpyridine, N-methyldiphenylamine, 4-isopropylbiphenyl, α,α-dichlorodiphenylmethane, 4-(3-phenylpropyl)pyridine, benzyl benzoate, 1,1-bis(3,4-dimethylphenyl)ethane, 2-isopropylnaphthalene, quinoline, isoquinoline, 2-furancarboxylic acid methyl ester, 2-furancarboxylic acid ethyl ester, etc.

The organic solvent may also be selected from an aromatic ketone solvent. Specifically, the organic solvent may be selected from 1-tetralone, 2-tetralone, 2-(phenylepoxy)tetralone, 6-(methoxy)tetralone, acetophenone, propiophenone, benzophenone and their derivatives, such as 4-methylacetophenone, 3-methylacetophenone, 2-methylacetophenone, 4-methylpropiophenone, 3-methylpropiophenone, 2-methylpropiophenone, etc.

The organic solvent may also be selected from an aromatic ether solvent. Specifically, the organic solvent may be selected from 3-phenoxytoluene, butoxybenzene, p-anisaldehyde dimethylacetal, tetrahydro-2-phenoxy-2H-pyran, 1,2-dimethoxy-4-(1-allyl)benzene, 1,4-benzodioxane, 1,3-dipropylbenzene, 2,5-dimethoxytoluene, 4-ethylphenethyl ether, 1,3-dipropoxybenzene, 1,2,4-trimethoxybenzene, 4-(1-propenyl)-1,2-dimethoxybenzene, 1,3-dimethoxybenzene, glycidyl phenyl ether, dibenzyl ether, 4-tert-butyl anisole, trans-p-propenyl anisole, 1,2-dimethoxybenzene, 1-methoxynaphthalene, diphenyl ether, 2-phenoxymethyl ether, 2-phenoxytetrahydrofuran, ethyl-2-naphthyl ether, etc.

The organic solvent may also be selected from an aliphatic ketone, such as 2-nonanone, 3-nonanone, 5-nonanone, 2-decanone, 2,5-hexanedione, 2,6,8-trimethyl-4-nonanone, fenchone, phorone, isophorone, di-n-amyl ketone, etc.; or an aliphatic ether, such as amyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, tetraethylene glycol dimethyl ether, etc.

The organic solvent may also be selected from an organic ester solvent. Specifically, the organic solvent may be selected from alkyl octanoate, alkyl sebacate, alkyl stearate, alkyl benzoate, alkyl phenylacetate, alkyl cinnamate, alkyl oxalate, alkyl maleate, alkyl lactone, alkyl oleate, etc. Octyl octanoate, diethyl sebacate, diallyl phthalate, isononyl isononanoate, etc. are particularly preferred.

The organic solvent may also be selected from one or more of methanol, ethanol, 2-methoxyethanol, dichloromethane, chloroform, chlorobenzene, o-dichlorobenzene, tetrahydrofuran, anisole, morpholine, toluene, o-xylene, m-xylene, p-xylene, 1,4-dioxane, acetone, methyl ethyl ketone, 1,2-dichloroethane, 3-phenoxytoluene, 1,1,1-trichloroethane, 1,1,2,2-tetrachloroethane, ethyl acetate, butyl acetate, dimethylformamide, dimethylacetamide, dimethyl sulfoxide, tetralin, decalin, indene and the like.

In addition to the dispersate and the dispersant, the composition may also include one or more components such as a surfactant compound, a lubricant, a wetting agent, a hydrophobic agent, an adhesive, etc., for adjusting viscosity, film-forming property, improving adhesion, etc.

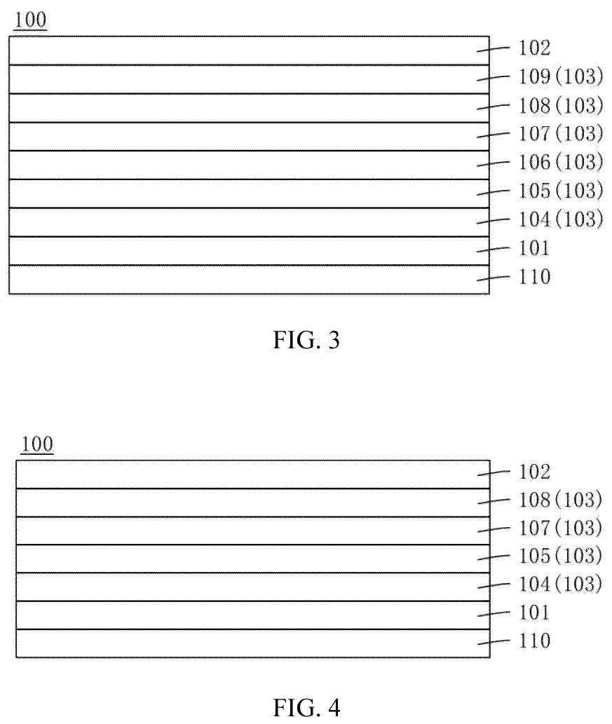

In addition, referring to FIG. 3, an embodiment of the present application further provides an organic light-emitting device 100, which includes: a first electrode 101 and a second electrode 102; an organic functional layer 103 located between the first electrode 101 and the second electrode 102; in which the material of the organic functional layer 103 includes one or more of the organic compounds described in the above embodiments, or the material of the organic functional layer 103 includes the mixture described in the above embodiments, or the material of the organic functional layer 103 includes the composition described in the above embodiments.

In some embodiments, the first electrode 101 may be an anode, and the second electrode 102 may be a cathode.

In some embodiments, the organic light-emitting device 100 can be used for an organic light-emitting diode, an organic photovoltaic cell, an organic light-emitting cell, an organic field effect transistor, an organic light-emitting field effect transistor, an organic laser, an organic spin electronic device, an organic sensor, and an organic plasmon emission diode, etc., preferably an organic light-emitting diode, an organic light-emitting cell, and an organic light-emitting field effect transistor.

In some embodiments, the organic light-emitting device 100 may be applied to a variety of electronic devices, such as a display panel, a lighting device, a light source, etc.

In some embodiments, the organic functional layer 103 may be a single layer. In this case, the organic functional layer 103 is a mixture layer, and the mixture layer includes a first compound and a second compound. The first compound is selected from one or more of the organic compounds described above, and the second compound is selected from one or more of the hole injection material, the hole transport material, the electron transport material, the hole blocking material, the luminescent guest material, the luminescent host material, and the organic dye. Detailed description of various organic functional materials included in the organic functional layer 103 are detailed in WO2010135519A1, US20090134784A1, and WO 2011110277A1, the entire contents of which are hereby incorporated herein by reference.

The luminescent guest material is selected from a singlet luminescent body (fluorescent luminescent body), a triplet luminescent body (phosphorescent luminescent body) and a TADF material.

When the second compound is selected from one or more of the hole injection material, the hole transport material, the electron transport material, the hole blocking material, the luminescent host material, and the organic dye, the mass ratio of the first compound to the second compound ranges from 1:99 to 30:70, preferably ranges 1:99 to 10:90.

When the second compound is a light-emitting guest material, the mass ratio of the first compound to the second compound ranges from 99:1 to 70:30, preferably ranges from 99:1 to 90:10.

In some embodiments, the organic functional layer 103 may include multiple layers. When the organic functional layer 103 is multiple layers, the organic functional layer 103 at least includes a light-emitting layer 107; preferably, the organic functional layer 103 includes a hole injection layer 104, a hole transport layer 105, an electron blocking layer 106, a light-emitting layer 107, an electron injection layer 109, and an electron transport layer 108; in other embodiments of the present application, the organic functional layer 103 may also include a hole blocking layer disposed between the light-emitting layer 107 and the electron transport layer 108.

In some embodiments, the organic light-emitting device 100 may be a blue organic light-emitting device, a green organic light-emitting device or a red organic light-emitting device, and the light-emitting layer 107 may include a host material and a guest material, the guest material is one or more of the organic compounds described above, and the host material includes a condensed aromatic derivative or a heteroaromatic compound.

The light-emitting wavelength of the organic light-emitting device 100 is between 300 nm and 1000 nm; further, the light-emitting wavelength of the organic light-emitting device 100 is between 350 nm and 900 nm; further, the light-emitting wavelength of the organic light-emitting device 100 is between 400 nm and 800 nm; further, the light-emitting wavelength of the organic light-emitting device 100 is within the wavelength range of blue light.

In some embodiments, the host material includes at least one of anthracene derivatives, pyrene derivatives, naphthalene derivatives, pentacene derivatives, phenanthrene compounds, fluoranthene compounds, carbazole derivatives, dibenzofuran derivatives, ladder-type furan compounds, and pyrimidine derivatives. Preferably, the host material is a blue light host material used in a blue organic light-emitting device; when the host material is the blue light host material, the host material is preferably an anthracene organic compound.

In some embodiments, the mass ratio of the host material to the guest material ranges from 99:1 to 70:30, such as 90:10, 85:15, 80:20, 75:25, etc.; preferably ranges from 99:1 to 90:10, such as 97:3, 96:4, 95:5, 93:7, 92:8, etc. The guest material is dispersed in the host material, and the mass ratio of the host material to the guest material is 99:1 to 70:30, which is conducive to inhibiting the crystallization of the light-emitting layer 107 and inhibiting the concentration quenching of the guest material caused due to high concentration, thereby improving the luminescence efficiency of the organic light-emitting device 100.

In some embodiments, the anode is an electrode for injecting holes, and the anode can inject holes into the organic functional layer 103, for example: the anode injects holes into the hole injection layer, the hole transport layer or the light-emitting layer. The anode may include at least one of a conductive metal, a conductive metal oxide, or a conductive polymer. Preferably, the absolute value of the difference between the work function of the anode and the HOMO (Highest Occupied Molecular Orbital) energy level or valence band energy level of the p-type semiconductor material as the hole injection layer, or the HOMO (Highest Occupied Molecular Orbital) energy level or valence band energy level of the p-type semiconductor material in the hole injection layer and the hole transport layer or the electron blocking layer is less than 0.5 eV, preferably less than 0.3 eV, and more preferably less than 0.2 eV. The material of the anode includes but is not limited to: at least one of Al, Cu, Au, Ag, Mg, Fe, Co, Ni, Mn, Pd, Pt, ITO (Indium Tin Oxide), aluminum-doped zinc oxide (AZO), etc., or other suitable and known anode materials, which can be easily selected and used by one ordinary skilled in the art. The material of the anode may be deposited using any suitable technology, such as a suitable physical vapor deposition method, including radio frequency magnetron sputtering, vacuum thermal evaporation, electron beam (e-beam), etc. In some embodiments, the anode may be patterned and structured, such as: patterned ITO conductive substrates are available on the market and can be used to prepare the organic light-emitting device 100 of the present application.

In some embodiments, the cathode is an electrode for injecting electrons, and the cathode can inject electrons into the organic functional layer, for example: the cathode injects electrons into the electron injection layer, the electron transport layer, or the light-emitting layer. The cathode may include at least one of a conductive metal or a conductive metal oxide. Preferably, the absolute value of the difference between the work function of the cathode and the LUMO (Lowest Unoccupied Molecular Orbital) energy level or conduction band energy level of an n-type semiconductor material as an electron injection layer, or the LUMO (Lowest Unoccupied Molecular Orbital) energy level or conduction band energy level of an n-type semiconductor material of an electron injection layer and an electron transport layer or a hole blocking layer are less than 0.5 eV, preferably less than 0.3 eV, and more preferably less than 0.2 eV. All materials that may be used as the cathode of the organic electronic device may be used as the cathode materials of the device of the present application, and the cathode materials include but are not limited to at least one of Al, Au, Ag, Ca, Ba, Mg, LiF/Al, MgAg alloy, BaF₂/Al, Cu, Fe, Co, Ni, Mn, Pd, Pt, ITO, etc. The cathode material may be deposited using any suitable technique, such as a suitable physical vapor deposition method, including radio frequency magnetron sputtering, vacuum thermal evaporation, electron beam (e-beam), etc.

In some embodiments, the hole injection layer 104 is used to promote the injection of holes from the anode to the light-emitting layer 107, and the hole injection layer 104 includes a hole injection material, which is a material that can receive holes injected from the positive electrode at a low voltage, and preferably, the highest occupied molecular orbital (HOMO) of the hole injection material is between the work function of the material of the anode and the HOMO of the functional material of the film layer (such as the hole transport material of the hole transport layer) into which the holes are injected away from the anode. The hole injection material includes but is not limited to: at least one of metal porphyrin, oligothiophene, an organic material based on arylamine, an organic material based on hexanitrile hexaazabenzophenanthrene, an organic material based on quinacridone, an organic material based on perylene, anthraquinone, a conductive polymer based on polyaniline and polythiophene, etc.

In some embodiments, the hole transport layer 105 can be used to transport holes to the light-emitting layer 107, and the hole transport layer 105 includes a hole transport material, and the hole transport material receives holes transmitted from the anode or the hole injection layer and transfers the holes to the light-emitting layer. The hole transport material is a material with high hole mobility known in the art, and the hole transport material may include but is not limited to at least one of an organic material based on arylamine, a conductive polymer, a block copolymer having both a conjugated part and a non-conjugated part, and the like.

In some embodiments, the electron transport layer 108 is used to transport electrons, and the electron transport layer 108 includes an electron transport material, which receives electrons injected from the negative electrode and transfers the electrons to the light-emitting layer 107. The electron transport material is a material with high electron mobility known in the art, and the electron transport material may include but is not limited to: at least one of an A1 complex of 8-hydroxyquinoline, a complex containing Alq3, an organic free radical compound, a hydroxyflavone-metal complex, 8-hydroxyquinoline lithium (LiQ), and a benzimidazole-based compound.

In some embodiments, the electron injection layer 109 is used to inject electrons, and the electron injection layer 109 includes an electron injection material, and the electron injection material preferably has the ability to transport electrons, has the effect of injecting electrons from the negative electrode, has an excellent effect of injecting electrons into the light-emitting layer 107 or the light-emitting material, and has the ability to prevent the excitons generated by the light-emitting layer 107 from moving to the hole injection layer, and also has an excellent ability to form a thin film. The electron injection material includes, but is not limited to, at least one of 8-hydroxyquinoline lithium (LiQ), fluorenone, anthraquinone dimethane, diphenoquinone, thiopyran dioxide, pyrazole, diazole, triazole, imidazole, perylene tetracarboxylic acid, fluorenyl methane, anthrone, etc. and their derivatives, metal complex compounds, nitrogen-containing 5-membered ring derivatives, etc.

In some embodiments, the hole blocking layer is used to block holes from reaching the negative electrode, and may generally be formed under the same conditions as the hole injection layer 104. The hole blocking layer includes a hole blocking material, which includes but is not limited to at least one of diazole derivatives or triazole derivatives, phenanthroline derivatives, BCP, aluminum complexes, and the like.

In some embodiments, the organic light-emitting device 100 further includes a substrate 110, and the first electrode 101, the hole injection layer 104, the hole transport layer 105, the electron blocking layer 106, the light-emitting layer 107, the electron transport layer 108, the electron injection layer 109, and the second electrode 102 are sequentially stacked on the substrate 110. The substrate 110 may be a transparent substrate or an opaque substrate. When the substrate 110 is a transparent substrate, a transparent organic light-emitting device 100 may be manufactured; the substrate 110 may be a rigid substrate or a flexible substrate with elasticity, and the material of the substrate 110 may include but is not limited to plastic, polymer, metal, semiconductor wafer or glass. Preferably, the substrate 110 includes at least one smooth surface for forming the anode on the surface. More preferably, the surface has no surface defects. Preferably, the material of the substrate 110 is a polymer film or plastic, including but not limited to polyethylene terephthalate (PET material) and polyethylene glycol (2,6-naphthalene) (PEN material), and the glass transition temperature of the substrate 110 is greater than or equal to 150° C., preferably greater than or equal to 200° C., more preferably greater than or equal to 250° C., and most preferably greater than or equal to 300° C.

In some embodiments, the organic light-emitting device 100 may be a solution-type organic light-emitting device, that is, at least one of the organic functional layers is prepared by printing (e.g., inkjet printing).

In some embodiments, the mixture layer or the light-emitting layer may be formed by a printing or coating process of the composition. The printing or coating process includes inkjet printing, nozzle printing, letterpress printing, screen printing, dip coating, spin coating, blade coating, roller printing, twist roller printing, lithography, flexographic printing, rotary printing, spraying, brushing or pad printing, slit extrusion coating, etc. Preferably, the printing or coating process is gravure printing, nozzle printing and inkjet printing.

Furthermore, the examples of the present application calculate the HOMO energy level, LUMO energy level, S1 energy level and T1 energy level of the organic compounds shown in the above-mentioned Examples 1 to Examples 36 and the Comparative Compound 1 in Comparative Example 1 to verify the performance of the organic compounds provided by the examples of the present application.

The structural formula of Comparative Compound 1 is:

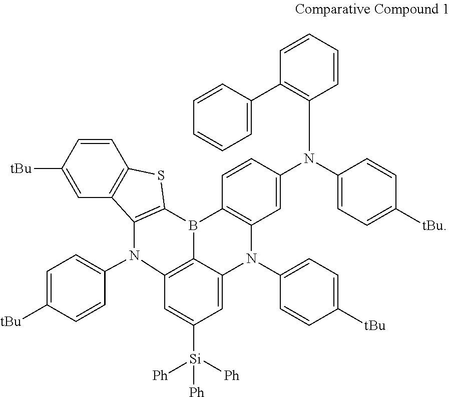 [SMILES: CC(C)(C)c1ccc(N(c2ccc3c(c2)N(c2ccc(C(C)(C)C)cc2)c2cc([Si](c4ccccc4)(c4ccccc4)c4ccccc4)cc4c2B3c2sc3ccc(C(C)(C)C)cc3c2N4c2ccc(C(C)(C)C)cc2)c2ccccc2-c2ccccc2)cc1]

As shown in Table 1 below, the HOMO (Highest Occupied Molecular Orbital) energy level, LUMO (Lowest Unoccupied Molecular Orbital) energy level, T1 (first excited triplet state) energy level, and S1 (first excited singlet state) energy level of Compounds M1 to M36 obtained in Examples 1 to 36 and the Comparative Compound 1 in Comparative Example 1 can be obtained through quantum calculation. Specifically, TD-DFT (time-dependent density functional theory) is used through Gaussian09W (Gaussian Inc.). The specific simulation method may be found in WO2011141110. First, the molecular geometry is optimized using the semi-empirical method “Ground State/Semi-empirical/Default Spin/AMP” (Charge 0/Spin Singlet). Then, the energy structure of the organic molecule is calculated by TD-DFT (time-dependent density functional theory) and “TD-SCF/DFT/Default Spin/B3PW91” with the basis set “6-31G (d)” (Charge 0/Spin Singlet). The HOMO energy level and the LUMO energy level are calculated according to the following calibration formula, and the S1 energy level and the T1 energy level are used directly.

HOMO(eV)=((HOMO(G)×27.212)−0.9899)/1.1206.

LUMO(eV)=((LUMO(G)×27.212)−2.0041)/1.385.

HOMO, LUMO, T1 and S1 are the direct calculation results of Gaussian 09W, and the unit thereof is Hartree.

TABLE 1
Calculation results of HOMO energy levels of the organic compounds

| | Compounds | HOMO[eV] | LUMO [eV] | T1[eV] | S1[eV] |
|---|---|---|---|---|---|
| Example 1 | Organic compound M1 | −5.03 | −2.43 | 2.31 | 3.01 |
| Example 2 | Organic compound M2 | −5.01 | −2.43 | 2.34 | 2.95 |
| Example 3 | Organic compound M3 | −5.04 | −2.41 | 2.34 | 2.99 |
| Example 4 | Organic Compound M4 | −4.99 | −2.46 | 2.34 | 3.08 |
| Example 5 | Organic Compound M5 | −5.08 | −2.41 | 2.38 | 3.01 |
| Example 6 | Organic Compound M6 | −5.02 | −2.48 | 2.39 | 3.09 |
| Example 7 | Organic Compound M7 | −5.03 | −2.41 | 2.38 | 3.06 |
| Example 8 | Organic Compound M8 | −4.98 | −2.39 | 2.35 | 3.01 |
| Example 9 | Organic Compound M9 | −4.91 | −2.42 | 2.35 | 2.96 |
| Example 10 | Organic Compound M10 | −5.02 | −2.42 | 2.35 | 3.06 |
| Embodiment | Organic Compound M11 | −5.07 | −2.41 | 2.31 | 3.08 |
| 11 | | | | | |
| Example 12 | Organic Compound M12 | −5.03 | −2.47 | 2.31 | 3.01 |
| Example 13 | Organic Compound M13 | −5.05 | −2.45 | 2.37 | 3.03 |
| Embodiment | Organic Compound M14 | −4.98 | −2.39 | 2.31 | 2.99 |
| 14 | | | | | |
| Embodiment | Organic Compound M15 | −4.87 | −2.39 | 2.35 | 2.95 |
| 15 | | | | | |
| Example 16 | Organic Compound M16 | −4.97 | −2.41 | 2.38 | 2.91 |
| Embodiment | Organic Compound M17 | −4.94 | −2.41 | 2.31 | 3.06 |
| 17 | | | | | |
| Embodiment | Organic Compound M18 | −4.93 | −2.46 | 2.35 | 3.08 |
| 18 | | | | | |
| Embodiment | Organic Compound M19 | −5.05 | −2.41 | 2.32 | 3.03 |
| 19 | | | | | |
| Embodiment | Organic Compound M20 | −4.96 | −2.42 | 2.33 | 3.01 |
| 20 | | | | | |
| Embodiment | Organic Compound M21 | −5.01 | −2.43 | 2.33 | 3.06 |
| 21 | | | | | |
| Embodiment | Organic Compound M22 | −4.98 | −2.45 | 2.36 | 3.03 |
| 22 | | | | | |
| Embodiment | Organic Compound M23 | −5.00 | −2.47 | 2.35 | 3.07 |
| 23 | | | | | |
| Embodiment | Organic Compound M24 | −5.03 | −2.41 | 2.31 | 3.01 |
| 24 | | | | | |
| Embodiment | Organic Compound M25 | −4.91 | −2.41 | 2.38 | 3.01 |
| 25 | | | | | |
| Embodiment | Organic Compound M26 | −5.03 | −2.49 | 2.38 | 3.08 |
| 26 | | | | | |
| Embodiment | Organic Compound M27 | −5.03 | −2.51 | 2.32 | 2.99 |
| 27 | | | | | |
| Embodiment | Organic Compound M28 | −5.02 | −2.43 | 2.33 | 3.06 |
| 28 | | | | | |
| Embodiment | Organic Compound M29 | −5.01 | −2.41 | 2.35 | 3.09 |
| 29 | | | | | |
| Example 30 | Organic Compound M30 | −5.04 | −2.48 | 2.37 | 3.11 |
| Example 31 | Organic Compound M31 | −5.03 | −2.43 | 2.36 | 3.01 |
| Example 32 | Organic Compound M32 | −5.02 | −2.41 | 2.39 | 3.01 |
| Example 33 | Organic Compound M33 | −5.01 | −2.39 | 2.37 | 3.03 |
| Example 34 | Organic Compound M34 | −5.01 | −2.41 | 2.35 | 3.05 |
| Example 35 | Organic Compound M35 | −5.03 | −2.37 | 2.36 | 3.0 |
| Example 36 | Organic Compound M36 | −5.03 | −2.42 | 2.36 | 3.04 |
| Comparative | Comparative Compound | −5.13 | −2.30 | 2.41 | 2.85 |
| Example 1 | 1 | | | | |

From the results in Table 1, it can be seen that both the T1 energy level and S1 energy level of the organic compounds M1 to M36 provided in Examples 1 to 36 of the present application are higher than the T1 energy level and S1 energy level of the Comparative Compound 1, which further indicates that compared with the Comparative Compound 1, the blue light emitted by the organic compounds M1 to M36 provided in the examples of the present application is more inclined to dark blue, which is conducive to obtaining better color coordinates for the blue organic light-emitting device using the organic compounds M1 to M36 as the guest material in the light-emitting layer.

Further, referring to FIG. 4, an embodiment of the present application provides exemplary preparation steps of the organic light-emitting device 100 as shown in FIG. 4, as shown in the following exemplary Embodiment 1.

### Embodiment 1

In the organic light-emitting device provided in the present embodiment, ITO (indium tin oxide) is used as the anode 101, PEDOT (polyethylene dioxythiophene, Clevios™ A14083) is used as the material of the hole injection layer 104, and PVK (poly (9-vinyl carbazole, Sigma Aldrich, average Mn 25,000-50,000) is used as the material of the hole transport layer 105, BH-1 to BH-3 (whose structural formula are shown below) are respectively used as the host material in the light-emitting layer 107 of the corresponding organic light-emitting device, the organic compounds M1 to M36 in Embodiments 1 to 40 and the Comparative Compound 1 in Comparative Example 1 are respectively used as the guest material in the light-emitting layer 107 of the corresponding organic light-emitting device, ET and Liq (8-hydroxyquinoline lithium) are used as the materials of the electron transport layer 108, and A1 is used as the cathode 102. The specific preparation steps are as follows:
a. Cleaning of ITO anode 101: Using chloroform, acetone and/or isopropyl alcohol to clean the ITO conductive glass, and then performing UV ozone treatment;
b. Forming a hole injection layer 104: Spin-coating a hole injection layer material PEDOT (polyethylene dioxythiophene, Clevios™ A14083) on the ITO anode 101 and treating it on a hot plate at 180° C. for 10 minutes. The thickness of the hole injection layer 104 is 40 nm.
c. Forming a hole transport layer 105: Spin-coating a toluene solution of PVK (Sigma Aldrich, Mn 25,000-50,000) with a concentration of 5 mg/ml on the hole injection layer 104, and then treating the same on a hot plate at 180° C. for 60 minutes. The thickness of the hole transport layer 105 is 20 nm.
d. Forming the light-emitting layer 107: In a nitrogen glove box, spin-coating the light-emitting layer 107 material on the hole transport layer 105, and then treating it on a hot plate at 140° C. for 10 minutes. The host material in the light-emitting layer 107 of the different organic light-emitting devices corresponds to BH-1, BH-2 or BH-3, respectively. The guest material in the light-emitting layer 107 of the different organic light-emitting devices corresponds to one of organic compounds M1 to organic compounds M36, respectively. The solvent is methyl benzoate solution. The mass ratio of the host material to the guest material is 95:5. The concentration of the material of the light-emitting layer 107 is 15 mg/ml. The thickness of the light-emitting layer 107 finally formed is 40 nm.
e. Forming an electron transport layer 108: In a vacuum chamber, placing ET and Liq in different evaporation units, and co-depositing ET and Liq at a weight ratio of 50:50 under a high vacuum (1×10⁻⁶ mbar) environment on the light-emitting layer 107 to form an electron transport layer 108 with a thickness of 20 nm;
f. Forming a cathode layer 102: depositing A1 on the electron transport layer 108 to obtain an A1 cathode 102 with a thickness of 100 nm;
g. Packaging: packaging the device with UV-curable resin in a nitrogen glove box.

Specifically, in the present embodiments, the above steps are used to obtain the organic light-emitting devices 1 to 40 and comparative elements 1 to 3. The guest materials used in the organic light-emitting devices 1 to 36 are the organic compounds M1 to M36, respectively, and the host materials used in the organic light-emitting devices 1 to 36 are BH-1; the guest materials used in the organic light-emitting devices 37 and 39 are the organic compounds M1, and the host materials used in the organic light-emitting devices 37 and 39 are BH-2 and BH-3, respectively; the guest materials used in the organic light-emitting devices 38 and 40 are the organic compound M18, and the host materials used in the organic light-emitting devices 38 and 40 are BH-2 and BH-3, respectively; the guest materials used in the comparative elements 1 to 3 are comparative compounds 1, and the host materials used in the comparative elements 1 to 3 are BH-1, BH-2 and BH-3, respectively.

Specifically, the chemical structural formulas of BH-1, BH-2, BH-3, E1 and Liq are as follows:

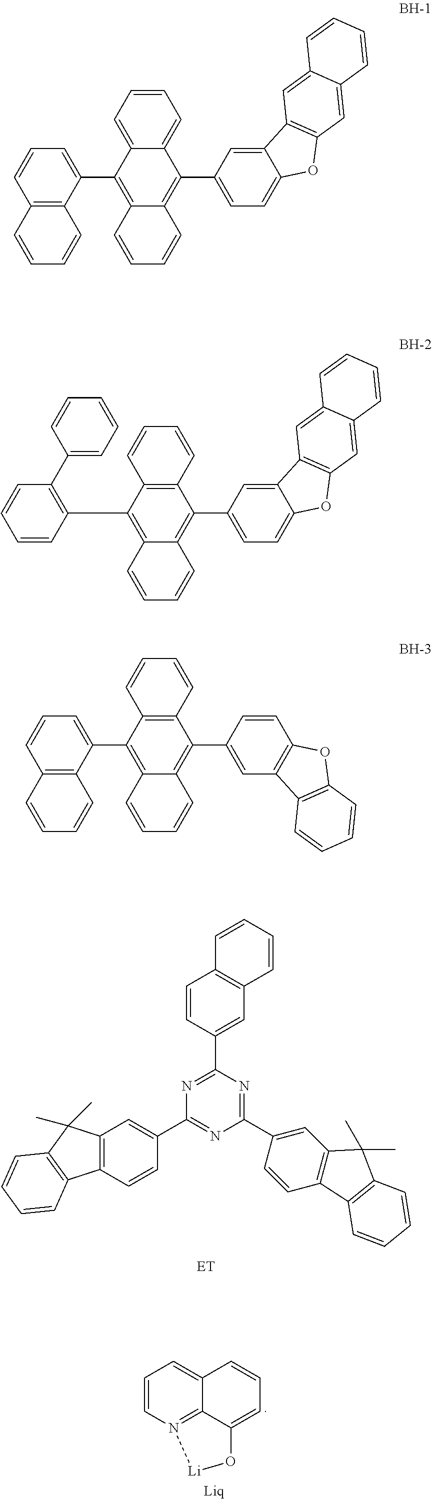

In the present embodiment, the organic light-emitting devices 1 to 40 and the comparative elements 1 to 3 were tested for current-voltage (JV) characteristics, and for each of the organic light⁻emitting devices and the comparative elements, the CIE color coordinates (x, y), the driving voltage at 1 knits brightness (voltage@1 knits[V]), the luminescence efficiency obtained when the current density was 10 mA/cm² (CE@1 knits[cd/A]), and the time taken for the brightness to decrease from the initial brightness of 1 knits to 90% of the initial brightness (LT90@1 knits[h]) were obtained. The specific results are shown in Table 2.

TABLE 2
Performance data of the organic light-emitting devices

| | Guest | Host | CIE(x, y) | V@1knits[V] | CE@1knits[cd/A] | LT90@1knits[h] |
|---|---|---|---|---|---|---|
| Embodiment 1 | Organic | BH-1 | 0.143, 0.083 | 5.5 | 6.5 | 179 |
| | compound M1 | | | | | |
| Embodiment 2 | Organic | BH-1 | 0.141, 0.081 | 5.5 | 6.3 | 180 |
| | Compound M2 | | | | | |
| Embodiment 3 | Organic | BH-1 | 0.143, 0.081 | 5.5 | 6.1 | 173 |
| | Compound M3 | | | | | |
| Embodiment 4 | Organic | BH-1 | 0.143, 0.081 | 5.5 | 5.9 | 162 |
| | Compound M4 | | | | | |
| Embodiment 5 | Organic | BH-1 | 0.144, 0.081 | 5.5 | 5.9 | 159 |
| | Compound M5 | | | | | |
| Embodiment 6 | Organic | BH-1 | 0.141, 0.081 | 5.5 | 5.7 | 153 |
| | Compound M6 | | | | | |
| Embodiment 7 | Organic | BH-1 | 0.141, 0.081 | 5.5 | 5.8 | 151 |
| | Compound M7 | | | | | |
| Embodiment 8 | Organic | BH-1 | 0.141, 0.088 | 5.5 | 5.6 | 159 |
| | Compound M8 | | | | | |
| Embodiment 9 | Organic | BH-1 | 0.143, 0.081 | 5.5 | 5.9 | 149 |
| | Compound M9 | | | | | |
| Embodiment 10 | Organic | BH-1 | 0.141, 0.083 | 5.5 | 5.9 | 152 |
| | Compound M10 | | | | | |
| Embodiment 11 | Organic | BH-1 | 0.141, 0.083 | 5.5 | 5.8 | 151 |
| | Compound M11 | | | | | |
| Embodiment 12 | Organic | BH-1 | 0.141, 0.081 | 5.5 | 5.8 | 150 |
| | Compound M12 | | | | | |
| Embodiment 13 | Organic | BH-1 | 0.143, 0.081 | 5.5 | 5.9 | 162 |
| | Compound M13 | | | | | |
| Embodiment 14 | Organic | BH-1 | 0.142, 0.081 | 5.7 | 5.9 | 151 |
| | Compound M14 | | | | | |
| Embodiment 15 | Organic | BH-1 | 0.143, 0.081 | 5.5 | 5.6 | 151 |
| | Compound M15 | | | | | |
| Embodiment 16 | Organic | BH-1 | 0.141, 0.083 | 5.5 | 5.8 | 150 |
| | Compound M16 | | | | | |
| Embodiment 17 | Organic | BH-1 | 0.141, 0.083 | 5.6 | 5.9 | 158 |
| | Compound M17 | | | | | |
| Embodiment 18 | Organic | BH-1 | 0.141, 0.081 | 5.6 | 6.5 | 179 |
| | Compound M18 | | | | | |
| Embodiment 19 | Organic | BH-1 | 0.141, 0.081 | 5.5 | 6.4 | 177 |
| | Compound M19 | | | | | |
| Embodiment 20 | Organic | BH-1 | 0.141, 0.083 | 5.5 | 5.7 | 153 |
| | Compound M20 | | | | | |
| Embodiment 21 | Organic | BH-1 | 0.141, 0.083 | 5.5 | 5.9 | 151 |
| | Compound M21 | | | | | |
| Embodiment 22 | Organic | BH-1 | 0.141, 0.081 | 5.5 | 6.4 | 171 |
| | Compound M22 | | | | | |
| Embodiment 23 | Organic | BH-1 | 0.141, 0.081 | 5.5 | 6.2 | 173 |
| | Compound M23 | | | | | |
| Embodiment 24 | Organic | BH-1 | 0.141, 0.083 | 5.5 | 6.1 | 174 |
| | Compound M24 | | | | | |
| Embodiment 25 | Organic | BH-1 | 0.141, 0.083 | 5.5 | 6.1 | 177 |
| | Compound M25 | | | | | |
| Embodiment 26 | Organic | BH-1 | 0.141, 0.083 | 5.5 | 6.2 | 179 |
| | Compound M26 | | | | | |
| Embodiment 27 | Organic | BH-1 | 0.141, 0.083 | 5.5 | 6.3 | 175 |
| | Compound M27 | | | | | |
| Embodiment 28 | Organic | BH-1 | 0.141, 0.081 | 5.5 | 6.1 | 175 |
| | Compound M28 | | | | | |
| Embodiment 29 | Organic | BH-1 | 0.141, 0.081 | 5.5 | 6.1 | 178 |
| | Compound M29 | | | | | |
| Embodiment 30 | Organic | BH-1 | 0.141, 0.083 | 5.5 | 6.2 | 171 |
| | Compound M30 | | | | | |
| Embodiment 31 | Organic | BH-1 | 0.141, 0.083 | 5.5 | 6.1 | 175 |
| | Compound M31 | | | | | |
| Embodiment 32 | Organic | BH-1 | 0.141, 0.081 | 5.5 | 6.2 | 172 |
| | Compound M32 | | | | | |
| Embodiment 33 | Organic | BH-1 | 0.141, 0.081 | 5.5 | 6.3 | 171 |
| | Compound M33 | | | | | |
| Embodiment 34 | Organic | BH-1 | 0.141, 0.082 | 5.5 | 6.3 | 176 |
| | Compound M34 | | | | | |
| Embodiment 35 | Organic | BH-1 | 0.141, 0.083 | 5.5 | 6.4 | 175 |
| | Compound M35 | | | | | |
| Embodiment 36 | Organic | BH-1 | 0.141, 0.081 | 5.5 | 6.3 | 173 |
| | Compound M36 | | | | | |
| Embodiment 37 | Organic | BH-2 | 0.142, 0.108 | 5.5 | 5.3 | 141 |
| | compound M1 | | | | | |
| Embodiment 38 | Organic | BH-2 | 0.143, 0.123 | 5.5 | 5.5 | 132 |
| | Compound M18 | | | | | |
| Embodiment 39 | Organic | BH-3 | 0.143, 0.113 | 5.5 | 5.2 | 130 |
| | compound M1 | | | | | |
| Embodiment 40 | Organic | BH-3 | 0.141, 0.11 | 5.5 | 5.6 | 129 |
| | Compound | | | | | |
| Comparative | Comparative | BH-1 | 0.159, 0.136 | 6.5 | 2.1 | 93 |
| Element 1 | Compound 1 | | | | | |
| Comparative | Comparative | BH-2 | 0.153, 0139 | 6.0 | 2.3 | 81 |
| Element 2 | Compound 1 | | | | | |
| Comparative | Comparative | BH-3 | 0.152, 0160 | 6.1 | 2.7 | 82 |
| Element 3 | Compound 1 | | | | | |

The organic light-emitting devices 1 to 40 obtained by using the guest materials M1 to M36 in the light-emitting layer of the present application have better color coordinates than those of Comparative Elements 1 to 3; further, the luminescence efficiency of the organic light-emitting devices 1 to 40 is 5.7˜6.6 cd/A, indicating that the luminescence efficiency is much higher than that of Comparative Elements 1 to 3; further, the time taken for the brightness of the organic light-emitting devices 1 to 40 to decrease from the initial brightness of 1 knits to 90% of the initial brightness is in the range of 129-178 h, which is 50% to 100% larger than the time taken for the brightness of Comparative Elements 1 to 3 to decrease from the initial brightness of 1 knits to 90% of the initial brightness, indicating that the organic light-emitting devices 1 to 40 have significantly improved lifetime.

Meanwhile, compared with Comparative Example 1, the organic compounds M1 to M36 have introduced large groups (alkyl silicon based groups, dibenzofuran based groups) into the phenyl amino of the boron nitrogen compound benzothiophene or have introduced triphenylsilicon, indenocarbazole, indolecarbazole groups, fluorenecarbazole, triazine, dicarbazolylphenyl, and 2,6-diphenylphenyl into the para position of boron, so that the overall molecular solubility is improved and the compound is easily purified, thereby improving the purity of the compound and further improving the efficiency and lifetime of the prepared organic light-emitting devices.

In addition, the luminescence efficiency of the organic light-emitting devices 1, 2, 3,18, 19, 22, and 23-36 are all in the range of 6.1˜6.5 cd/A, and the lifetime is about 170 h. This is because compared with the guest materials in other organic light-emitting devices, the solubility and hole conduction ability of the guest material are improved, and the luminescence efficiency and lifetime of the organic light-emitting device are further improved since the introduced large groups in the phenyl amino of the boron nitrogen compound benzothiophene are triphenylsilyl group or indenocarbazole group, ortho-dibenzofuran based group, phenylcarbazole group, or triphenylamine group; or triphenylsilyl, indenocarbazolyl, the indolecarbazole group, fluorenecarbazolyl, the triazine group, dicarbazolylphenyl, 2,6-diphenylphenyl, or phenyl have been introduced at the para position of boron.

The organic light-emitting device disclosed in the embodiments of the present application have improved material properties, improved the luminescence efficiency of the organic light-emitting devices and prolonged the service life of the organic light-emitting devices by using boron nitrogen compounds and introducing biphenyl+benzothiophene aromatic amines and silicon-containing groups to make the overall conjugation of the compound greater, or introducing triphenylsilicon, indenocarbazole, the indolecarbazole group, fluorenecarbazole, the triazine group, dicarbazolylphenyl, 2,6-diphenylphenyl, or phenyl at the para position of boron.

The embodiment of the present application further discloses a display panel, which includes the organic light-emitting device described in the above embodiment.

In some embodiments, the display panel further includes an array substrate located at a side of the organic light-emitting device, and an encapsulation layer located at a side of the organic light-emitting device away from the array substrate and covering the organic light-emitting device. The display panel further includes a polarizer layer located at a side of the encapsulation layer away from the organic light-emitting device, and a cover layer located at a side of the polarizer layer away from the organic light-emitting device.

In some embodiments, the polarizer layer may be replaced by a color filter layer, and the color filter layer may include a plurality of color resists and a black matrix located at both sides of the color resists.

The display panel disclosed in the embodiment of the present application has used an organic light-emitting device containing the boron nitrogen compound, and introduced a silicon-containing group into the boron nitrogen compound to make the overall conjugation of the compound greater, thereby enhancing the conjugation effect of the material used in the organic light-emitting device, improving the material performance, improving the luminescence efficiency of the display panel and extending the service life of the display panel.

In the above embodiments, the description of each embodiment has its own emphasis. For parts that are not described in detail in a certain embodiment, reference can be made to the relevant descriptions of other embodiments.

The above is a detailed description of the organic compound, the mixture, the composition, the organic light-emitting device and the display panel provided in the embodiments of the present application. Specific examples are used herein to illustrate the principles and embodiments of the present application. The description of the above embodiments is only used to help understand the technical solution and its core idea of the present application. An ordinary skilled in the art should understand that they can still modify the technical solutions recorded in the aforementioned embodiments, or make equivalent replacements for some of the technical features therein; and these modifications or replacements do not make the essence of the corresponding technical solution deviate from the scope of the technical solution of the embodiments of the present application.

What is claimed is:

1. An organic compound, wherein the organic compound has a structure as represented by general formula (1) or general formula (2): 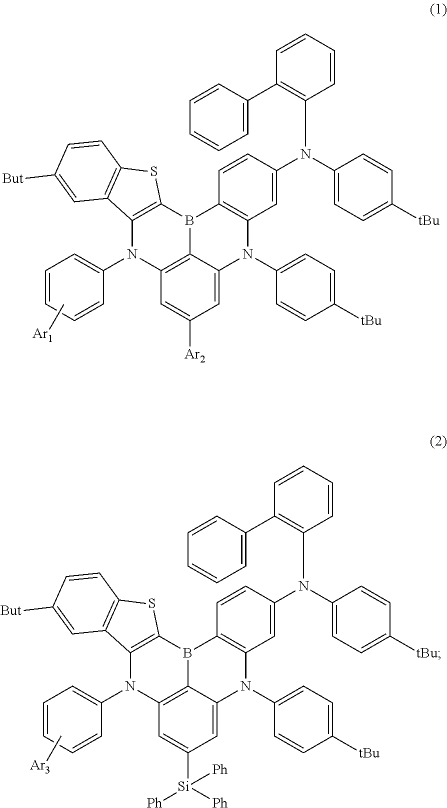
wherein, Ar₁ and Ar₃ are selected from a group represented by any one of formula (A-1) to formula (A-8): 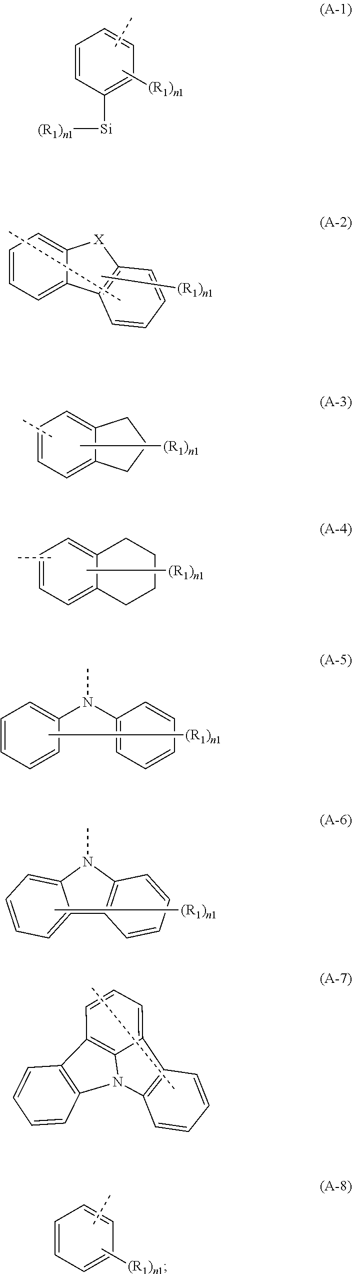
Ar₂ is selected from a group represented by any one of formula (B-1) to formula (B-9): 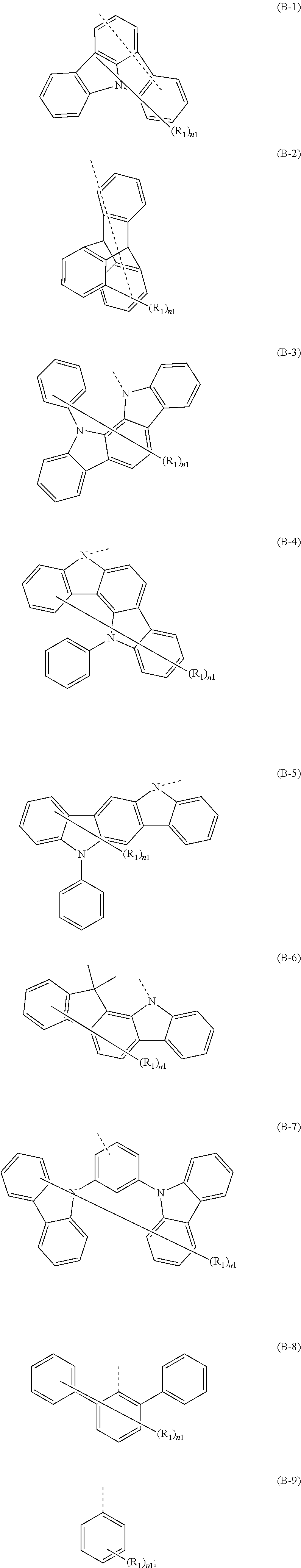
X is selected from O, S, N—CH₃, N-Ph or C(CH₃)₂;
n1 is selected from 0, 1, 2, 3, 4, 5, 6, 7, 8, 9 or 10;
R₁ is selected from H, D, a linear alkyl group having a carbon atom number ranging from 1 to 20, a linear silicon group having a carbon atom number ranging from 1 to 20, a branched silicon group having a carbon atom number ranging from 1 to 20, a linear alkoxy group having a carbon atom number ranging from 1 to 20, a linear thioalkoxy group having a carbon atom number ranging from 1 to 20, a branched alkyl group having a carbon atom number ranging from 3 to 20, a cyclic alkyl group having a carbon atom number ranging from 3 to 20, a branched alkoxy group having a carbon atom number ranging from 3 to 20, a cyclic alkoxy group having a carbon atom number ranging from 3 to 20, a branched thioalkoxy group having a carbon atom number ranging from 3 to 20, a cyclic thioalkoxy group having a carbon atom number ranging from 3 to 20, a silyl group, a trimethylsilyl group, a triphenylsilyl group, a keto group having a carbon atom number ranging from 1 to 20, an alkoxycarbonyl group having a carbon atom number ranging from 2 to 20, an aryloxycarbonyl group having a carbon atom number ranging from 7 to 20, an olefin group having a carbon atom number ranging from 1 to 20, CN, a carbamoyl group, a haloformyl group, a formyl group, isocyano, an isocyanate group, a thiocyanate group, an isothiocyanate group, a hydroxyl group, a nitro group, CF₃, Cl, Br, F, a substituted or unsubstituted aromatic group having a ring atom number ranging from 6 to 30, a substituted or unsubstituted heteroaromatic group having a ring atom number ranging from 5 to 30, a substituted or unsubstituted aryloxy group having a ring atom number ranging from 6 to 30, or a substituted or unsubstituted heteroaryloxy group having a ring atom number ranging from 5 to 30.

2. The organic compound according to claim 1, wherein Ar₂ is selected from the group represented by any one of the formulas (B-1) to (B-8);
alternatively, when Ar₂ is selected from the group represented by the formula (B-9), Ar₁ is selected from a group represented by any one of the formulas (A-1) to (A-7).

3. The organic compound according to claim 1, wherein Ar₃ is selected from a group represented by any one of the formulas (A-1) to (A-7).

4. The organic compound according to claim 1, wherein R1 is selected from H, D, a linear alkyl group having a carbon atom number ranging 1 to 10, a branched alkyl group having a carbon atom number ranging 3 to 10, and a cyclic alkyl group having a carbon atom number ranging 3 to 10.

5. The organic compound according to claim 1, wherein R1 is selected from H, D, a linear alkyl group having a carbon atom number ranging 1 to 4, and a branched alkyl group having a carbon atom number ranging 3 to 5.

6. The organic compound according to claim 4, wherein R₁ is selected from H, D, a linear alkyl group having a carbon atom number ranging 1 to 4, and a branched alkyl group having a carbon atom number ranging 3 to 5.

7. The organic compound according to claim 1, wherein when Ar₁ is a group represented by the formula (A-2), the group represented by the formula (A-2) is selected from:
at least one of

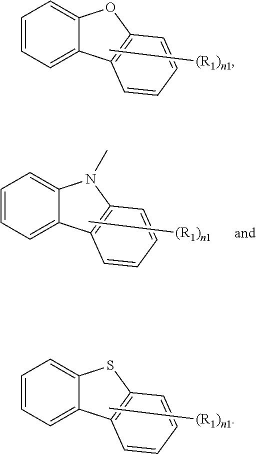

8. The organic compound according to claim 1, wherein the organic compound is a blue light-emitting material.

9. The organic compound according to claim 1, wherein the organic compound is selected from any one of the following compounds:

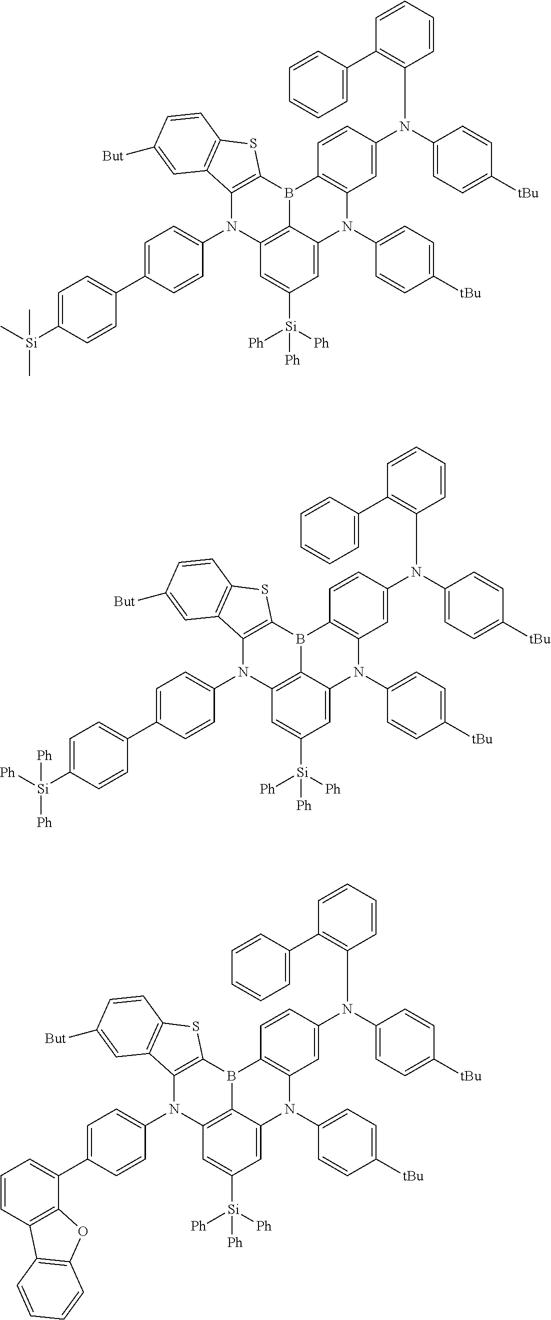

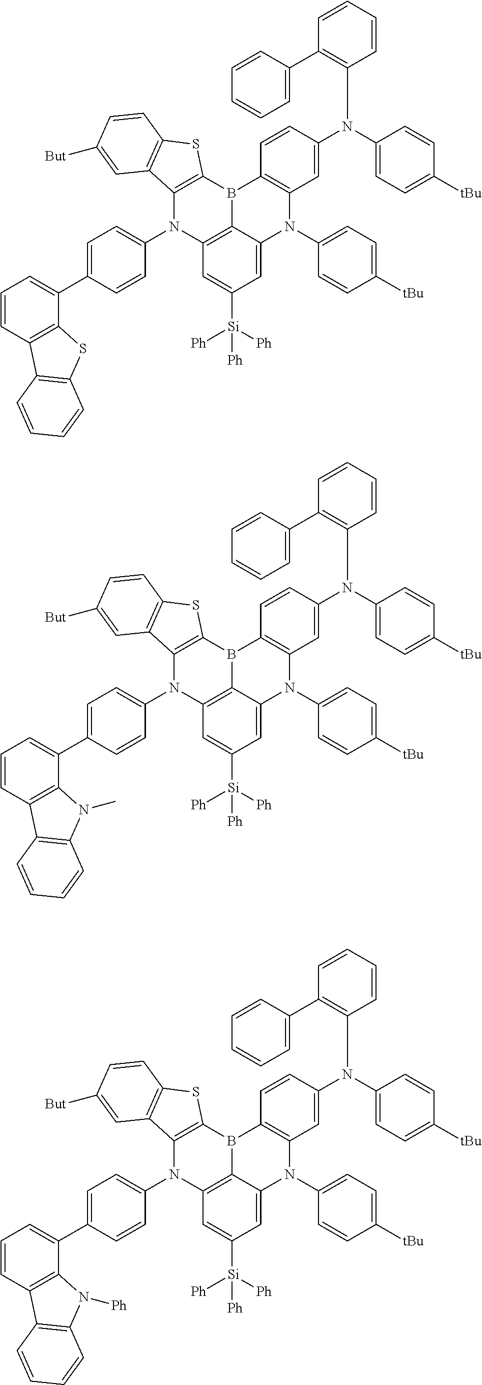

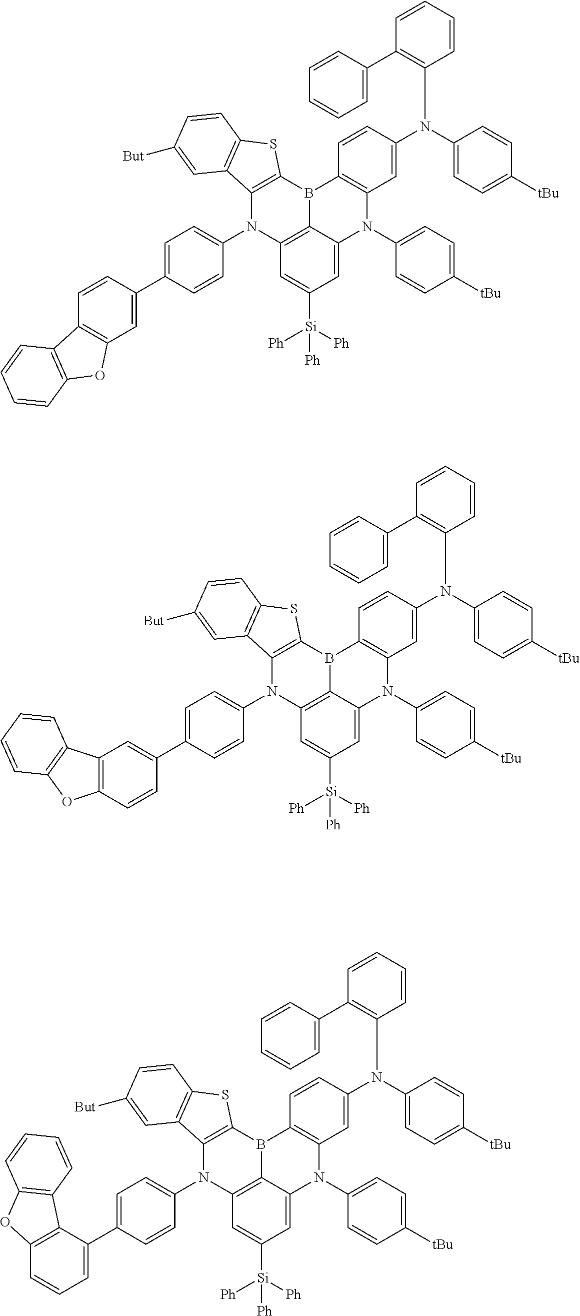

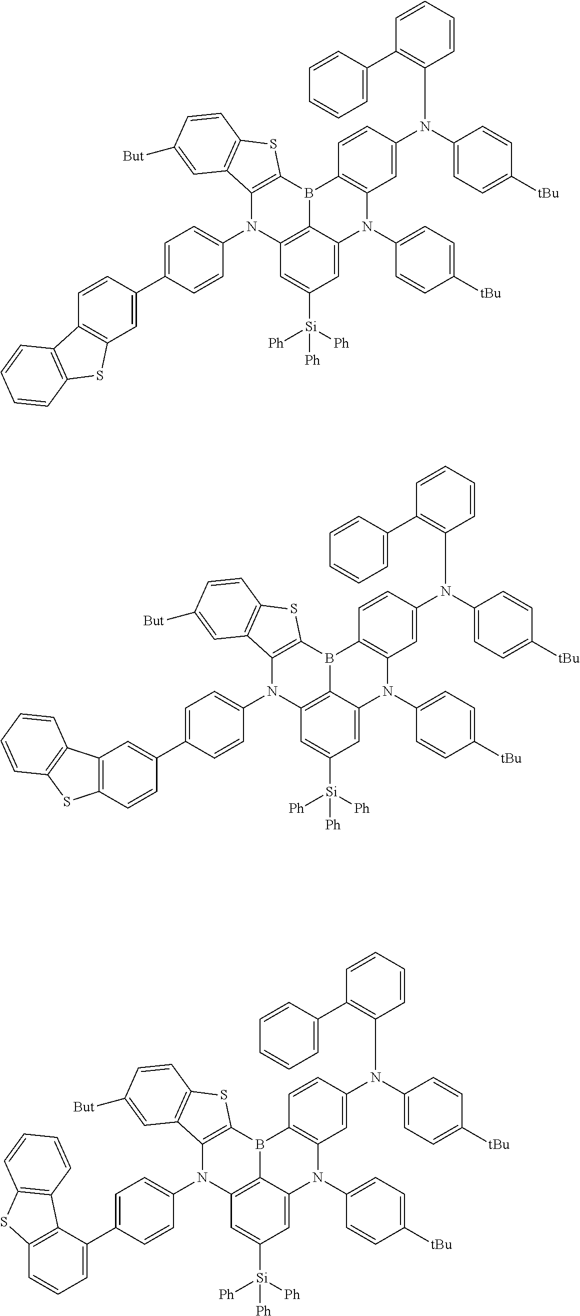

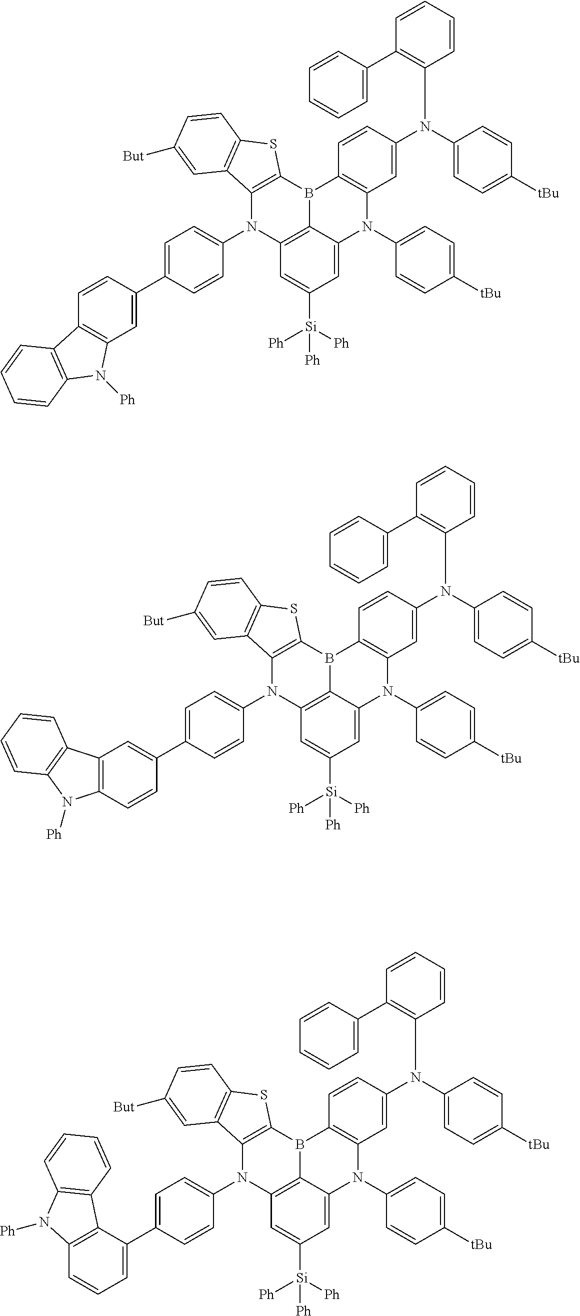

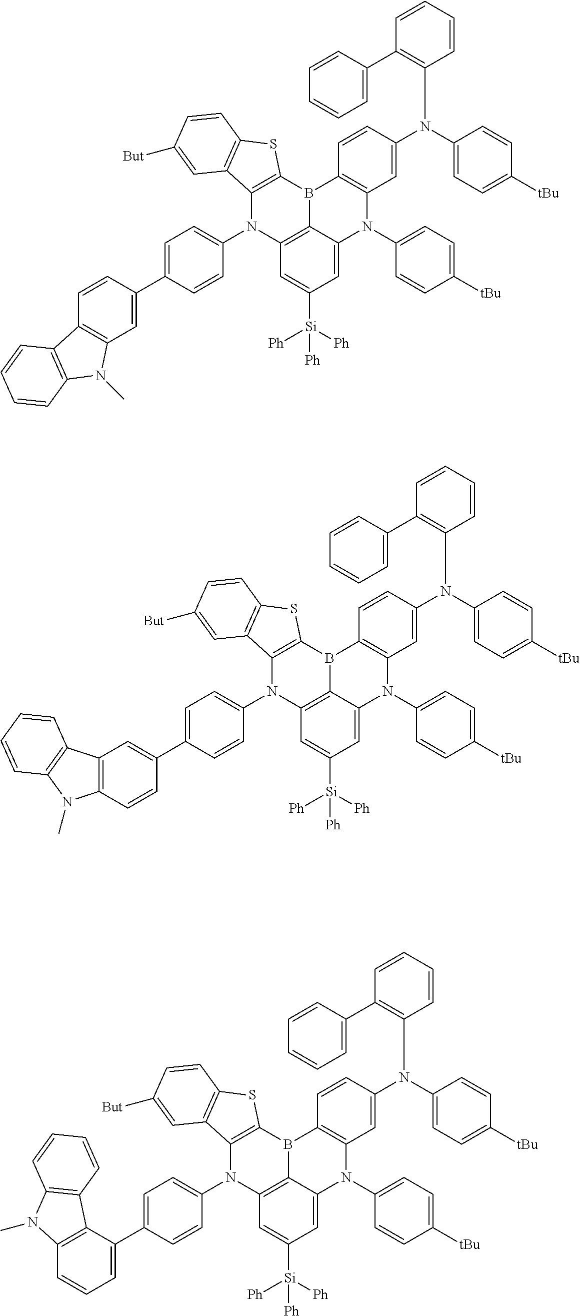

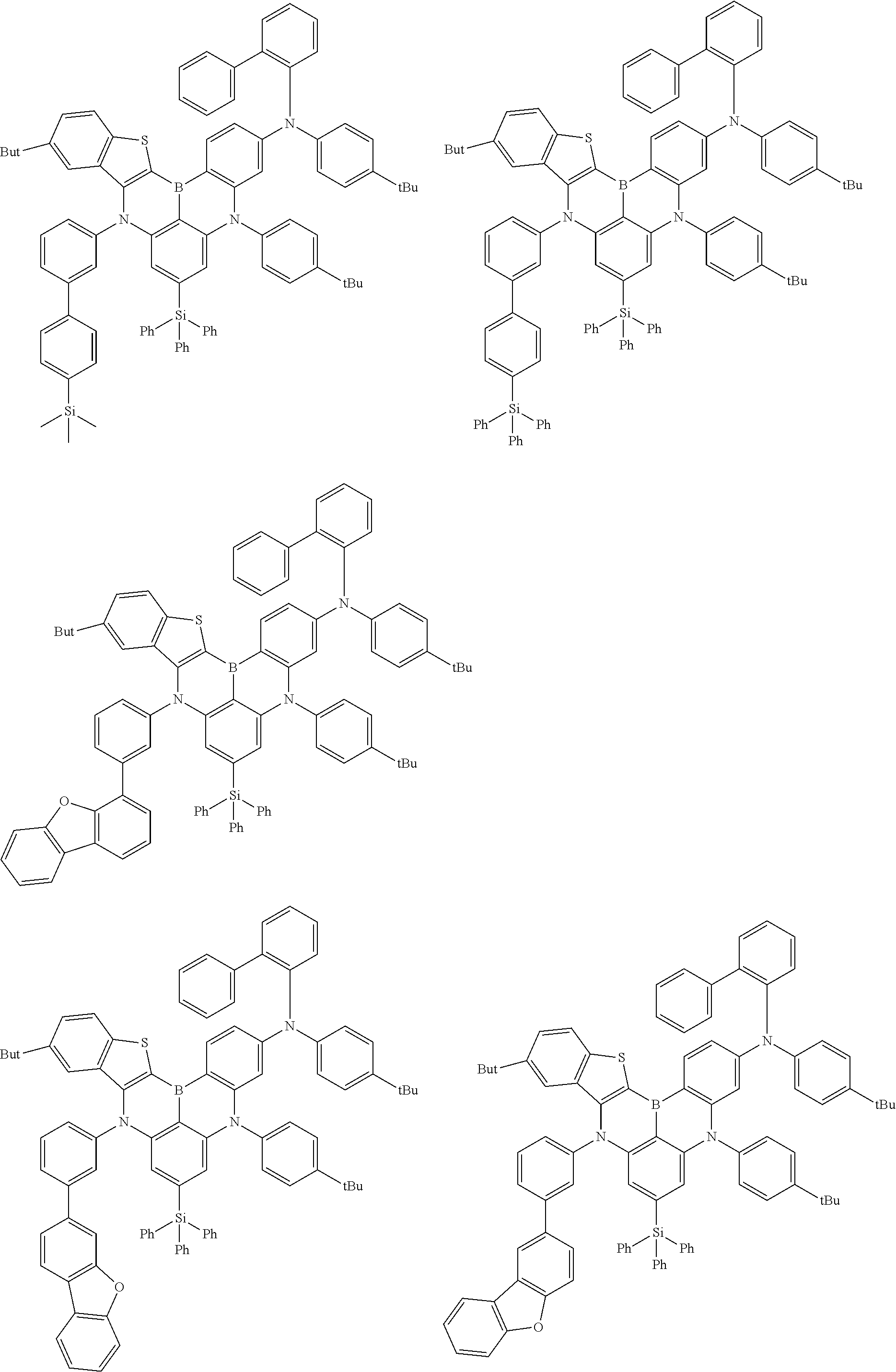

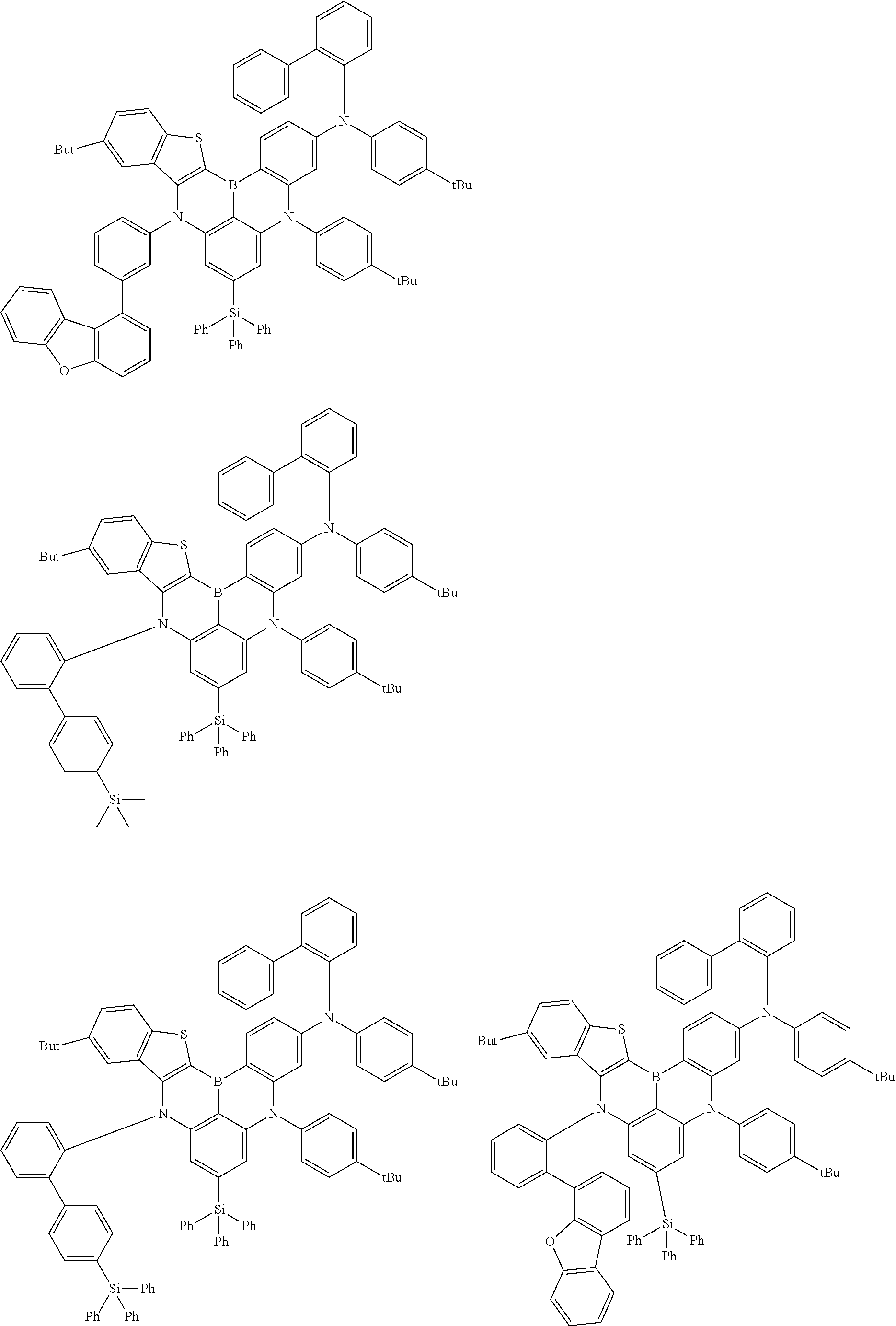

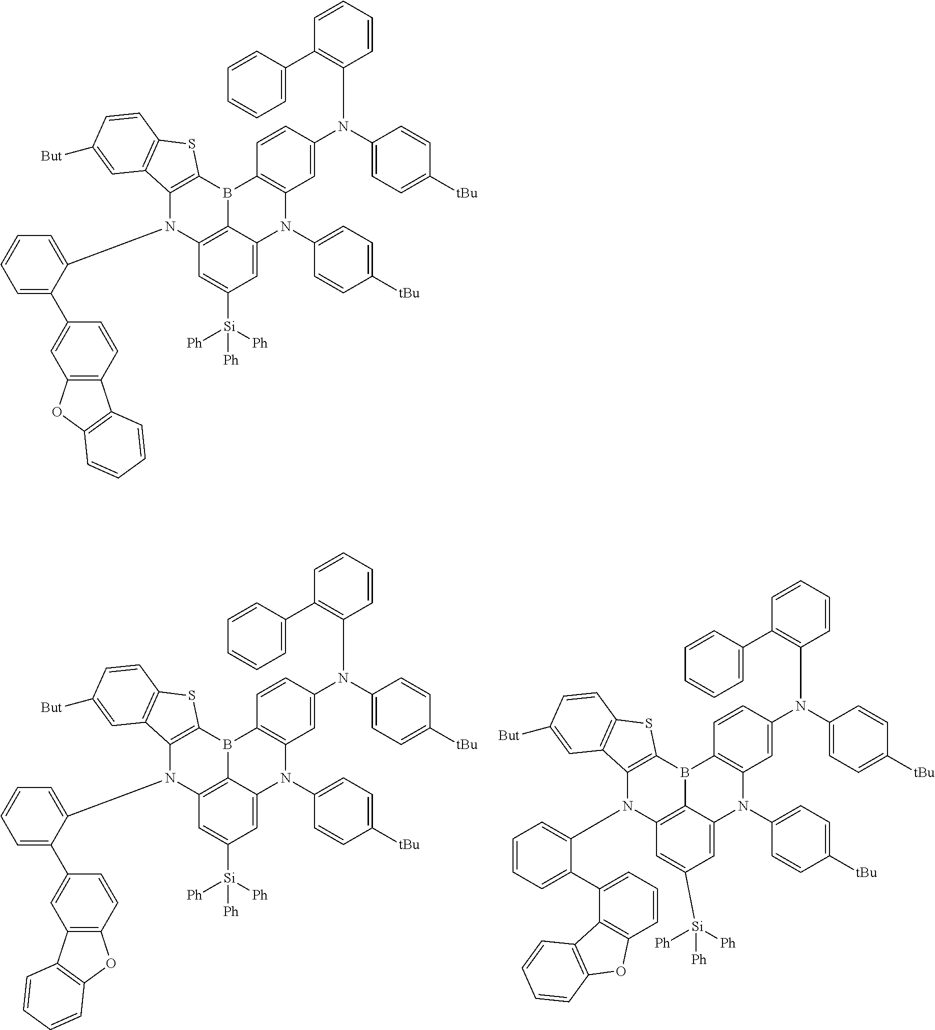

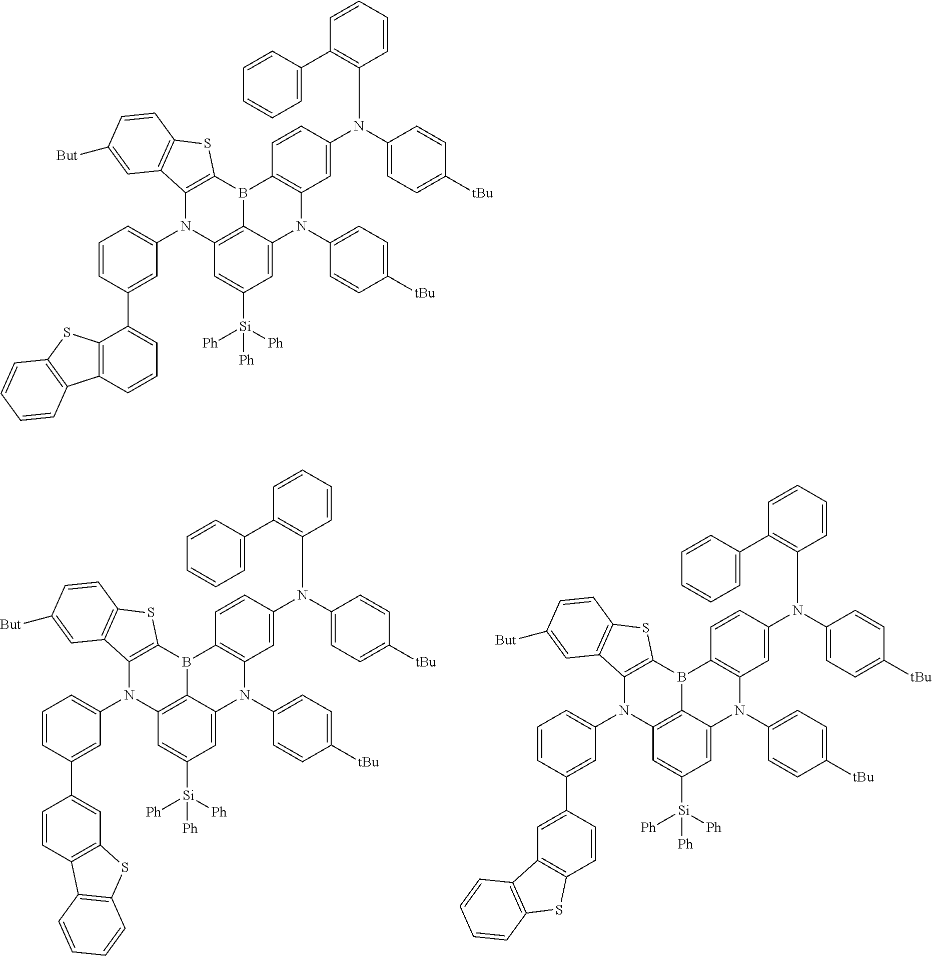

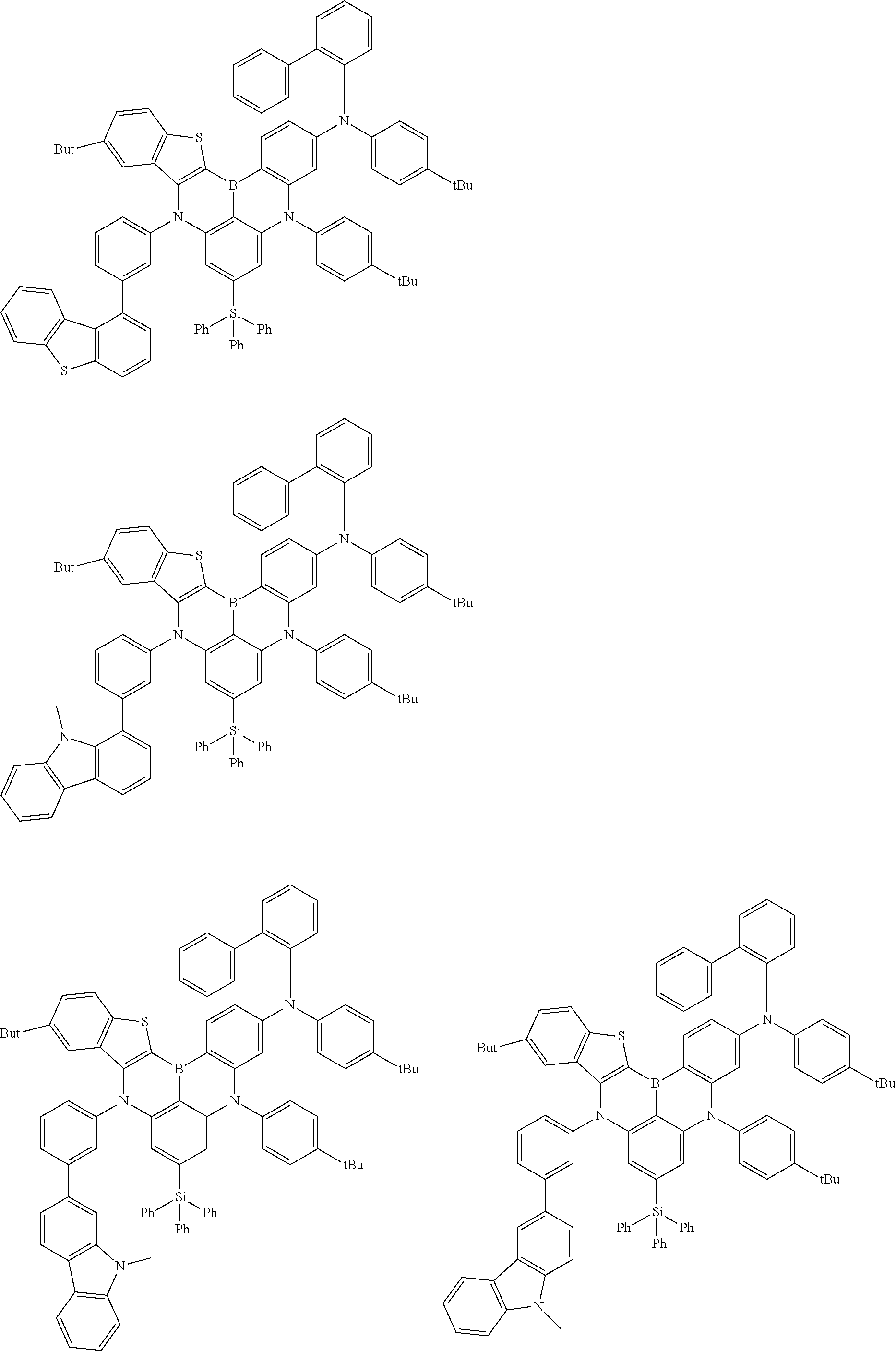

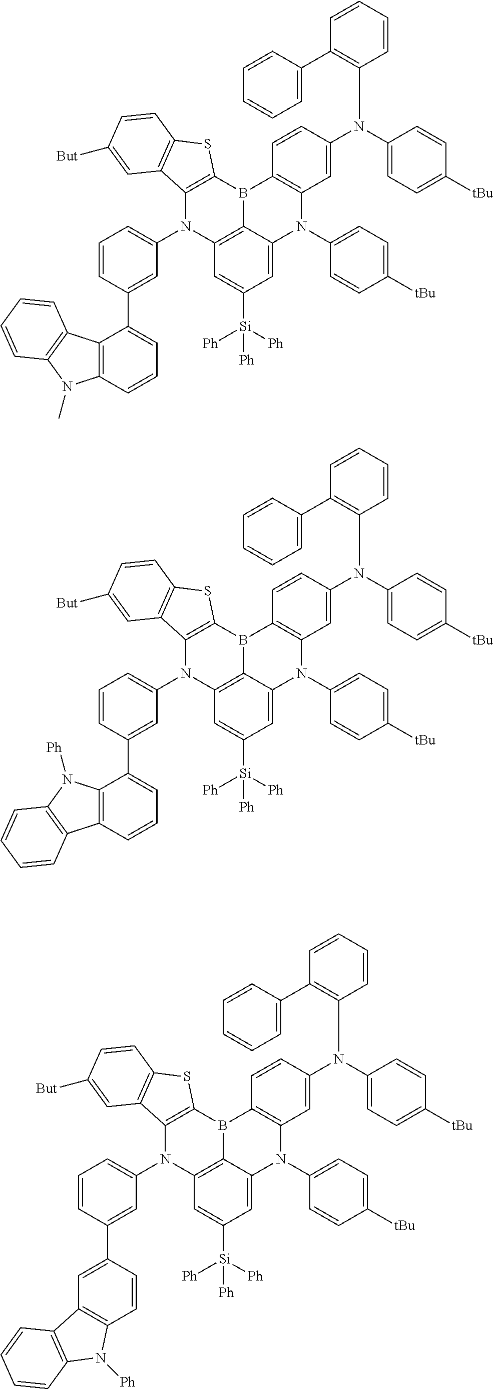

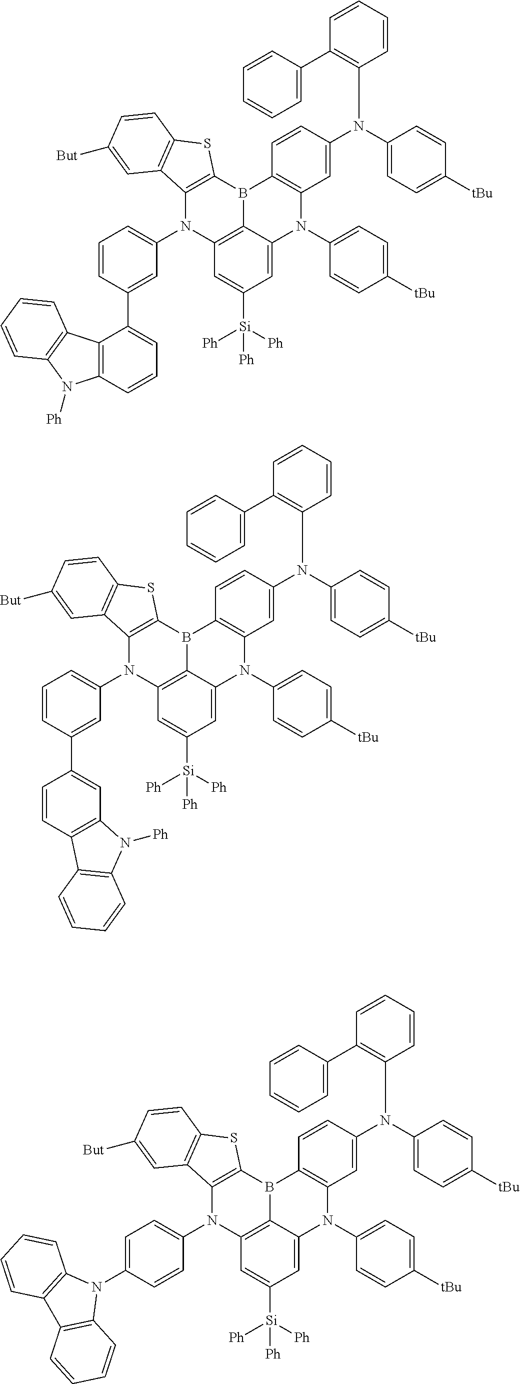

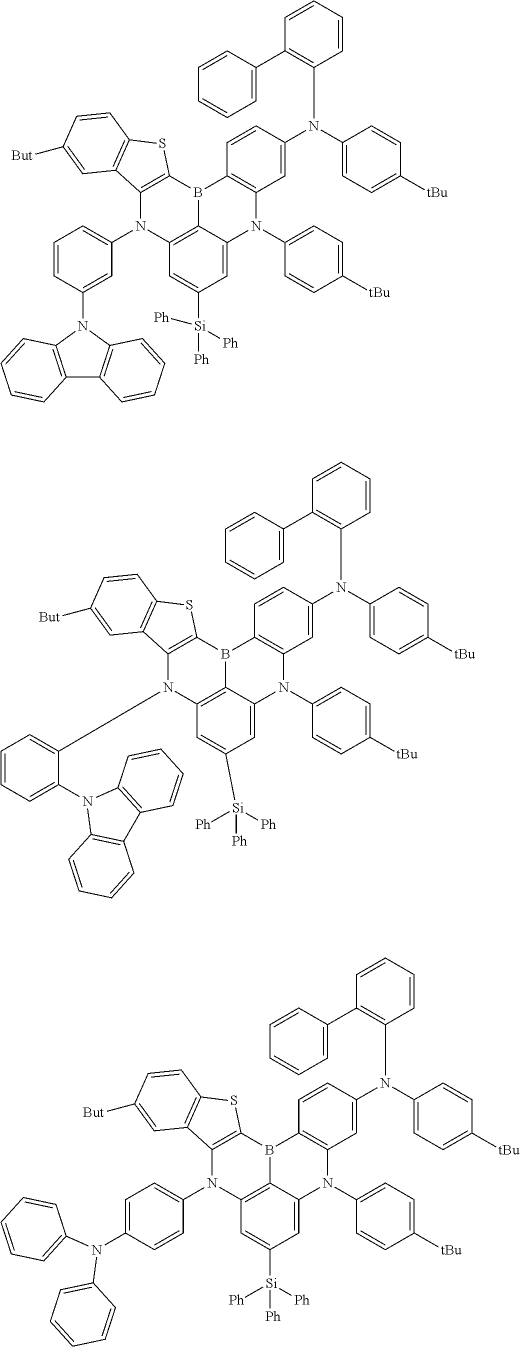

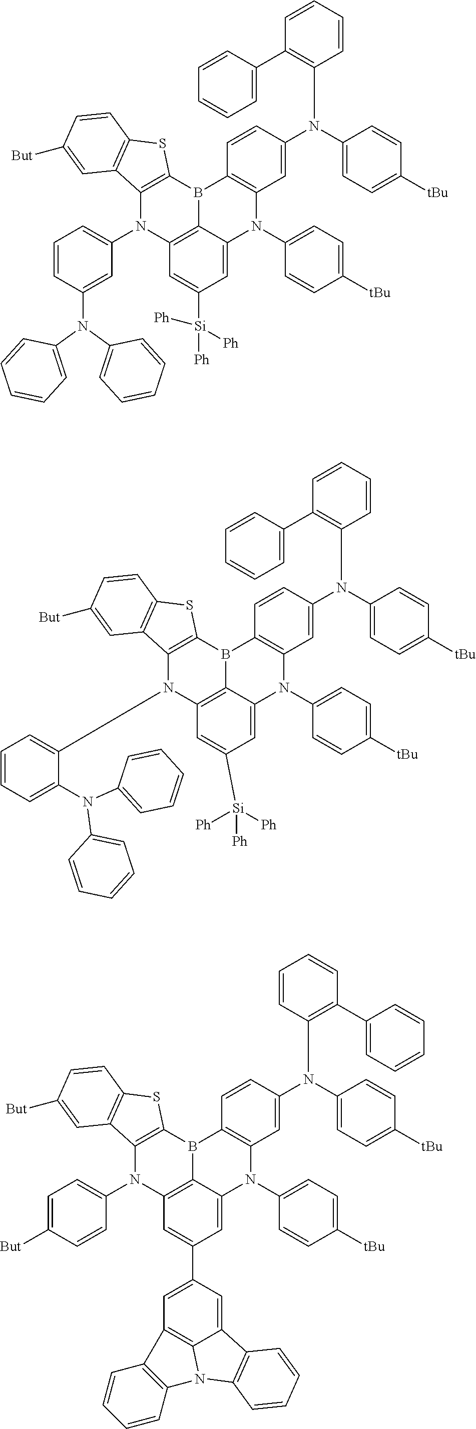

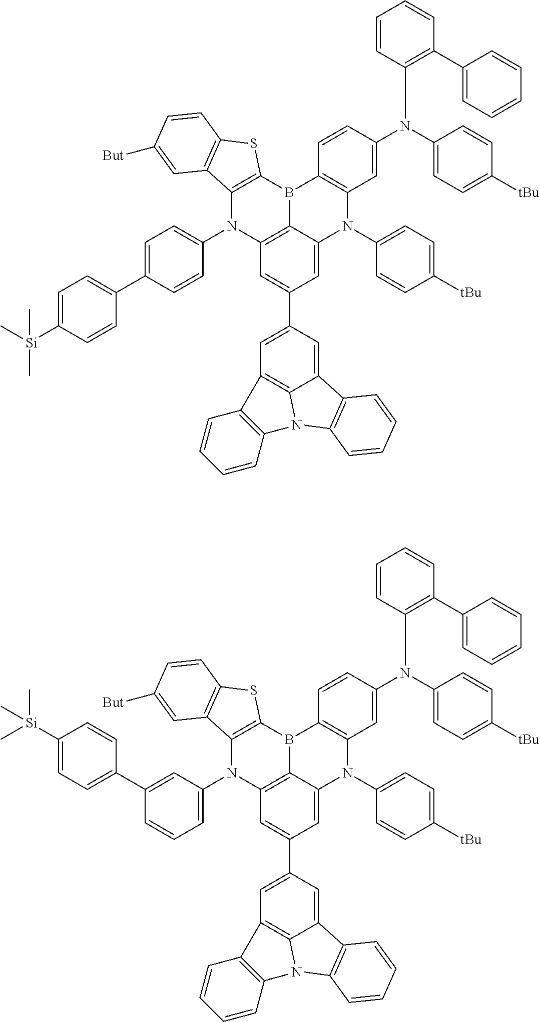

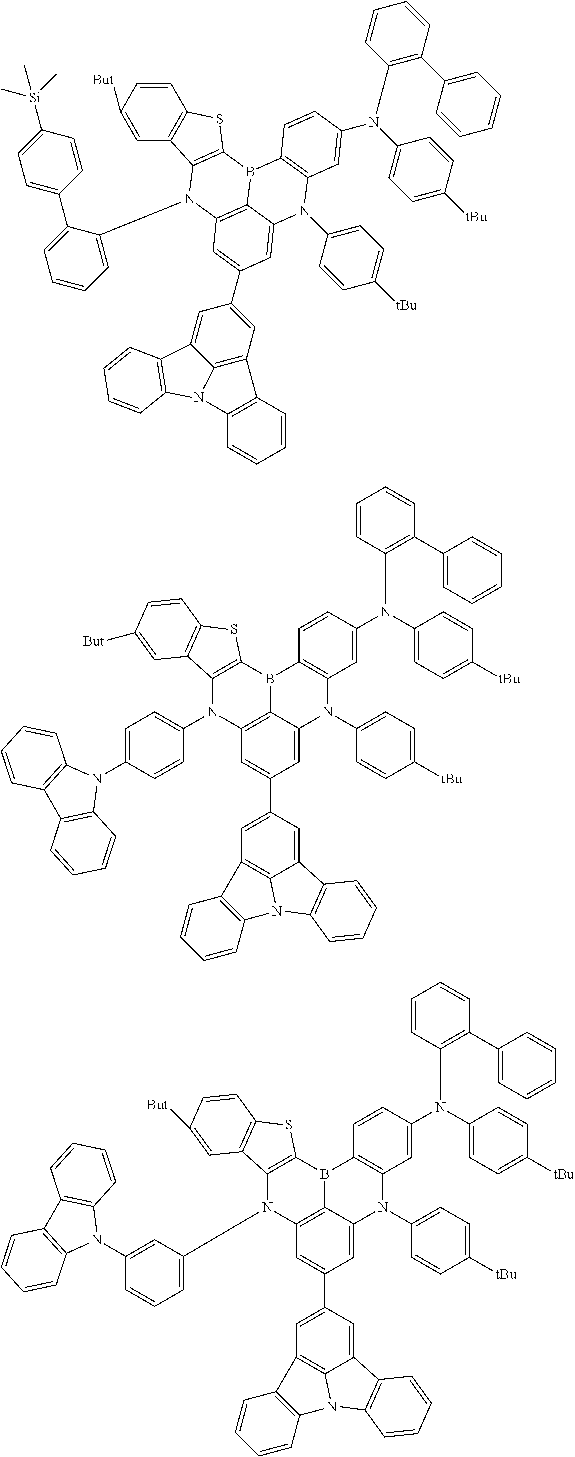

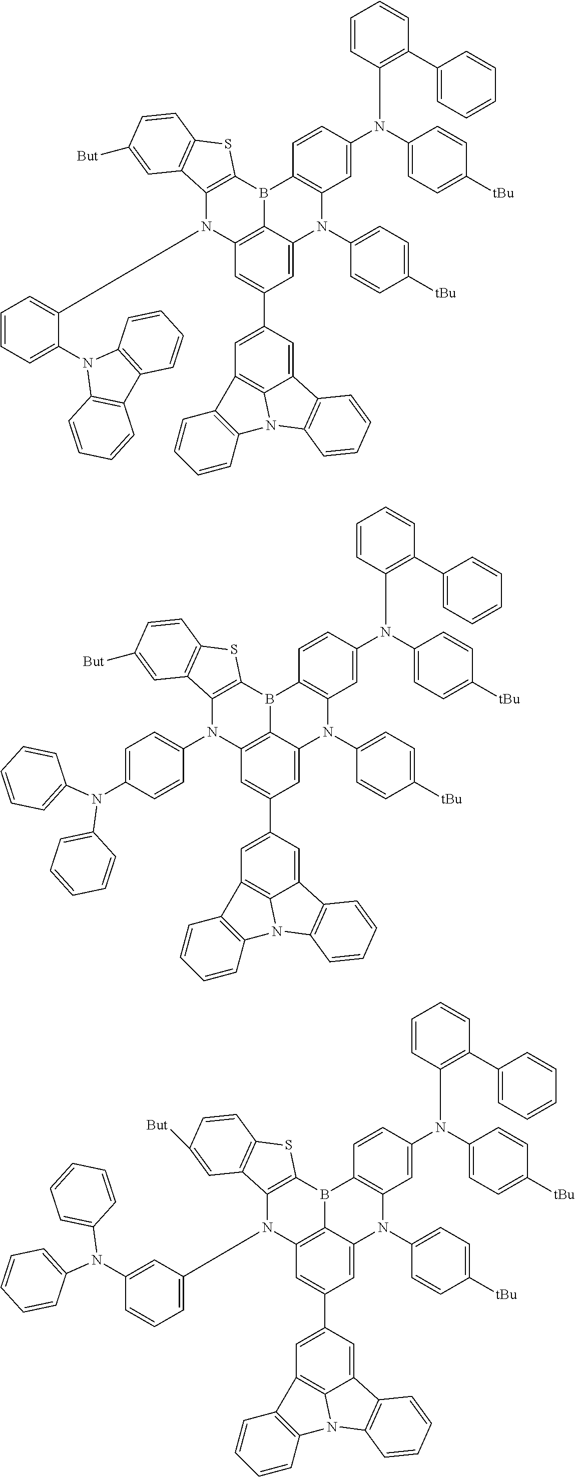

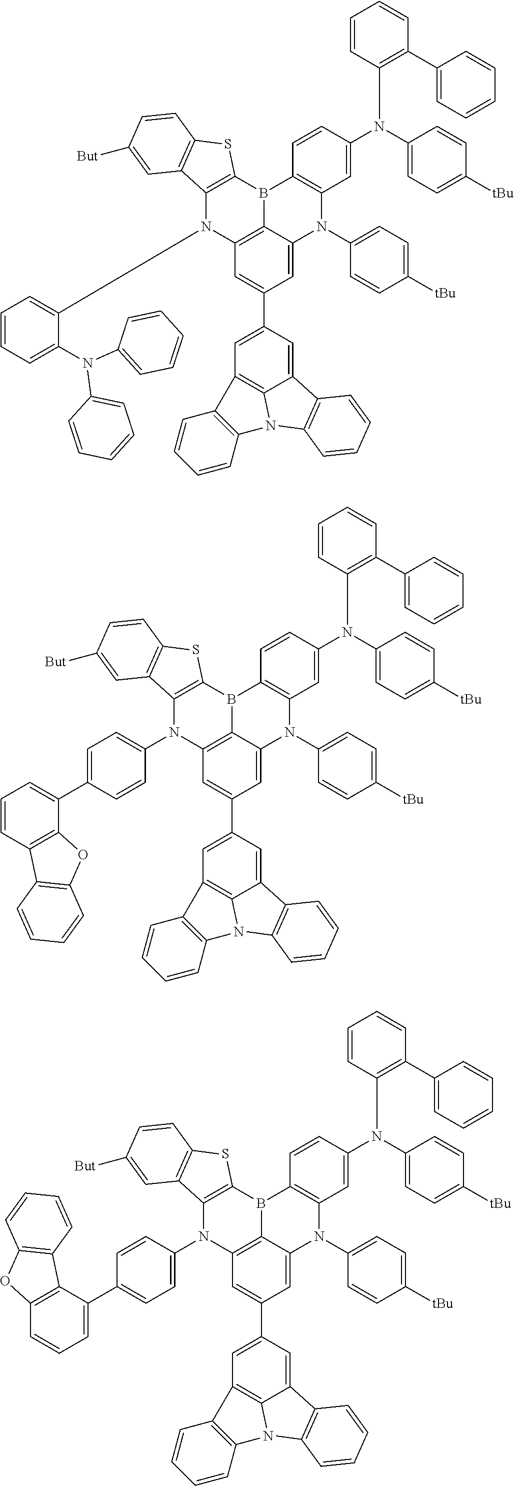

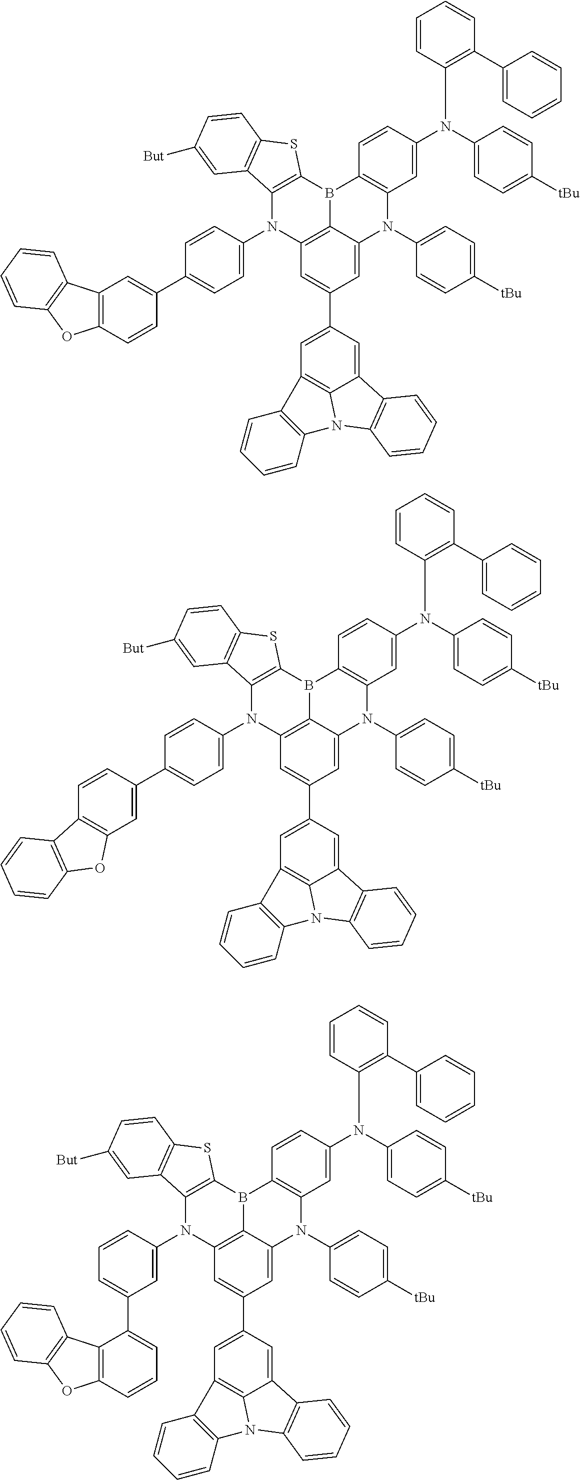

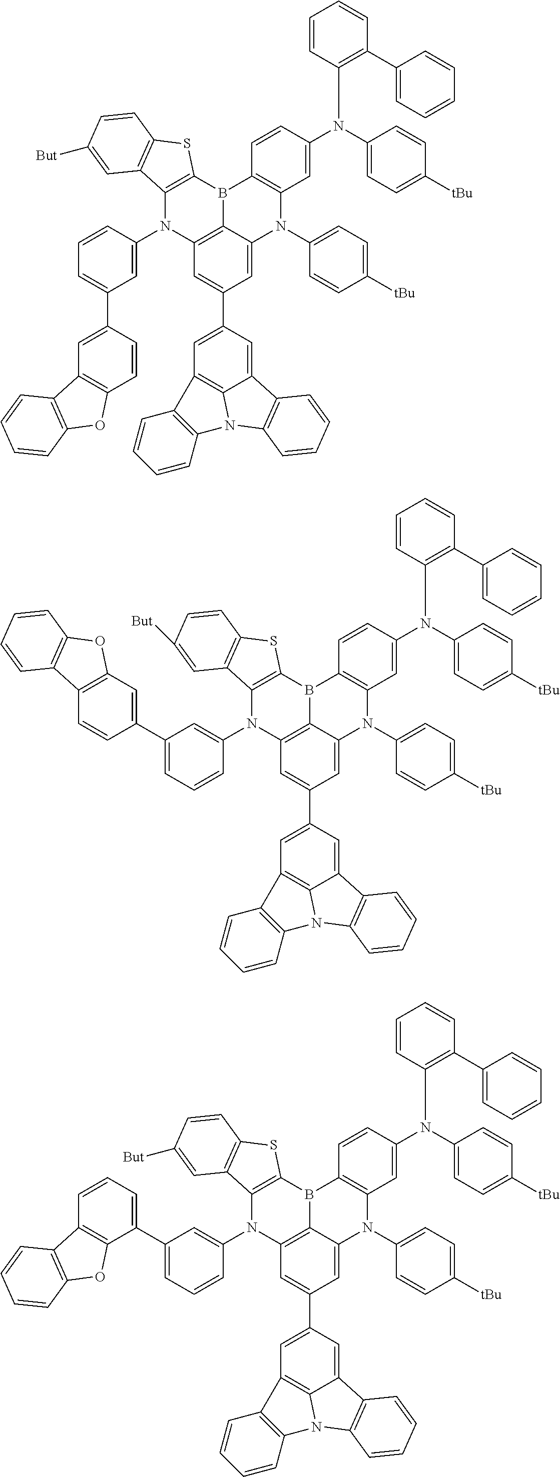

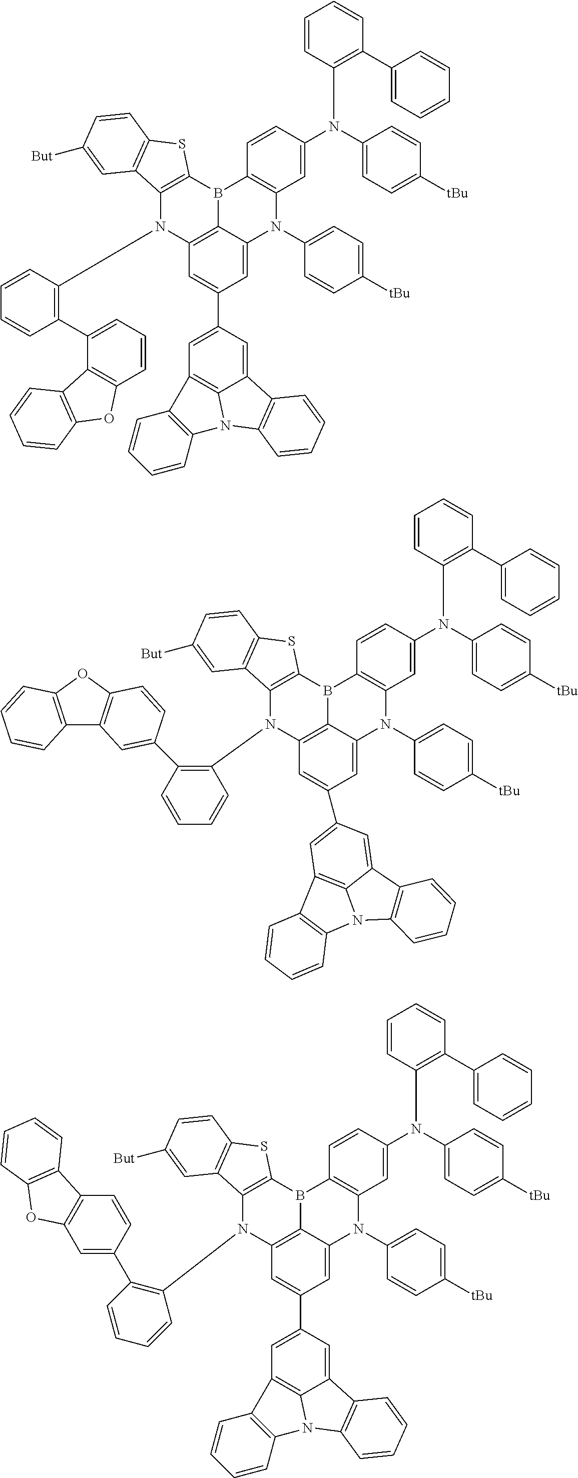

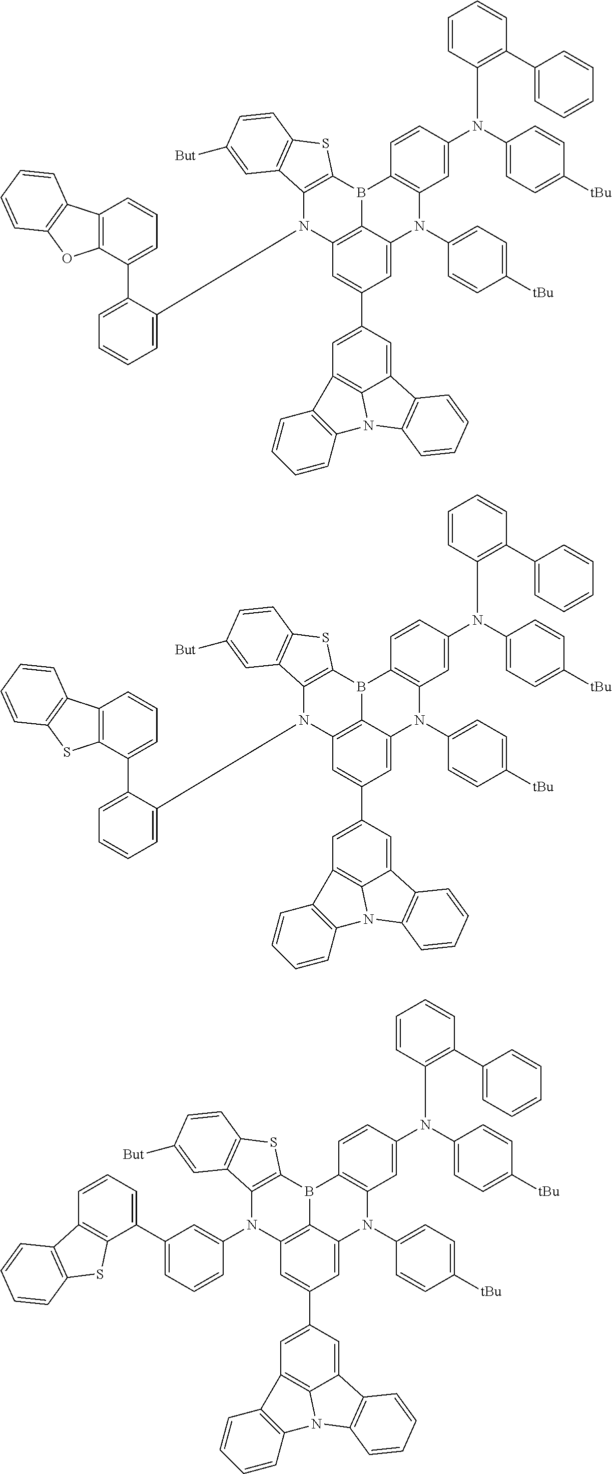

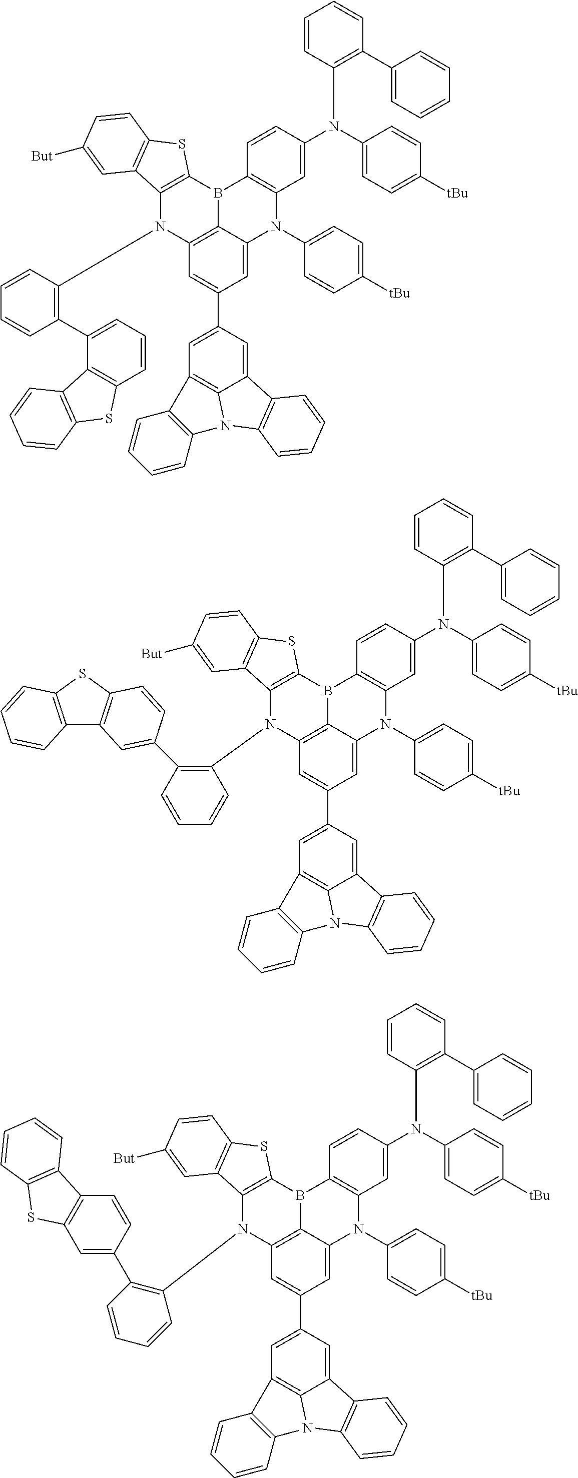

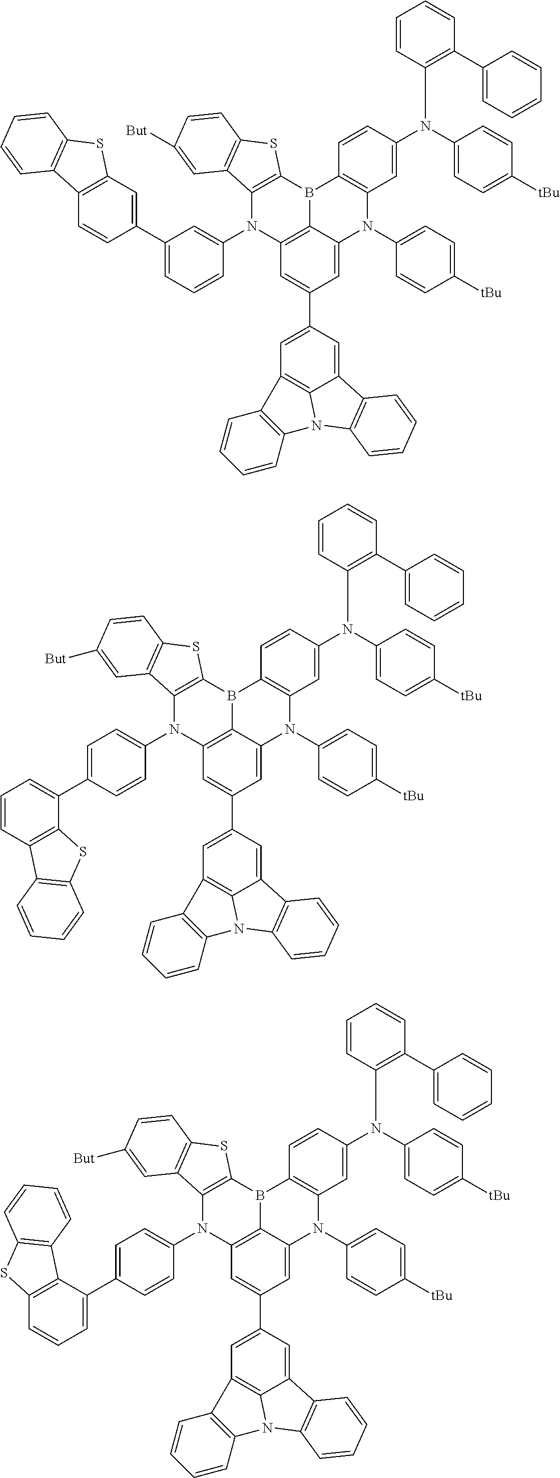

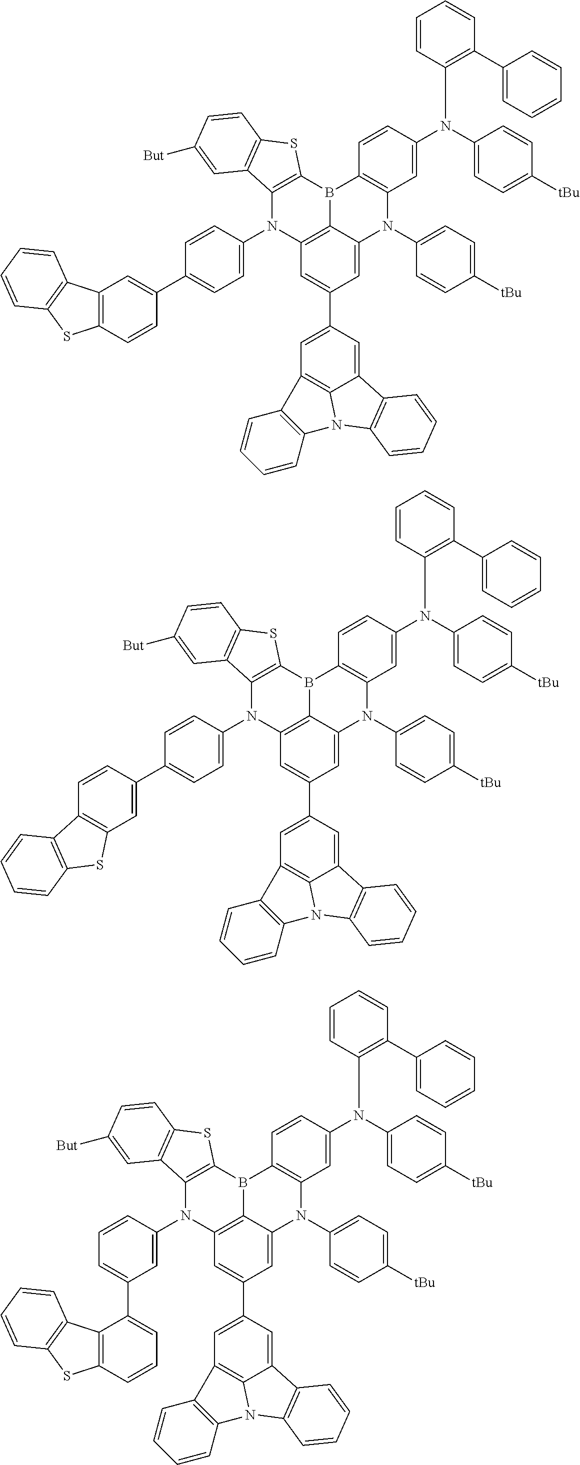

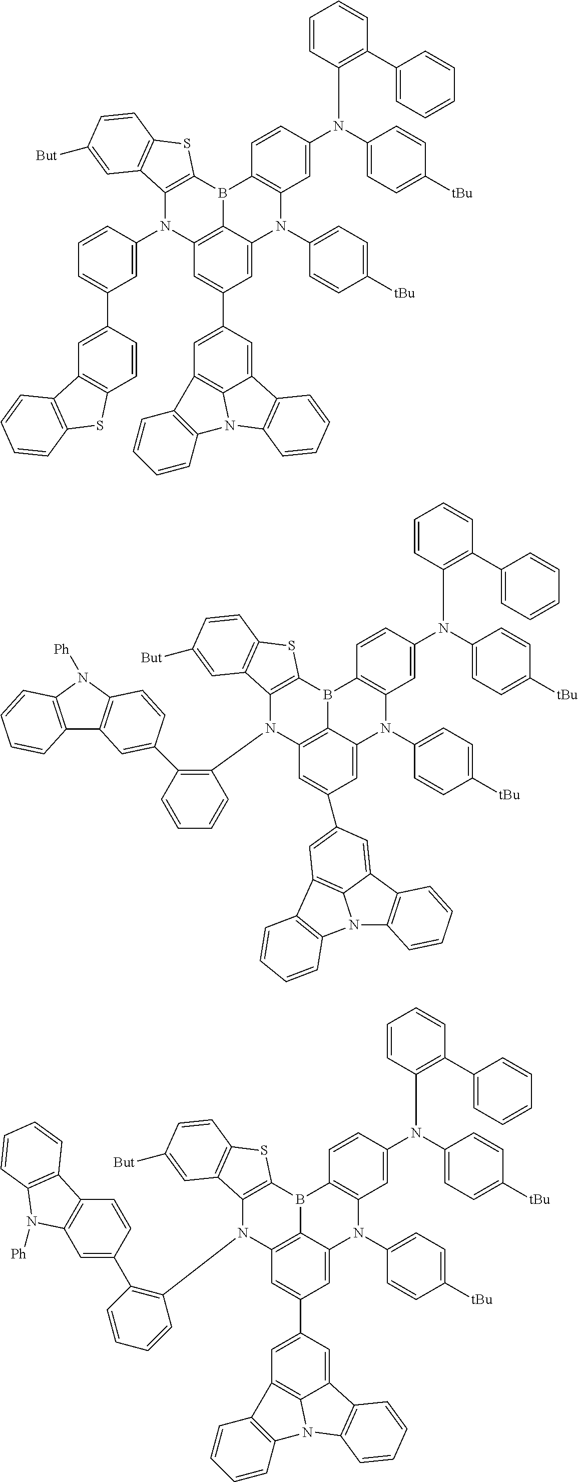

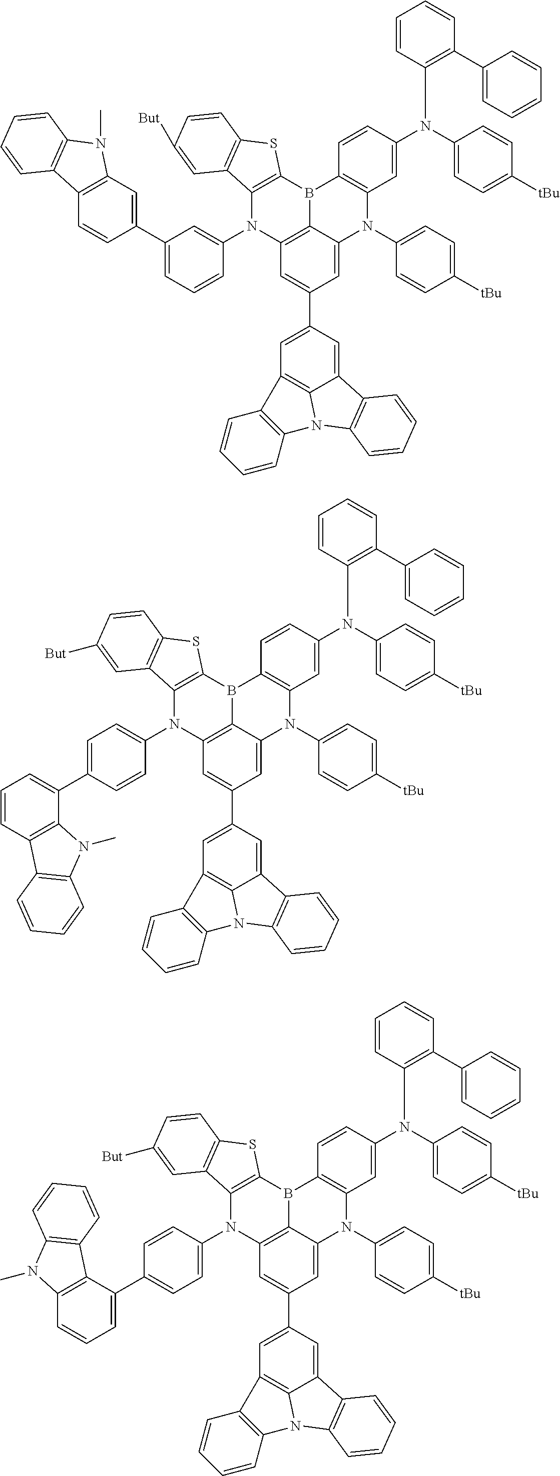

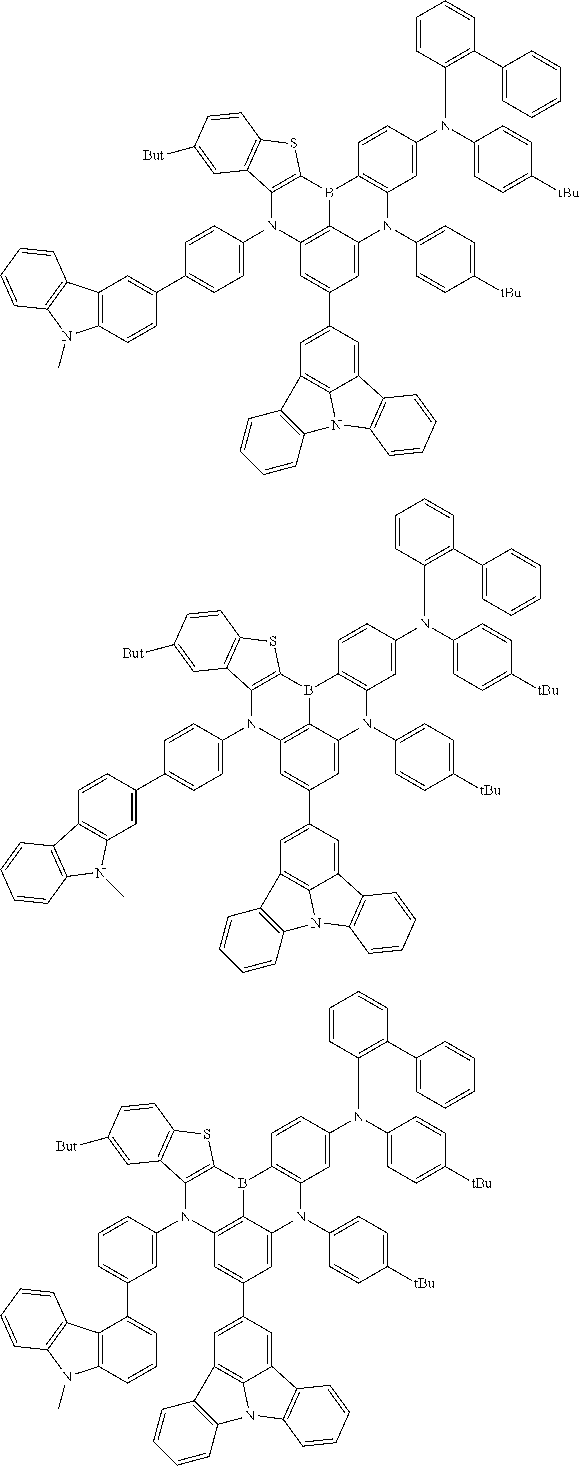

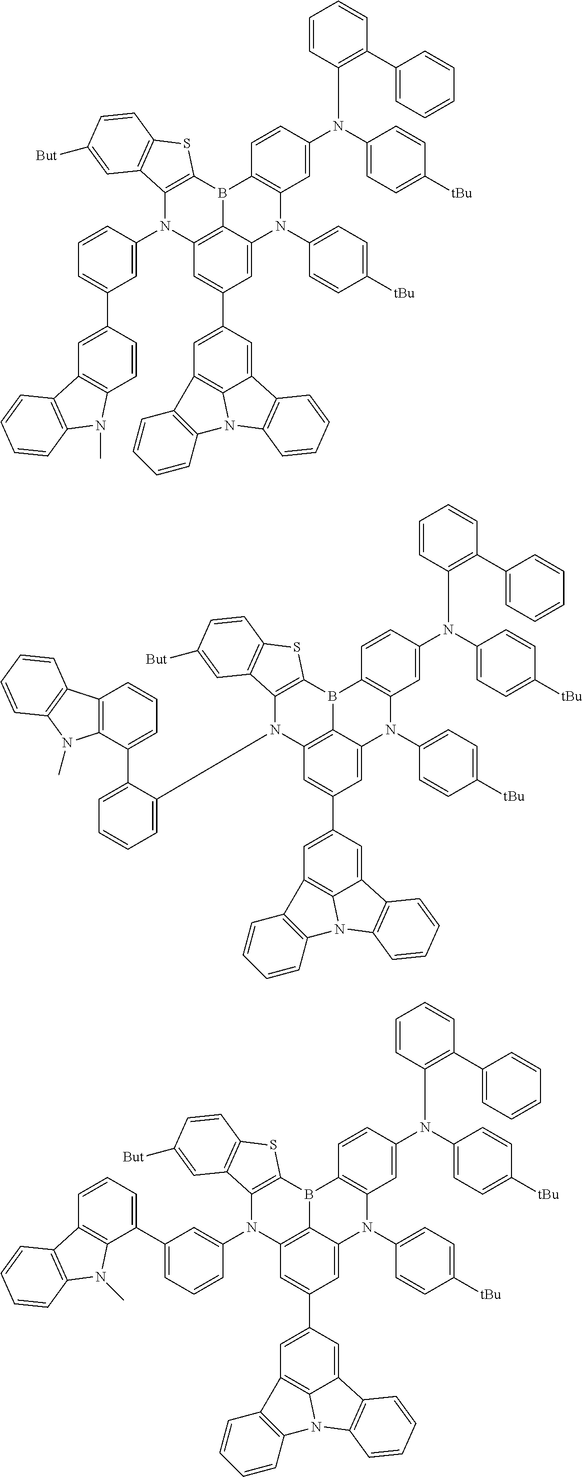

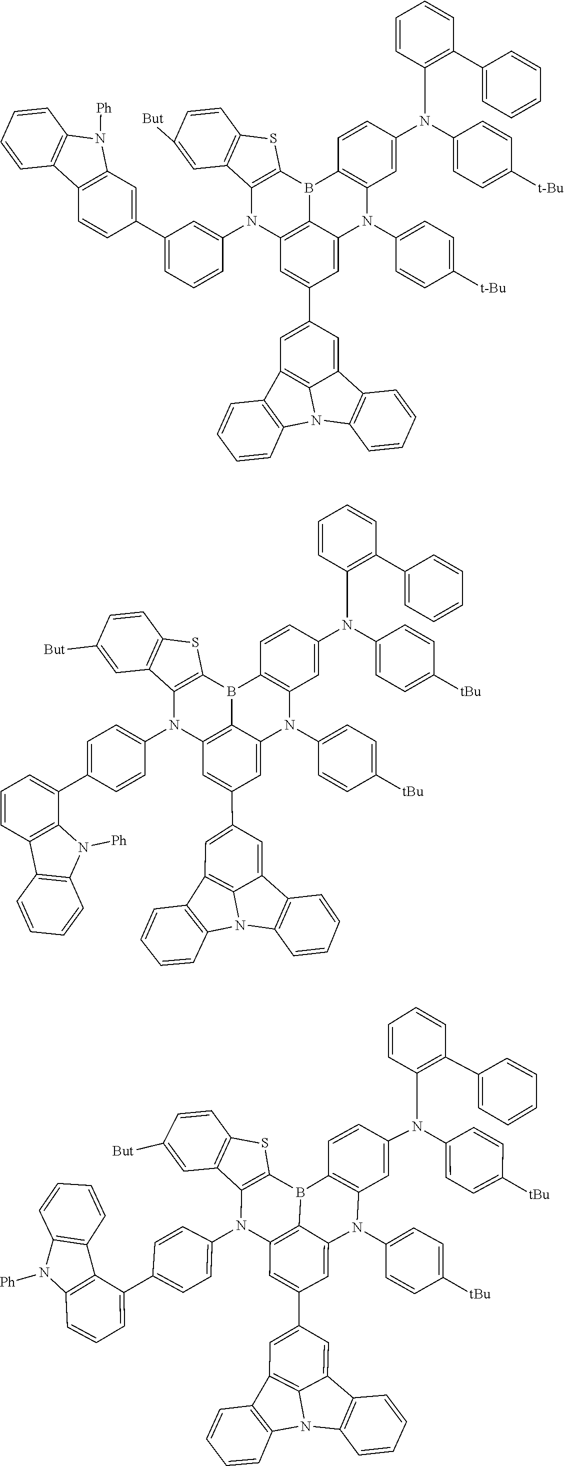

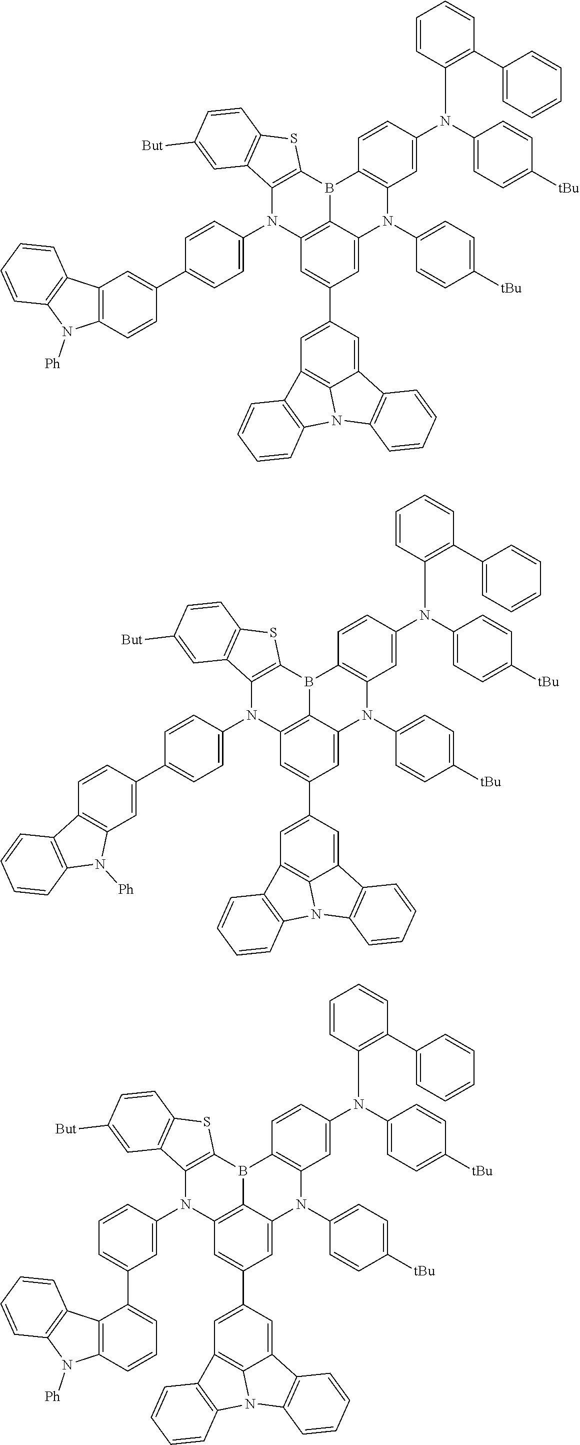

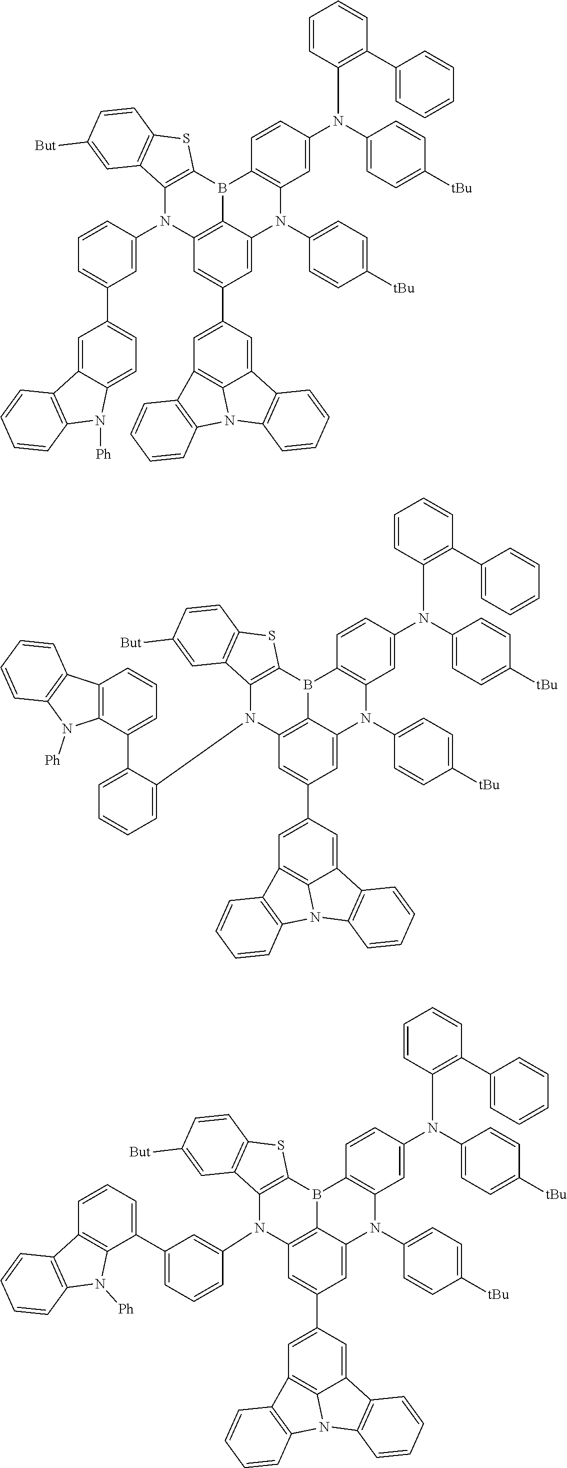

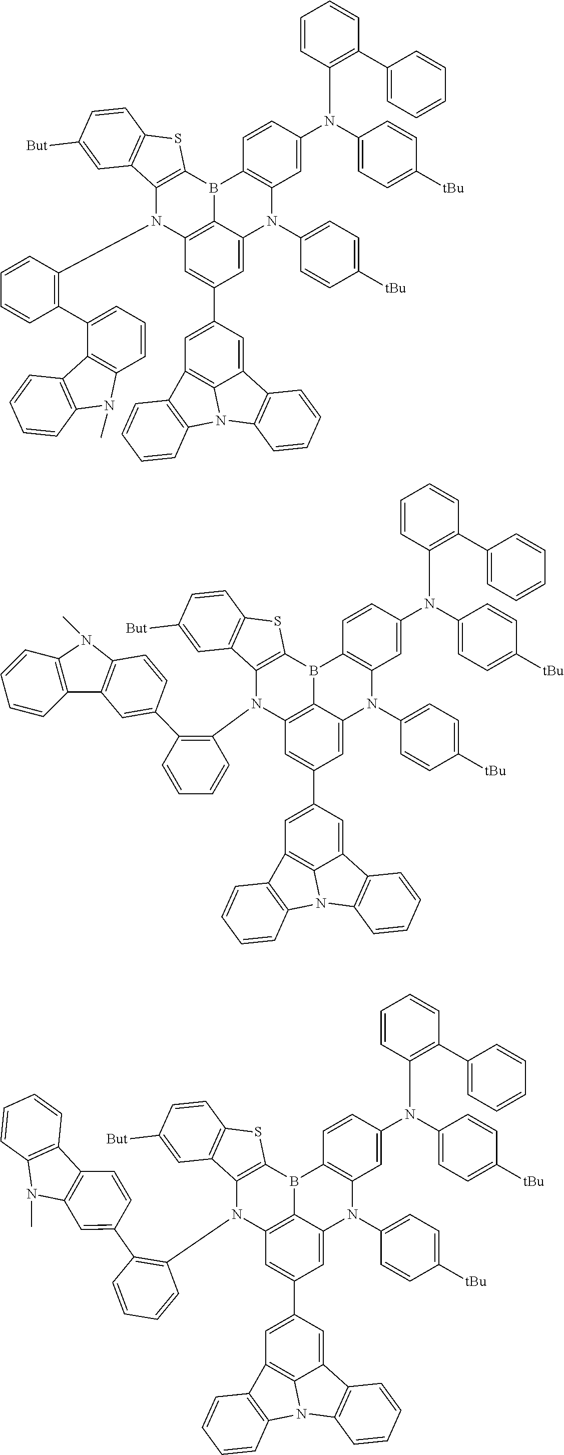

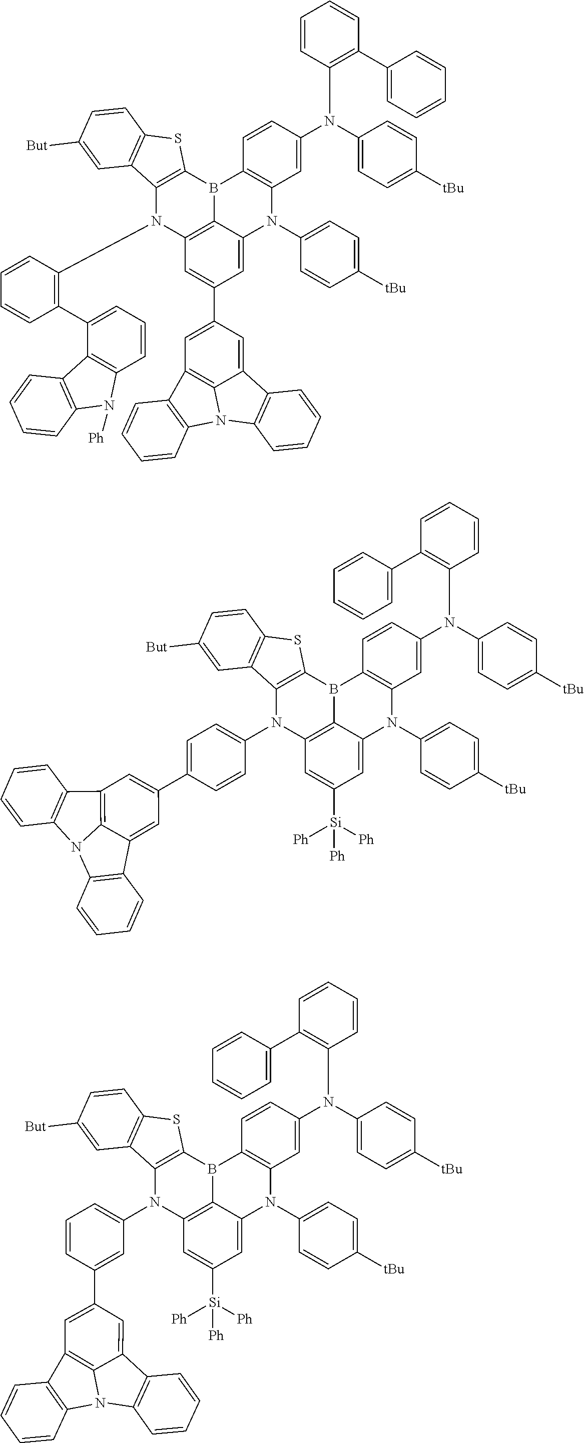

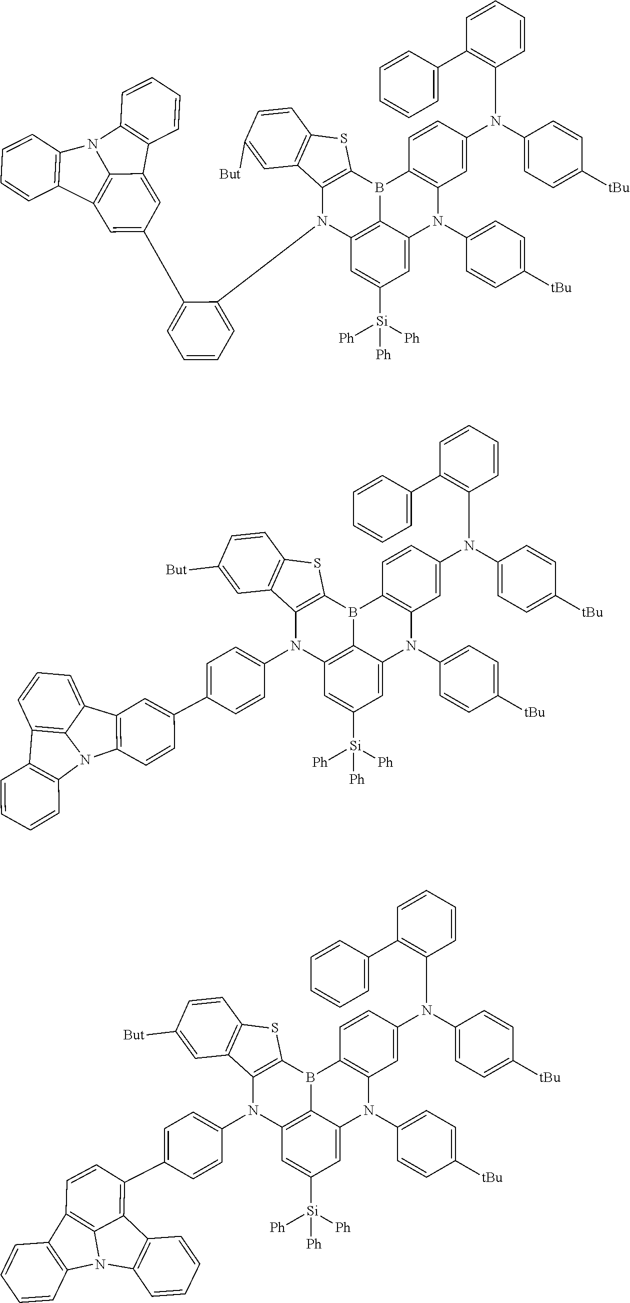

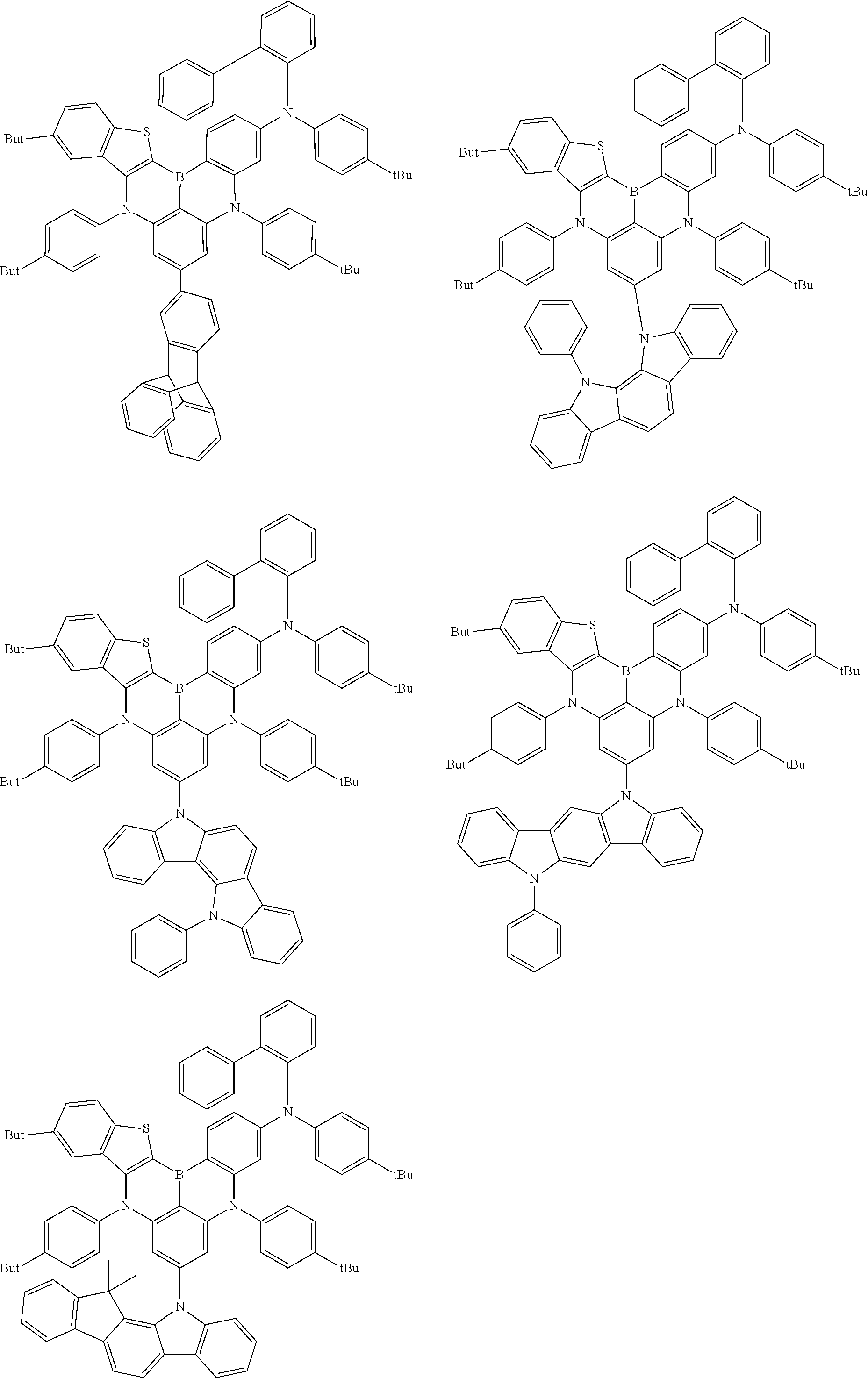

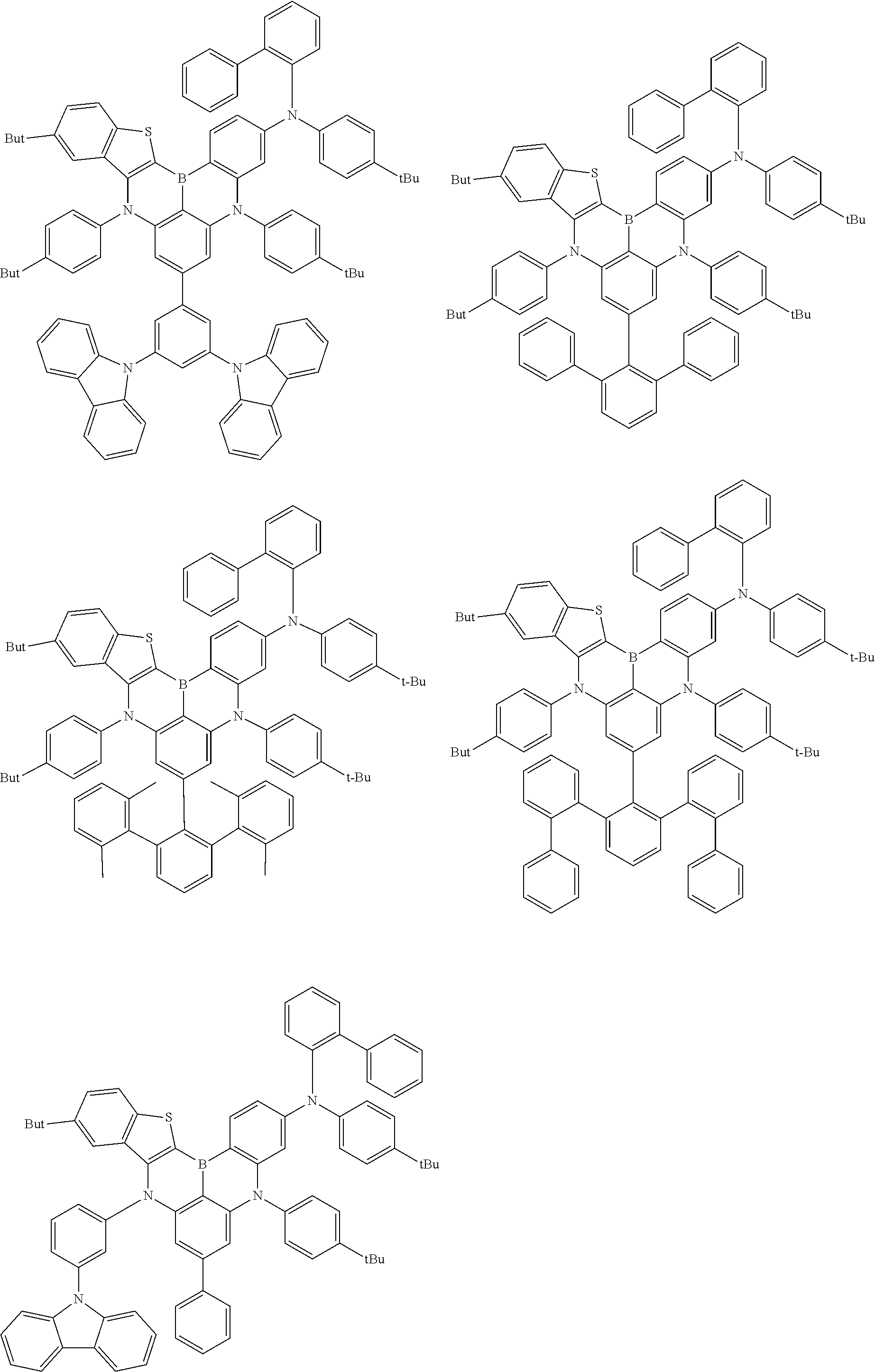

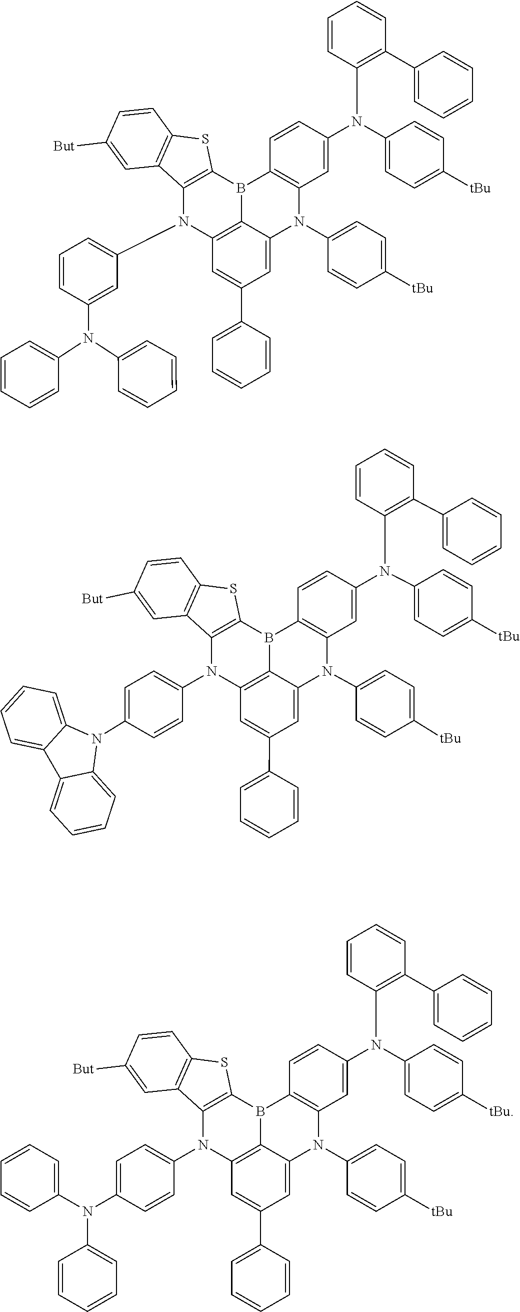

10. A mixture, wherein the mixture comprises the organic compound according to claim 1 and at least one organic functional material, wherein the organic functional material is selected from a hole injection material, a hole transport material, an electron transport material, an electron injection material, an electron blocking material, a hole blocking material, a light-emitting material, a host material or an organic dye.

11. A composition, wherein the composition comprises the organic compound according to claim 1 and at least one organic solvent.

12. A composition, wherein the composition comprises the mixture according to claim 10 and at least one organic solvent.

13. An organic light-emitting device, comprising:
a first electrode;
a second electrode, disposed opposite to the first electrode; and
an organic functional layer, located between the first electrode and the second electrode;
a material of the organic functional layer comprises an organic compound, wherein the organic compound has a structure as represented by general formula (1) or general formula (2): 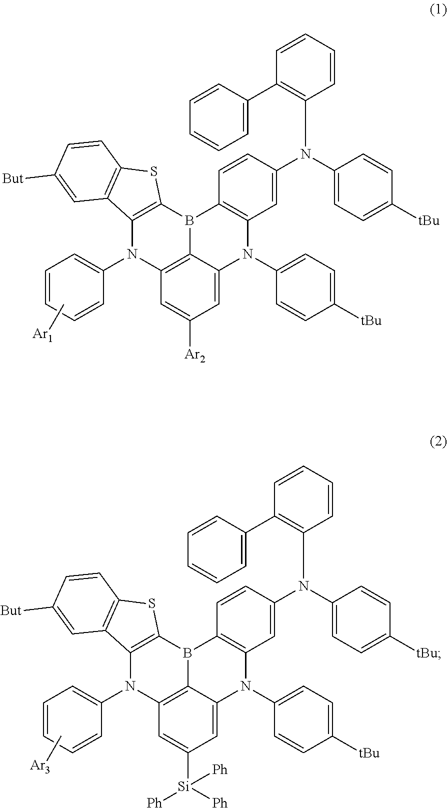
wherein, Ar₁ and Ar₃ are selected from a group represented by any one of formula (A-1) to formula (A-8): 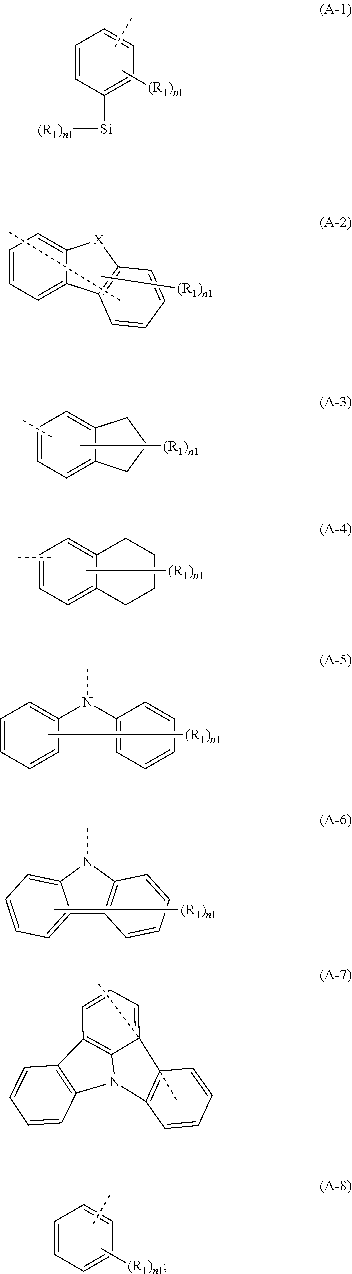
Ar₂ is selected from a group represented by any one of formula (B-1) to formula (B-9): 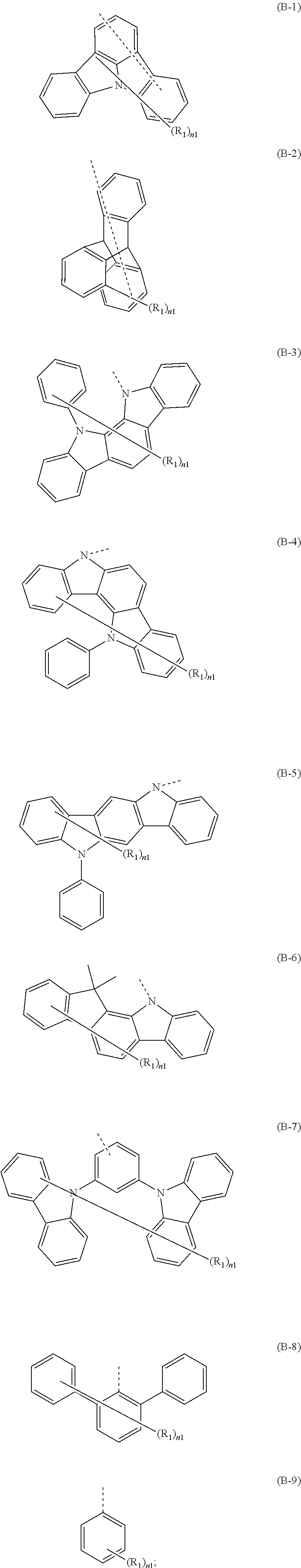
X is selected from O, S, N—CH₃, N-Ph or C(CH₃)₂;
n1 is selected from 0, 1, 2, 3, 4, 5, 6, 7, 8, 9 or 10;
R₁ is selected from H, D, a linear alkyl group having a carbon atom number ranging from 1 to 20, a linear silicon group having a carbon atom number ranging from 1 to 20, a branched silicon group having a carbon atom number ranging from 1 to 20, a linear alkoxy group having a carbon atom number ranging from 1 to 20, a linear thioalkoxy group having a carbon atom number ranging from 1 to 20, a branched alkyl group having a carbon atom number ranging from 3 to 20, a cyclic alkyl group having a carbon atom number ranging from 3 to 20, a branched alkoxy group having a carbon atom number ranging from 3 to 20, a cyclic alkoxy group having a carbon atom number ranging from 3 to 20, a branched thioalkoxy group having a carbon atom number ranging from 3 to 20, a cyclic thioalkoxy group having a carbon atom number ranging from 3 to 20, a silyl group, a trimethylsilyl group, a triphenylsilyl group, a keto group having a carbon atom number ranging from 1 to 20, an alkoxycarbonyl group having a carbon atom number ranging from 2 to 20, an aryloxycarbonyl group having a carbon atom number ranging from 7 to 20, an olefin group having a carbon atom number ranging from 1 to 20, CN, a carbamoyl group, a haloformyl group, a formyl group, isocyano, an isocyanate group, a thiocyanate group, an isothiocyanate group, a hydroxyl group, a nitro group, CF₃, Cl, Br, F, a substituted or unsubstituted aromatic group having a ring atom number ranging from 6 to 30, a substituted or unsubstituted heteroaromatic group having a ring atom number ranging from 5 to 30, a substituted or unsubstituted aryloxy group having a ring atom number ranging from 6 to 30, or a substituted or unsubstituted heteroaryloxy group having a ring atom number ranging from 5 to 30.

14. The organic light-emitting device according to claim 13, wherein the organic functional layer comprises a light-emitting layer, a material of the light-emitting layer comprises a host material and a guest material, and the guest material comprises one or more of the organic compounds.

15. The organic light-emitting device according to claim 14, wherein a mass ratio of the host material to the guest material ranges from 99:1 to 70:30.

16. An organic light-emitting device, comprising:
a first electrode;
a second electrode, disposed opposite to the first electrode; and
an organic functional layer, located between the first electrode and the second electrode;
wherein, a material of the organic functional layer comprises the mixture according to claim 10.

17. An organic light-emitting device, comprising:
a first electrode;
a second electrode, disposed opposite to the first electrode; and
an organic functional layer, located between the first electrode and the second electrode;
wherein, a material of the organic functional layer comprises the composition according to claim 11.

18. A display panel, wherein the display panel comprises the organic light-emitting device according to claim 13.

19. A display panel, wherein the display panel comprises the organic light-emitting device according to claim 16.

20. A display panel, wherein the display panel comprises the organic light-emitting device according to claim 17.
